(19) United States
(12) Patent Application Publication
(10) Pub. No.: US 2015/0194622 A1
(43) Pub. Date: Jul. 9, 2015

(54) BISCARBAZOLE DERIVATIVE HOST MATERIALS AND RED EMITTER FOR OLED EMISSIVE REGION

(71) Applicants: Hitoshi Yamamoto, Ewing, NJ (US); Michael S. Weaver, Ewing, NJ (US); Julia J. Brown, Ewing, NJ (US); Kazuki Nishimura, Tokyo (JP); Toshihiro Iwakuma, Tokyo (JP)

(72) Inventors: Hitoshi Yamamoto, Ewing, NJ (US); Michael S. Weaver, Ewing, NJ (US); Julia J. Brown, Ewing, NJ (US); Kazuki Nishimura, Tokyo (JP); Toshihiro Iwakuma, Tokyo (JP)

(73) Assignees: IDEMITSU KOSAN CO., LTD., Tokyo (JP); UNIVERSAL DISPLAY CORPORATION, Ewing, NJ (US)

(21) Appl. No.: 14/400,637

(22) PCT Filed: Jun. 14, 2012
(86) PCT No.: PCT/US2012/042356

§ 371 Date: Mar. 25, 2015

(51) Int. Cl. H01L 51/50

(52) U.S. Cl. CPC H01L 51/5016; H01L 51/0072

(57) ABSTRACT

The organic electroluminescence device utilizes a novel combination of a biscarbazole derivative compound as a phospherescent host materials and an orgaphosphorescent material as a red phosphorescent dopant material in the light emitting region of the device, where the biscarbazole derivative compound is represented by a formula (1); wherein the red phosphorescent dopant material is a phosphorescent organometallic complex having a substituted chemical structure represented by one of the partial chemical structures represented by a formulas (D1), (D2) and (D3).

### BACKGROUND OF THE INVENTION

The present invention relates to an organic electroluminescent (EL) device such as an organic light emitting device (hereinafter abbreviated as an OLED) and materials capable of being used in such an OLED. In particular, it relates to an OLED which comprises a light emitting layer which emits a red light, and materials for an OLED which are used for the same.

### RELATED ART

OLEDs which comprise an organic thin film layer which includes a light emitting layer located between an anode and a cathode are known in the art. In such devices, emission of light may be obtained from exciton energy, produced by recombination of a hole injected into a light emitting layer with an electron.

Generally, OLEDs are comprised of several organic layers in which at least one of the layers can be made to electroluminesce by applying a voltage across the device. When a voltage is applied across a device, the cathode effectively reduces the adjacent organic layers (i.e., injects electrons), and the anode effectively oxidizes the adjacent organic layers (i.e., injects holes). Holes and electrons migrate across the device toward their respective oppositely charged electrodes. When a hole and electron meet on the same molecule, recombination is said to occur, and an exciton is formed. Recombination of the hole and electron in luminescent compounds is accompanied by radiative emission, thereby producing electroluminescence.

Depending on the spin states of the hole and electron, the exciton resulting from hole and electron recombination can have either a triplet or singlet spin state. Luminescence from a singlet exciton results in fluorescence, whereas luminescence from a triplet exciton results in phosphorescence. Statistically, for organic materials typically used in OLEDs, one quarter of the excitons are singlets, and the remaining three-quarters are triplets (see, e.g., Baldo, et al., Phys. Rev. B, 1999, 60, 14422). Until the discovery that there were certain phosphorescent materials that could be used to fabricate practical electro-phosphorescent OLEDs (U.S. Pat. No. 6,303,238) and, subsequently, demonstration that such electro-phosphorescent OLEDs could have a theoretical quantum efficiency of up to 100% (i.e., harvesting all of both triplets and singlets), the most efficient OLEDs were typically based on materials that fluoresced. Fluorescent materials luminesce with a maximum theoretical quantum efficiency of only 25% (where quantum efficiency of an OLED refers to the efficiency with which holes and electrons recombine to produce luminescence), since the triplet to ground state transition of phosphorescent emission is formally a spin forbidden process. Electro-phosphorescent OLEDs have now been shown to have superior overall device efficiencies as compared with electro-fluorescent OLEDs (see, e.g., Baldo, et al., Nature, 1998, 395, 151 and Baldo, et al., Appl. Phys. Lett. 1999, 75(3), 4).

Due to strong spin-orbit coupling that leads to singlet-triplet state mixing, heavy metal complexes often display efficient phosphorescent emission from such triplets at room temperature. Accordingly, OLEDs comprising such complexes have been shown to have internal quantum efficiencies of more than 75% (Adachi, et al., Appl. Phys. Lett., 2000, 77, 904). Certain organometallic iridium complexes have been reported as having intense phosphorescence (Lamansky, et al., Inorganic Chemistry, 2001, 40, 1704), and efficient OLEDs emitting in the green to red spectrum have been prepared with these complexes (Lamansky, et al., J. Am. Chem. Soc., 2001, 123, 4304). Phosphorescent heavy metal organometallic complexes and their respective devices have been the subject of U.S. Pat. Nos. 6,830,828 and 6,902,830; U.S. Publications 2006/0202194 and 2006/0204785; and U.S. Pat. Nos. 7,001,536; 6,911,271; 6,939,624; and 6,835,469.

OLEDs, as described above, generally provide excellent luminous efficiency, image quality, power consumption and the ability to be incorporated into thin design products such as flat screens, and therefore hold many advantages over prior technology, such as cathode ray devices.

However, improved OLEDs, including, for example, the preparation of OLEDs having greater current efficiency are desirable. In this regard, light emitting materials (phosphorescent materials) have been developed in which light emission is obtained from a triplet exciton in order to enhance internal quantum efficiency.

As discussed above, such OLEDs can have a theoretical internal quantum efficiency up to 100% by using such phosphorescent materials in the light emitting layer (phosphorescent layer), and the resulting OLED will have a high efficiency and low power consumption. Such phosphorescent materials may be used as a dopant in a host material which comprises such a light emitting layer.

In a light emitting layer formed by doping with a light emitting material such as a phosphorescent material, excitons can efficiently be produced from a charge injected into a host material. Exciton energy of an exciton produced may be transferred to a dopant, and emission may be obtained from the dopant at high efficiency. Exitons may be formed either on the host materials or directly on the dopant.

In order to achieve intermolecular energy transfer from a host material to a phosphorescent dopant with high device efficiencies, the excited triplet energy EgH of the host material must be greater than the excited triplet energy EgD of the phosphorescent dopant.

In order to carry out intermolecular energy transfer from a host material to a phosphorescent dopant, an excited triplet energy Eg (T) of the host material has to be larger than an excited triplet energy Eg (S) of the phosphorescent dopant.

CBP (4,4′-bis(N-carbazolyl)biphenyl) is known to be a representative example of a material having an efficient and large excited triplet energy. See, e.g., U.S. Pat. No. 6,939,624. If CBP is used as a host material, energy can be transferred to a phosphorescent dopant having a prescribed emission wavelength, such as green, and an OLED having a high efficiency can be obtained. When CBP is used as a host material, the luminous efficiency is notably enhanced by phosphorescent emission. However, CBP is known to have a very short lifetime, and therefore it is not suitable for practical use in EL devices such as an OLED. Without being bound by scientific theory, it is believed that this is because CBP may be heavily deteriorated by a hole due to its oxidative stability not being high, in terms of molecular structure.

International Patent Application Publication WO 2005/112519 discloses a technique in which a condensed ring derivative having a nitrogen-containing ring such as carbazole and the like is used as a host material for a phosphorescent layer showing green phosphorescence. The current efficiency and the lifetime are improved by the above technique, but it is not satisfactory in a certain case for practical use.

On the other hand, a wide variety of host materials (fluorescent hosts) for a fluorescent dopant showing fluorescent emission are known, and various host materials can be proposed which, by combination with a fluorescent dopant, may form a fluorescent layer which exhibits excellent luminous efficiency and lifetime.

In a fluorescent host, an excited singlet energy Eg (S) is larger than in a fluorescent dopant, but an excited triplet energy Eg (T) of such a host is not necessarily larger. Accordingly, a fluorescent host cannot simply be used in place of a phosphorescent host as a host material to provide a phosphorescent emitting layer.

For example, anthracene derivatives are known well as a fluorescent host. However, an excited state triplet energy Eg (T) of anthracene derivatives may be as small as about 1.9 eV. Thus, energy transfer to a phosphorescent dopant having an emission wavelength in a visible light region of 500 nm to 720 nm cannot be achieved using such a host, since the excited state triplet energy would be quenched by a host having such a low triplet state energy. Accordingly, anthracene derivatives are unsuitable as a phosphorescent host.

Perylene derivatives, pyrene derivatives and naphthacene derivatives are not preferred as phosphorescent hosts for the same reason.

The use of aromatic hydrocarbon compounds as phosphorescent hosts is disclosed in Japanese Patent Application Laid-Open No. 142267/2003. That application discloses phosphorescent host compounds with a benzene skeleton core and with two aromatic substituents bonded at meta positions.

However, the aromatic hydrocarbon compounds described in Japanese Patent Application Laid-Open No. 142267/2003 assume a rigid molecular structure having a good symmetric property and provided with five aromatic rings in which molecules are arranged in a bilaterally symmetrical manner toward a central benzene skeleton. Such an arrangement has the drawback of a likelihood of crystallization of the light emitting layer.

On the other hand, OLEDs in which various aromatic hydrocarbon compounds are used are disclosed in International Patent Application Publications WO 2007/046685; Japanese Patent Application Laid-Open No. 151966/2006; Japanese Patent Application Laid-Open No. 8588/2005; Japanese Patent Application Laid-Open No. 19219/2005; Japanese Patent Application Laid-Open No. 19219/2005; and Japanese Patent Application Laid-Open No. 75567/2004. However, the efficiency of these materials as a phosphorescent host is not disclosed.

In addition, OLEDs prepared by using various fluorene compounds are disclosed in Japanese Patent Application Laid-Open No. 043349/2004; Japanese Patent Application Laid-Open No. 314506/2007; and Japanese Patent Application Laid-Open No. 042485/2004. However, the effectiveness of these materials as a phosphorescent host is not disclosed.

Further, Japanese Patent Application Laid-Open No. 042485/2004 discloses hydrocarbon compounds in which a condensed polycyclic aromatic ring is bonded directly to a fluorene ring. However, the effectiveness of an OLED prepared by combining such materials with a phosphorescent material is not disclosed, and the application discloses perylene and pyrene rings which are known to have a small triplet energy level as condensed polycyclic aromatic rings, and which are not preferred for use as a light emitting layer of a phosphorescent device, and materials which are effective for a phosphorescent device are not selected.

Despite the recent advancements in OLED technology, there remains a need for host materials which can transfer energy to a phosphorescent material with high efficiency and with an extended lifetime.

### SUMMARY OF THE INVENTION

One embodiment of the present disclosure provides an organic electroluminescence device such as an OLED that utilizes a novel combination of biscarbazole derivative compound as a host compound in the light emitting region of the device and an organometallic phosphorescent material as a dopant in the light emitting region of the device. The organic electroluminescence device of the present disclosure comprises a cathode, an anode, and a plurality of organic thin-film layers provided between the cathode and the anode. The plurality of organic thin-film layers comprises at least one emitting layer. At least one of the emitting layers comprises a red phosphorescent dopant material and a host material that is a biscarbazole derivative compound represented by a formula (1) below:

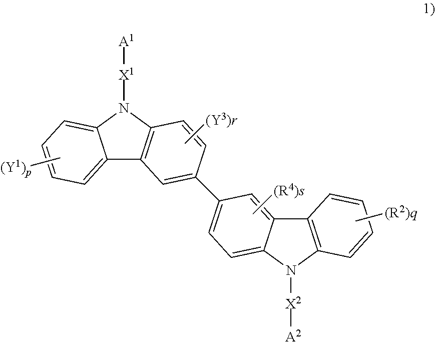

where A¹ represents a substituted or unsubstituted nitrogen-containing heterocyclic group having 1 to 30 ring carbon atoms;

A² represents a substituted or unsubstituted aromatic hydrocarbon group having 6 to 30 ring carbon atoms, or substituted or unsubstituted nitrogen-containing heterocyclic group having 1 to 30 ring carbon atoms;

X¹ and X² each are a linking group and independently represent a single bond, substituted or unsubstituted aromatic hydrocarbon group having 6 to 30 ring carbon atoms, substituted or unsubstituted fused aromatic hydrocarbon group having 6 to 30 ring carbon atoms, substituted or unsubstituted aromatic heterocyclic group having 2 to 30 ring carbon atoms, or substituted or unsubstituted fused aromatic heterocyclic group having 2 to 30 ring carbon atoms;

Y¹ to Y⁴ independently represent a hydrogen atom, fluorine atom, cyano group, substituted or unsubstituted alkyl group having 1 to 20 carbon atoms, substituted or unsubstituted alkoxy group having 1 to 20 carbon atoms, substituted or unsubstituted haloalkyl group having 1 to 20 carbon atoms, substituted or unsubstituted haloalkoxy group having 1 to 20 carbon atoms, substituted or unsubstituted alkylsilyl having 1 to 10 carbon atoms, substituted or unsubstituted arylsilyl having 6 to 30 carbon atoms, substituted or unsubstituted aromatic hydrocarbon group having 6 to 30 ring carbon atoms, substituted or unsubstituted fused aromatic hydrocarbon group having 6 to 30 ring carbon atoms, substituted or unsubstituted aromatic heterocyclic group having 2 to 30 ring carbon atoms, or substituted or unsubstituted fused aromatic heterocyclic group having 2 to 30 ring carbon atoms;

adjacent ones of Y¹ to Y⁴ are allowed to be bonded to each other to form a ring structure;

p and q represent an integer of 1 to 4; r and s represent an integer of 1 to 3; and

when p and q are an integer of 2 to 4 and r and s are an integer of 2 to 3, a plurality of Y¹ to Y⁴ are allowed to be the same or different;

wherein the red phosphorescent dopant material is a phosphorescent organometallic complex having a substituted chemical structure represented by one of the following partial chemical structures represented by the following formulas (D1), (D2), and (D3):

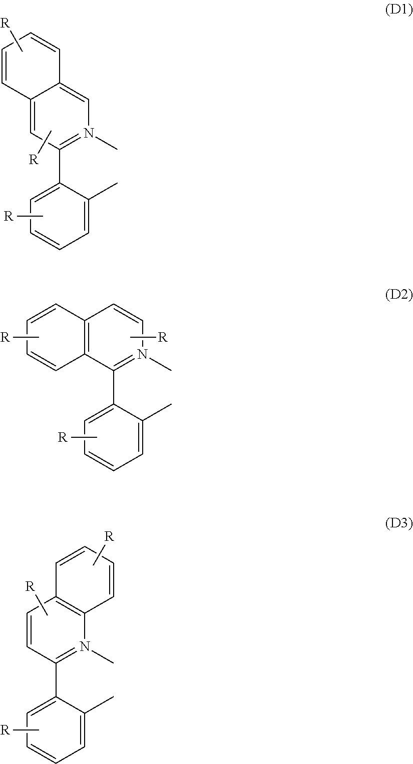

where each R is independently selected from the group consisting of H, alkyl, alkenyl, alkynyl, alkylaryl, CN, CF₃, CₙF₂₊₁, trifluorovinyl, CO₂R, C(O)R, NR₂, NO₂, OR, halo, aryl, heteroaryl, substituted aryl, substituted heteroaryl or a heterocyclic group.

As used herein, “hydrogen atom” includes hydrogen isotopes such as protium, deuterium, and tritium.

In another embodiment, the organic electroluminescence device comprises a cathode, an anode, and a plurality of organic thin-film layers provided between the cathode and the anode. The plurality of organic thin-film layers comprises at least one emitting layer and the at least one of the emitting layers comprises a first host material, a second host material that is different from the first host material and a red phosphorescent dopant material. The first host material is a biscarbazole derivative compound represented by the formula (1) below:

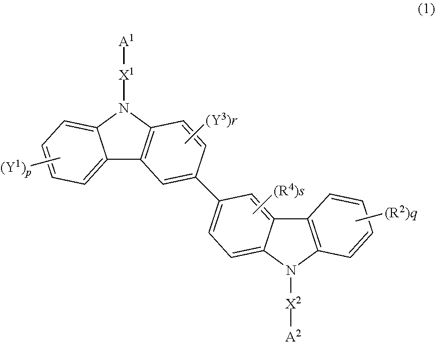

wherein A¹ represents a substituted or unsubstituted nitrogen-containing heterocyclic group having 1 to 30 ring carbon atoms;
A² represents a substituted or unsubstituted aromatic hydrocarbon group having 6 to 30 ring carbon atoms, or substituted or unsubstituted nitrogen-containing heterocyclic group having 1 to 30 ring carbon atoms;

X¹ and X² each are a linking group and independently represent a single bond, substituted or unsubstituted aromatic hydrocarbon group having 6 to 30 ring carbon atoms, substituted or unsubstituted fused aromatic hydrocarbon group having 6 to 30 ring carbon atoms, substituted or unsubstituted aromatic heterocyclic group having 2 to 30 ring carbon atoms, or substituted or unsubstituted fused aromatic heterocyclic group having 2 to 30 ring carbon atoms;

Y¹ to Y⁴ independently represent a hydrogen atom, fluorine atom, cyano group, substituted or unsubstituted alkyl group having 1 to 20 carbon atoms, substituted or unsubstituted alkoxy group having 1 to 20 carbon atoms, substituted or unsubstituted haloalkyl group having 1 to 20 carbon atoms, substituted or unsubstituted haloalkoxy group having 1 to 20 carbon atoms, substituted or unsubstituted alkylsilyl having 1 to 10 carbon atoms, substituted or unsubstituted arylsilyl having 6 to 30 carbon atoms, substituted or unsubstituted aromatic hydrocarbon group having 6 to 30 ring carbon atoms, substituted or unsubstituted fused aromatic hydrocarbon group having 6 to 30 ring carbon atoms, substituted or unsubstituted aromatic heterocyclic group having 2 to 30 ring carbon atoms, or substituted or unsubstituted fused aromatic heterocyclic group having 2 to 30 ring carbon atoms;

adjacent ones of Y¹ to Y⁴ are allowed to be bonded to each other to form a ring structure;

p and q represent an integer of 1 to 4; r and s represent an integer of 1 to 3; and
when p and q are an integer of 2 to 4 and r and s are an integer of 2 to 3, a plurality of Y¹ to Y⁴ are allowed to be the same or different;

wherein the red phosphorescent dopant material is a phosphorescent organometallic complex having a substituted chemical structure represented by one of the following partial chemical structures represented by the formulas (D1), (D2), and (D3):

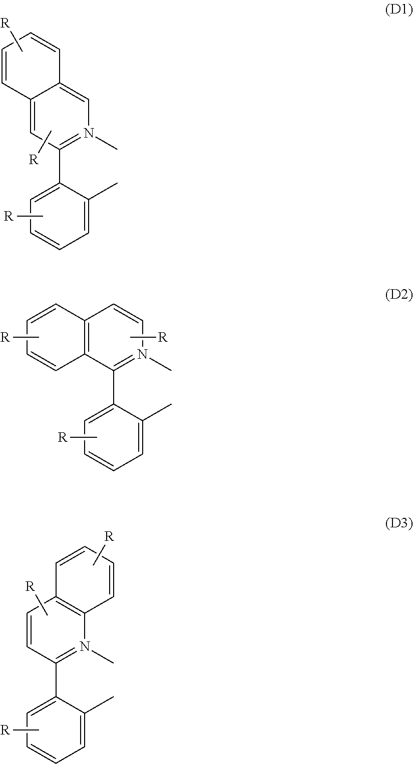

where each R is independently selected from the group consisting of H, alkyl, alkenyl, alkynyl, alkylaryl, CN, CF₃, CₙF₂ₙ₊₁, trifluorovinyl, CO₂R, C(O)R, NR₂, NO₂, OR, halo, aryl, heteroaryl, substituted aryl, substituted heteroaryl or a heterocyclic group.

The inventors have found that the organic EL devices comprising the host materials and phosphorescent dopant materials combination according to the present disclosure exhibit low voltage requirement with high luminous efficiency. Additionally, the devices comprising the combination of the co-host materials and the phosphorescent dopant materials in the emitting layer according to the present disclosure are expected to exhibit an additional benefit of improved life time of more than 3 times when compared to a single-host example device.

A luminous efficiency and a lifetime of the multilayered organic EL device depend on a carrier balance of the entire organic EL device. The main factors that control the carrier balance are carrier transporting capability of each of the organic layers and carrier injecting capability in the interfacial region of separate organic layers. The combination of the co-host materials and the phosphorescent dopant materials can provide an improved charge carrier balance of the entire organic EL device by putting two of positive hole transportability materials and electronic transportability materials together. The provision of such co-host materials can reduce deterioration by the carrier invasion to the adjacent layer.

For example, the emitter host materials disclosed in the present disclosure can function well not only as a single host in an emitter layer but also as a co-host material in combination with a second host material that is different from them. By providing two compounds as a host material in the emitter layer, the carrier injecting capability to neighboring layers in the emitting layer (recombination region) can be balanced.

The combination of the emitter layer host material and the red phosphorescent dopant material of the present disclosure resulted in an organic EL device having an enhanced life.

### BRIEF DESCRIPTION OF THE DRAWING

FIG. 1 is a schematic drawing of an exemplary arrangement for an OLED according to an exemplary embodiment of the present disclosure.

### DETAILED DESCRIPTION

The OLEDs of the present invention may comprise a plurality of layers located between an anode and a cathode. Representative OLEDs according to the invention include, but are not limited to, structures having constituent layers as described below:

(1) anode/light emitting layer/cathode;
(2) anode/hole injecting layer/light emitting layer/cathode;
(3) anode/light emitting layer/electron injecting•transporting layer/cathode;
(4) anode/hole injecting layer/light emitting layer/electron injecting•transporting layer/cathode;
(5) anode/organic semiconductor layer/light emitting layer/cathode;
(6) anode/organic semiconductor layer/electron blocking layer/light emitting layer/cathode;
(7) anode/organic semiconductor layer/light emitting layer/adhesion improving layer/cathode;
(8) anode/hole injecting•transporting layer/light emitting layer/electron injecting•transporting layer/cathode;
(9) anode/insulating layer/light emitting layer/insulating layer/cathode;
(10) anode/inorganic semiconductor layer/insulating layer/light emitting layer/insulating layer/cathode;
(11) anode/organic semiconductor layer/insulating layer/light emitting layer/insulating layer/cathode;
(12) anode/insulating layer/hole injecting•transporting layer/light emitting layer/insulating layer/cathode; and
(13) anode/insulating layer/hole injecting•transporting layer/light emitting layer/electron injecting•transporting layer/cathode.

Among the OLED constituent structures described above, constituent structure number (8) is a preferred structure, but the present invention is not limited to these disclosed constituent structures.

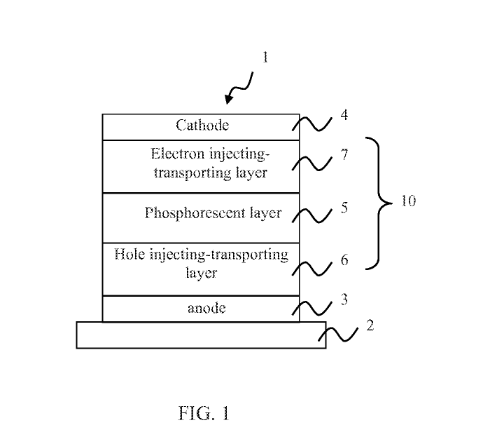

FIG. 1 shows an OLED 1 according to an embodiment. The OLED 1 comprises a transparent substrate 2, an anode 3, a cathode 4 and a plurality of organic thin film layers 10 disposed between the anode 3 and the cathode 4. At least one of the plurality of organic thin film layers 10 is a phosphorescence emitting layer 5 comprising one or more phosphorescent host material and a phosphorescent dopant material.

The plurality of organic thin film layers 10 can include other layers such as a hole injecting•transporting layer 6 and the like between the phosphorescence emitting layer 5 and the anode 3. The plurality of organic thin film layers 10 can also include layers such as an electron injecting•transporting layer 7 and the like between the phosphorescence emitting layer 5 and the cathode 4.

Further, there may be provided respectively an electron blocking layer disposed between the anode 3 and the phosphorescence emitting layer 5, and a hole blocking layer disposed between the cathode 4 and the phosphorescence emitting layer 5. This makes it possible to contain electrons and holes in the phosphorescence emitting layer 5 to enhance the production rate of excitons in the phosphorescence emitting layer 5.

In the present disclosure, the term “phosphorescent host” is used to refer to a host material that functions as a phosphorescent host when combined with a phosphorescent dopant and should not be limited to a classification of the host material based solely on molecular structure.

Thus, a phosphorescent host means a material constituting the phosphorescence emitting layer containing a phosphorescent dopant and does not mean a material which can be used only for a host of a phosphorescent material. A phosphorescence emitting layer is also referred to herein as a light emitting layer.

In the present specification, “a hole injecting•transporting layer” means at least either one of a hole injecting layer and a hole transporting layer, and “an electron injecting•transporting layer” means at least either one of an electron injecting layer and an electron transporting layer.

### [Substrate]

The OLED of the present disclosure may be prepared on a substrate. The substrate referred to in this case is a substrate for supporting the OLED, and it is preferably a flat substrate in which light in the visible region of about 400 to about 700 nm has a transmittance of at least about 50%.

The substrate may include a glass plate, a polymer plate and the like. In particular, the glass plate may include soda lime glass, barium•strontium-containing glass, lead glass, aluminosilicate glass, borosilicate glass, barium borosilicate glass, quartz and the like. The polymer plate may include polycarbonate, acryl, polyethylene terephthalate, polyether sulfide, polysulfone and the like.

### [Anode and Cathode]

An anode in the OLED of the present disclosure assumes the role of injecting a hole into the hole injecting layer, the hole transporting layer or the light emitting layer. Typically the anode has a work function of 4.5 eV or more.

Specific examples of a material suitable for use as the anode include indium tin oxide alloy (ITO), tin oxide (NESA glass), indium zinc oxide, gold, silver, platinum, copper and the like. The anode can be prepared by forming a thin film from electrode substances, such as those discussed above, by a method such as a vapor deposition method, a sputtering method and the like.

When light is emitted from the light emitting layer, the transmittance of light in the visible light region in the anode is preferably larger than 10%. The sheet resistance of the anode is preferably several hundred a/square or less. The film thickness of the anode is selected, depending on the material, and is typically in the range of from about 10 nm to about 1 μm, and preferably from about 10 nm to about 200 nm.

The cathode comprises preferably a material having a small work function for the purpose of injecting an electron into the electron injecting layer, the electron transporting layer or the light emitting layer. Materials suitable for use as the cathode include, but are not limited to indium, aluminum, magnesium, magnesium-indium alloys, magnesium-aluminum alloys, aluminum-lithium alloys, aluminum-scandium-lithium alloys, magnesium-silver alloys and the like. For transparent or top-emitting devices, a TOLED cathode such as disclosed in U.S. Pat. No. 6,548,956 is preferred.

The cathode can be prepared, as is the case with the anode, by forming a thin film by a method such as a vapor deposition method, a sputtering method and the like. Further, an embodiment in which light emission is taken out from a cathode side can be employed as well.

### [Light Emitting Layer According to First Embodiment]

The light emitting layer in the OLED of the present disclosure may be capable of carrying out the following functions singly or in combination:
(1) injecting function: a function in which a hole can be injected from an anode or a hole injecting layer in applying an electric field and in which an electron can be injected from a cathode or an electron injecting layer;
(2) transporting function: a function in which a charge (electron and hole) injected may be transferred by virtue of a force of an electric field; and
(3) light emitting function: a function in which a region for recombination of an electron and a hole may be provided, and which results in the emission of light.

A difference may be present between ease of injection of a hole and ease of injection of an electron, and a difference may be present in the transporting ability shown by the mobilities of a hole and an electron.

Known methods including, for example, vapor deposition, spin coating, Langmuir Blodgett methods and the like can be used to prepare the light emitting layer. The light emitting layer is preferably a molecularly deposited film. In this regard, the term “molecularly deposited film” means a thin film formed by depositing a compound from the gas phase and a film formed by solidifying a material compound in a solution state or a liquid phase state, and usually the above-referenced molecular deposit film can be distinguished from a thin film (molecular accumulation film) formed by an LB method by a difference in an aggregation structure and a higher order structure and a functional difference originating in it.

In preferred embodiments, the film thickness of the light emitting layer is preferably from about 5 to about 50 nm, more preferably from about 7 to about 50 nm and most preferably from about 10 to about 50 nm. If the film thickness is less than 5 nm, it is likely to be difficult to form the light emitting layer and control the chromaticity. On the other hand, if it exceeds about 50 nm, the operating voltage is likely to go up.

### [Biscarbazole Derivative as a Host Material in a Single-Host Device]

The plurality of organic thin-film layers 10 in the OLED 1 according to an embodiment of the present disclosure comprises at least one light emitting layer. At least one of the light emitting layers comprises a novel combination of a biscarbazole derivative compound as a host material in the light emitting region of the device and an organometallic red phostphorescent material as a dopant in the light emitting region. The at least one of the emitting layers comprises a red phosphorescent dopant material and a host material that is a biscarbazole derivative compound represented by a formula (1) below:

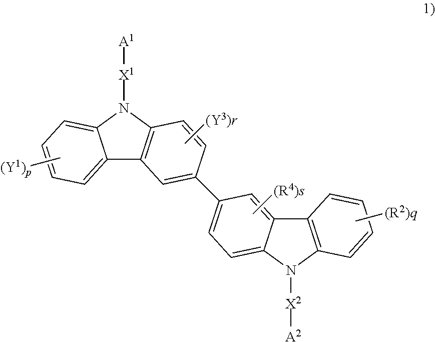

wherein A¹ represents a substituted or unsubstituted nitrogen-containing heterocyclic group having 1 to 30 ring carbon atoms;

A² represents a substituted or unsubstituted aromatic hydrocarbon group having 6 to 30 ring carbon atoms, or substituted or unsubstituted nitrogen-containing heterocyclic group having 1 to 30 ring carbon atoms;

X¹ and X² each are a linking group and independently represent a single bond, substituted or unsubstituted aromatic hydrocarbon group having 6 to 30 ring carbon atoms, substituted or unsubstituted fused aromatic hydrocarbon group having 6 to 30 ring carbon atoms, substituted or unsubstituted aromatic heterocyclic group having 2 to 30 ring carbon atoms, or substituted or unsubstituted fused aromatic heterocyclic group having 2 to 30 ring carbon atoms;

Y¹ to Y⁴ independently represent a hydrogen atom, fluorine atom, cyano group, substituted or unsubstituted alkyl group having 1 to 20 carbon atoms, substituted or unsubstituted alkoxy group having 1 to 20 carbon atoms, substituted or unsubstituted haloalkyl group having 1 to 20 carbon atoms, substituted or unsubstituted haloalkoxy group having 1 to 20 carbon atoms, substituted or unsubstituted alkylsilyl having 1 to 10 carbon atoms, substituted or unsubstituted arylsilyl having 6 to 30 carbon atoms, substituted or unsubstituted aromatic hydrocarbon group having 6 to 30 ring carbon atoms, substituted or unsubstituted fused aromatic hydrocarbon group having 6 to 30 ring carbon atoms, substituted or unsubstituted aromatic heterocyclic group having 2 to 30 ring carbon atoms, or substituted or unsubstituted fused aromatic heterocyclic group having 2 to 30 ring carbon atoms;

adjacent ones of Y¹ to Y⁴ are allowed to be bonded to each other to form a ring structure;

p and q represent an integer of 1 to 4; r and s represent an integer of 1 to 3; and

when p and q are an integer of 2 to 4 and r and s are an integer of 2 to 3, a plurality of Y¹ to Y⁴ are allowed to be the same or different.

According to another aspect of the present disclosure, the A¹ in the host material of formula (1) is preferably selected from the group consisting of a substituted or unsubstituted pyridine ring, substituted or unsubstituted pyrimidine ring and substituted or unsubstituted triazine ring. The A¹ in the host material of formula (1) is more preferably selected from a substituted or unsubstituted pyrimidine ring or substitute or unsubstituted triazine ring. The A¹ in the host material of formula (1) is particularly preferably a substituted or unsubstituted quinazoline ring.

According to an aspect of the present disclosure, the host material is preferably a biscarbazole derivative compound represented by a formula (2) below:

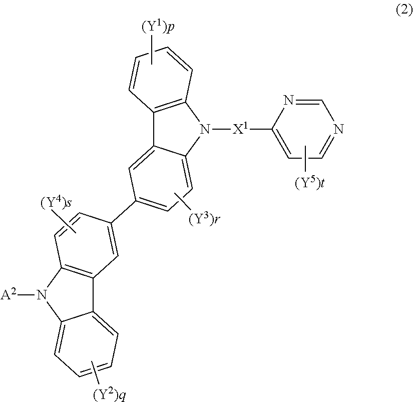

where A², X¹, Y¹ to Y⁴, p, q, r and s represent the same as A², X¹, Y¹ to Y⁴, p, q, r and s of the formula (1); Y⁵ represents the same as Y¹ to Y⁴ of the formula (1); t represents an integer in a range of 1 to 3; and when t is an integer of 2 to 3, a plurality of Y⁵ are allowed to be the same or different.

In the host material of the formulas (1) and (2), when Y¹ to Y⁴ are bonded to each other to form a ring structure, the ring structure is exemplified by structures represented by one of the following formulas:

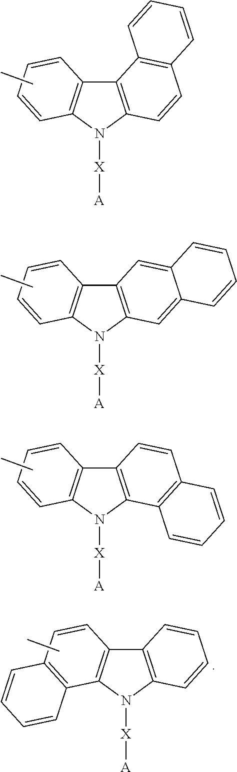

In the formula (2) for the host material, A² is preferably a nitrogen-containing heterocyclic group. More preferably, A² is a substituted or unsubstituted aromatic heterocyclic group having 2 to 30 ring carbon atoms, or substituted or unsubstituted fused aromatic heterocyclic group having 2 to 30 ring carbon atoms.

In the formulas (1) and (2) for the host material, X¹ is preferably a single bond or a substituted or unsubstituted divalent aromatic hydrocarbon group having 6 to 30 ring carbon atoms, more preferably a substituted or unsubstituted divalent aromatic hydrocarbon group having 6 to 30 ring carbon atoms, particularly preferably a benzene ring or naphthalene ring.

When X¹ is a substituted or unsubstituted benzene ring in the formulas (1) and (2), A¹ and the carbazolyl group, which are bonded to X¹, are preferably in meta positions or para positions. Particularly preferably, X¹ is unsubstituted para-phenylene.

In the formulas (1) and (2) for the host material, the pyridine ring, pyrimidine ring and triazine ring are more preferably represented by the following formulas. In the formulas, Y and Y′ represent a substituent. Examples of the substituent are the same groups as those represented by Y¹ to Y⁴ as described above. Y and Y′ may be the same or different. Preferred examples thereof are the substituted or unsubstituted aromatic hydrocarbon group or fused aromatic hydrocarbon group having 6 to 30 ring carbon atoms, and the substituted or unsubstituted aromatic heterocyclic group or fused aromatic heterocyclic group having 2 to 30 ring carbon atoms. In the following formulas, * represents a bonding position to X¹ or X².

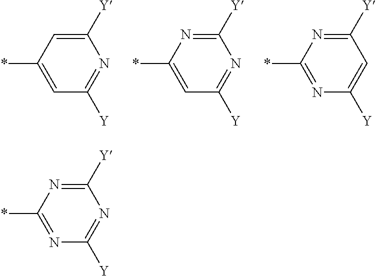

In the formulas (1) and (2) for the host material, the quinazoline ring is represented by the following formula. Y represents a substituent. u represents an integer of 1 to 5. When u is an integer of 2 to 5, a plurality of Y may be the same or different. As the substituent Y, the same groups as those for the above Y¹ to Y⁴ are usable, among which preferred examples thereof are the substituted or unsubstituted aromatic hydrocarbon group or fused aromatic hydrocarbon group having 6 to 30 ring carbon atoms, and the substituted or unsubstituted aromatic heterocyclic group or fused aromatic heterocyclic group having 2 to 30 ring carbon atoms. Also in the following formulae, * represents a bonding position to X¹ or X².

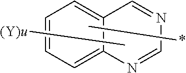

In the formulas (1) and (2) for the host material, the alkyl group, alkoxy group, haloalkyl group, haloalkoxy group and alkylsilyl group, which are represented by Y¹ to Y⁵, may be linear, branched or cyclic.

In the formulas (1) and (2) for the host material, examples of the alkyl group having 1 to 20 carbon atoms are a methyl group, ethyl group, propyl group, isopropyl group, n-butyl group, s-butyl group, isobutyl group, t-butyl group, n-pentyl group, n-hexyl group, n-heptyl group, n-octyl group, n-nonyl group, n-decyl group, n-undecyl group, n-dodecyl group, n-tridecyl group, n-tetradecyl group, n-pentadecyl group, n-hexadecyl group, n-heptadecyl group, n-octadecyl group, neo-pentyl group, 1-methylpentyl group, 2-methylpentyl group, 1-pentylhexyl group, 1-butylpentyl group, 1-heptyloctyl group, 3-methylpentyl group, cyclopentyl group, cyclohexyl group, cycloheptyl group, cyclooctyl group and 3,5-tetramethylcyclohexyl group. Examples of the alkyl group having 1 to 10 carbon atoms are a methyl group, ethyl group, propyl group, isopropyl group, n-butyl group, s-butyl group, isobutyl group, t-butyl group, cyclopentyl group, cyclohexyl group and cycloheptyl group.

As the alkoxy group having 1 to 20 carbon atoms, an alkoxy group having 1 to 6 carbon atoms is preferable and specific examples thereof are a methoxy group, ethoxy group, propoxy group, butoxy group, pentyloxy group, and hexyloxy group.

The haloalkyl group having 1 to 20 carbon atoms is exemplified by an haloalkyl group provided by substituting the alkyl group having 1 to 20 carbon atoms with one or more halogen atoms. Preferred one of the halogen atoms is fluorine. The haloalkyl group is exemplified by a trifluoromethyl group and a 2,2,2-trifluoroethyl group.

The haloalkoxy group having 1 to 20 carbon atoms is exemplified by a haloalkoxy group provided by substituting the alkoxy group having 1 to 20 carbon atoms with one or more halogen atoms.

Some examples of the alkylsilyl group having 1 to 10 carbon atoms are a trimethylsilyl group, triethylsilyl group, tributylsilyl group, dimethylethylsilyl group, dimethylisopropylsilyl group, dimethylpropylsilyl group, dimethylbutylsilyl group, dimethyl-tertiary-butylsilyl group and diethylisopropylsilyl group.

Some examples of the arylsilyl group having 6 to 30 carbon atoms are a phenyldimethylsilyl group, diphenylmethylsilyl group, diphenyl-tertiary-butylsilyl group and triphenylsilyl group.

Some examples of the aromatic heterocyclic group or fused aromatic heterocyclic group having 2 to 30 ring carbon atoms are a pyroryl group, pyrazinyl group, pyridinyl group, indolyl group, isoindolyl group, furyl group, benzofuranyl group, isobenzofuranyl group, dibenzofuranyl group, dibenzothiophenyl group, quinolyl group, isoquinolyl group, quinoxalinyl group, carbazolyl group, phenantridinyl group, acridinyl group, phenanthrolinyl group, thienyl group and a group formed from a pyridine ring, pyrazine ring, pyrimidine ring, pyridazine ring, triazine ring, indol ring, quinoline ring, acridine ring, pirrolidine ring, dioxane ring, piperidine ring, morpholine ring, piperadine ring, carbazole ring, furan ring, thiophene ring, oxazole ring, oxadiazole ring, benzooxazole ring, thiazole ring, thiadiazole ring, benzothiazole ring, triazole ring, imidazole ring, benzoimidazole ring, pyrane ring and dibenzofuran ring. Among the above, the aromatic heterocyclic group or fused aromatic heterocyclic group having 2 to 10 ring carbon atoms is preferable.

Some examples of the aromatic hydrocarbon group or fused aromatic hydrocarbon group having 6 to 30 ring carbon atoms are a phenyl group, naphthyl group, phenanthryl group, biphenyl group, terphenyl group, quarterphenyl group, fluoranthenyl group, triphenylenyl group, phenanthrenyl group, pyrenyl group, chrysenyl group, fluorenyl group, and 9,9-dimethylfluorenyl group. Among the above, the aromatic hydrocarbon group or fused aromatic hydrocarbon group having 6 to 20 ring carbon atoms is preferable.

When A¹, A², X¹, X² and Y¹ to Y⁵ of the formulas (1) to (2) each have one or more substituents, the substituents are preferably a linear, branched or cyclic alkyl group having 1 to 20 carbon atoms; linear, branched or cyclic alkoxy group having 1 to 20 carbon atoms; linear, branched or cyclic haloalkyl group having 1 to 20 carbon atoms; linear, branched or cyclic alkylsilyl group having 1 to 10 carbon atoms; arylsilyl group having 6 to 30 ring carbon atoms; cyano group; halogen atom; aromatic hydrocarbon group or fused aromatic hydrocarbon group having 6 to 30 ring carbon atoms; or aromatic heterocyclic group or fused aromatic heterocyclic group having 2 to 30 ring carbon atoms.

Some examples of the linear, branched or cyclic alkyl group having 1 to 20 carbon atoms; linear, branched or cyclic alkoxy group having 1 to 20 carbon atoms; linear, branched or cyclic haloalkyl group having 1 to 20 carbon atoms; linear, branched or cyclic alkylsilyl group having 1 to 10 carbon atoms; arylsilyl group having 6 to 30 ring carbon atoms; aromatic hydrocarbon group or fused aromatic hydrocarbon group having 6 to 30 ring carbon atoms; and aromatic heterocyclic group or fused aromatic heterocyclic group having 2 to 30 ring carbon atoms are the above-described groups. The halogen atom is exemplified by a fluorine atom.

Some examples of compounds for the biscarbazole derivative according to the exemplary embodiment represented by the formulas (1) or (2) are as follows:

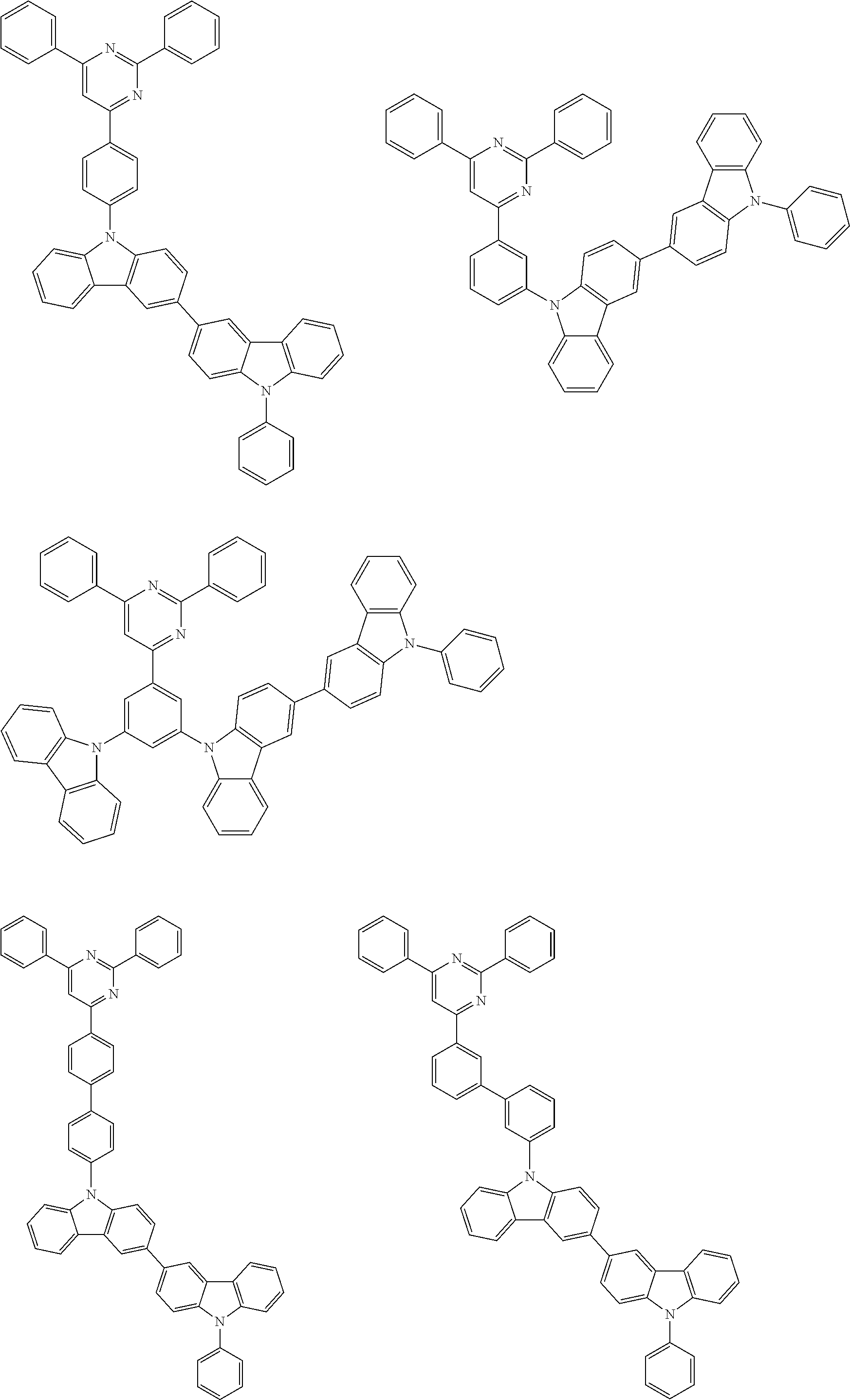

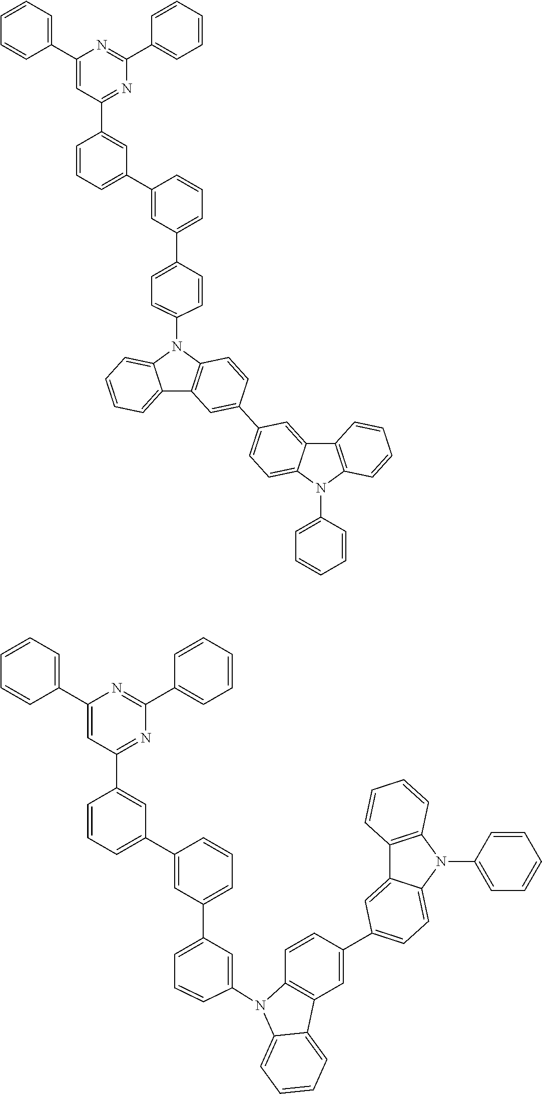 [SMILES: c1ccc(-c2cc(-c3cccc(-c4cccc(-c5ccc(-n6c7ccccc7c7cc(-c8ccc9c(c8)c8ccccc8n9-c8ccccc8)ccc76)cc5)c4)c3)nc(-c3ccccc3)n2)cc1 ; c1ccc(-c2cc(-c3cccc(-c4cccc(-c5cccc(-n6c7ccccc7c7cc(-c8ccc9c(c8)c8ccccc8n9-c8ccccc8)ccc76)c5)c4)c3)nc(-c3ccccc3)n2)cc1]

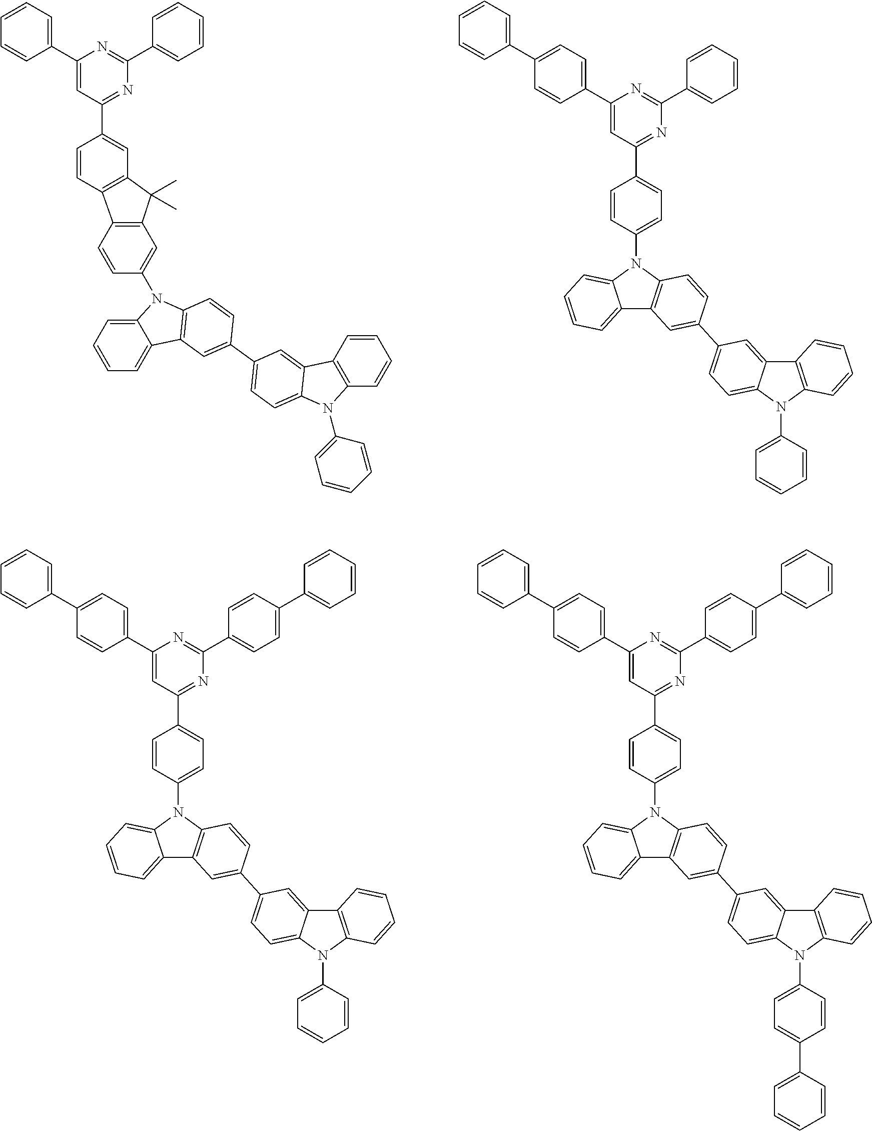 [SMILES: CC1(C)c2cc(-c3cc(-c4ccccc4)nc(-c4ccccc4)n3)ccc2-c2ccc(-n3c4ccccc4c4cc(-c5ccc6c(c5)c5ccccc5n6-c5ccccc5)ccc43)cc21 ; c1ccc(-c2ccc(-c3cc(-c4ccc(-n5c6ccccc6c6cc(-c7ccc8c(c7)c7ccccc7n8-c7ccccc7)ccc65)cc4)nc(-c4ccccc4)n3)cc2)cc1 ; c1ccc(-c2ccc(-c3cc(-c4ccc(-n5c6ccccc6c6cc(-c7ccc8c(c7)c7ccccc7n8-c7ccccc7)ccc65)cc4)nc(-c4ccc(-c5ccccc5)cc4)n3)cc2)cc1 ; c1ccc(-c2ccc(-c3cc(-c4ccc(-n5c6ccccc6c6cc(-c7ccc8c(c7)c7ccccc7n8-c7ccc(-c8ccccc8)cc7)ccc65)cc4)nc(-c4ccc(-c5ccccc5)cc4)n3)cc2)cc1]

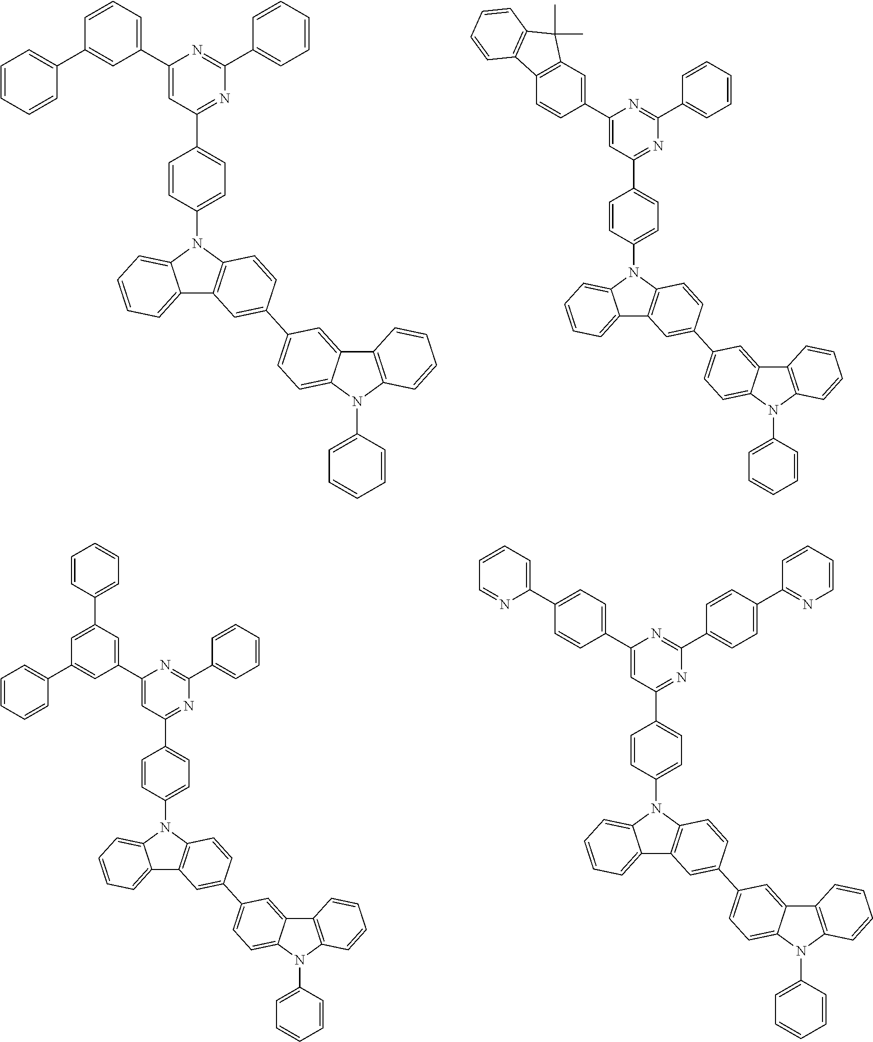 [SMILES: c1ccc(-c2cccc(-c3cc(-c4ccc(-n5c6ccccc6c6cc(-c7ccc8c(c7)c7ccccc7n8-c7ccccc7)ccc65)cc4)nc(-c4ccccc4)n3)c2)cc1 ; CC1(C)c2ccccc2-c2ccc(-c3cc(-c4ccc(-n5c6ccccc6c6cc(-c7ccc8c(c7)c7ccccc7n8-c7ccccc7)ccc65)cc4)nc(-c4ccccc4)n3)cc21 ; c1ccc(-c2cc(-c3ccccc3)cc(-c3cc(-c4ccc(-n5c6ccccc6c6cc(-c7ccc8c(c7)c7ccccc7n8-c7ccccc7)ccc65)cc4)nc(-c4ccccc4)n3)c2)cc1 ; c1ccc(-n2c3ccccc3c3cc(-c4ccc5c(c4)c4ccccc4n5-c4ccc(-c5cc(-c6ccc(-c7ccccn7)cc6)nc(-c6ccc(-c7ccccn7)cc6)n5)cc4)ccc32)cc1]

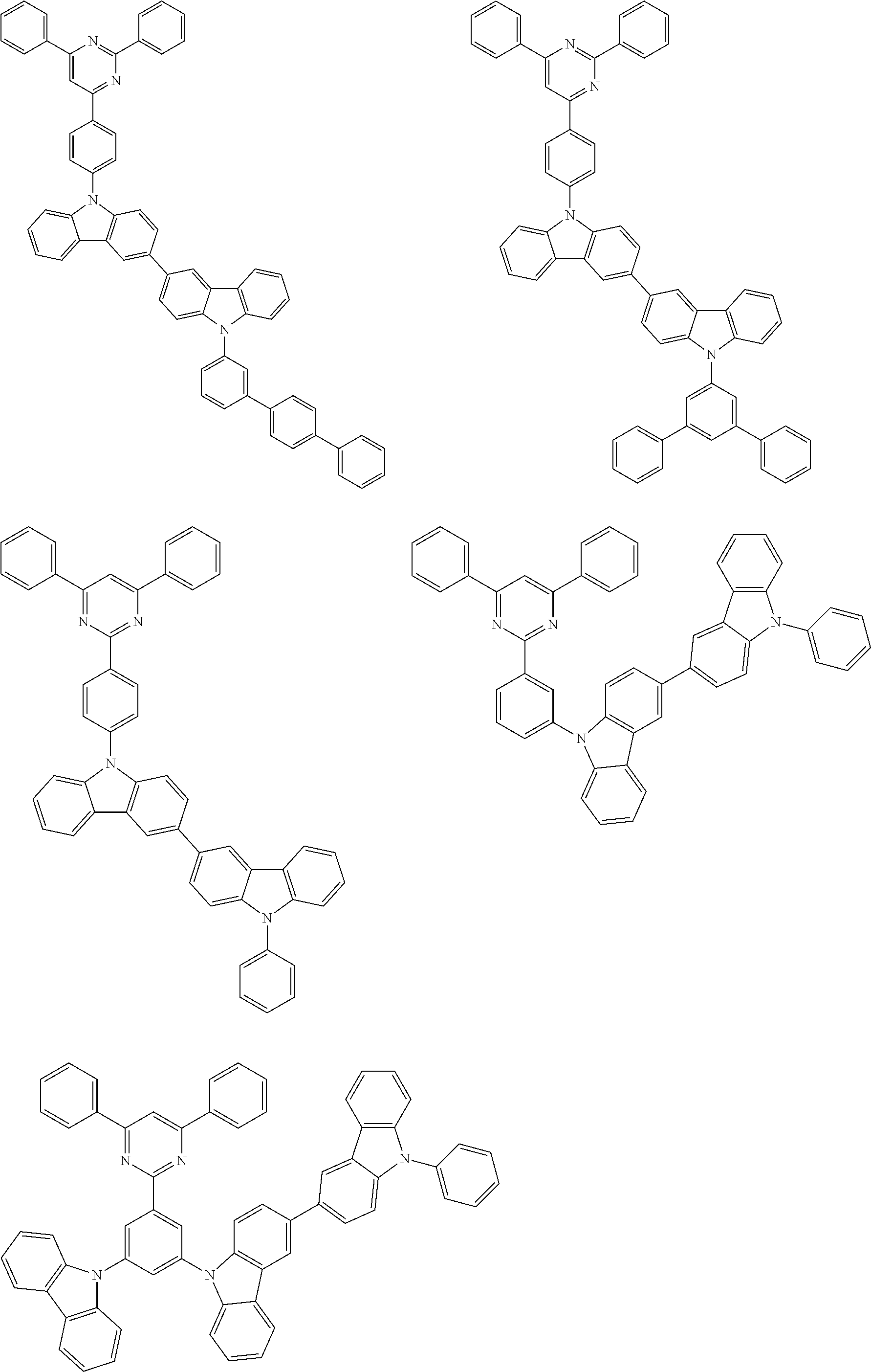

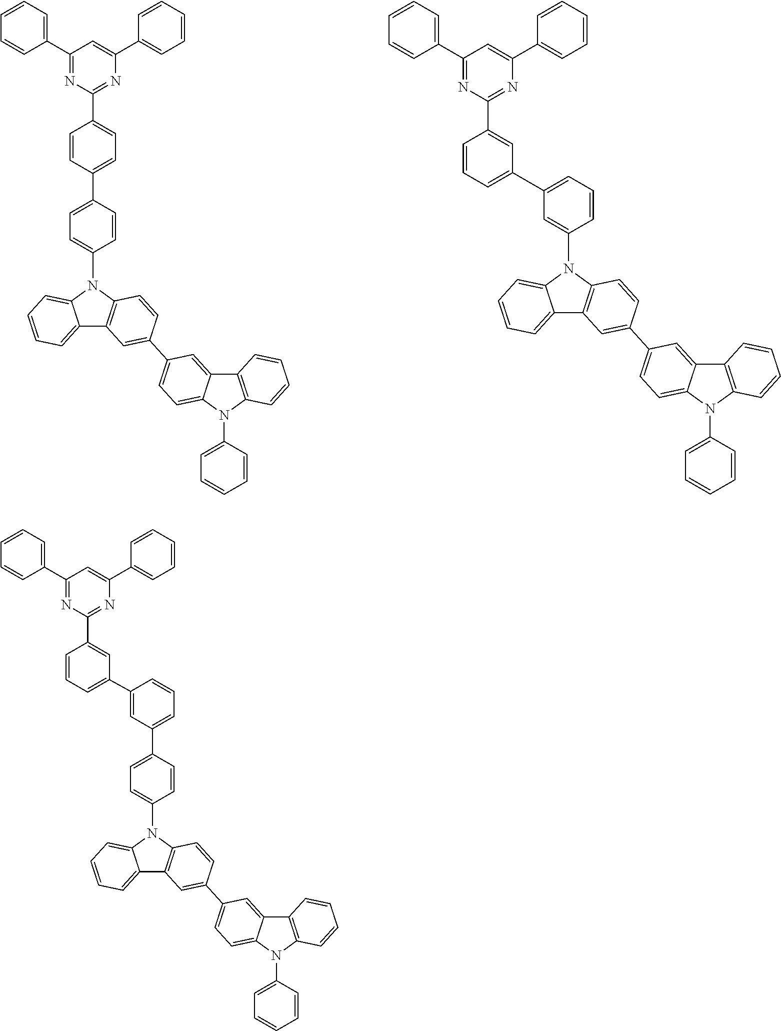 [SMILES: c1ccc(-c2cc(-c3ccccc3)nc(-c3ccc(-c4ccc(-n5c6ccccc6c6cc(-c7ccc8c(c7)c7ccccc7n8-c7ccccc7)ccc65)cc4)cc3)n2)cc1 ; c1ccc(-c2cc(-c3ccccc3)nc(-c3cccc(-c4cccc(-n5c6ccccc6c6cc(-c7ccc8c(c7)c7ccccc7n8-c7ccccc7)ccc65)c4)c3)n2)cc1 ; c1ccc(-c2cc(-c3ccccc3)nc(-c3cccc(-c4cccc(-c5ccc(-n6c7ccccc7c7cc(-c8ccc9c(c8)c8ccccc8n9-c8ccccc8)ccc76)cc5)c4)c3)n2)cc1]

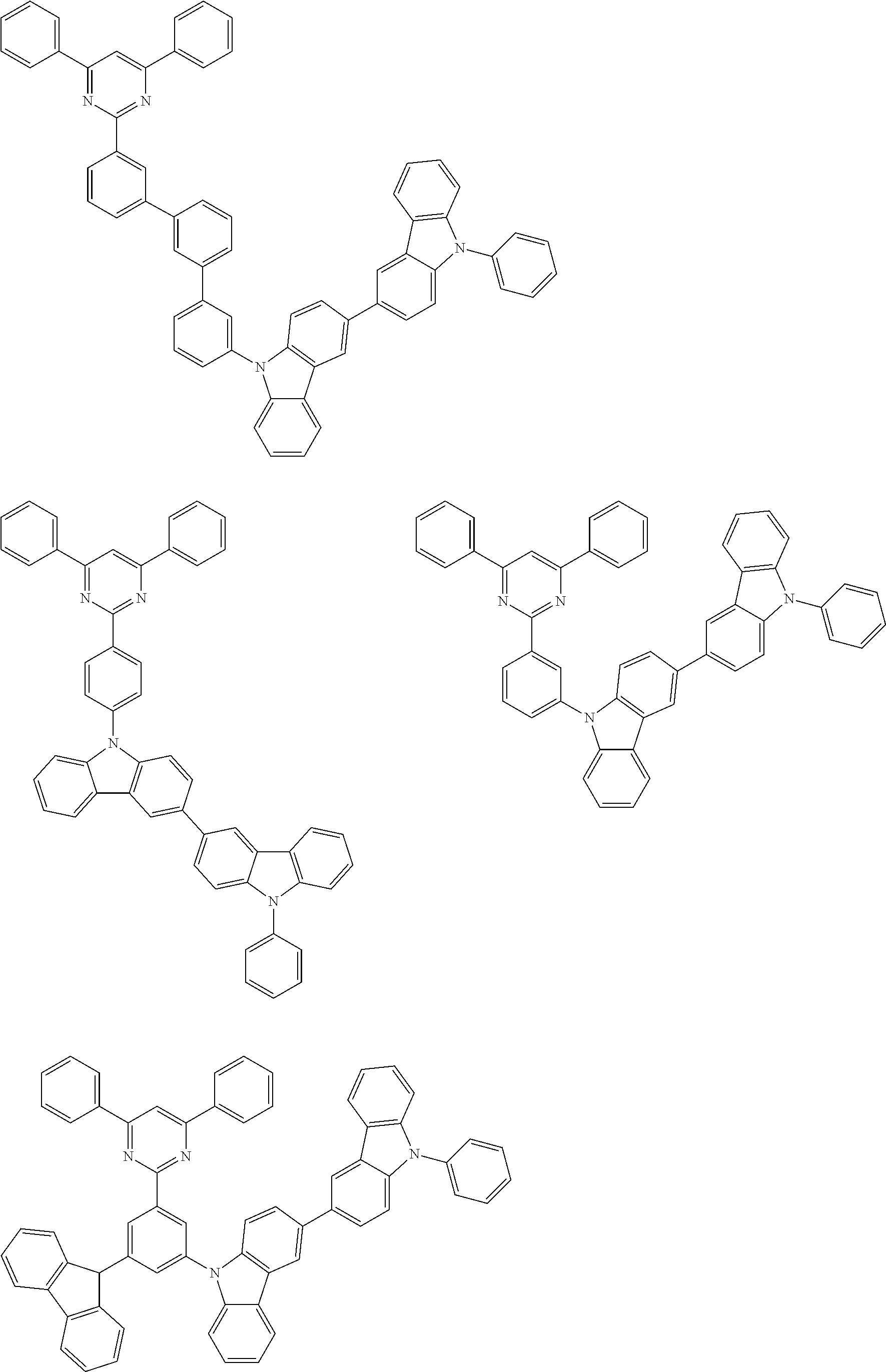 [SMILES: c1ccc(-c2cc(-c3ccccc3)nc(-c3cccc(-c4cccc(-c5cccc(-n6c7ccccc7c7cc(-c8ccc9c(c8)c8ccccc8n9-c8ccccc8)ccc76)c5)c4)c3)n2)cc1 ; c1ccc(-c2cc(-c3ccccc3)nc(-c3ccc(-n4c5ccccc5c5cc(-c6ccc7c(c6)c6ccccc6n7-c6ccccc6)ccc54)cc3)n2)cc1 ; c1ccc(-c2cc(-c3ccccc3)nc(-c3cccc(-n4c5ccccc5c5cc(-c6ccc7c(c6)c6ccccc6n7-c6ccccc6)ccc54)c3)n2)cc1 ; c1ccc(-c2cc(-c3ccccc3)nc(-c3cc(C4c5ccccc5-c5ccccc54)cc(-n4c5ccccc5c5cc(-c6ccc7c(c6)c6ccccc6n7-c6ccccc6)ccc54)c3)n2)cc1]

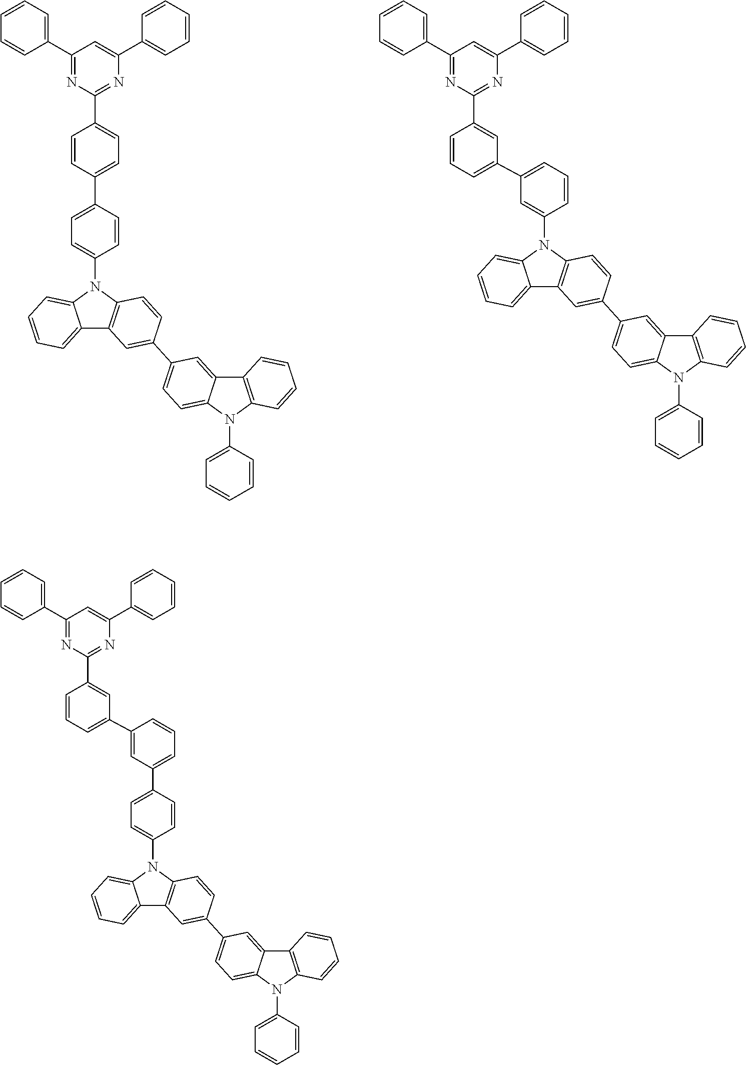 [SMILES: c1ccc(-c2cc(-c3ccccc3)nc(-c3ccc(-c4ccc(-n5c6ccccc6c6cc(-c7ccc8c(c7)c7ccccc7n8-c7ccccc7)ccc65)cc4)cc3)n2)cc1 ; c1ccc(-c2cc(-c3ccccc3)nc(-c3cccc(-c4cccc(-n5c6ccccc6c6cc(-c7ccc8c(c7)c7ccccc7n8-c7ccccc7)ccc65)c4)c3)n2)cc1 ; c1ccc(-c2cc(-c3ccccc3)nc(-c3cccc(-c4cccc(-c5ccc(-n6c7ccccc7c7cc(-c8ccc9c(c8)c8ccccc8n9-c8ccccc8)ccc76)cc5)c4)c3)n2)cc1]

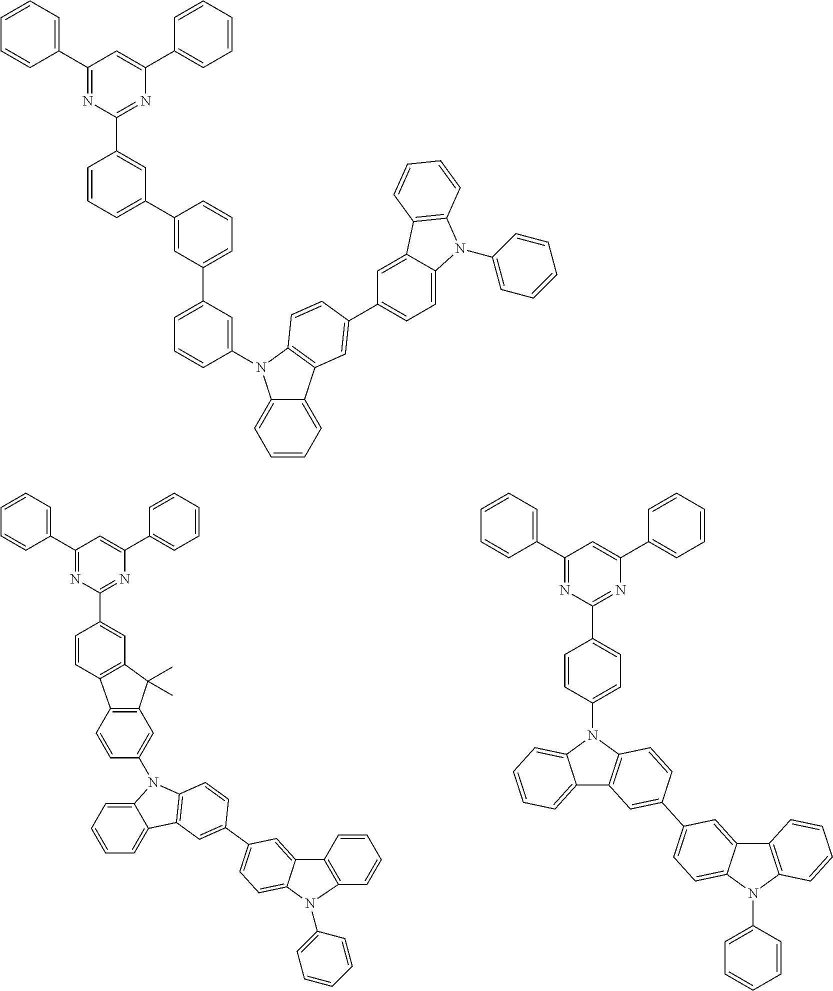 [SMILES: c1ccc(-c2cc(-c3ccccc3)nc(-c3cccc(-c4cccc(-c5cccc(-n6c7ccccc7c7cc(-c8ccc9c(c8)c8ccccc8n9-c8ccccc8)ccc76)c5)c4)c3)n2)cc1 ; CC1(C)c2cc(-c3nc(-c4ccccc4)cc(-c4ccccc4)n3)ccc2-c2ccc(-n3c4ccccc4c4cc(-c5ccc6c(c5)c5ccccc5n6-c5ccccc5)ccc43)cc21 ; c1ccc(-c2cc(-c3ccccc3)nc(-c3ccc(-n4c5ccccc5c5cc(-c6ccc7c(c6)c6ccccc6n7-c6ccccc6)ccc54)cc3)n2)cc1]

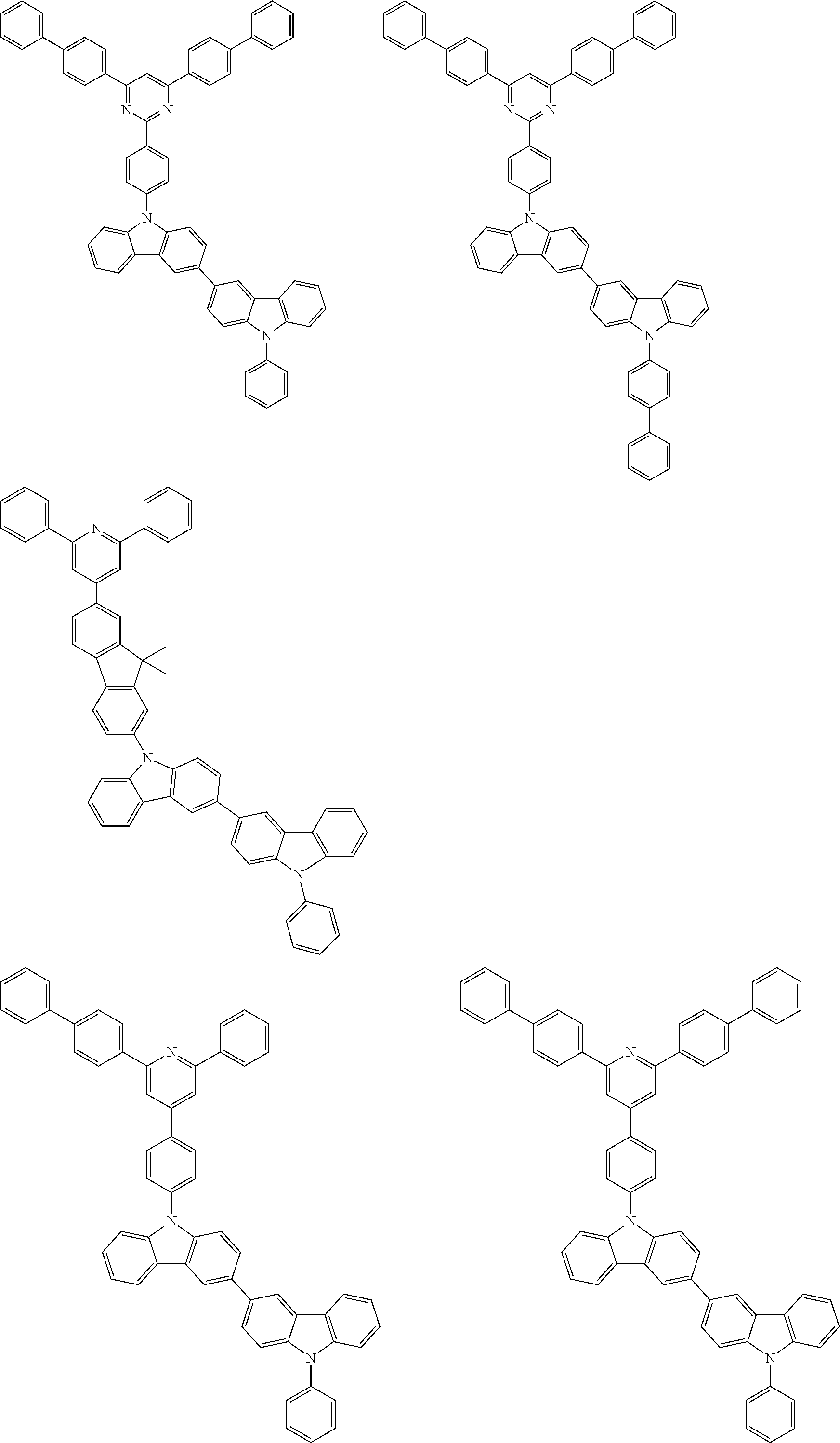

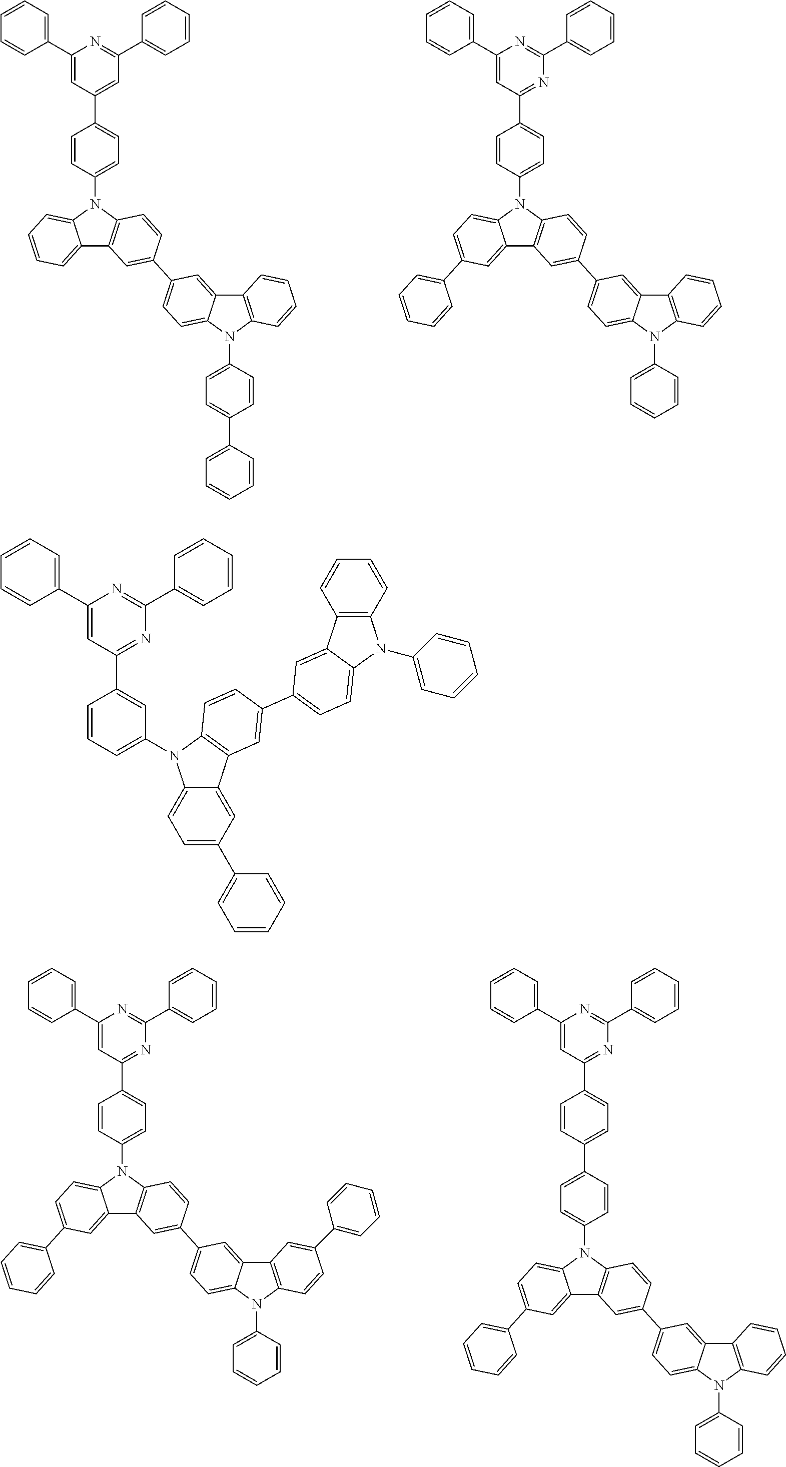

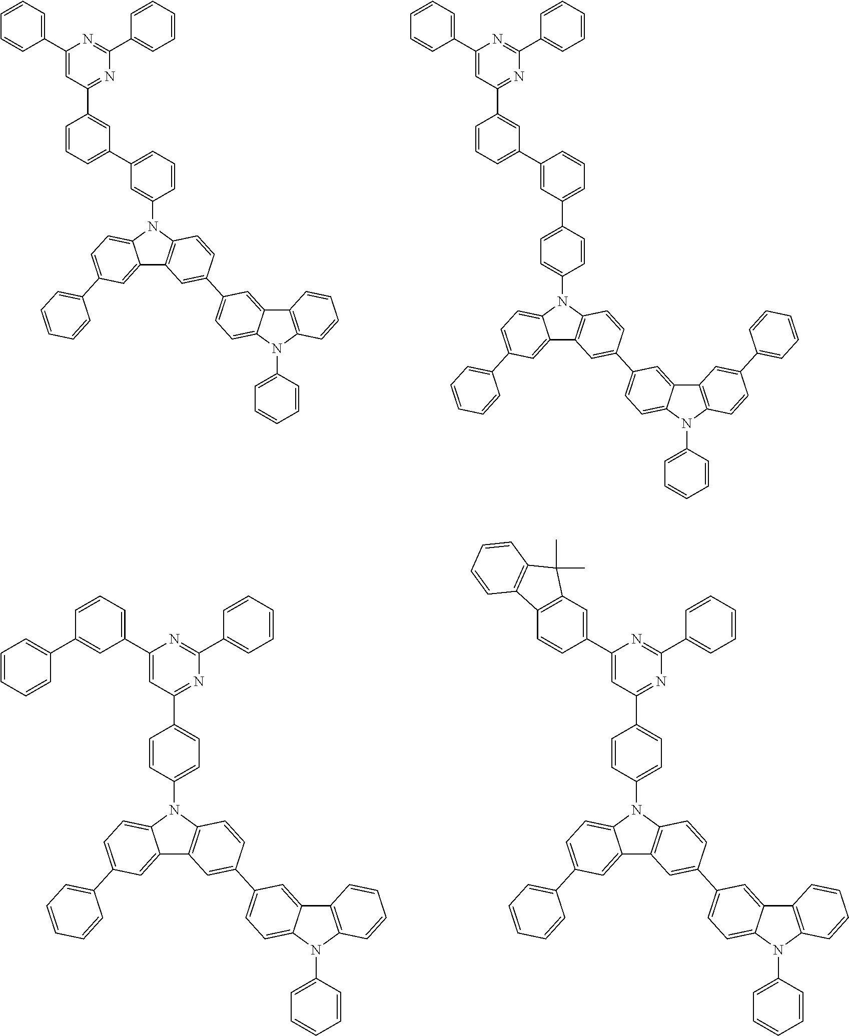

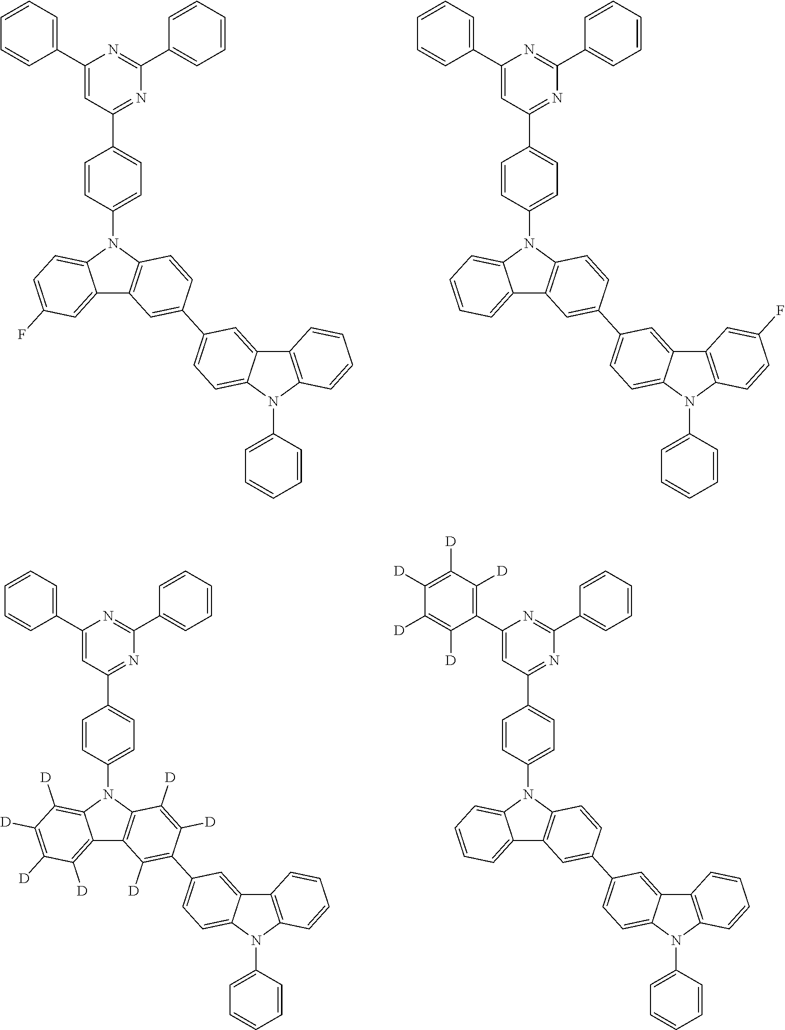 [SMILES: Fc1ccc2c(c1)c1cc(-c3ccc4c(c3)c3ccccc3n4-c3ccccc3)ccc1n2-c1ccc(-c2cc(-c3ccccc3)nc(-c3ccccc3)n2)cc1 ; Fc1ccc2c(c1)c1cc(-c3ccc4c(c3)c3ccccc3n4-c3ccc(-c4cc(-c5ccccc5)nc(-c5ccccc5)n4)cc3)ccc1n2-c1ccccc1 ; [2H]c1c([2H])c([2H])c2c(c1[2H])c1c([2H])c(-c3ccc4c(c3)c3ccccc3n4-c3ccccc3)c([2H])c([2H])c1n2-c1ccc(-c2cc(-c3ccccc3)nc(-c3ccccc3)n2)cc1 ; [2H]c1c([2H])c([2H])c(-c2cc(-c3ccc(-n4c5ccccc5c5cc(-c6ccc7c(c6)c6ccccc6n7-c6ccccc6)ccc54)cc3)nc(-c3ccccc3)n2)c([2H])c1[2H]]

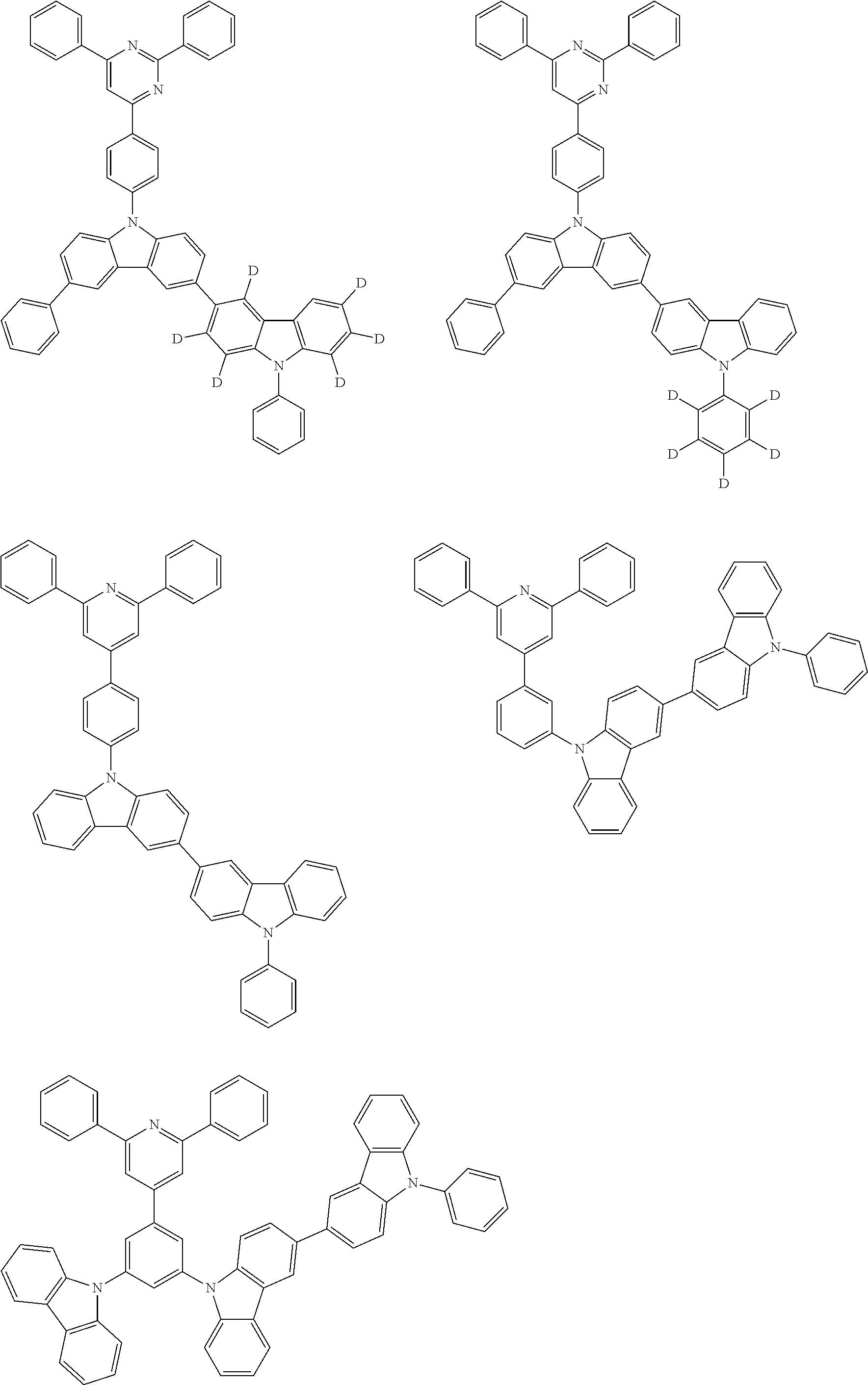

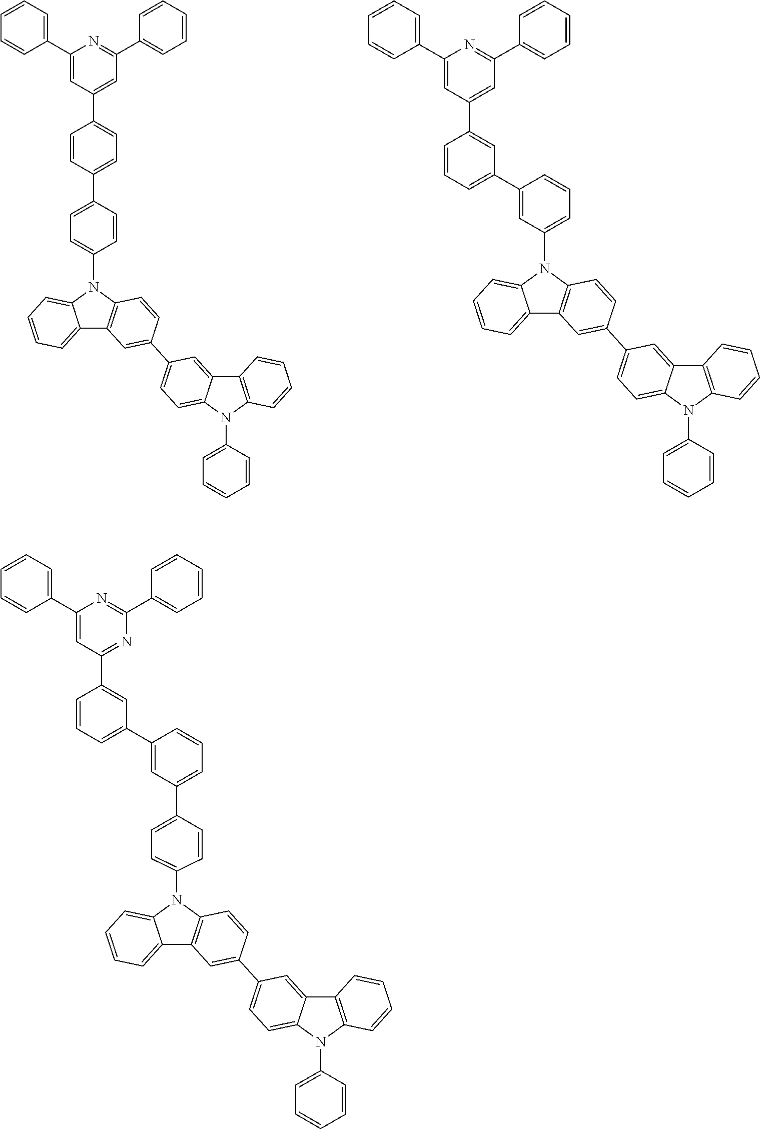 [SMILES: c1ccc(-c2cc(-c3ccc(-c4ccc(-n5c6ccccc6c6cc(-c7ccc8c(c7)c7ccccc7n8-c7ccccc7)ccc65)cc4)cc3)cc(-c3ccccc3)n2)cc1 ; c1ccc(-c2cc(-c3cccc(-c4cccc(-n5c6ccccc6c6cc(-c7ccc8c(c7)c7ccccc7n8-c7ccccc7)ccc65)c4)c3)cc(-c3ccccc3)n2)cc1 ; c1ccc(-c2cc(-c3cccc(-c4cccc(-c5ccc(-n6c7ccccc7c7cc(-c8ccc9c(c8)c8ccccc8n9-c8ccccc8)ccc76)cc5)c4)c3)nc(-c3ccccc3)n2)cc1]

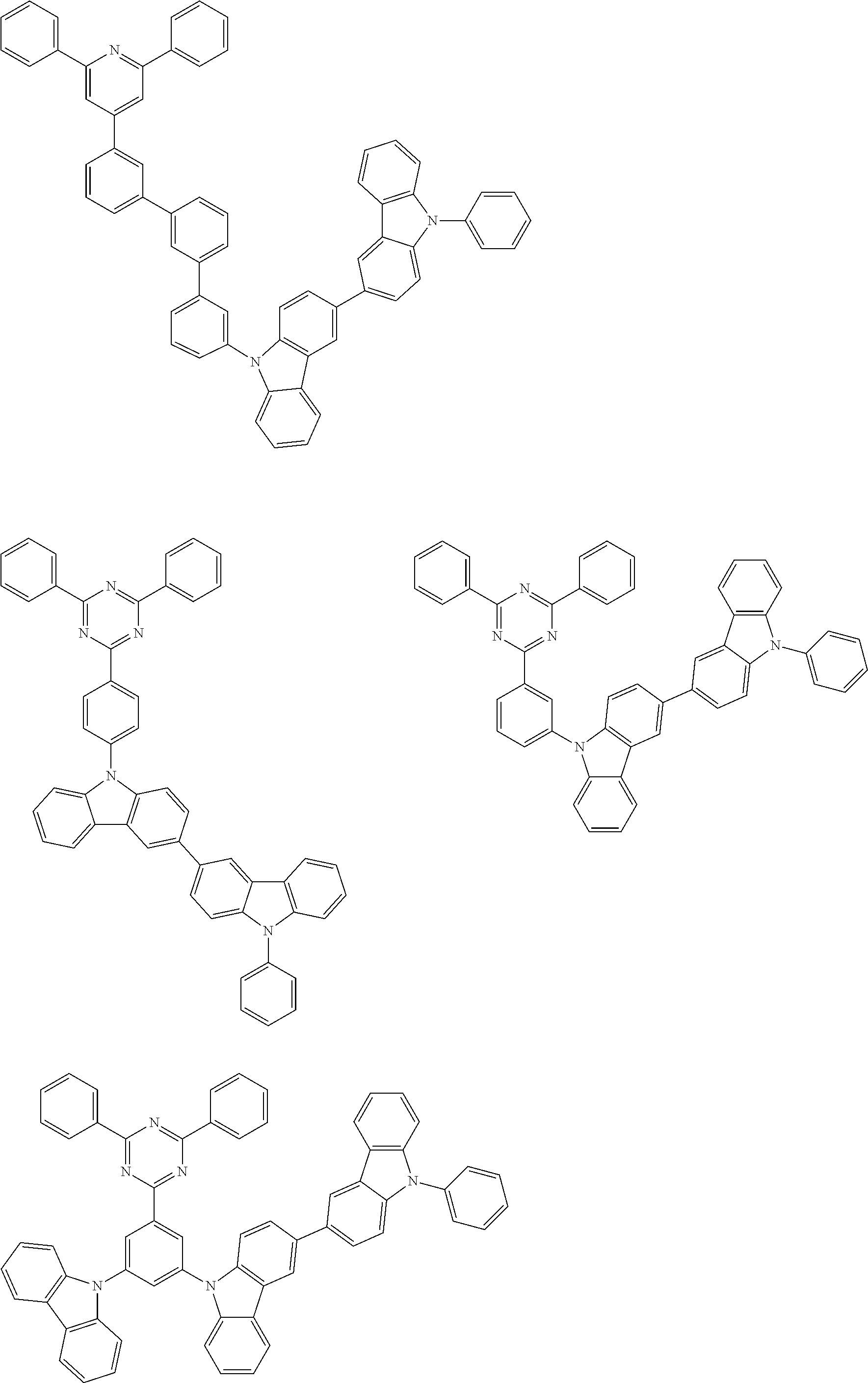 [SMILES: c1ccc(-c2cc(-c3cccc(-c4cccc(-c5cccc(-n6c7ccccc7c7cc(-c8ccc9c(c8)c8ccccc8n9-c8ccccc8)ccc76)c5)c4)c3)cc(-c3ccccc3)n2)cc1 ; c1ccc(-c2nc(-c3ccccc3)nc(-c3ccc(-n4c5ccccc5c5cc(-c6ccc7c(c6)c6ccccc6n7-c6ccccc6)ccc54)cc3)n2)cc1 ; c1ccc(-c2nc(-c3ccccc3)nc(-c3cccc(-n4c5ccccc5c5cc(-c6ccc7c(c6)c6ccccc6n7-c6ccccc6)ccc54)c3)n2)cc1 ; c1ccc(-c2nc(-c3ccccc3)nc(-c3cc(-n4c5ccccc5c5ccccc54)cc(-n4c5ccccc5c5cc(-c6ccc7c(c6)c6ccccc6n7-c6ccccc6)ccc54)c3)n2)cc1]

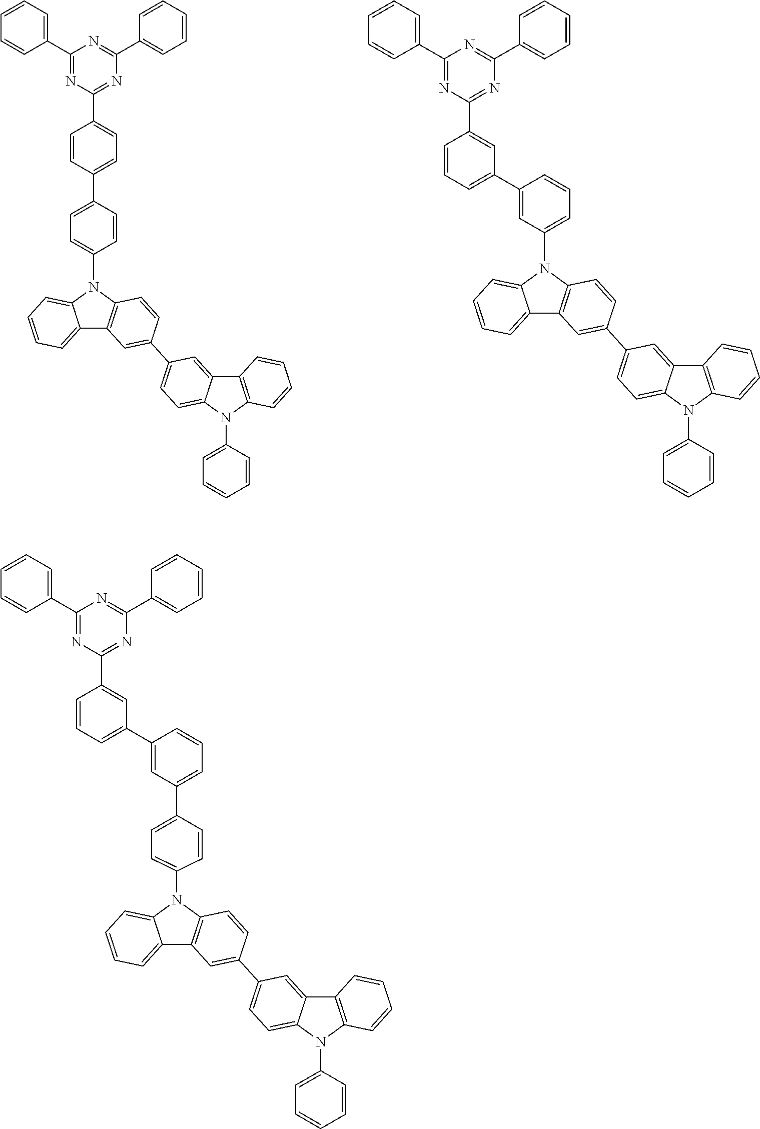 [SMILES: c1ccc(-c2nc(-c3ccccc3)nc(-c3ccc(-c4ccc(-n5c6ccccc6c6cc(-c7ccc8c(c7)c7ccccc7n8-c7ccccc7)ccc65)cc4)cc3)n2)cc1 ; c1ccc(-c2nc(-c3ccccc3)nc(-c3cccc(-c4cccc(-n5c6ccccc6c6cc(-c7ccc8c(c7)c7ccccc7n8-c7ccccc7)ccc65)c4)c3)n2)cc1 ; c1ccc(-c2nc(-c3ccccc3)nc(-c3cccc(-c4cccc(-c5ccc(-n6c7ccccc7c7cc(-c8ccc9c(c8)c8ccccc8n9-c8ccccc8)ccc76)cc5)c4)c3)n2)cc1]

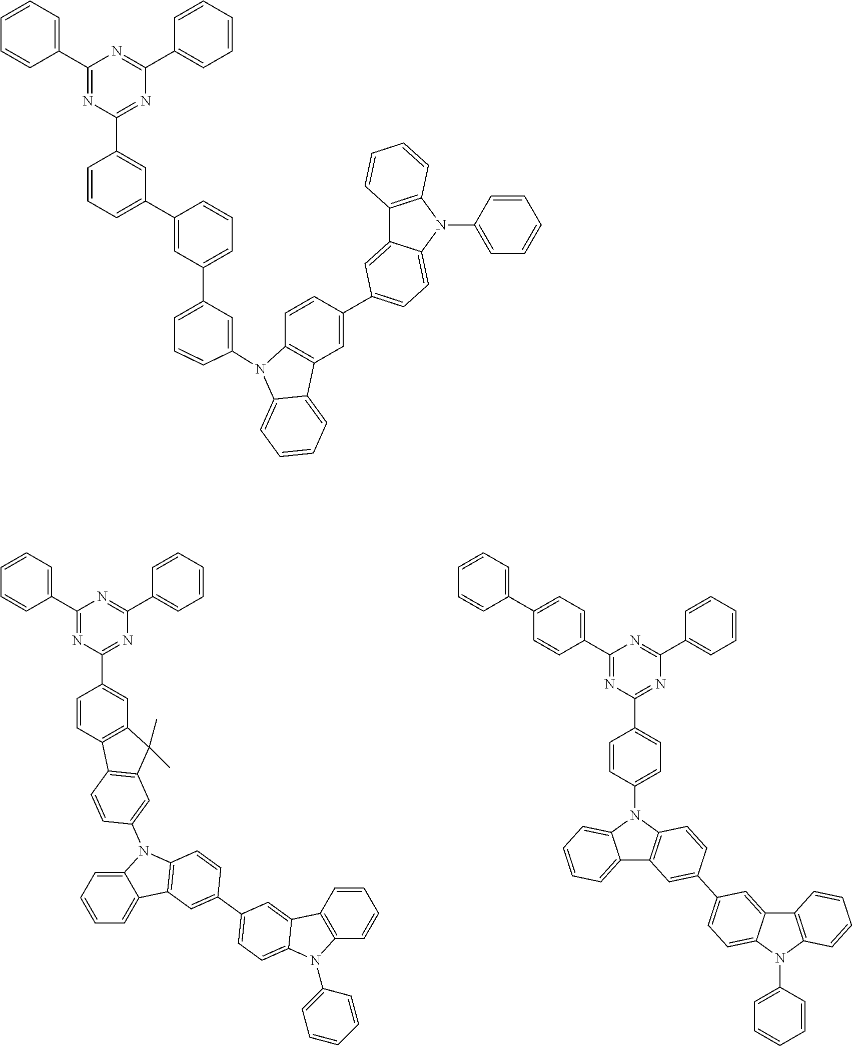 [SMILES: c1ccc(-c2nc(-c3ccccc3)nc(-c3cccc(-c4cccc(-c5cccc(-n6c7ccccc7c7cc(-c8ccc9c(c8)c8ccccc8n9-c8ccccc8)ccc76)c5)c4)c3)n2)cc1 ; CC1(C)c2cc(-c3nc(-c4ccccc4)nc(-c4ccccc4)n3)ccc2-c2ccc(-n3c4ccccc4c4cc(-c5ccc6c(c5)c5ccccc5n6-c5ccccc5)ccc43)cc21 ; c1ccc(-c2ccc(-c3nc(-c4ccccc4)nc(-c4ccc(-n5c6ccccc6c6cc(-c7ccc8c(c7)c7ccccc7n8-c7ccccc7)ccc65)cc4)n3)cc2)cc1]

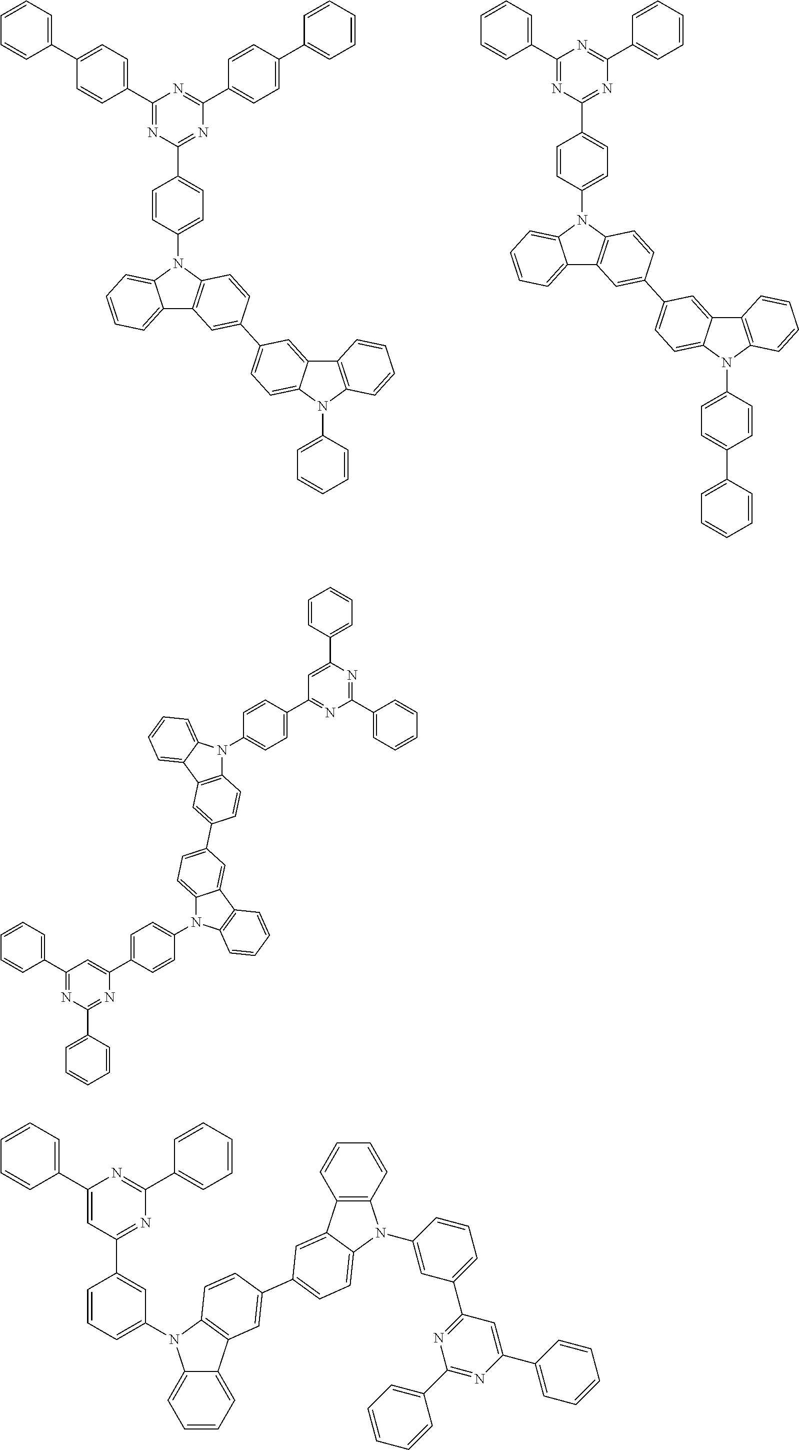 [SMILES: c1ccc(-c2ccc(-c3nc(-c4ccc(-c5ccccc5)cc4)nc(-c4ccc(-n5c6ccccc6c6cc(-c7ccc8c(c7)c7ccccc7n8-c7ccccc7)ccc65)cc4)n3)cc2)cc1 ; c1ccc(-c2ccc(-n3c4ccccc4c4cc(-c5ccc6c(c5)c5ccccc5n6-c5ccc(-c6nc(-c7ccccc7)nc(-c7ccccc7)n6)cc5)ccc43)cc2)cc1 ; c1ccc(-c2cc(-c3ccc(-n4c5ccccc5c5cc(-c6ccc7c(c6)c6ccccc6n7-c6ccc(-c7cc(-c8ccccc8)nc(-c8ccccc8)n7)cc6)ccc54)cc3)nc(-c3ccccc3)n2)cc1 ; c1ccc(-c2cc(-c3cccc(-n4c5ccccc5c5cc(-c6ccc7c(c6)c6ccccc6n7-c6cccc(-c7cc(-c8ccccc8)nc(-c8ccccc8)n7)c6)ccc54)c3)nc(-c3ccccc3)n2)cc1]

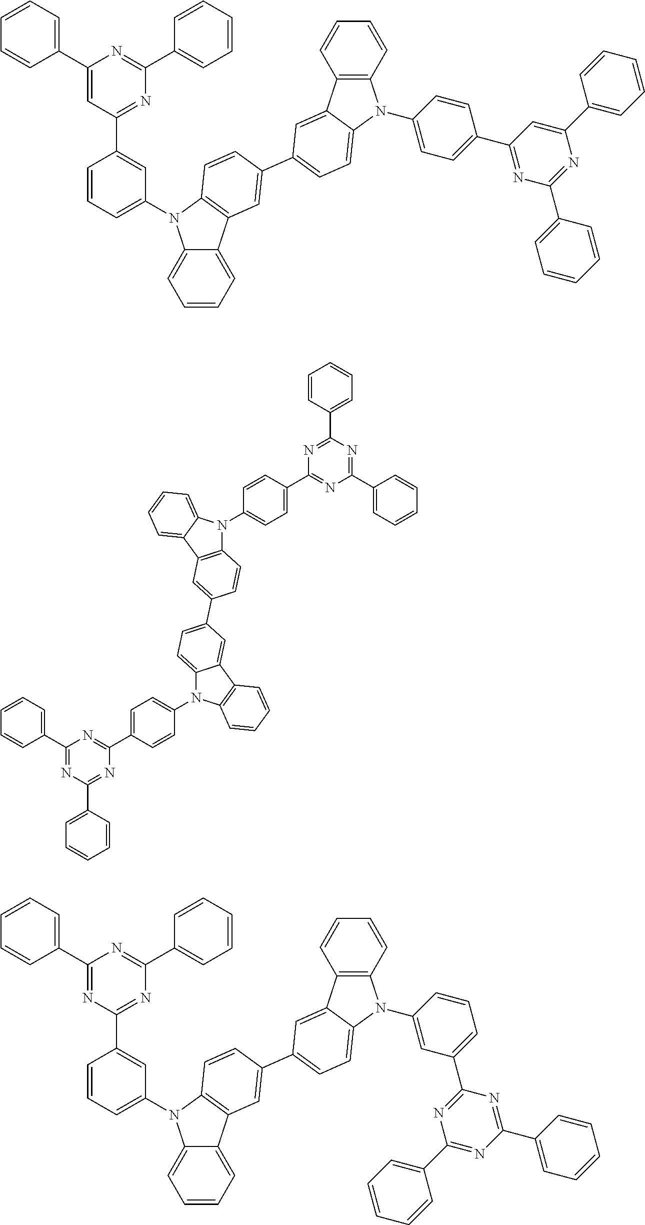 [SMILES: c1ccc(-c2cc(-c3ccc(-n4c5ccccc5c5cc(-c6ccc7c(c6)c6ccccc6n7-c6cccc(-c7cc(-c8ccccc8)nc(-c8ccccc8)n7)c6)ccc54)cc3)nc(-c3ccccc3)n2)cc1 ; c1ccc(-c2nc(-c3ccccc3)nc(-c3ccc(-n4c5ccccc5c5cc(-c6ccc7c(c6)c6ccccc6n7-c6ccc(-c7nc(-c8ccccc8)nc(-c8ccccc8)n7)cc6)ccc54)cc3)n2)cc1 ; c1ccc(-c2nc(-c3ccccc3)nc(-c3cccc(-n4c5ccccc5c5cc(-c6ccc7c(c6)c6ccccc6n7-c6cccc(-c7nc(-c8ccccc8)nc(-c8ccccc8)n7)c6)ccc54)c3)n2)cc1]

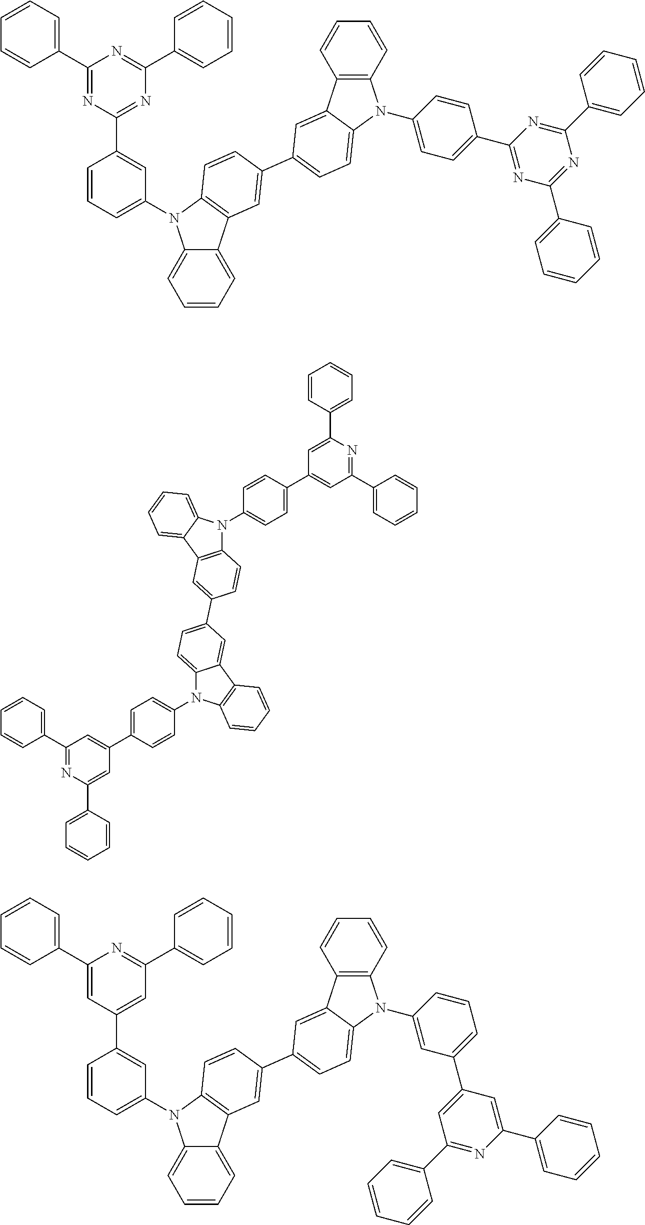 [SMILES: c1ccc(-c2nc(-c3ccccc3)nc(-c3ccc(-n4c5ccccc5c5cc(-c6ccc7c(c6)c6ccccc6n7-c6cccc(-c7nc(-c8ccccc8)nc(-c8ccccc8)n7)c6)ccc54)cc3)n2)cc1 ; c1ccc(-c2cc(-c3ccc(-n4c5ccccc5c5cc(-c6ccc7c(c6)c6ccccc6n7-c6ccc(-c7cc(-c8ccccc8)nc(-c8ccccc8)c7)cc6)ccc54)cc3)cc(-c3ccccc3)n2)cc1 ; c1ccc(-c2cc(-c3cccc(-n4c5ccccc5c5cc(-c6ccc7c(c6)c6ccccc6n7-c6cccc(-c7cc(-c8ccccc8)nc(-c8ccccc8)c7)c6)ccc54)c3)cc(-c3ccccc3)n2)cc1]

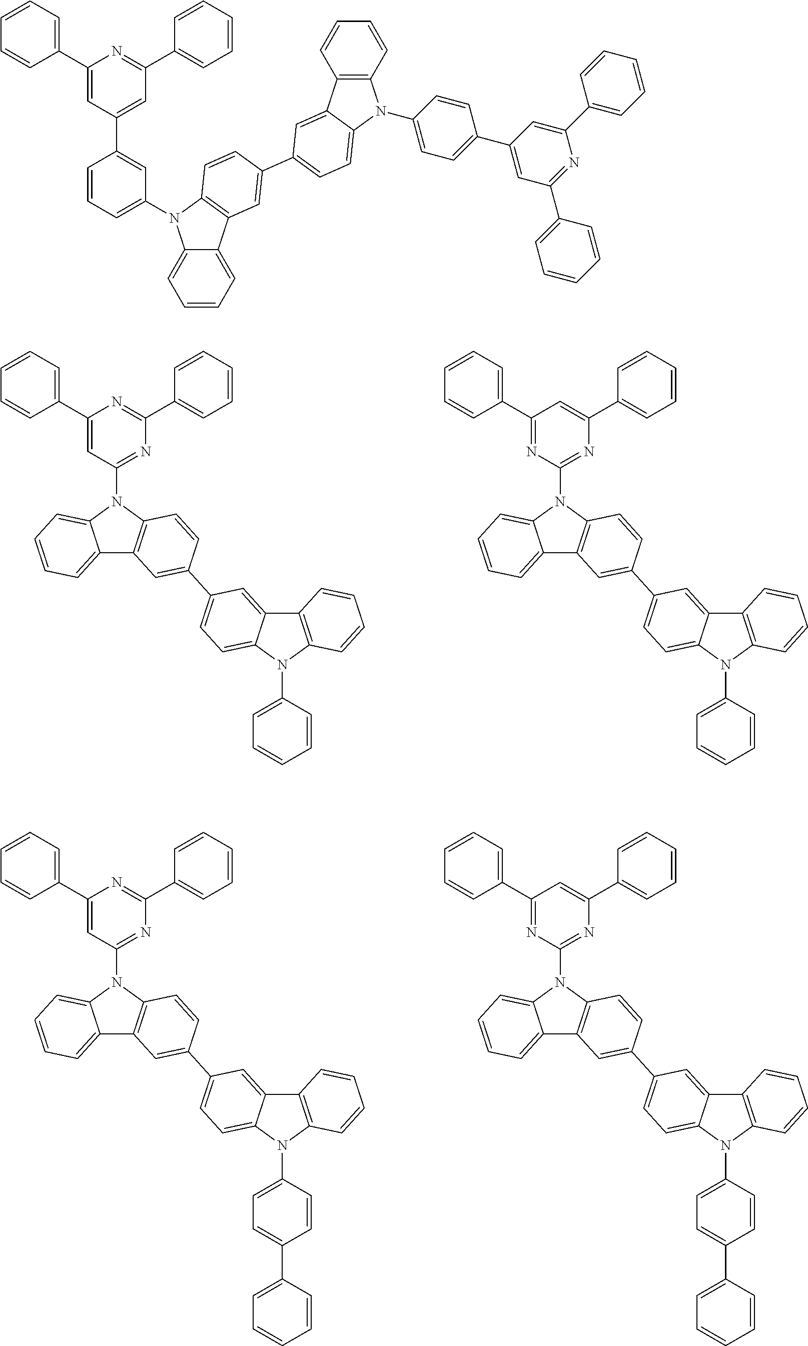

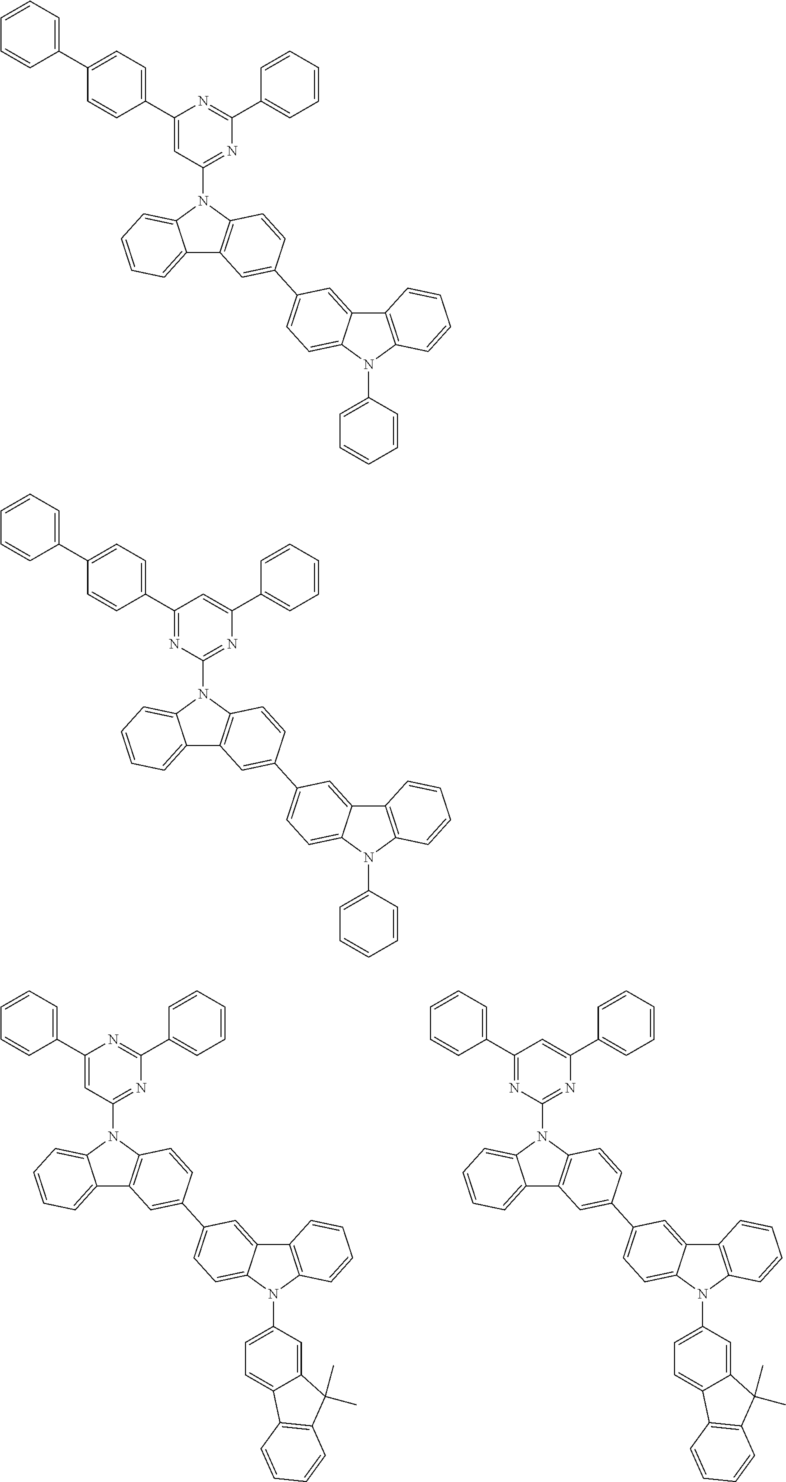 [SMILES: c1ccc(-c2ccc(-c3cc(-n4c5ccccc5c5cc(-c6ccc7c(c6)c6ccccc6n7-c6ccccc6)ccc54)nc(-c4ccccc4)n3)cc2)cc1 ; c1ccc(-c2ccc(-c3cc(-c4ccccc4)nc(-n4c5ccccc5c5cc(-c6ccc7c(c6)c6ccccc6n7-c6ccccc6)ccc54)n3)cc2)cc1 ; CC1(C)c2ccccc2-c2ccc(-n3c4ccccc4c4cc(-c5ccc6c(c5)c5ccccc5n6-c5cc(-c6ccccc6)nc(-c6ccccc6)n5)ccc43)cc21 ; CC1(C)c2ccccc2-c2ccc(-n3c4ccccc4c4cc(-c5ccc6c(c5)c5ccccc5n6-c5nc(-c6ccccc6)cc(-c6ccccc6)n5)ccc43)cc21]

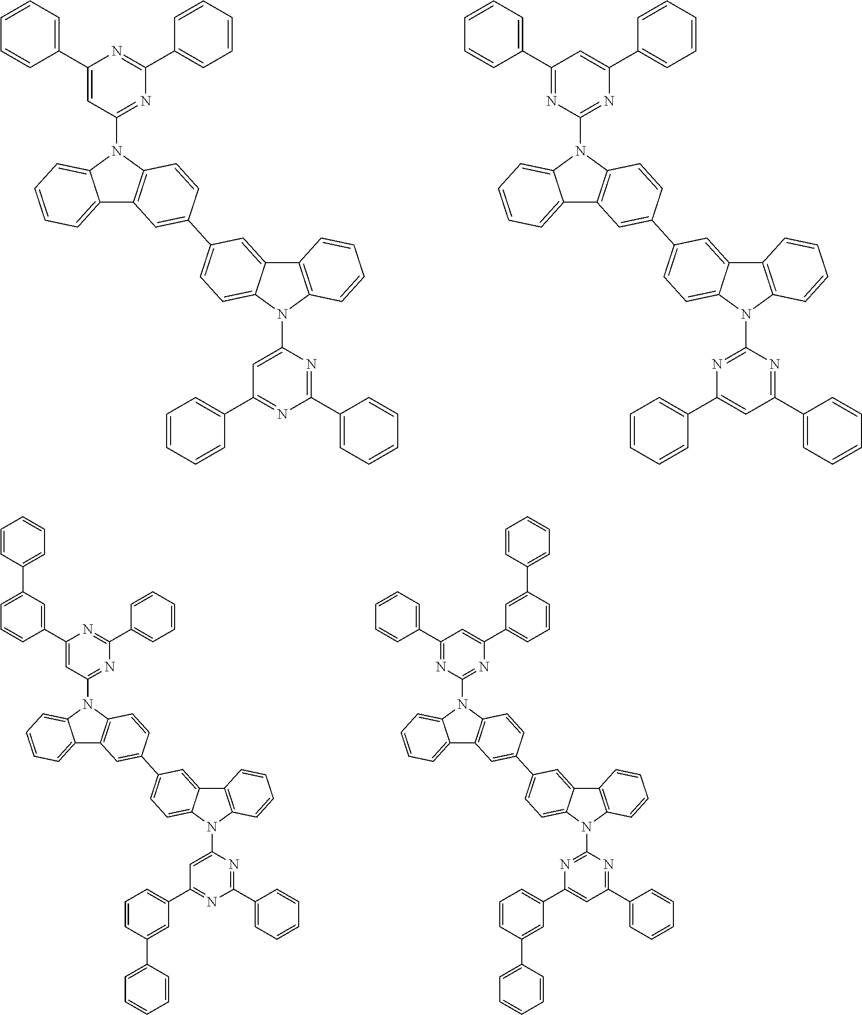 [SMILES: c1ccc(-c2cc(-n3c4ccccc4c4cc(-c5ccc6c(c5)c5ccccc5n6-c5cc(-c6ccccc6)nc(-c6ccccc6)n5)ccc43)nc(-c3ccccc3)n2)cc1 ; c1ccc(-c2cc(-c3ccccc3)nc(-n3c4ccccc4c4cc(-c5ccc6c(c5)c5ccccc5n6-c5nc(-c6ccccc6)cc(-c6ccccc6)n5)ccc43)n2)cc1 ; c1ccc(-c2cccc(-c3cc(-n4c5ccccc5c5cc(-c6ccc7c(c6)c6ccccc6n7-c6cc(-c7cccc(-c8ccccc8)c7)nc(-c7ccccc7)n6)ccc54)nc(-c4ccccc4)n3)c2)cc1 ; c1ccc(-c2cccc(-c3cc(-c4ccccc4)nc(-n4c5ccccc5c5cc(-c6ccc7c(c6)c6ccccc6n7-c6nc(-c7ccccc7)cc(-c7cccc(-c8ccccc8)c7)n6)ccc54)n3)c2)cc1]

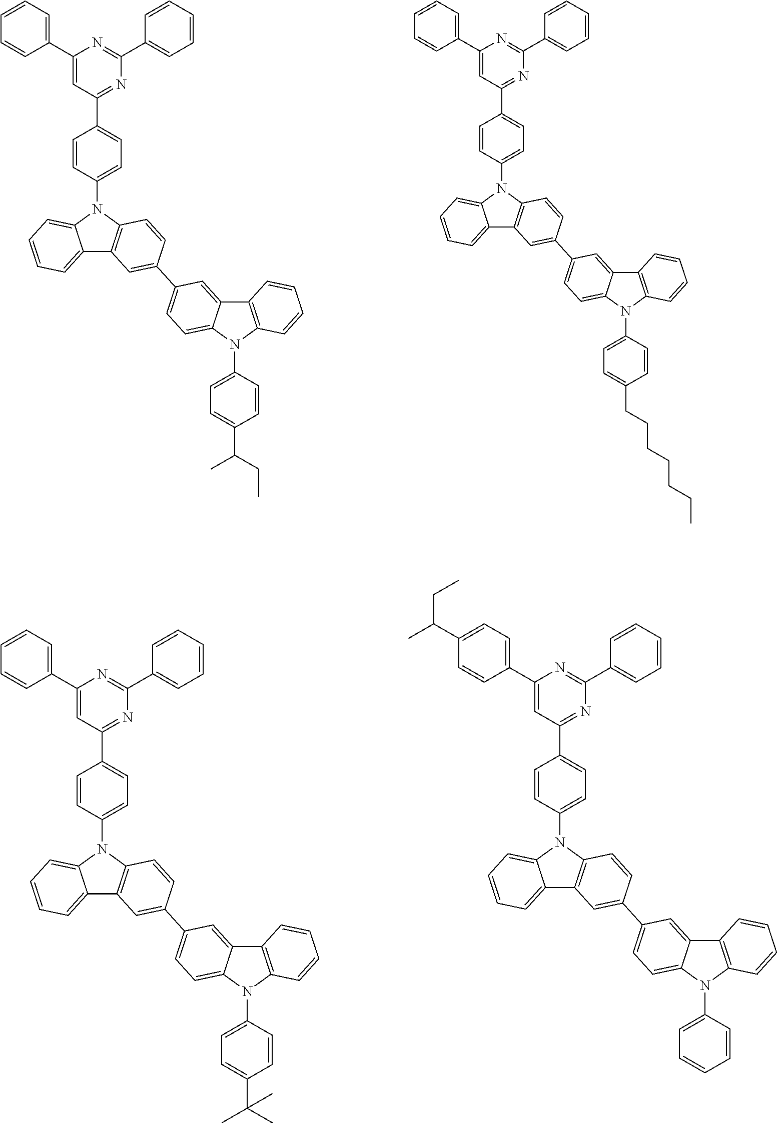 [SMILES: CCC(C)c1ccc(-n2c3ccccc3c3cc(-c4ccc5c(c4)c4ccccc4n5-c4ccc(-c5cc(-c6ccccc6)nc(-c6ccccc6)n5)cc4)ccc32)cc1 ; CCCCCCCc1ccc(-n2c3ccccc3c3cc(-c4ccc5c(c4)c4ccccc4n5-c4ccc(-c5cc(-c6ccccc6)nc(-c6ccccc6)n5)cc4)ccc32)cc1 ; CC(C)(C)c1ccc(-n2c3ccccc3c3cc(-c4ccc5c(c4)c4ccccc4n5-c4ccc(-c5cc(-c6ccccc6)nc(-c6ccccc6)n5)cc4)ccc32)cc1 ; CCC(C)c1ccc(-c2cc(-c3ccc(-n4c5ccccc5c5cc(-c6ccc7c(c6)c6ccccc6n7-c6ccccc6)ccc54)cc3)nc(-c3ccccc3)n2)cc1]

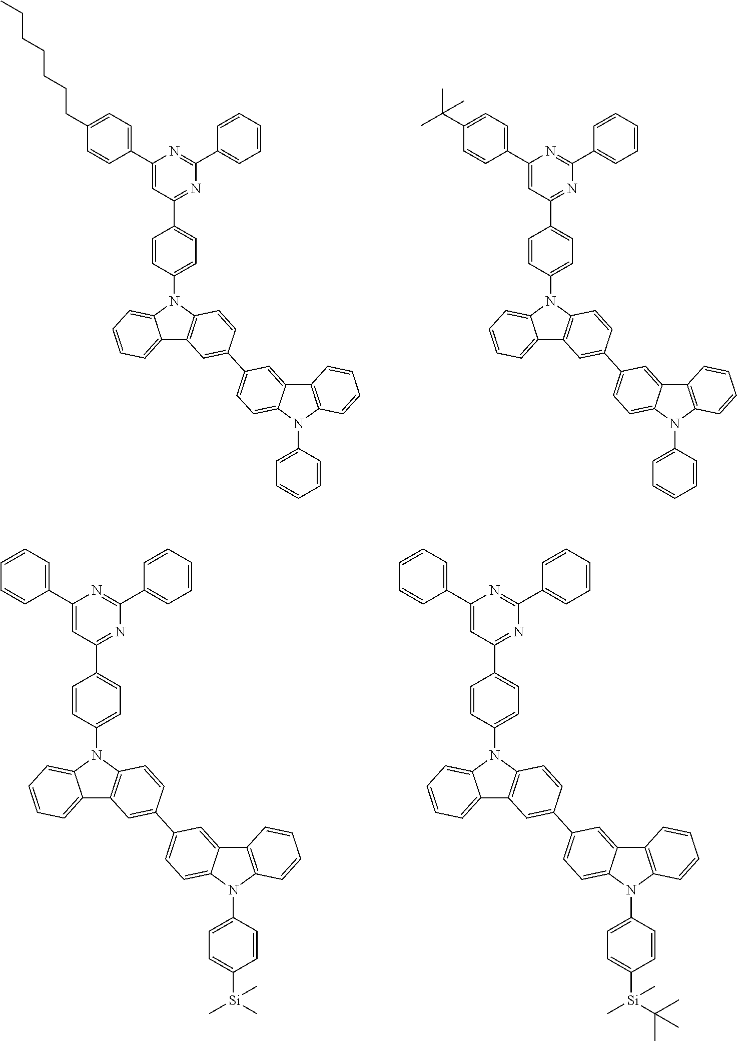 [SMILES: CCCCCCCc1ccc(-c2cc(-c3ccc(-n4c5ccccc5c5cc(-c6ccc7c(c6)c6ccccc6n7-c6ccccc6)ccc54)cc3)nc(-c3ccccc3)n2)cc1 ; CC(C)(C)c1ccc(-c2cc(-c3ccc(-n4c5ccccc5c5cc(-c6ccc7c(c6)c6ccccc6n7-c6ccccc6)ccc54)cc3)nc(-c3ccccc3)n2)cc1 ; C[Si](C)(C)c1ccc(-n2c3ccccc3c3cc(-c4ccc5c(c4)c4ccccc4n5-c4ccc(-c5cc(-c6ccccc6)nc(-c6ccccc6)n5)cc4)ccc32)cc1 ; CC(C)(C)[Si](C)(C)c1ccc(-n2c3ccccc3c3cc(-c4ccc5c(c4)c4ccccc4n5-c4ccc(-c5cc(-c6ccccc6)nc(-c6ccccc6)n5)cc4)ccc32)cc1]

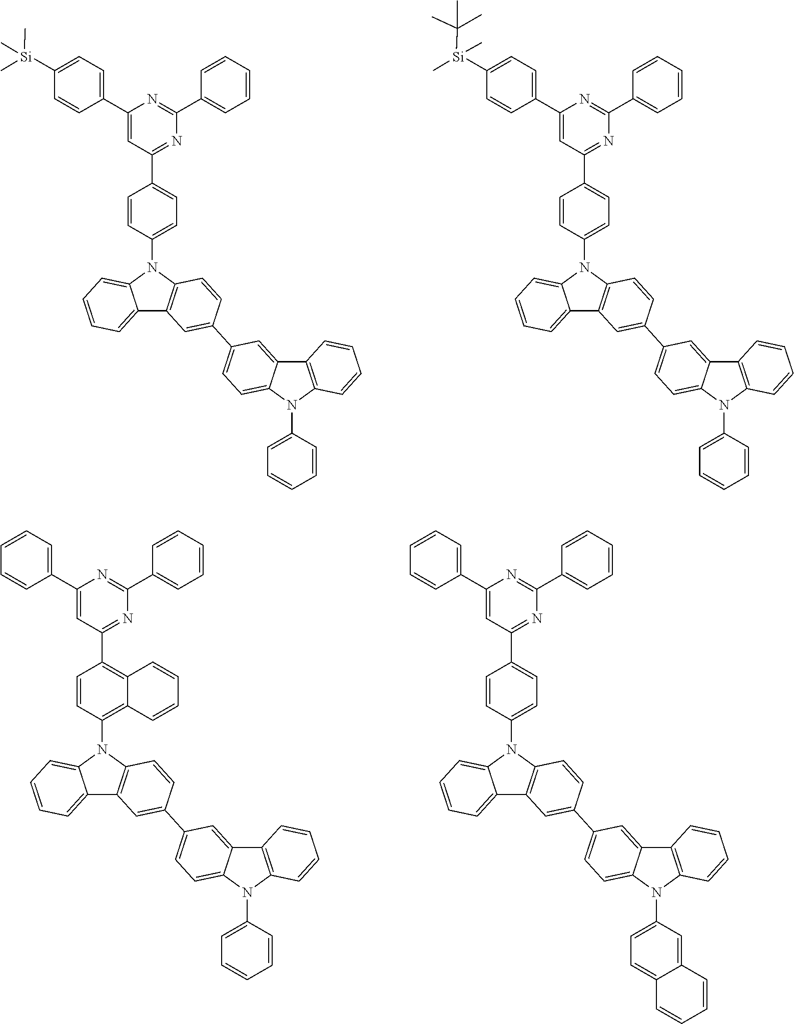 [SMILES: C[Si](C)(C)c1ccc(-c2cc(-c3ccc(-n4c5ccccc5c5cc(-c6ccc7c(c6)c6ccccc6n7-c6ccccc6)ccc54)cc3)nc(-c3ccccc3)n2)cc1 ; CC(C)(C)[Si](C)(C)c1ccc(-c2cc(-c3ccc(-n4c5ccccc5c5cc(-c6ccc7c(c6)c6ccccc6n7-c6ccccc6)ccc54)cc3)nc(-c3ccccc3)n2)cc1 ; c1ccc(-c2cc(-c3ccc(-n4c5ccccc5c5cc(-c6ccc7c(c6)c6ccccc6n7-c6ccccc6)ccc54)c4ccccc34)nc(-c3ccccc3)n2)cc1 ; c1ccc(-c2cc(-c3ccc(-n4c5ccccc5c5cc(-c6ccc7c(c6)c6ccccc6n7-c6ccc7ccccc7c6)ccc54)cc3)nc(-c3ccccc3)n2)cc1]

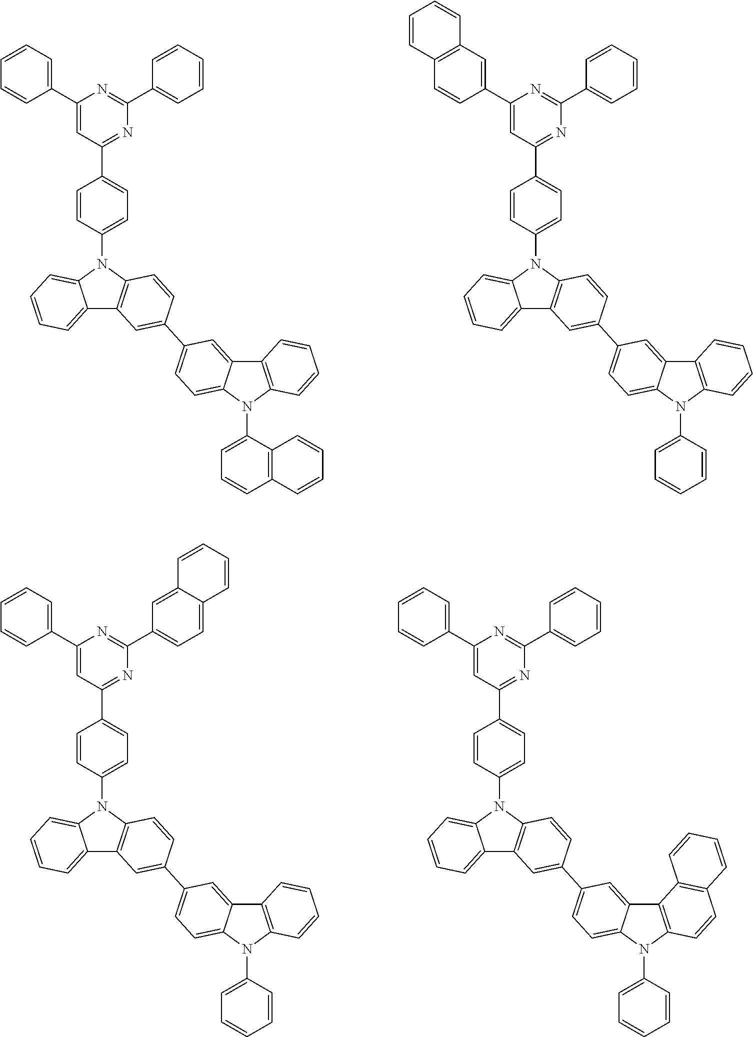 [SMILES: c1ccc(-c2cc(-c3ccc(-n4c5ccccc5c5cc(-c6ccc7c(c6)c6ccccc6n7-c6cccc7ccccc67)ccc54)cc3)nc(-c3ccccc3)n2)cc1 ; c1ccc(-c2nc(-c3ccc(-n4c5ccccc5c5cc(-c6ccc7c(c6)c6ccccc6n7-c6ccccc6)ccc54)cc3)cc(-c3ccc4ccccc4c3)n2)cc1 ; c1ccc(-c2cc(-c3ccc(-n4c5ccccc5c5cc(-c6ccc7c(c6)c6ccccc6n7-c6ccccc6)ccc54)cc3)nc(-c3ccc4ccccc4c3)n2)cc1 ; c1ccc(-c2cc(-c3ccc(-n4c5ccccc5c5cc(-c6ccc7c(c6)c6c8ccccc8ccc6n7-c6ccccc6)ccc54)cc3)nc(-c3ccccc3)n2)cc1]

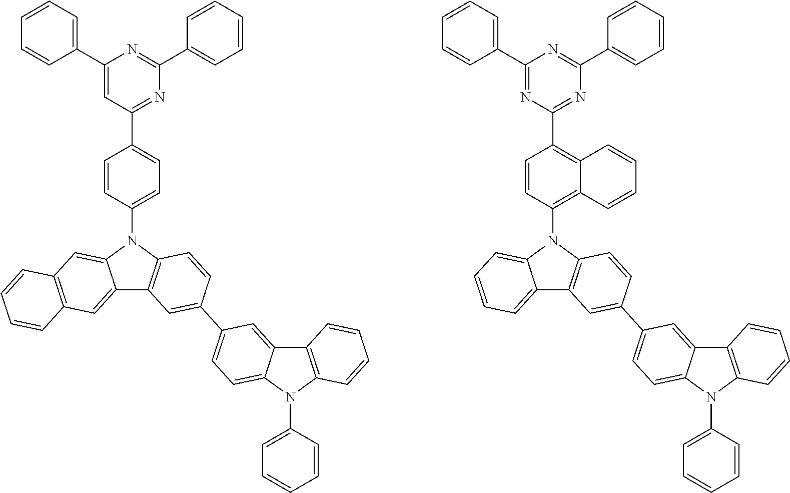 [SMILES: c1ccc(-c2cc(-c3ccc(-n4c5ccc(-c6ccc7c(c6)c6ccccc6n7-c6ccccc6)cc5c5cc6ccccc6cc54)cc3)nc(-c3ccccc3)n2)cc1 ; c1ccc(-c2nc(-c3ccccc3)nc(-c3ccc(-n4c5ccccc5c5cc(-c6ccc7c(c6)c6ccccc6n7-c6ccccc6)ccc54)c4ccccc34)n2)cc1]

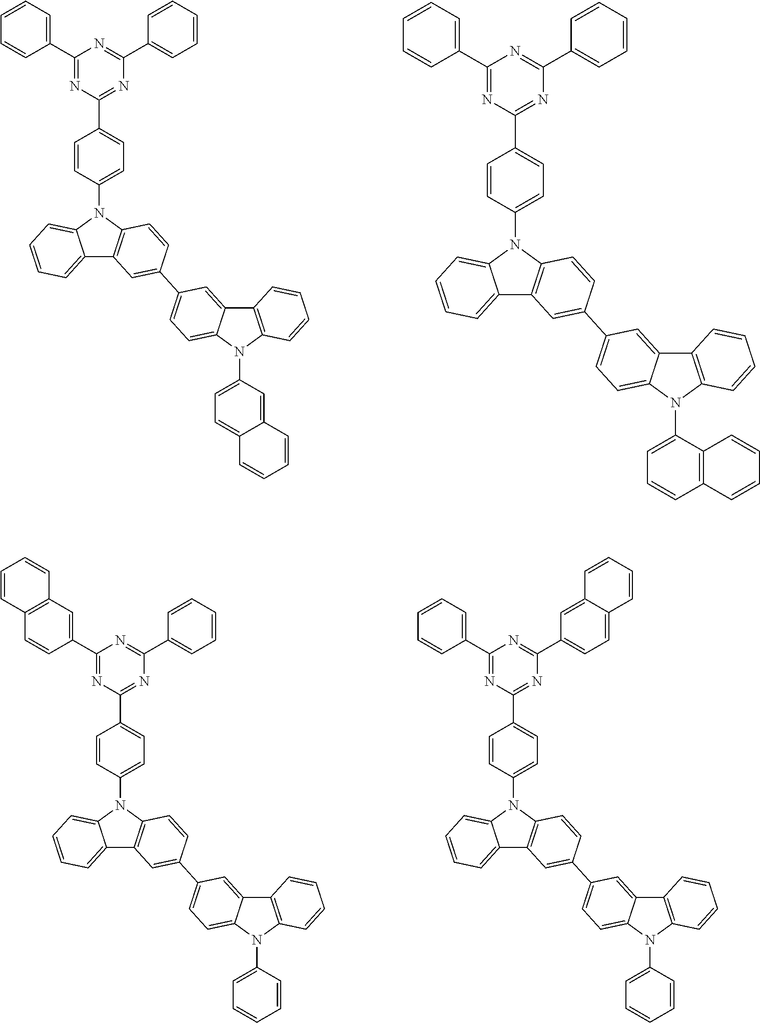 [SMILES: c1ccc(-c2nc(-c3ccccc3)nc(-c3ccc(-n4c5ccccc5c5cc(-c6ccc7c(c6)c6ccccc6n7-c6ccc7ccccc7c6)ccc54)cc3)n2)cc1 ; c1ccc(-c2nc(-c3ccccc3)nc(-c3ccc(-n4c5ccccc5c5cc(-c6ccc7c(c6)c6ccccc6n7-c6cccc7ccccc67)ccc54)cc3)n2)cc1 ; c1ccc(-c2nc(-c3ccc(-n4c5ccccc5c5cc(-c6ccc7c(c6)c6ccccc6n7-c6ccccc6)ccc54)cc3)nc(-c3ccc4ccccc4c3)n2)cc1 ; c1ccc(-c2nc(-c3ccc(-n4c5ccccc5c5cc(-c6ccc7c(c6)c6ccccc6n7-c6ccccc6)ccc54)cc3)nc(-c3ccc4ccccc4c3)n2)cc1]

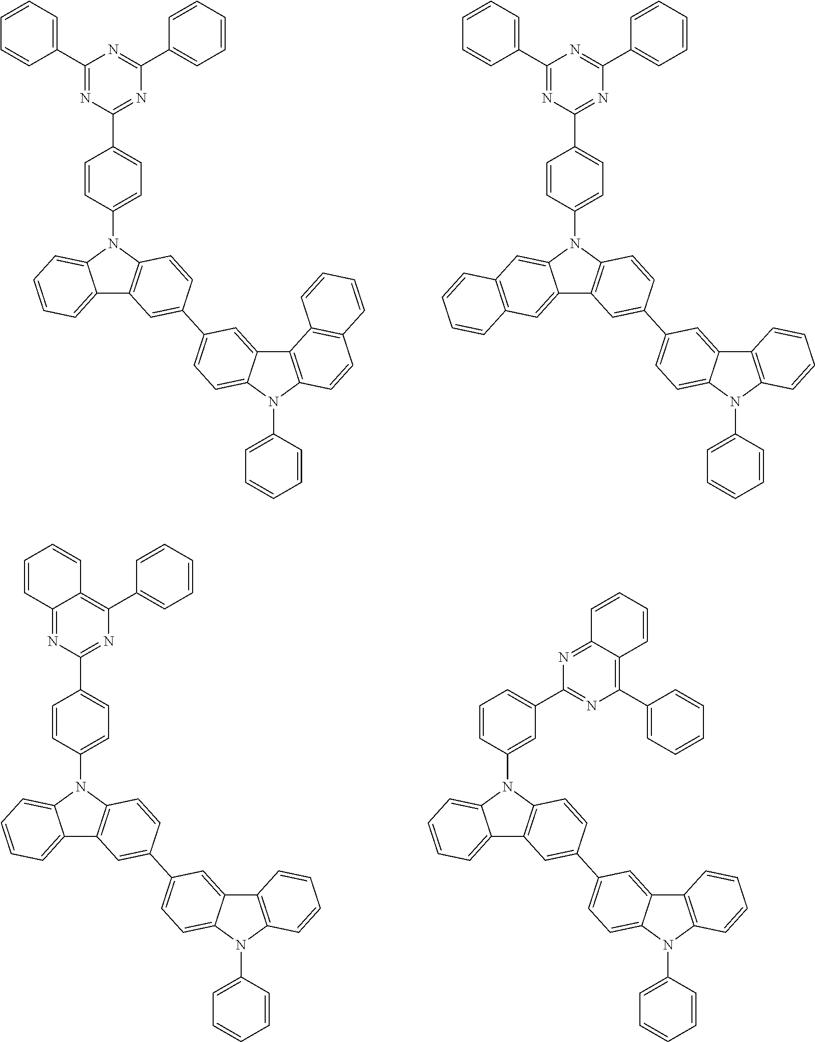 [SMILES: c1ccc(-c2nc(-c3ccccc3)nc(-c3ccc(-n4c5ccccc5c5cc(-c6ccc7c(c6)c6c8ccccc8ccc6n7-c6ccccc6)ccc54)cc3)n2)cc1 ; c1ccc(-c2nc(-c3ccccc3)nc(-c3ccc(-n4c5ccc(-c6ccc7c(c6)c6ccccc6n7-c6ccccc6)cc5c5cc6ccccc6cc54)cc3)n2)cc1 ; c1ccc(-c2nc(-c3ccc(-n4c5ccccc5c5cc(-c6ccc7c(c6)c6ccccc6n7-c6ccccc6)ccc54)cc3)nc3ccccc23)cc1 ; c1ccc(-c2nc(-c3cccc(-n4c5ccccc5c5cc(-c6ccc7c(c6)c6ccccc6n7-c6ccccc6)ccc54)c3)nc3ccccc23)cc1]

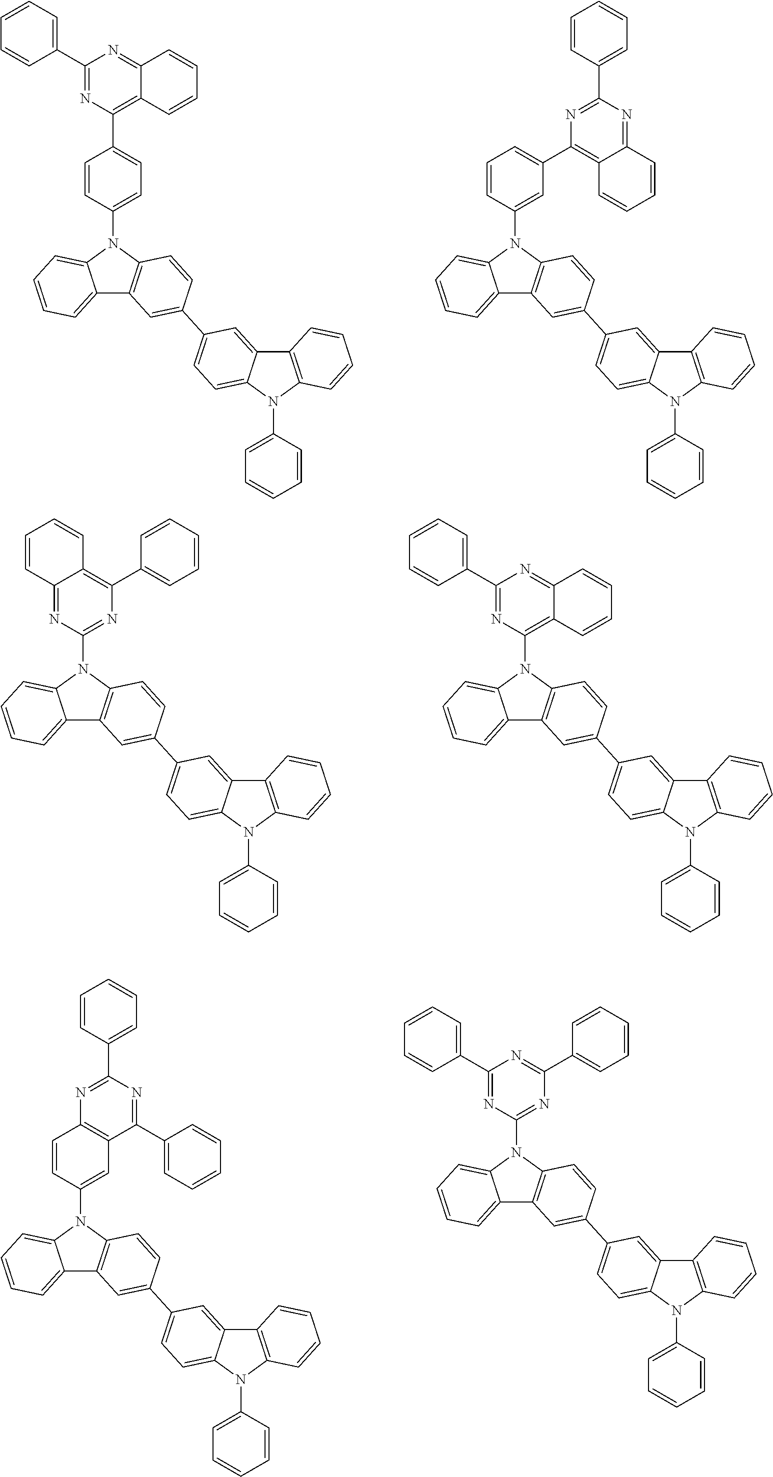

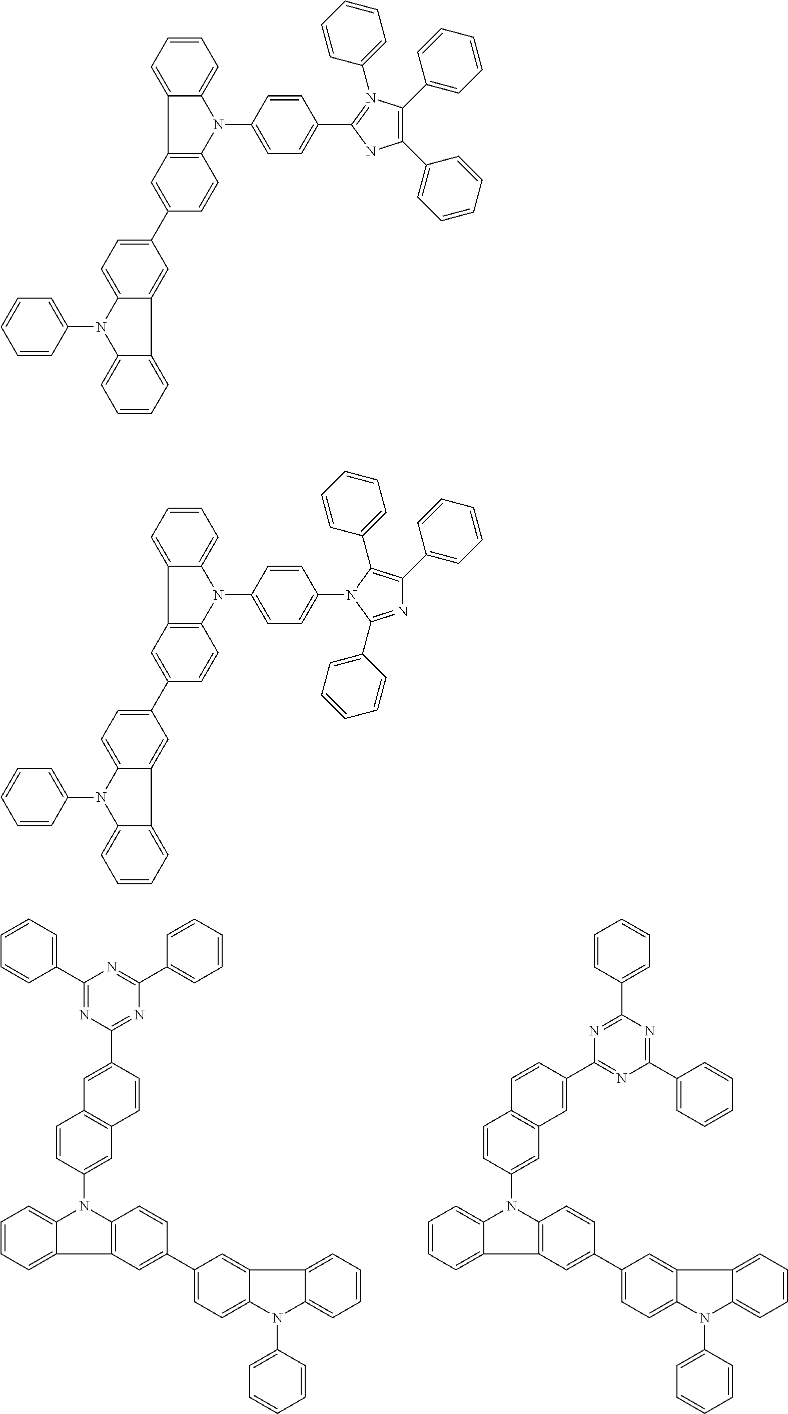

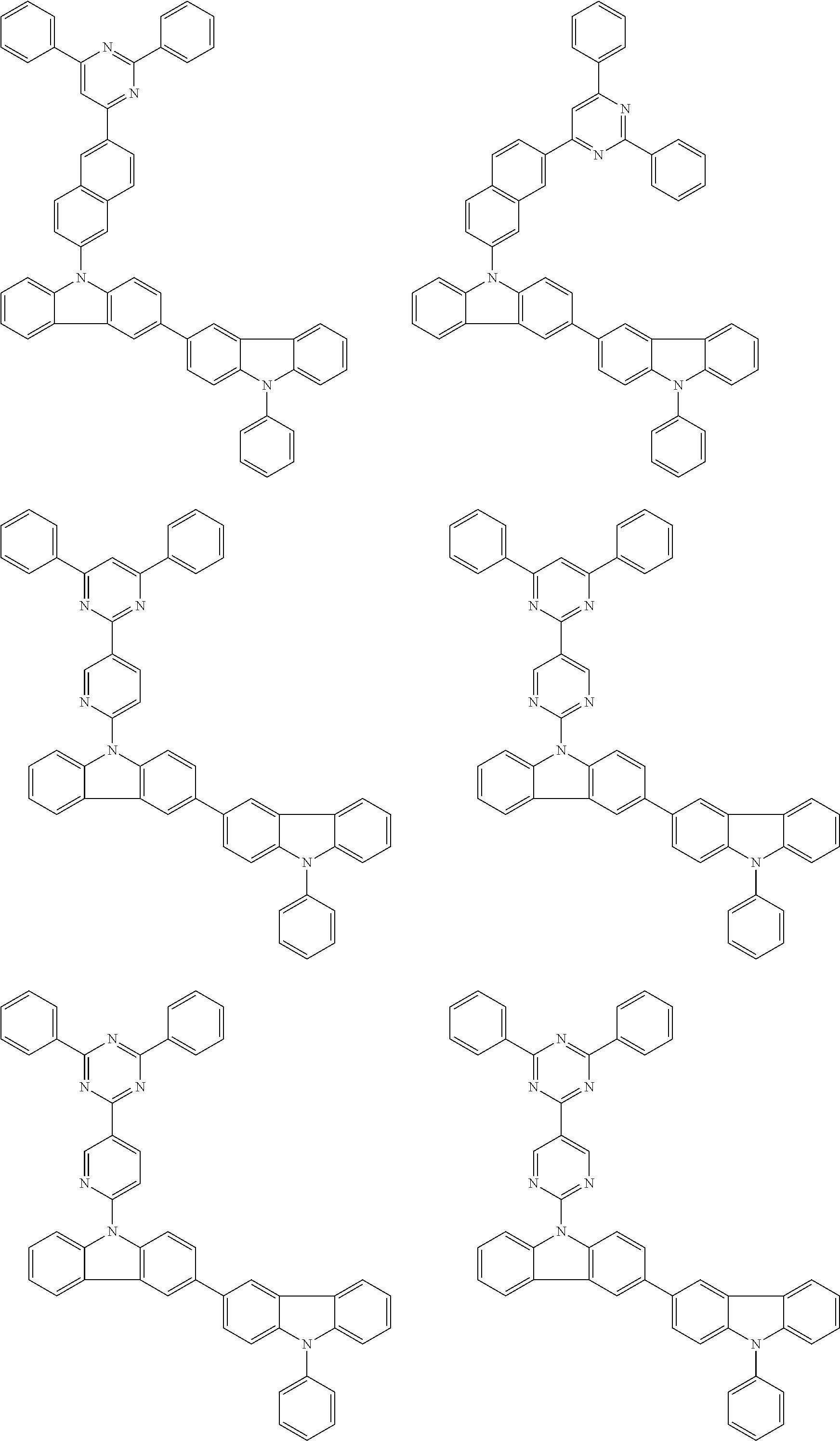

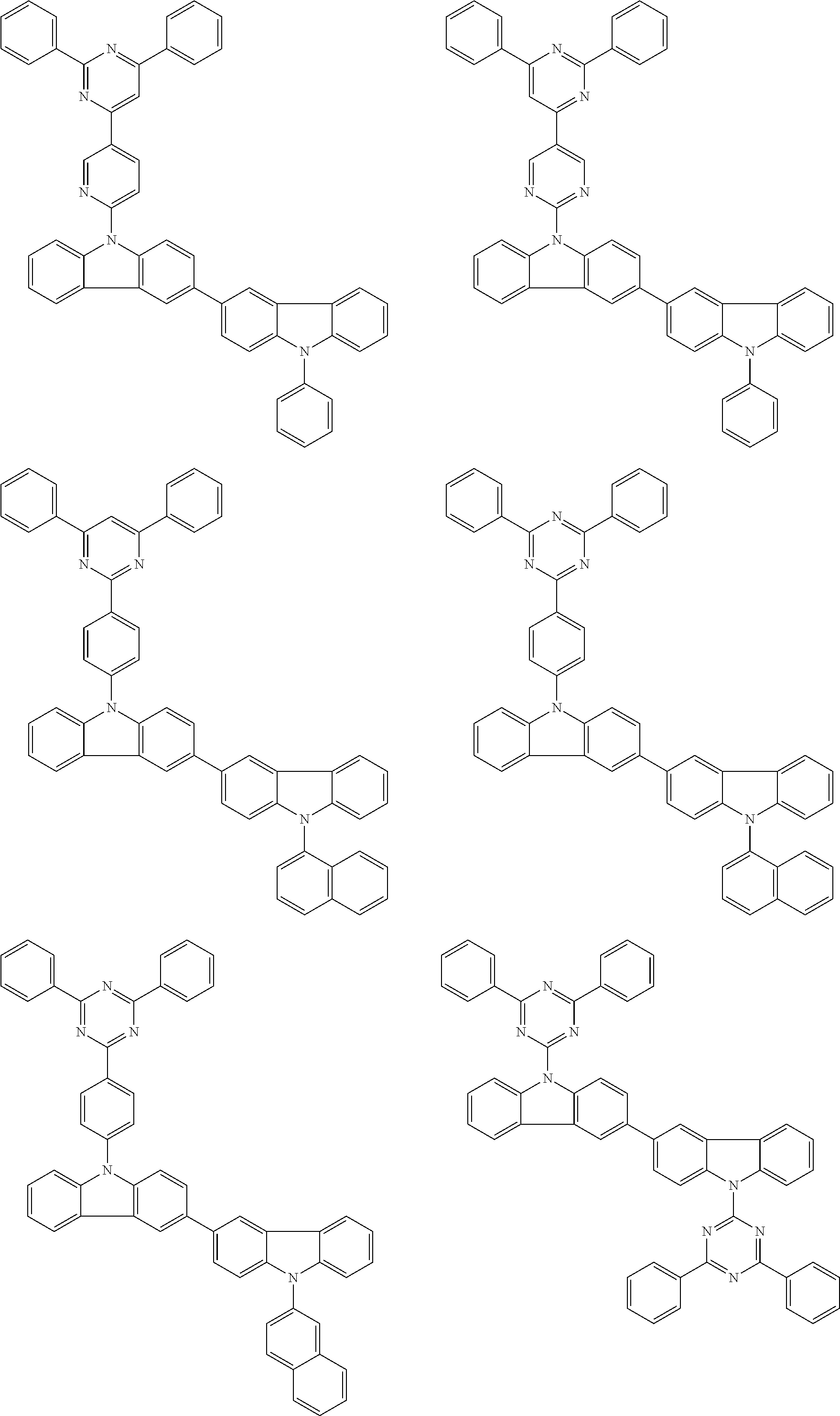

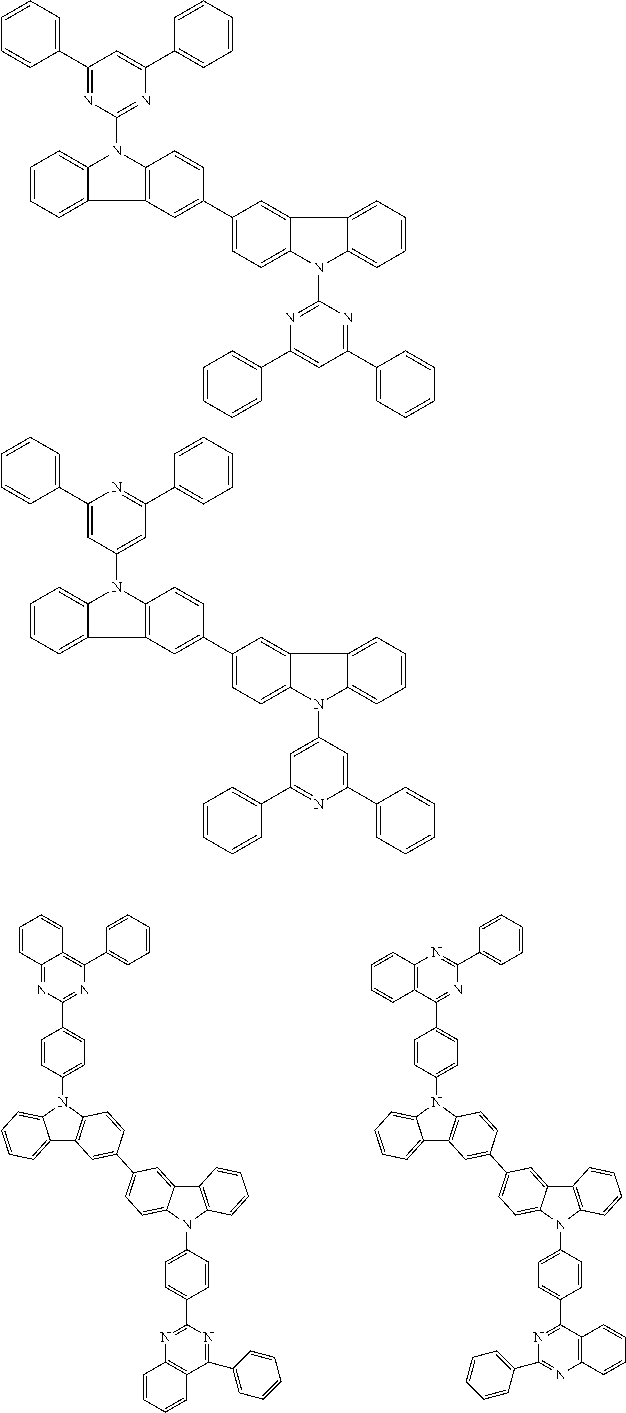

As described above, the host material in the emitting layer of the organic EL device includes a biscarbazole derivative compound represented by any one of the above-listed examples represented by the formulas (1) or (2). According to another embodiment, the host material in the organic EL device is more preferably a biscarbazole derivative compound represented by formula (H1) below:

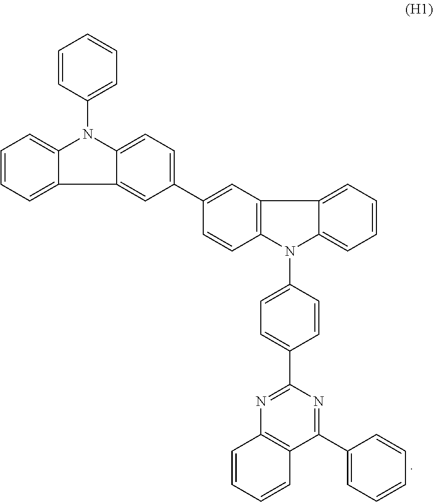 [SMILES: c1ccc(-c2nc(-c3ccc(-n4c5ccccc5c5cc(-c6ccc7c(c6)c6ccccc6n7-c6ccccc6)ccc54)cc3)nc3ccccc23)cc1]

### [Phosphorescent Dopant Material]

In the organic EL device of the present disclosure, the red phosphorescent dopant material is a phosphorescent organometallic complex having a substituted chemical structure represented by one of the following partial chemical structures represented by the formulas (D1), (D2), and (D3):

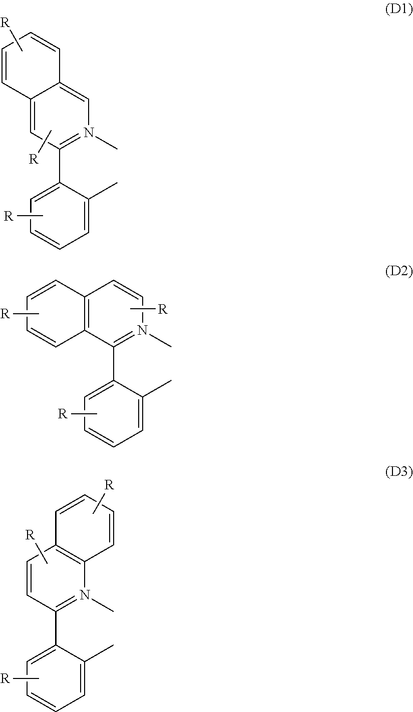

where each R is independently selected from the group consisting of H, alkyl, alkenyl, alkynyl, alkylaryl, CN, CF₃, CₙF₂ₙ₊₁, trifluorovinyl, CO₂R, C(O)R, NR₂, NO₂, OR, halo, aryl, heteroaryl, substituted aryl, substituted heteroaryl or a heterocyclic group.

According to another aspect of the present disclosure, the red phosphorescent dopant material is an iridium compound having the formula:

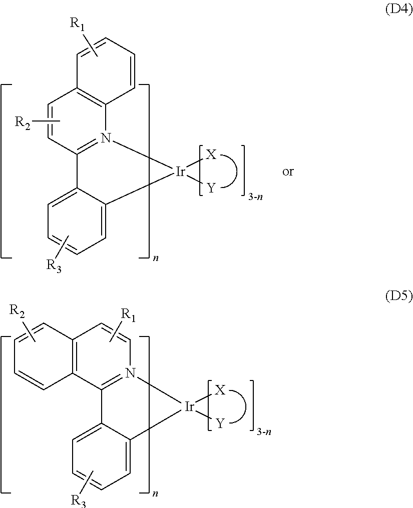

where n is 1, 2 or 3; each of R₁, R₂, and R₃ is independently a hydrogen, or a mono-, di-, tri-, tetra-, or penta-substitution of alkyl or aryl, wherein R₃ is di-alkyl or di-aryl; and X—Y is an ancillary ligand.

According to another aspect of the present disclosure, the red phosphorescent dopant material is an iridium compound having the formula:

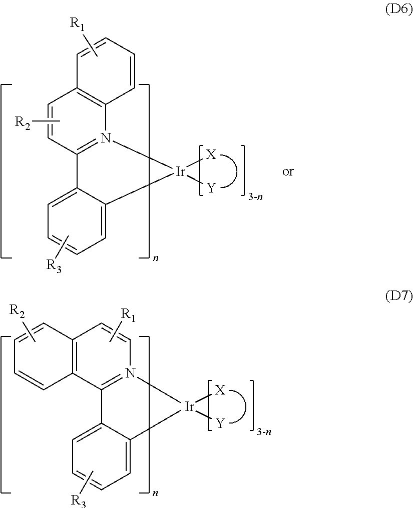

where n is 1, 2 or 3; each of R₁, R₂, and R₃ is independently a hydrogen, or a mono-, di-, tri-, tetra-, or penta-substitution of alkyl or aryl; at least one of R₁, R₂, and R₃ is a branched alkyl containing at least 4 carbon atoms; and X—Y is an ancillary ligand.

According to another aspect of the present disclosure, the red phosphorescent dopant material is preferably an iridium compound having the formula (D8) below:

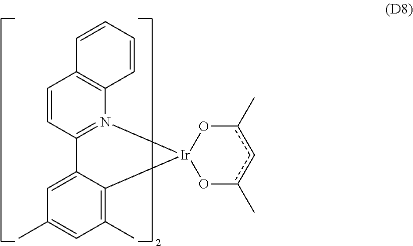

According to another aspect of the present disclosure, the red phosphorescent dopant material is preferably an iridium compound having the formula (D9) below:

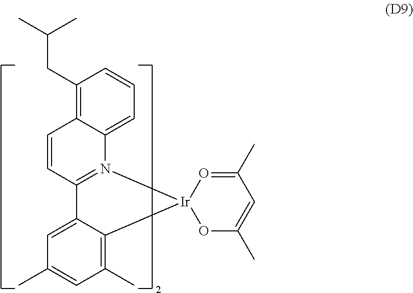

In another embodiment of the present disclosure, the host material in the electroluminescence device comprises the biscarbazole derivative compound (H1) and the red phosphorescent dopant material having the formula (D8) or (D9).

### [EIL/ETL]

The electron injecting layer or the electron transporting layer, which aids injection of the electrons into the emitting layer, has a large electron mobility. The electron injecting layer is provided for adjusting energy level, by which, for instance, sudden changes of the energy level can be reduced.

The organic EL device according to this embodiment preferably includes the electron injecting layer between the emitting layer and the cathode, and the electron injecting layer preferably contains a nitrogen-containing cyclic derivative as the main component. The electron injecting layer may serve as the electron transporting layer. It should be noted that “as the main component” means that the nitrogen-containing cyclic derivative is contained in the electron injecting layer at a content of 50 mass % or more.

A preferable example of an electron transporting material for forming the electron injecting layer is an aromatic heterocyclic compound having in the molecule at least one heteroatom. Particularly, a nitrogen-containing cyclic derivative is preferable. The nitrogen-containing cyclic derivative is preferably an aromatic ring having a nitrogen-containing six-membered or five-membered ring skeleton, or a fused aromatic cyclic compound having a nitrogen-containing six-membered or five-membered ring skeleton.

The nitrogen-containing cyclic derivative is preferably exemplified by a nitrogen-containing cyclic metal chelate complex represented by the following formula (E1).

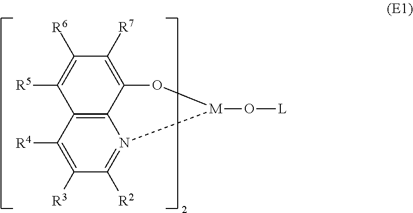

R² to R⁷ in the formula (E1) each independently represent a hydrogen atom, a halogen atom, an oxy group, an amino group, a hydrocarbon group having 1 to 40 carbon atoms, an alkoxy group, an aryloxy group, an alkoxycarbonyl group, or an aromatic heterocyclic group. These groups may be substituted or unsubstituted.

Examples of the halogen atom include fluorine, chlorine, bromine, and iodine. In addition, examples of the substituted or unsubstituted amino group include an alkylamino group, an arylamino group, and an aralkylamino group.

The alkoxycarbonyl group is represented by —COOY′. Examples of Y′ are the same as the examples of the alkyl group. The alkylamino group and the aralkylamino group are represented by —NQ¹Q². Examples for each of Q¹ and Q² are the same as the examples described in relation to the alkyl group and the aralkyl group, and preferred examples for each of Q¹ and Q² are also the same as those described in relation to the alkyl group and the aralkyl group. Either one of Q¹ and Q² may be a hydrogen atom.

The arylamino group is represented by —NAr¹Ar². Examples for each of Ar¹ and Ar² are the same as the examples described in relation to the non-fused aromatic hydrocarbon group and the fused aromatic hydrocarbon group. Either one of Ar¹ and Ar² may be a hydrogen atom.

M in the formula (E1) represents aluminum (Al), gallium (Ga) or indium (In), among which In is preferable.

L in the formula (E1) represents a group represented by a formula (A′) or (A″) below.

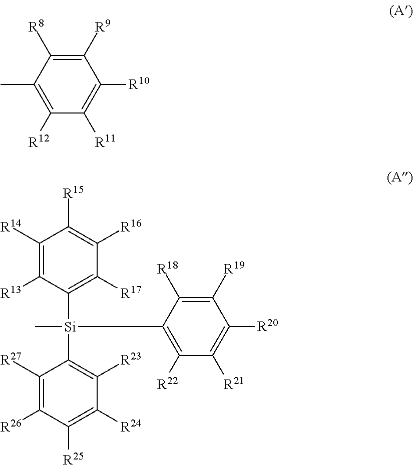

In the formula (A′), R⁸ to R¹² each independently represent a hydrogen atom or a substituted or unsubstituted hydrocarbon group having 1 to 40 carbon atoms. Adjacent groups may form a cyclic structure. In the formula (A″), R¹³ to R²⁷ each independently represent a hydrogen atom or a substituted or unsubstituted hydrocarbon group having 1 to 40 carbon atoms. Adjacent groups may form a cyclic structure.

Examples of the hydrocarbon group having 1 to 40 carbon atoms represented by each of R⁸ to R¹² and R¹³ to R²⁷ in the formulas (A′) and (A″) are the same as those of R² to R⁷ in the formula (E1).

Examples of a divalent group formed when an adjacent set of R⁸ to R¹² and R¹³ to R²⁷ forms a cyclic structure are a tetramethylene group, a pentamethylene group, a hexamethylene group, a diphenylmethane-2,2′-diyl group, a diphenylethane-3,3′-diyl group, a diphenylpropane-4,4′-diyl group and the like.

Moreover, according to an embodiment, the electron transporting layer may contain the biscarbazole derivative compound represented by the formulas (1), (2), or (H1).

As an electron transporting compound for the electron injecting layer or the electron transporting layer, 8-hydroxyquinoline or a metal complex of its derivative, an oxadiazole derivative and a nitrogen-containing heterocyclic derivative are preferable. A specific example of the 8-hydroxyquinoline or the metal complex of its derivative is a metal chelate oxinoid compound containing a chelate of oxine (typically 8-quinolinol or 8-hydroxyquinoline). For instance, tris(8-quinolinol) aluminum can be used. Examples of the oxadiazole derivative are represented by the following formulas:

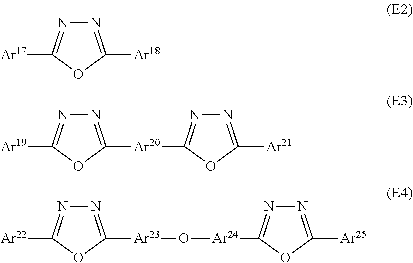

In the formulas above, Ar¹⁷, Ar¹⁸, Ar¹⁹, Ar²¹, Ar²² and Ar²⁵ each represent a substituted or unsubstituted aromatic hydrocarbon group or fused aromatic hydrocarbon group having 6 to 40 ring carbon atoms. Ar¹⁷, Ar¹⁹ and Ar²² may be the same as or different from Ar¹⁸, Ar²¹ and Ar²⁵ respectively. Examples of the aromatic hydrocarbon group or fused aromatic hydrocarbon group having 6 to 40 ring carbon atoms are a phenyl group, biphenyl group, anthranil group, perylenyl group and pyrenyl group. Examples of the substituent therefor are an alkyl group having 1 to 10 carbon atoms, alkoxy group having 1 to 10 carbon atoms and cyano group.

Ar²⁰, Ar²³ and Ar²⁴ each represent a substituted or, unsubstituted divalent aromatic hydrocarbon group or fused aromatic hydrocarbon group having 6 to 40 ring carbon atoms. Ar²³ and Ar²⁴ may be mutually the same or different. Examples of the divalent aromatic hydrocarbon group or fused aromatic hydrocarbon group having 6 to 40 ring carbon atoms are a phenylene group, naphthylene group, biphenylene group, anthranylene group, perylenylene group and pyrenylene group. Examples of the substituent therefor are an alkyl group having 1 to 10 carbon atoms, alkoxy group having 1 to 10 carbon atoms and cyano group.

Preferably, such electron transport compound can be favorably formed into a thin film(s). Some examples of the electron transporting compounds are as follows:

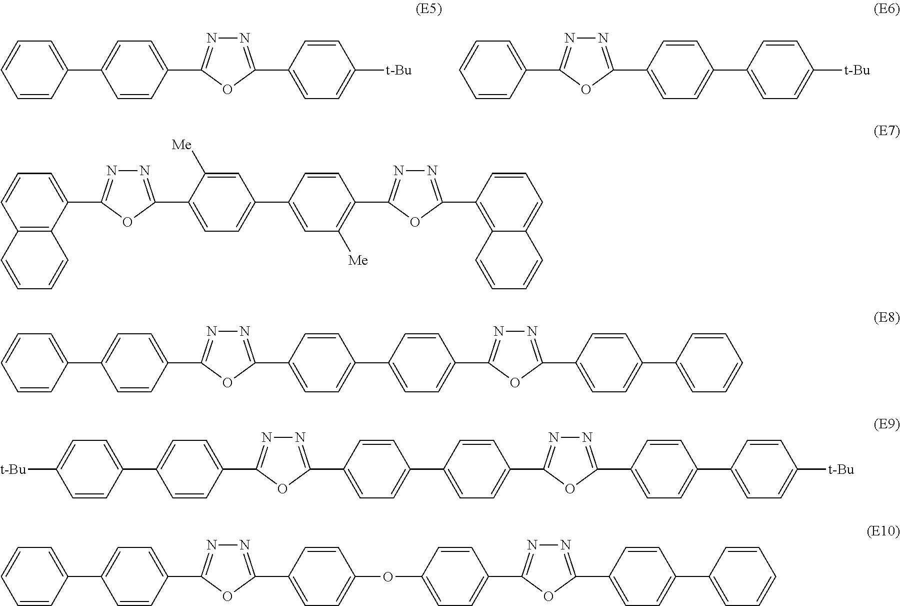

An example of the nitrogen-containing heterocyclic derivative as the electron transporting compound is a nitrogen-containing compound that is not a metal complex, the derivative being formed of an organic compound represented by one of the following general formulae. Examples of the nitrogen-containing heterocyclic derivative are a five-membered ring or six-membered ring derivative having a skeleton represented by the following formula (A) and a derivative having a structure represented by the following formula (B).

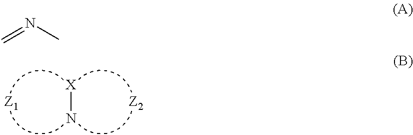

In the formula (B) above, X represents a carbon atom or a nitrogen atom. Z₁ and Z₂ each independently represent a group of atoms capable of forming a nitrogen-containing heterocycle.

Preferably, the nitrogen-containing heterocyclic derivative is an organic compound having a nitrogen-containing aromatic polycyclic group having a five-membered ring or six-membered ring. When the nitrogen-containing heterocyclic derivative includes such nitrogen-containing aromatic polycyclic series having plural nitrogen atoms, the nitrogen-containing heterocyclic derivative may be a nitrogen-containing aromatic polycyclic organic compound having a skeleton formed by a combination of the skeletons respectively represented by the formulas (A) and (B), or by a combination of the skeletons respectively represented by the formulas (A) and (C).

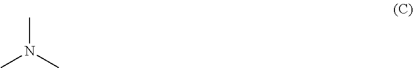

A nitrogen-containing group of the nitrogen-containing aromatic polycyclic organic compound is selected from nitrogen-containing heterocyclic groups respectively represented by the following general formulas:

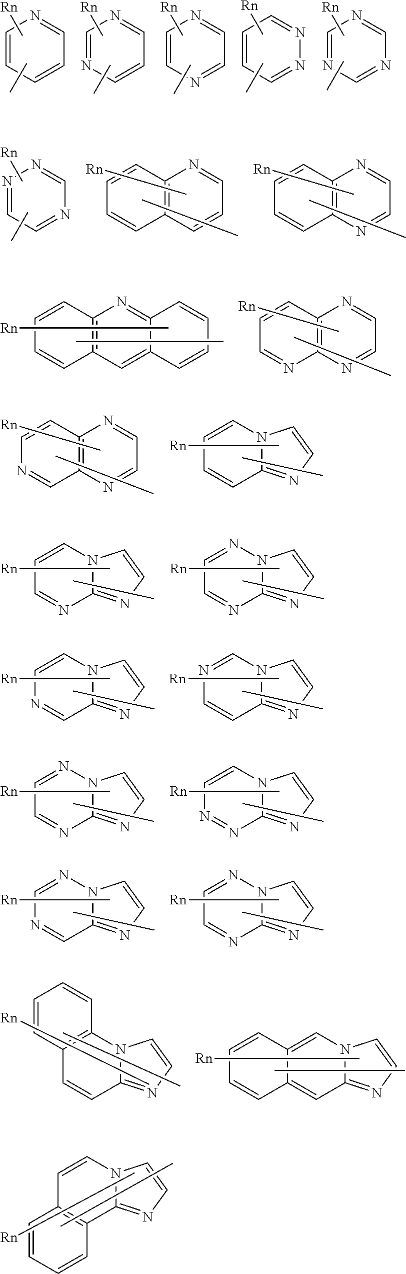

where, R represents an aromatic hydrocarbon group or fused aromatic hydrocarbon group having 6 to 40 ring carbon atoms, an aromatic heterocyclic group or fused aromatic heterocyclic group having 2 to 40 ring carbon atoms, an alkyl group having 1 to 20 carbon atoms or alkoxy group having 1 to 20 carbon atoms, and n represents an integer in a range of 0 to 5. When n is an integer of 2 or more, plural R may be mutually the same or different.

An example of a preferable specific compound is a nitrogen-containing heterocyclic derivative represented by the following formula:

HAr-L¹-Ar¹—Ar²

where, HAr represents a substituted or unsubstituted nitrogen-containing heterocyclic group having 1 to 40 ring carbon atoms, L¹ represents a single bond, substituted or unsubstituted aromatic hydrocarbon group or fused aromatic hydrocarbon group having 6 to 40 ring carbon atoms, or substituted or unsubstituted aromatic heterocyclic group or fused aromatic heterocyclic group having 2 to 40 ring carbon atoms, Ar¹ represents a substituted or unsubstituted divalent aromatic hydrocarbon group having 6 to 40 ring carbon atoms; and Ar² represents a substituted or unsubstituted aromatic hydrocarbon group or fused aromatic hydrocarbon group having 6 to 40 ring carbon atoms, or substituted or unsubstituted aromatic heterocyclic group or fused aromatic heterocyclic group having 2 to 40 ring carbon atoms.

Examples of HAr can be selected from the following group:

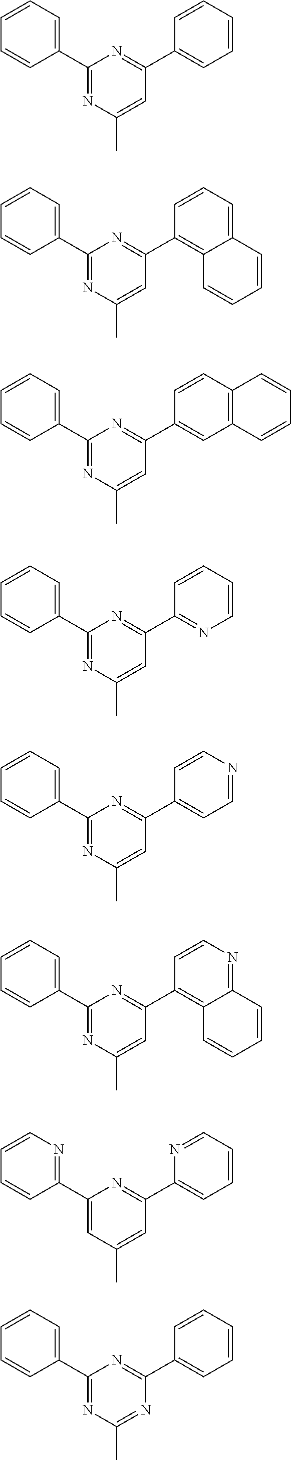

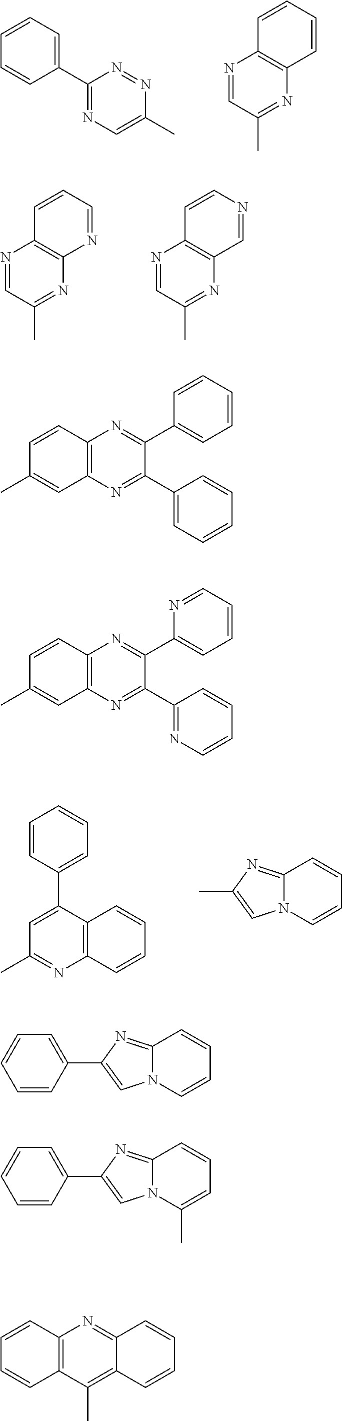

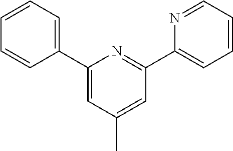 [SMILES: Cc1cc(-c2ccccc2)nc(-c2ccccn2)c1]

Examples of L¹ can be selected from the following group:

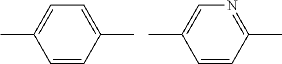

Examples of Ar¹ can be selected from the following group:

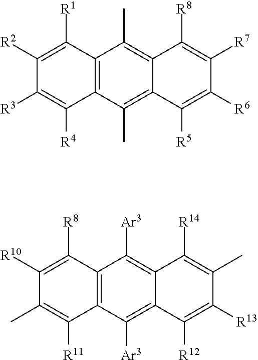

where, R¹ to R¹⁴ each independently represent a hydrogen atom, halogen atom, alkyl group having 1 to 20 carbon atoms, alkoxy group having 1 to 20 carbon atoms, aryloxy group having 6 to 40 ring carbon atoms, substituted or unsubstituted aromatic hydrocarbon group or fused aromatic hydrocarbon group having 6 to 40 ring carbon atoms, or aromatic heterocyclic group or fused aromatic heterocyclic group having 2 to 40 ring carbon atoms; and Ar³ represents aromatic hydrocarbon group or fused aromatic hydrocarbon group having 6 to 40 ring carbon atoms, or aromatic heterocyclic group or fused aromatic heterocyclic group having 2 to 40 ring carbon atoms. All of R¹ to R⁸ of a nitrogen-containing heterocyclic derivative may be hydrogen atoms.

Examples of Ar² can be selected from the following group:

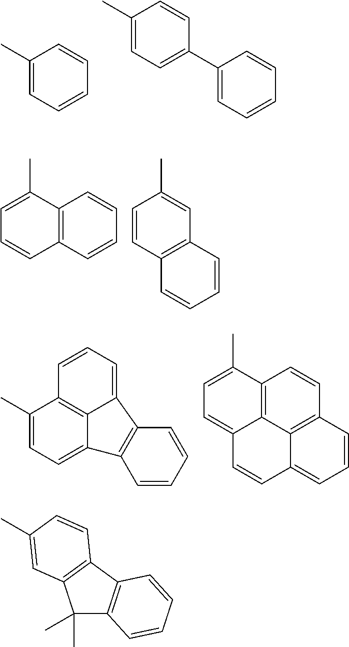

In addition to the above examples, the following nitrogen-containing aromatic polycyclic organic compound (see JP-A-9-3448) can be favorably used as the electron transporting compound.

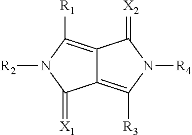

where, R₁ to R₄ each independently represent a hydrogen atom, substituted or unsubstituted aliphatic group, substituted or unsubstituted alicyclic group, substituted or unsubstituted carbocyclic aromatic cyclic group or substituted or unsubstituted heterocyclic group; and X₁ and X₂ each independently represent an oxygen atom, sulfur atom or dicyanomethylene group.

Additional examples of compounds that can be used as electron transporting material can be found in JP-A-2000-173774.

The electron injecting layer preferably contains an inorganic compound such as an insulator or a semiconductor in addition to the nitrogen-containing cyclic derivative. Such an insulator or a semiconductor, when contained in the electron injecting layer, can effectively prevent a current leak, thereby enhancing electron capability of the electron injecting layer.

As the insulator, it is preferable to use at least one metal compound selected from the group consisting of an alkali metal chalcogenide, an alkali earth metal chalcogenide, a halogenide of alkali metal and a halogenide of alkali earth metal. By forming the electron injecting layer from the alkali metal chalcogenide or the like, the electron injecting capability can preferably be further enhanced. Specifically, preferred examples of the alkali metal chalcogenide are Li₂O, K₂O, Na₂S, Na₂Se and Na₂O, while preferable example of the alkali earth metal chalcogenide are CaO, BaO, SrO, BeO, BaS and CaSe. Preferred examples of the halogenide of the alkali metal are LiF, NaF, KF, LiCl, KCl and NaCl. Preferred examples of the halogenide of the alkali earth metal are fluorides such as CaF₂, BaF₂, SrF₂, MgF₂ and BeF₂, and halogenides other than the fluoride.

Examples of the semiconductor are one of or a combination of two or more of an oxide, a nitride or an oxidized nitride containing at least one element selected from Ba, Ca, Sr, Yb, Al, Ga, In, Li, Na, Cd, Mg, Si, Ta, Sb and Zn. An inorganic compound for forming the electron injecting layer is preferably a microcrystalline or amorphous semiconductor film. When the electron injecting layer is formed of such insulator film, more uniform thin film can be formed, thereby reducing pixel defects such as a dark spot. Examples of such an inorganic compound are the above-described alkali metal chalcogenide, alkali earth metal chalcogenide, halogenide of the alkali metal and halogenide of the alkali earth metal.

When the electron injecting layer contains such an insulator or such a semiconductor, a thickness thereof is preferably in a range of approximately 0.1 nm to 15 nm. The electron injecting layer in this exemplary embodiment may preferably contain the above-described reduction-causing dopant.

### [HIL/HTL]

The hole injecting layer or the hole transporting layer (including the hole injecting/transporting layer) may contain an aromatic amine compound such as an aromatic amine derivative represented by the following general formula (I).

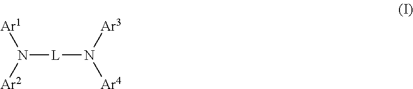

where, Ar¹ to Ar⁴ each represent a substituted or unsubstituted aromatic hydrocarbon group or fused aromatic hydrocarbon group having 6 to 50 ring carbon atoms, substituted or unsubstituted aromatic heterocyclic group or fused aromatic heterocyclic group having 2 to 40 ring carbon atoms, or a group formed by combining the aromatic hydrocarbon group or the fused aromatic hydrocarbon group with the aromatic heterocyclic group or fused aromatic heterocyclic group.

Some examples of the compound represented by the general formula (I) can be found, for example, in United States Patent Application Publication No. US 2011/0278555 A1, the disclosures of which is incorporated herein by reference. However, the compound represented by the general formula (I) is not limited thereto.

Aromatic amine represented by the following formula (II) can also be used for forming the hole injecting layer or the hole transporting layer.

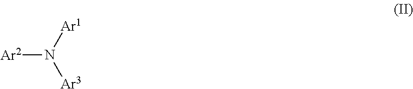

where, Ar¹ to Ar³ each represent the same as Ar¹ to Ar⁴ of the formula (I) above. Some examples of the compound represented by the general formula (II) can be found, for example, in United States Patent Application Publication No. US 2011/0278555 A1, the disclosures of which is incorporated herein by reference. However, the compound represented by the general formula (II) is not limited thereto.

A method of forming each of the layers in the organic EL device of the various embodiments described herein is not particularly limited. A conventionally-known methods such as vacuum deposition or spin coating may be employed for forming the layers. The organic thin-film layer containing the compound represented by the formula (1A) or (1B), which is used in the organic EL device according to this exemplary embodiment, may be formed by a conventional coating method such as vacuum deposition, molecular beam epitaxy (MBE method) and coating methods using a solution such as a dipping, spin coating, casting, bar coating, and roll coating.

Although the thickness of each organic layer of the organic EL device according to this exemplary embodiment is not particularly limited, the thickness is generally preferably in a range of several nanometers to 1 μm because an excessively-thinned film likely entails defects such as a pin hole while an excessively-thickened film requires high voltage to be applied and deteriorates efficiency.

In an OLED embodiment according to the present disclosure, a plurality of organic thin film layers provided between a cathode and an anode; the plurality of organic thin film layers comprise at least one phosphorescence emitting layer comprising at least one phosphorescent dopant material and at least one biscarbazole derivative host material as described below.

As described above, a phosphorescence emitting layer having high efficiency and long lifetime can be prepared according to the teachings of the present invention, especially a high stability at high operating temperatures.

In this regard, an excited triplet energy gap Eg(T) of the material constituting the OLED of the present disclosure may be prescribed based on its phosphorescence emission spectrum, and it is given as an example in the present disclosure that the energy gap may be prescribed, as is commonly used, in the following manner.

The respective materials are dissolved in an EPA solvent (diethyl ether:isopentane:ethanol=5:5:2 in terms of a volume ratio) in a concentration of 10 μmol/L to prepare a sample for measuring phosphorescence. This phosphorescence measuring sample is placed in a quartz cell and cooled to 77 K, and is subsequently irradiated with exciting light to measure the wavelength of a phosphorescence emitted.

A tangent line is drawn based on the increase of phosphorescence emission spectrum thus obtained at the short wavelength side, and the wavelength value of the intersection point of the above tangent line and the base line is converted to an energy value, which is set as an excited triplet energy gap Eg(T). A commercially available measuring equipment F-4500 (manufactured by Hitachi, Ltd.) can be used for the measurement.

However, a value which can be defined as the triplet energy gap can be used without depending on the above procedure as long as it does not deviate from the scope of the present invention.

### [Biscarbazone Derivative as a Host Material in a Co-Host Device]

According to another embodiment, the organic electroluminescence device comprises a cathode, an anode, and a plurality of organic thin-film layers provided between the cathode and the anode. The plurality of organic thin-film layers comprises at least one emitting layer and the at least one of the emitting layers comprises a first host material, a second host material that is different from the first host material and a red phosphorescent dopant material.

The first host material is the biscarbazole derivative compound represented by the formulas (1) and preferably represented by the formula (2) as described above. According to another aspect of the present disclosure, more preferably, the first host material is the biscarbazole derivative compound represented by the formula (H1) as described above. The red phosphorescent dopant material in this embodiment is the phosphorescent organometallic complex having a substituted chemical structure represented by one of the partial chemical structures represented by the formulas (D1), (D2), and (D3) as described above.

However, as mentioned previously above, a luminous efficiency and lifetime of multilayered organic EL devices depend on a carrier balance of the entire organic EL device. The main factors for controlling the carrier balance are carrier transporting capability of each of the organic layers and carrier injecting capability in the interfacial region of separate organic layers. In order to balance the carrier injecting capability to neighboring layers in the emitting layer (recombination region), it is preferable to adjust the carrier balance by a plurality of host materials. Specifically, it is preferable that, in addition to the first host material, the second host material is suitably selected as a co-host in the emitting layer. The co-host system of the combinations disclosed herein were found to provide such enhancements.

According to another aspect of the present disclosure, the red phosphorescent dopant material in this embodiment is preferably the iridium compound represented by the formulas (D4), (D5), (D6) or (D7) as described above. According to another aspect of the present disclosure, the red phosphorescent dopant material in this embodiment is more preferably the iridium compound represented by the formulas (D8) or (D9) as described above

When a material having a poor electron injecting capability (e.g., metal chelate complex) is used as the cathode, a carrier balance in the emitting layer becomes shifted toward the cathode. For improving such a disadvantage, it is preferable to select a material having a high electron transporting capability as the second host material. Specifically, the second host material of this embodiment is preferably represented by a formula (5) or (6) provided below.

(Cz-)ₐA³ (5)

Cz(-A³)_{b} (6)

In the formula (5) or (6): Cz represents a substituted or unsubstituted arylcarbazolyl group or carbazolylaryl group; A³ represents a group represented by a formula (7A) below; and a and b each represent an integer of 1 to 3.

(M¹)_{c}-(L⁵)_{d}-(M²)ₑ (7A)

In the formula (7A), M¹ and M² each independently represent a substituted or unsubstituted nitrogen-containing aromatic heterocyclic ring or nitrogen-containing fused aromatic heterocyclic ring having 2 to 40 ring carbon atoms; M¹ and M² may be the same or different; L⁵ represents a single bond, substituted or unsubstituted aromatic hydrocarbon group having 6 to 30 carbon atoms, substituted or unsubstituted fused aromatic hydrocarbon group having 6 to 30 carbon atoms, substituted or unsubstituted cycloalkylene group having 5 to 30 carbon atoms, substituted or unsubstituted aromatic heterocyclic group having 2 to 30 carbon atoms, or substituted or unsubstituted fused aromatic heterocyclic group having 2 to 30 carbon atoms; c represents an integer of 0 to 2; d represents an integer of 1 to 2; e represents an integer of 0 to 2; and c+e represents 1 or more.

### [Compounds Represented by Formulas (5) and (6)]

Cz is a substituted or unsubstituted arylcarbazolyl group or substituted or unsubstituted carbazolylaryl group. An arylcarbazolyl group means a carbazolyl group having at least one aryl group or heteroaryl group as a substituent, in which a position where the aryl group or heteroaryl group is substituted does not matter. Specific examples are as follows. In the following chemical formulas, Ar represents an aryl group or heteroaryl group. * represents a position where another group is bonded.

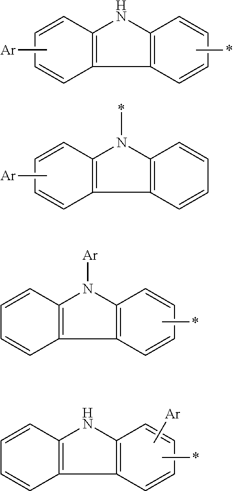

A carbazolylaryl group means an aryl group having at least one carbazolyl group as a substituent, in which a position where the aryl group is substituted does not matter. Specific examples are as follows. In the following chemical formulas, Ar represents an aryl group. * represents a position where another group is bonded.

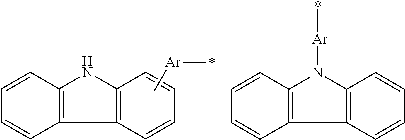

A substituted arylcarbazolyl group means the arylcarbazolyl group having at least one substituent irrespective of a substitution position. A substituted carbazolylaryl group means the carbazolylaryl group having at least one substituent irrespective of a substitution position.

In the formulae (5) and (6), a and b each represent an integer of 1 to 3. An aryl group in the arylcarbazolyl group or carbazolylaryl group preferably has 6 to 30 carbon atoms. Examples of the aryl group are a phenyl group, naphthyl group, anthryl group, phenanthryl group, naphthacenyl group, pyrenyl group, fluorenyl group, biphenyl group and terphenyl group, among of which a phenyl group, naphthyl group, biphenyl group and terphenyl group are preferable.

Examples of the heteroaryl group in the arylcarbazolyl group are groups formed based on rings of pyridine, pyrimidine, pyrazine, triazine, aziridine, azaindolizine, indolizine, imidazoles, indole, isoindole, indazole, purine, pteridine, â-carboline, naphthyridine, quinoxaline, terpyridine, bipyridine, acridine, phenanthroline, phenazine and imidazopyridine, among which rings of pyridine, terpyridine, pyrimidine, imidazopyridine and triazine are preferable.

A³ in the formulae (5) and (6) is a group represented by the formula (7A).

In the formula (7A), M¹ and M² each independently represent a substituted or unsubstituted nitrogen-containing heterocyclic group having 2 to 40 ring carbon atoms. M¹ and M² may be the same or different.

Examples of the nitrogen-containing heterocyclic ring in the arylcarbazolyl group are groups formed based on rings of pyridine, pyrimidine, pyrazine, triazine, aziridine, azaindolizine, indolizine, imidazoles, indole, isoindole, indazole, purine, pteridine, â-carboline, naphthyridine, quinoxaline, terpyridine, bipyridine, acridine, phenanthroline, phenazine and imidazopyridine, among which rings of pyridine, terpyridine, pyrimidine, imidazopyridine and triazine are preferable.

L⁵ represents a single bond, substituted or unsubstituted aromatic hydrocarbon group or fused aromatic hydrocarbon group having 6 to 30 carbon atoms, substituted or unsubstituted cycloalkylene group having 5 to 30 carbon atoms, or substituted or unsubstituted aromatic heterocyclic group or fused aromatic heterocyclic group having 2 to 30 carbon atoms. c represents an integer of 0 to 2; d represents an integer of 1 to 2; e represents an integer of 0 to 2; and c+e represents 1 or more.

Examples of the aromatic hydrocarbon group or fused aromatic hydrocarbon group having 6 to 30 carbon atoms are a phenyl group, biphenyl group, terphenyl group, naphthyl group, anthranil group, phenanthryl group, pyrenyl group, crycenyl group, fluoranthenyl group and perfluoroaryl group, fluorenyl group, and 9,9-dimethylfluorenyl group, among which a phenyl group, biphenyl group, terphenyl group and perfluoroaryl group are preferable.

Examples of the cycloalkylene group having 5 to 30 carbon atoms are cyclopentyl group, cyclohexylene group, and cyclohepthylene group, among which a cyclohexylene group is preferable.

Examples of the aromatic heterocyclic group or fused aromatic heterocyclic group having 2 to 30 carbon atoms are 1-pyrrolyl group, 2-pyrrolyl group, 3-pyrrolyl group, pyrazinyl group, 2-pyridinyl group, 3-pyridinyl group, 4-pyridinyl group, 1-indolyl group, 2-indolyl group, 3-indolyl group, 4-indolyl group, 5-indolyl group, 6-indolyl group, 7-indolyl group, 1-isoindolyl group, 2-isoindolyl group, 3-isoindolyl group, 4-isoindolyl group, 5-isoindolyl group, 6-isoindolyl group, 7-isoindolyl group, 2-furyl group, 3-furyl group, 2-benzofuranyl group, 3-benzofuranyl group, 4-benzofuranyl group, 5-benzofuranyl group, 6-benzofuranyl group, 7-benzofuranyl group, 1-isobenzofuranyl group, 3-isobenzofuranyl group, 4-isobenzofuranyl group, 5-isobenzofuranyl group, 6-isobenzofuranyl group, 7-isobenzofuranyl group, 2-quinolyl group, 3-quinolyl group, 4-quinolyl group, 5-quinolyl group, 6-quinolyl group, 7-quinolyl group, 8-quinolyl group, 1-isoquinolyl group, 3-isoquinolyl group, 4-isoquinolyl group, 5-isoquinolyl group, 6-isoquinolyl group, 7-isoquinolyl group, 8-isoquinolyl group, 2-quinoxalinyl group, 5-quinoxalinyl group, 6-quinoxalinyl group, 1-carbazolyl group, 2-carbazolyl group, 3-carbazolyl group, 4-carbazolyl group, 9-carbazolyl group, 1-phenanthridinyl group, 2-phenanthridinyl group, 3-phenanthridinyl group, 4-phenanthridinyl group, 6-phenanthridinyl group, 7-phenanthridinyl group, 8-phenanthridinyl group, 9-phenanthridinyl group, 10-phenanthridinyl group, 1-acridinyl group, 2-acridinyl group, 3-acridinyl group, 4-acridinyl group, 9-acridinyl group, 1,7-phenanthrolin-2-yl group, 1,7-phenanthrolin-3-yl group, 1,7-phenanthrolin-4-yl group, 1,7-phenanthrolin-5-yl group, 1,7-phenanthrolin-6-yl group, 1,7-phenanthrolin-8-yl group, 1,7-phenanthrolin-9-yl group, 1,7-phenanthrolin-10-yl group, 1,8-phenanthrolin-2-yl group, 1,8-phenanthrolin-3-yl group, 1,8-phenanthrolin-4-yl group, 1,8-phenanthrolin-5-yl group, 1,8-phenanthrolin-6-yl group, 1,8-phenanthrolin-7-yl group, 1,8-phenanthrolin-9-yl group, 1,8-phenanthrolin-10-yl group, 1,9-phenanthrolin-2-yl group, 1,9-phenanthrolin-3-yl group, 1,9-phenanthrolin-4-yl group, 1,9-phenanthrolin-5-yl group, 1,9-phenanthrolin-6-yl group, 1,9-phenanthrolin-7-yl group, 1,9-phenanthrolin-8-yl group, 1,9-phenanthrolin-10-yl group, 1,10-phenanthrolin-2-yl group, 1,10-phenanthrolin-3-yl group, 1,10-phenanthrolin-4-yl group, 1,10-phenanthirolin-5-yl group, 2,9-phenanthrolin-1-yl group, 2,9-phenanthrolin-3-yl group, 2,9-phenanthrolin-4-yl group, 2,9-phenanthrolin-5-yl group, 2,9-phenanthrolin-6-yl group, 2,9-phenanthrolin-7-yl group, 2,9-phenanthrolin-8-yl group, 2,9-phenanthrolin-10-yl group, 2,8-phenanthrolin-1-yl group, 2,8-phenanthrolin-3-yl group, 2,8-phenanthrolin-4-yl group, 2,8-phenanthrolin-5-yl group, 2,8-phenanthrolin-6-yl group, 2,8-phenanthrolin-7-yl group, 2,8-phenanthrolin-9-yl group, 2,8-phenanthrolin-10-yl group, 2,7-phenanthrolin-1-yl group, 2,7-phenanthrolin-3-yl group, 2,7-phenanthrolin-4-yl group, 2,7-phenanthrolin-5-yl group, 2,7-phenanthrolin-6-yl group, 2,7-phenanthrolin-8-yl group, 2,7-phenanthrolin-9-yl group, 2,7-phenanthrolin-10-yl group, 1-phenazinyl group, 2-phenazinyl group, 1-phenothiazinyl group, 2-phenothiazinyl group, 3-phenothiazinyl group, 4-phenothiazinyl group, 10-phenothiazinyl group, 1-phenoxazinyl group, 2-phenoxazinyl group, 3-phenoxazinyl group, 4-phenoxazinyl group, 10-phenoxazinyl group, 2-oxazolyl group, 4-oxazolyl group, 5-oxazolyl group, 2-oxadiazolyl group, 5-oxadiazolyl group, 3-furazanyl group, 2-thienyl group, 3-thienyl group, 2-methylpyrrol-1-yl group, 2-methylpyrrol-3-yl group, 2-methylpyrrol-4-yl group, 2-methylpyrrol-5-yl group, 3-methylpyrrol-1-yl group, 3-methylpyrrol-2-yl group, 3-methylpyrrol-4-yl group, 3-methylpyrrol-5-yl group, 2-t-butylpyrrol-4-yl group, 3-(2-phenylpropyl)pyrrol-1-yl group, 2-methyl-1-indolyl group, 4-methyl-1-indolyl group, 2-methyl-3-indolyl group, 4-methyl-3-indolyl group, 2-t-butyl-1-indolyl group, 4-t-butyl-1-indolyl group, 2-t-butyl-3-indolyl group, and 4-t-butyl-3-indolyl group, among which a pyridinyl group and quinolyl group are preferable.

Some examples of the substituents for Cz, M¹ and M² in the formulae (5), (6) and (7A) are a halogen atom such as chlorine, bromine and fluorine, carbazole group, hydroxyl group, substituted or unsubstituted amino group, nitro group, cyano group, silyl group, trifluoromethyl group, carbonyl group, carboxyl group, substituted or unsubstituted alkyl group, substituted or unsubstituted alkenyl group, substituted or unsubstituted arylalkyl group, substituted or unsubstituted aromatic hydrocarbon group or fused aromatic hydrocarbon group, substituted or unsubstituted aromatic heterocyclic group or fused aromatic heterocyclic group, substituted or unsubstituted aralkyl group, substituted or unsubstituted aryloxy group, and substituted or unsubstituted alkyloxy group. Among these, a fluorine atom, methyl group, perfluorophenylene group, phenyl group, naphthyl group, pyridyl group, pyrazil group, pyrimidyl group, adamantyl group, benzyl group, cyano group and silyl group are preferable.

Bonding patterns of the compound represented by the formula (5) or (6) are shown in Table 1 below in accordance with values of a and b.

TABLE 1

| a = b = 1 | a = 2 | a = 3 | b = 2 | b = 3 |
|---|---|---|---|---|
| Cz—A³ | Cz—A³—Cz | 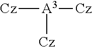 | A³—Cz—A³ | 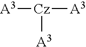 |

Bonding patterns of the compound represented by the formula (7A) are shown in Tables 2 and 3 below in accordance with values of c, d and e.

TABLE 2

| No | c | d | e | Bonding Patterns |
|---|---|---|---|---|
| (1) | 0 | 1 | 1 | L⁵—M² |
| (2) | 0 | 1 | 2 | L⁵—M²—M², M²—L⁵—M² |
| (3) | 0 | 2 | 1 | L⁵—L⁵—M², L⁵—M²—L⁵ |
| (4) | 0 | 2 | 2 | L⁵—L⁵—M²—M², M²—L⁵—L⁵—M², |
| | | | | 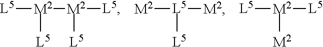 |
| (5) | 1 | 1 | 0 | the same as [1] (M² is replaced with M¹) |
| (6) | 1 | 1 | 1 | M¹—L⁵—M² |
| (7) | 1 | 1 | 2 | 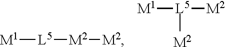 |
| (8) | 1 | 2 | 0 | the same as [3] (M² is replaced with M¹) |
| (9) | 1 | 2 | 1 | M¹—L⁵—L⁵—M², L⁵—M¹—L⁵—M², |
| | | | | L⁵—M¹—L⁵—M² |
| (10) | 1 | 2 | 2 | M¹—L⁵—L⁵—M²—M², M²—L⁵—M¹—L⁵—M², |
| | | | | 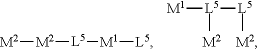 |
| | | | | 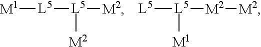 |
| | | | | 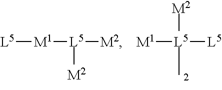 |
| (11) | 2 | 1 | 0 | the same as [2] (M² is replaced with M¹) |
| (12) | 2 | 1 | 1 | the same as [7] (M² is replaced with M¹) |
| (13) | 2 | 1 | 2 | M¹—M¹—L⁵—M²—M², |
| | | | | 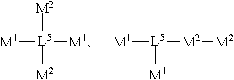 |

TABLE 3

| No | c | d | c | Bonding Patterns |
|---|---|---|---|---|
| (14) | 2 | 2 | 0 | the same as [4] (M² is replaced with M¹) |
| (15) | 2 | 2 | 1 | the same as [10] (M² is replaced with M¹) |
| (16) | 2 | 2 | 2 | M¹—M¹—L⁵—L⁵—M²—M², |
| | | | | 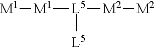 |
| | | | | 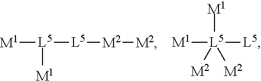 |
| | | | | 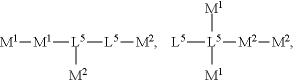 |
| | | | | 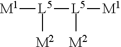 |

Cz bonded to A³ may be bonded to any one of M¹, L⁵ and M² of the formula (7A) representing A³.

For instance, when a=b=1 and Cz-A³-Cz are given in the formula (5) or (6) and [6] (c=d=e=1) of Table 2 is given in the formula (A), three bonding patterns of Cz-M¹-L⁵-M², M¹-L⁵(Cz)-M², and M¹-L⁵-M²-Cz are listed.

Moreover, for instance, when a=2 and Cz-A³-Cz are given in the formula (5) and [7] (c=d=1, e=2) Table 2 is given in the formula (7A), the following bonding patterns are listed.

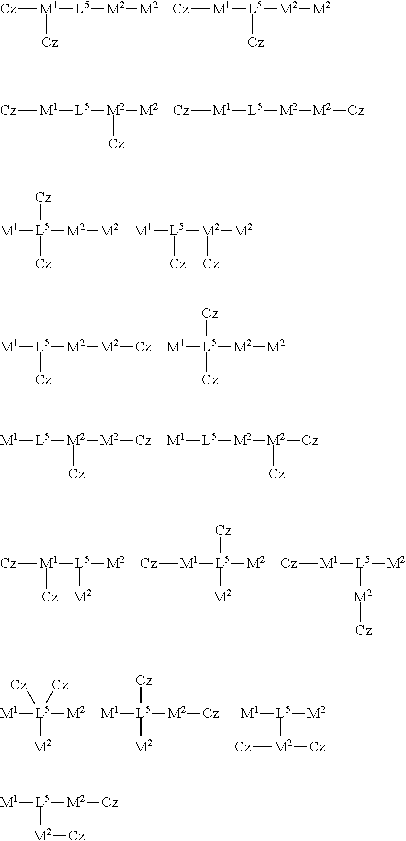

In the bonding patterns of the formulae (5), (6) and (7A) and exemplary combinations of the groups as described above, compounds represented by [1] to [4] below are preferable.

[1] a=1 is given in the formula (5) and c=1 and d=0 are given in the formula (7A). In the formula (5), Cz is a substituted or unsubstituted arylcarbazolyl group or substituted or unsubstituted carbazolylaryl group. In the formula (7A): M¹ is a substituted or unsubstituted nitrogen-containing six-membered or seven-membered hetero ring having 4 to 5 ring carbon atoms, substituted or unsubstituted nitrogen-containing five-membered hetero ring having 2 to 4 ring carbon atoms, substituted or unsubstituted nitrogen-containing hetero ring having 8 to 11 ring carbon atoms, substituted or unsubstituted imidazopyridinyl ring; and L⁵ is a substituted or unsubstituted aryl group or aromatic hydrocarbon group or fused aromatic hydrocarbon group having 6 to 30 carbon atoms and substituted or unsubstituted aromatic heterocyclic group or fused aromatic heterocyclic group having 2 to 30 carbon atoms.

[2] a=2 is given in the formula (5) and c=1 and e=0 are given in the formula (7A). In the formula (5), Cz is a substituted or unsubstituted arylcarbazolyl group or substituted or unsubstituted carbazolylaryl group. In the formula (7A): M¹ is a substituted or unsubstituted nitrogen-containing six-membered or seven-membered hetero ring having 4 to 5 ring carbon atoms, substituted or unsubstituted nitrogen-containing five-membered hetero ring having 2 to 4 ring carbon atoms, substituted or unsubstituted nitrogen-containing hetero ring having 8 to 11 ring carbon atoms, substituted or unsubstituted imidazopyridinyl ring; and L⁵ is a substituted or unsubstituted aryl group or aromatic hydrocarbon group or fused aromatic hydrocarbon group having 6 to 30 carbon atoms and substituted or unsubstituted aromatic heterocyclic group or fused aromatic heterocyclic group having 2 to 30 carbon atoms.

[3] a=1 is given in the formula (5) and c=2 and e=0 are given in the formula (7A). In the formula (5), Cz is a substituted or unsubstituted arylcarbazolyl group or substituted or unsubstituted carbazolylaryl group. In the formula (7A): M¹ is a substituted or unsubstituted nitrogen-containing six-membered or seven-membered hetero ring having 4 to 5 ring carbon atoms, substituted or unsubstituted nitrogen-containing five-membered hetero ring having 2 to 4 ring carbon atoms, substituted or unsubstituted nitrogen-containing hetero ring having 8 to 11 ring carbon atoms, substituted or unsubstituted imidazopyridinyl ring; and L⁵ is a substituted or unsubstituted aryl group or aromatic hydrocarbon group or fused aromatic hydrocarbon group having 6 to 30 carbon atoms and substituted or unsubstituted aromatic heterocyclic group or fused aromatic heterocyclic group having 2 to 30 carbon atoms.

[4] b=2 is given in the formula (6) and c=d=1 is given in the formula (7A). In the formula (6), Cz is a substituted or unsubstituted arylcarbazolyl group or substituted or unsubstituted carbazolylaryl group. In the formula (7A): M¹ is a substituted or unsubstituted nitrogen-containing six-membered or seven-membered hetero ring having 4 to 5 ring carbon atoms, substituted or unsubstituted nitrogen-containing five-membered hetero ring having 2 to 4 ring carbon atoms, substituted or unsubstituted nitrogen-containing hetero ring having 8 to 11 ring carbon atoms, substituted or unsubstituted imidazopyridinyl ring; and L⁵ is a substituted or unsubstituted aryl group or aromatic hydrocarbon group or fused aromatic hydrocarbon group having 6 to 30 carbon atoms and substituted or unsubstituted aromatic heterocyclic group or fused aromatic heterocyclic group having 2 to 30 carbon atoms.

In the formulae (5) and (6), Cz is preferably a substituted or unsubstituted arylcarbazolyl group, more preferably phenylcarbozolyl group. Moreover, an aryl site of the arylcarbazolyl group is preferably substituted by a carbazolyl group.

Some specific examples of the compound for the second host material represented by the formula (5) are shown below. However, the compound represented by the formula (5) is not limited thereto.

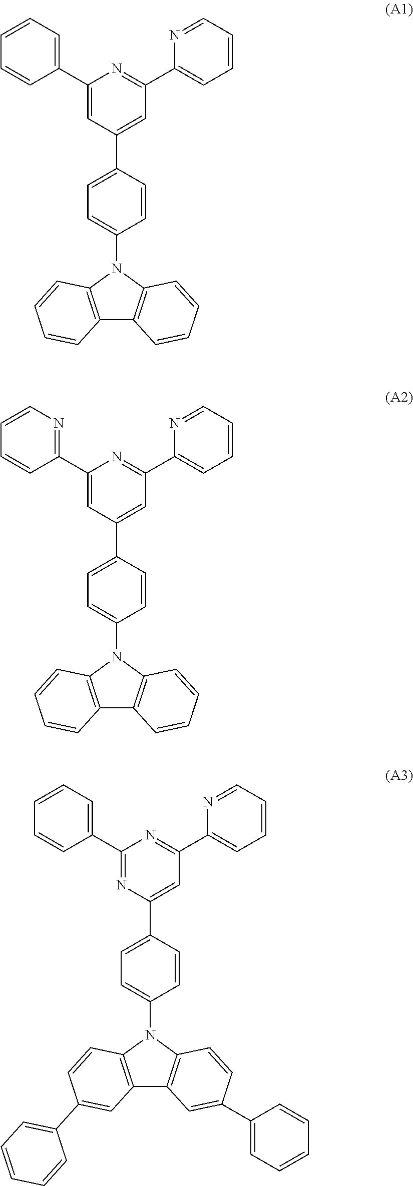 [SMILES: c1ccc(-c2cc(-c3ccc(-n4c5ccccc5c5ccccc54)cc3)cc(-c3ccccn3)n2)cc1 ; c1ccc(-c2cc(-c3ccc(-n4c5ccccc5c5ccccc54)cc3)cc(-c3ccccn3)n2)nc1 ; c1ccc(-c2ccc3c(c2)c2cc(-c4ccccc4)ccc2n3-c2ccc(-c3cc(-c4ccccn4)nc(-c4ccccc4)n3)cc2)cc1]

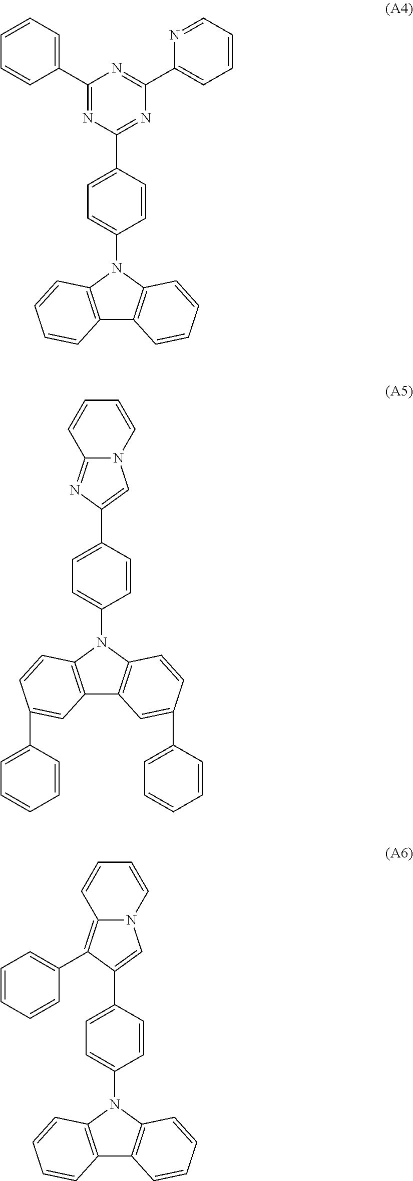 [SMILES: c1ccc(-c2nc(-c3ccc(-n4c5ccccc5c5ccccc54)cc3)nc(-c3ccccn3)n2)cc1 ; c1ccc(-c2ccc3c(c2)c2cc(-c4ccccc4)ccc2n3-c2ccc(-c3cn4ccccc4n3)cc2)cc1 ; c1ccc(-c2c(-c3ccc(-n4c5ccccc5c5ccccc54)cc3)cn3ccccc23)cc1]

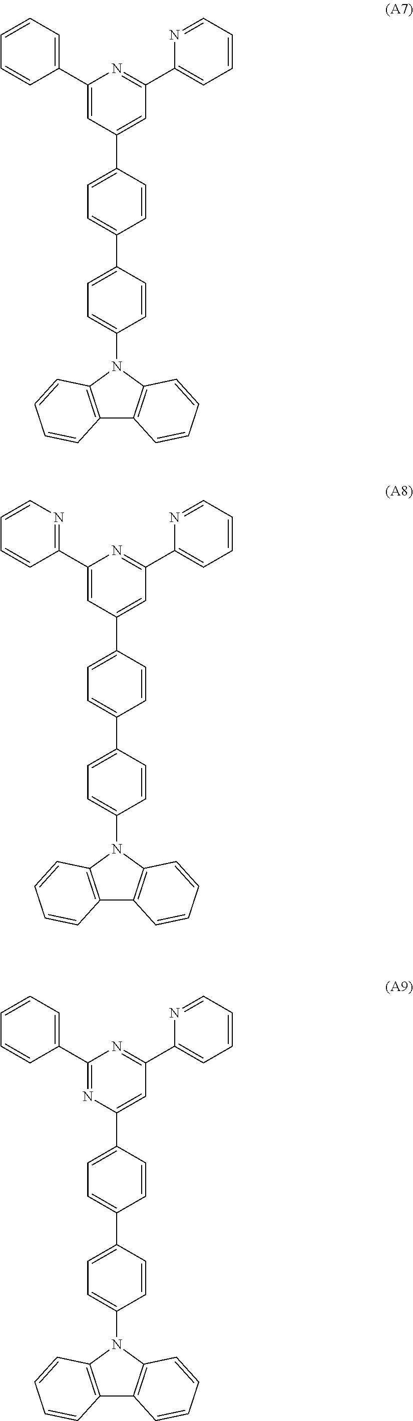 [SMILES: c1ccc(-c2cc(-c3ccc(-c4ccc(-n5c6ccccc6c6ccccc65)cc4)cc3)cc(-c3ccccn3)n2)cc1 ; c1ccc(-c2cc(-c3ccc(-c4ccc(-n5c6ccccc6c6ccccc65)cc4)cc3)cc(-c3ccccn3)n2)nc1 ; c1ccc(-c2nc(-c3ccc(-c4ccc(-n5c6ccccc6c6ccccc65)cc4)cc3)cc(-c3ccccn3)n2)cc1]

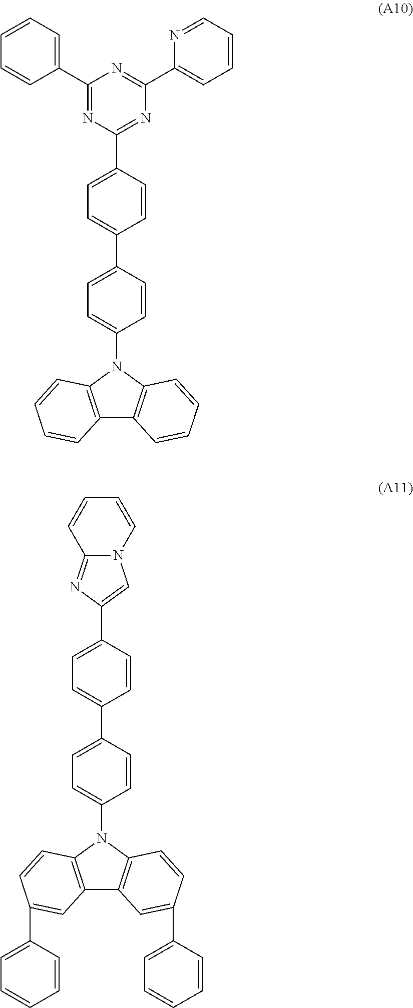 [SMILES: c1ccc(-c2nc(-c3ccc(-c4ccc(-n5c6ccccc6c6ccccc65)cc4)cc3)nc(-c3ccccn3)n2)cc1 ; c1ccc(-c2ccc3c(c2)c2cc(-c4ccccc4)ccc2n3-c2ccc(-c3ccc(-c4cn5ccccc5n4)cc3)cc2)cc1]

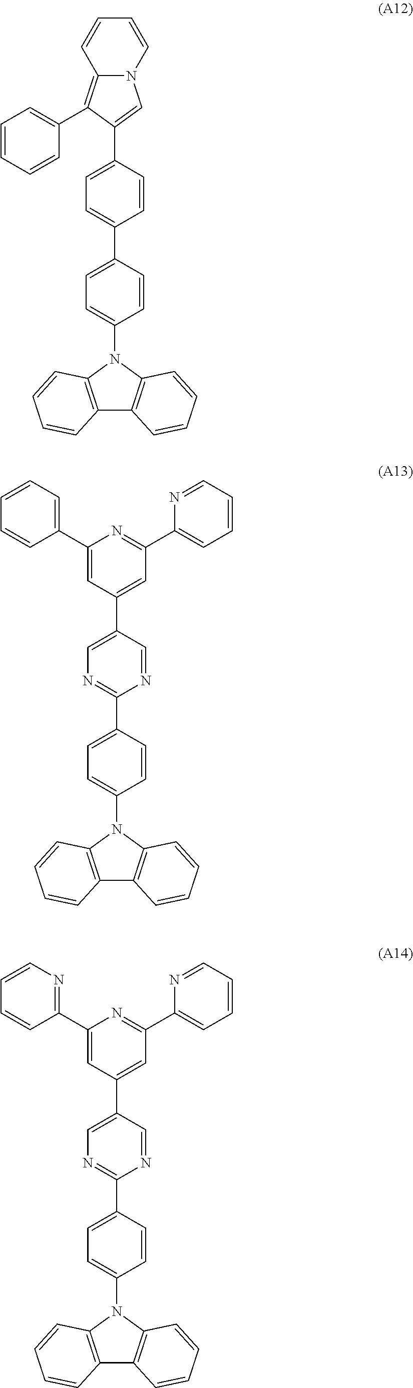 [SMILES: c1ccc(-c2c(-c3ccc(-c4ccc(-n5c6ccccc6c6ccccc65)cc4)cc3)cn3ccccc23)cc1 ; c1ccc(-c2cc(-c3cnc(-c4ccc(-n5c6ccccc6c6ccccc65)cc4)nc3)cc(-c3ccccn3)n2)cc1 ; c1ccc(-c2cc(-c3cnc(-c4ccc(-n5c6ccccc6c6ccccc65)cc4)nc3)cc(-c3ccccn3)n2)nc1]

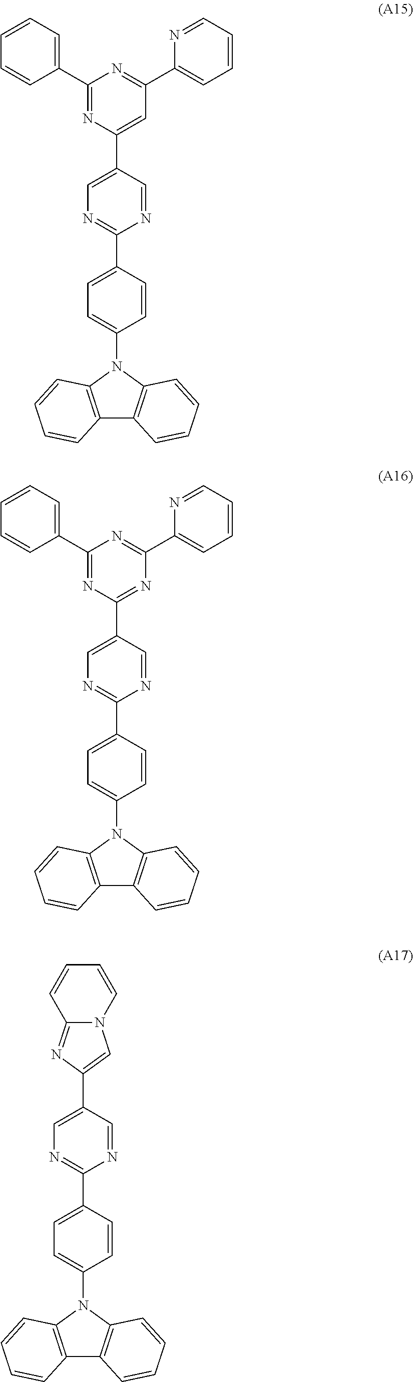 [SMILES: c1ccc(-c2nc(-c3cnc(-c4ccc(-n5c6ccccc6c6ccccc65)cc4)nc3)cc(-c3ccccn3)n2)cc1 ; c1ccc(-c2nc(-c3cnc(-c4ccc(-n5c6ccccc6c6ccccc65)cc4)nc3)nc(-c3ccccn3)n2)cc1 ; c1ccc2c(c1)c1ccccc1n2-c1ccc(-c2ncc(-c3cn4ccccc4n3)cn2)cc1]

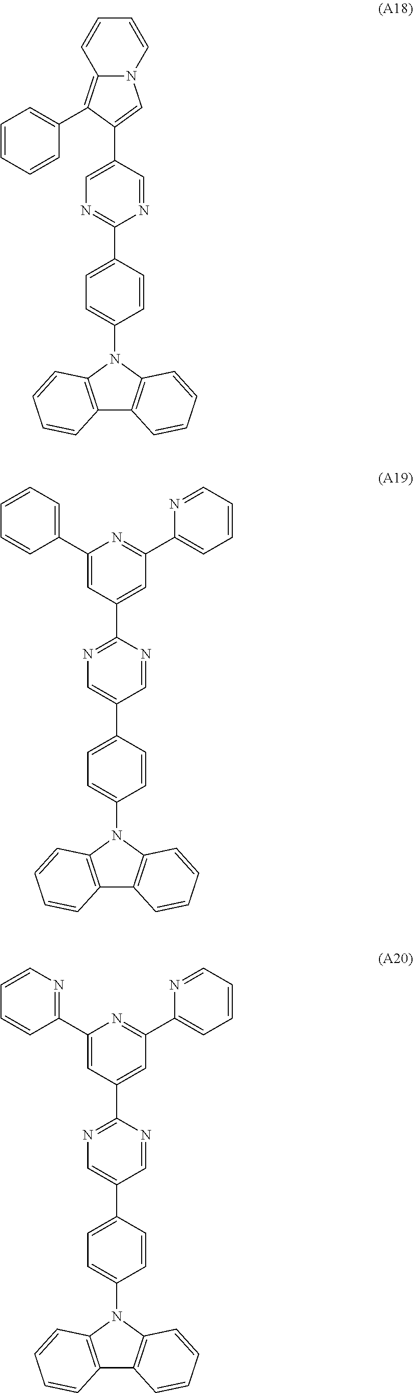 [SMILES: c1ccc(-c2c(-c3cnc(-c4ccc(-n5c6ccccc6c6ccccc65)cc4)nc3)cn3ccccc23)cc1 ; c1ccc(-c2cc(-c3ncc(-c4ccc(-n5c6ccccc6c6ccccc65)cc4)cn3)cc(-c3ccccn3)n2)cc1 ; c1ccc(-c2cc(-c3ncc(-c4ccc(-n5c6ccccc6c6ccccc65)cc4)cn3)cc(-c3ccccn3)n2)nc1]

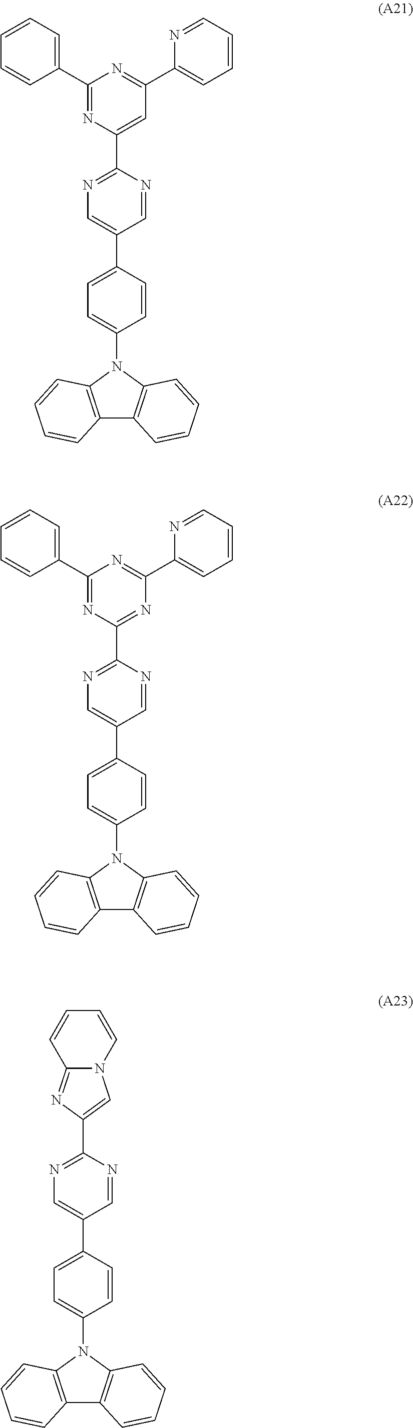 [SMILES: c1ccc(-c2nc(-c3ccccn3)cc(-c3ncc(-c4ccc(-n5c6ccccc6c6ccccc65)cc4)cn3)n2)cc1 ; c1ccc(-c2nc(-c3ccccn3)nc(-c3ncc(-c4ccc(-n5c6ccccc6c6ccccc65)cc4)cn3)n2)cc1 ; c1ccc2c(c1)c1ccccc1n2-c1ccc(-c2cnc(-c3cn4ccccc4n3)nc2)cc1]

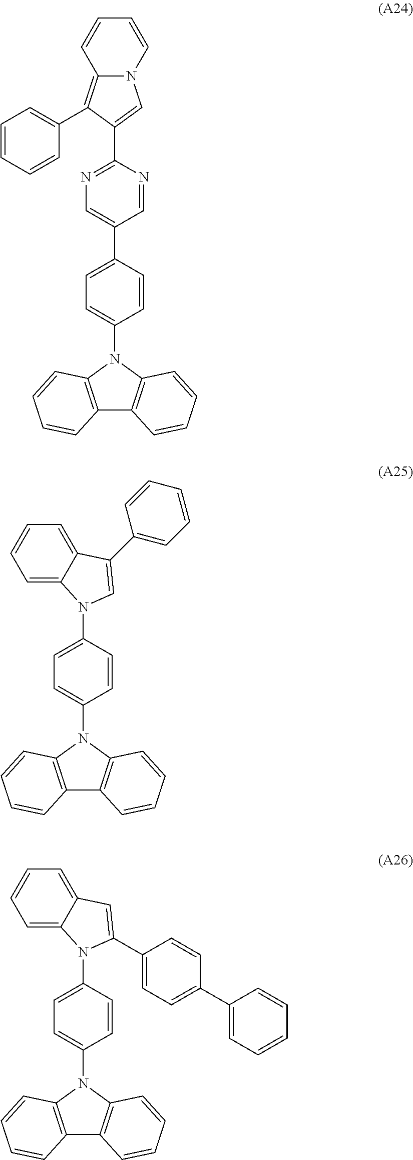

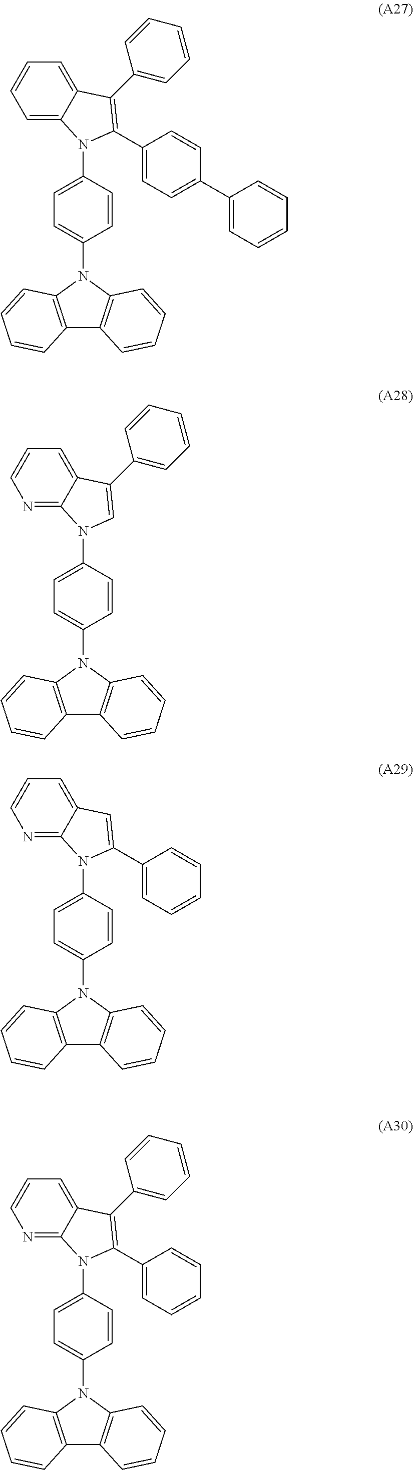

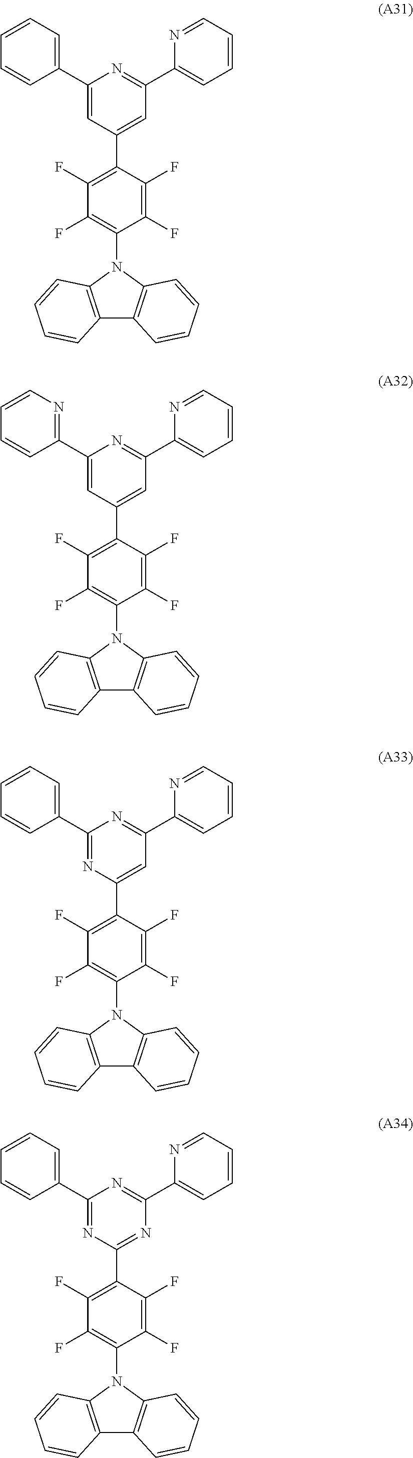 [SMILES: Fc1c(F)c(-n2c3ccccc3c3ccccc32)c(F)c(F)c1-c1cc(-c2ccccc2)nc(-c2ccccn2)c1 ; Fc1c(F)c(-n2c3ccccc3c3ccccc32)c(F)c(F)c1-c1cc(-c2ccccn2)nc(-c2ccccn2)c1 ; Fc1c(F)c(-n2c3ccccc3c3ccccc32)c(F)c(F)c1-c1cc(-c2ccccn2)nc(-c2ccccc2)n1 ; Fc1c(F)c(-n2c3ccccc3c3ccccc32)c(F)c(F)c1-c1nc(-c2ccccc2)nc(-c2ccccn2)n1]

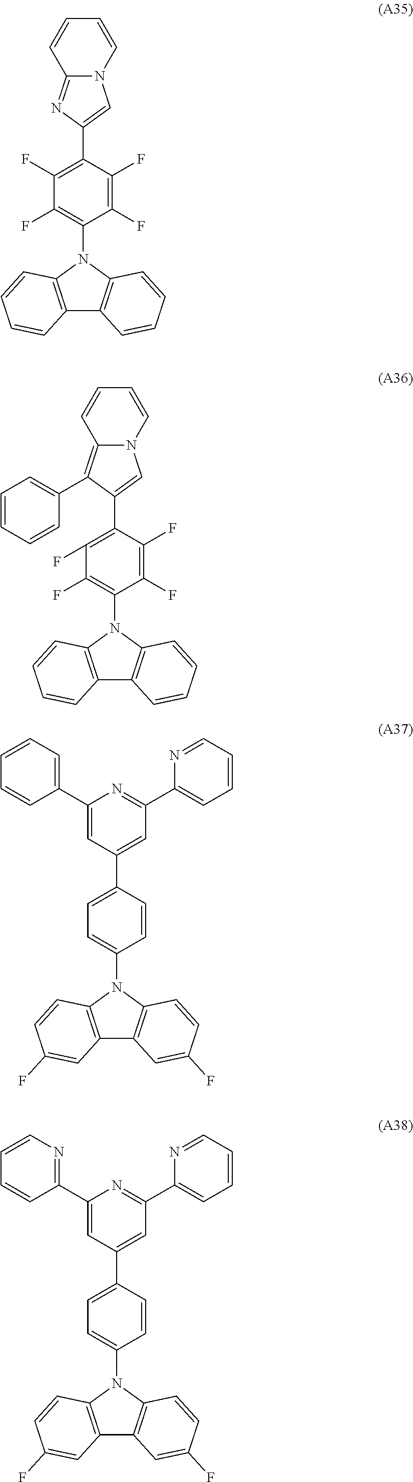

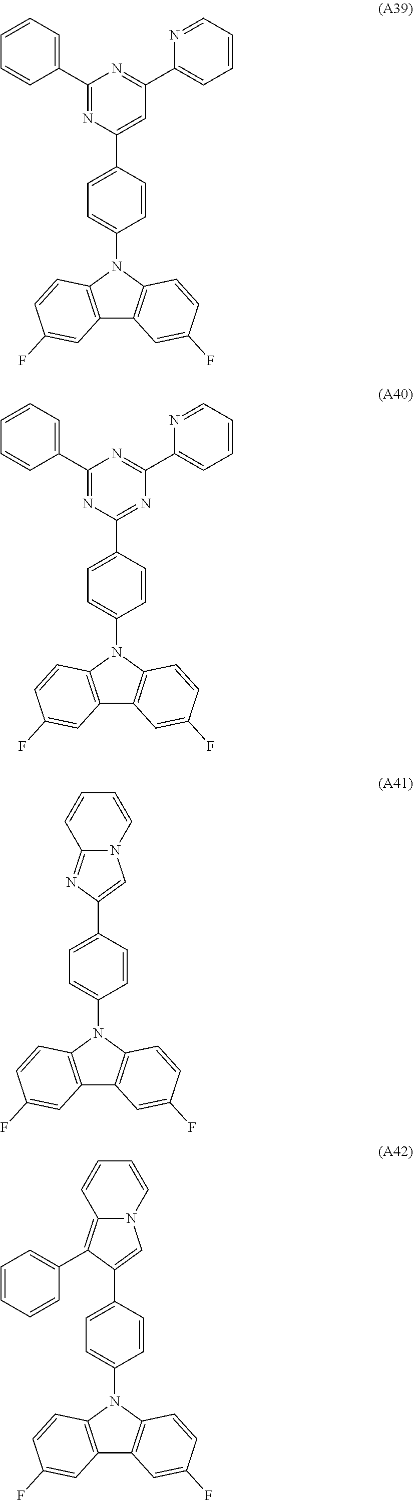

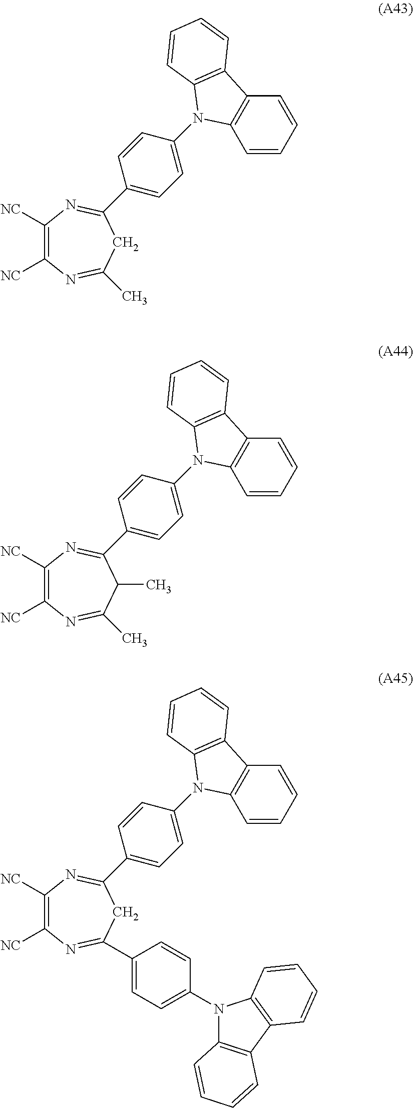 [SMILES: CC1=NC(C#N)=C(C#N)N=C(c2ccc(-n3c4ccccc4c4ccccc43)cc2)C1 ; CC1=NC(C#N)=C(C#N)N=C(c2ccc(-n3c4ccccc4c4ccccc43)cc2)C1C ; N#CC1=C(C#N)N=C(c2ccc(-n3c4ccccc4c4ccccc43)cc2)CC(c2ccc(-n3c4ccccc4c4ccccc43)cc2)=N1]

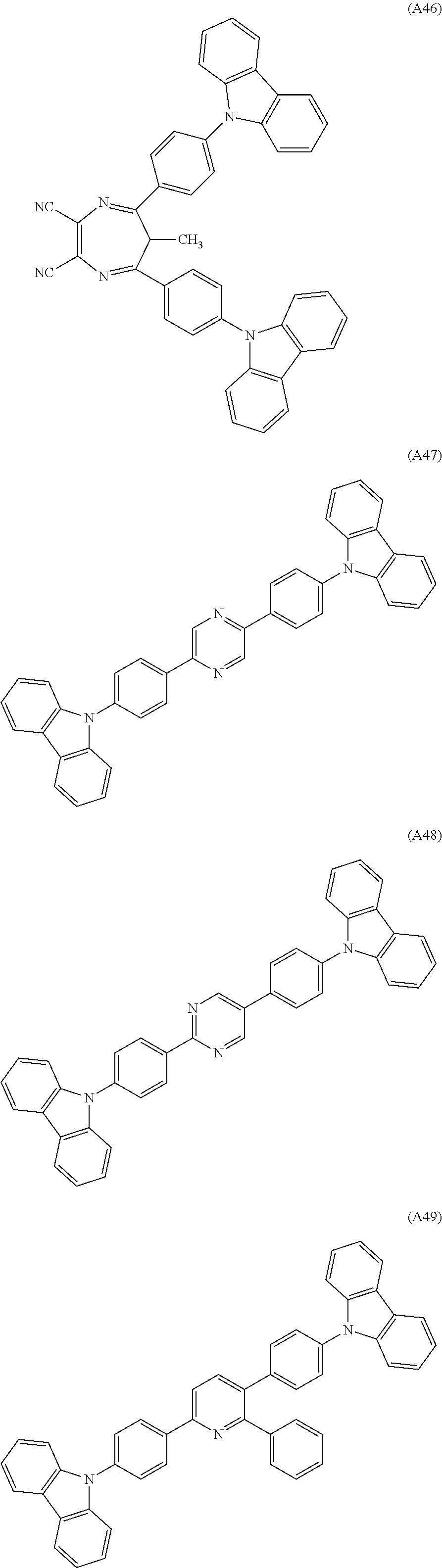 [SMILES: CC1C(c2ccc(-n3c4ccccc4c4ccccc43)cc2)=NC(C#N)=C(C#N)N=C1c1ccc(-n2c3ccccc3c3ccccc32)cc1 ; c1ccc2c(c1)c1ccccc1n2-c1ccc(-c2cnc(-c3ccc(-n4c5ccccc5c5ccccc54)cc3)cn2)cc1 ; c1ccc2c(c1)c1ccccc1n2-c1ccc(-c2cnc(-c3ccc(-n4c5ccccc5c5ccccc54)cc3)nc2)cc1 ; c1ccc(-c2nc(-c3ccc(-n4c5ccccc5c5ccccc54)cc3)ccc2-c2ccc(-n3c4ccccc4c4ccccc43)cc2)cc1]

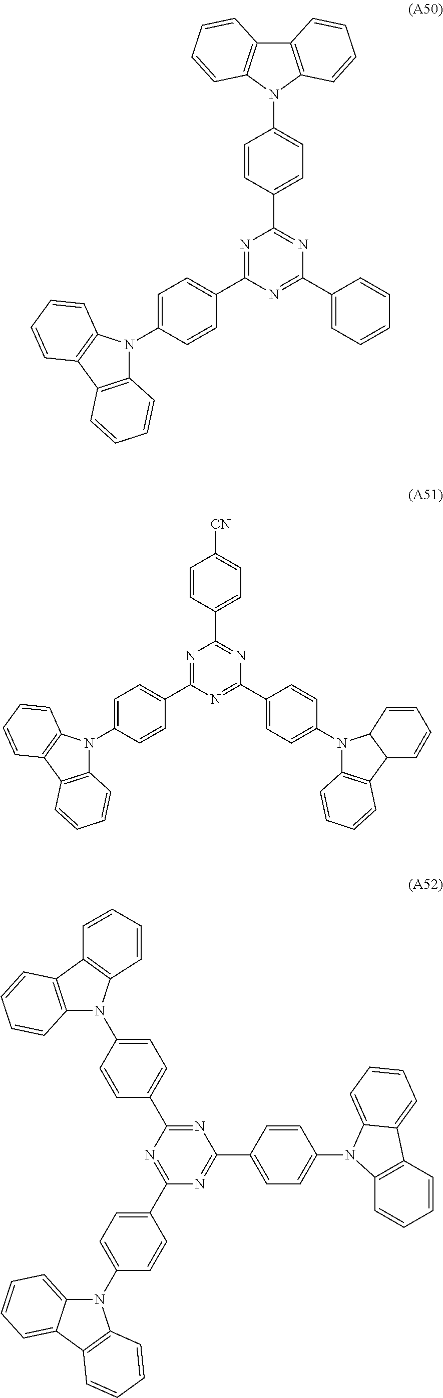 [SMILES: c1ccc(-c2nc(-c3ccc(-n4c5ccccc5c5ccccc54)cc3)nc(-c3ccc(-n4c5ccccc5c5ccccc54)cc3)n2)cc1 ; N#Cc1ccc(-c2nc(-c3ccc(N4c5ccccc5C5C=CC=CC54)cc3)nc(-c3ccc(-n4c5ccccc5c5ccccc54)cc3)n2)cc1 ; c1ccc2c(c1)c1ccccc1n2-c1ccc(-c2nc(-c3ccc(-n4c5ccccc5c5ccccc54)cc3)nc(-c3ccc(-n4c5ccccc5c5ccccc54)cc3)n2)cc1]

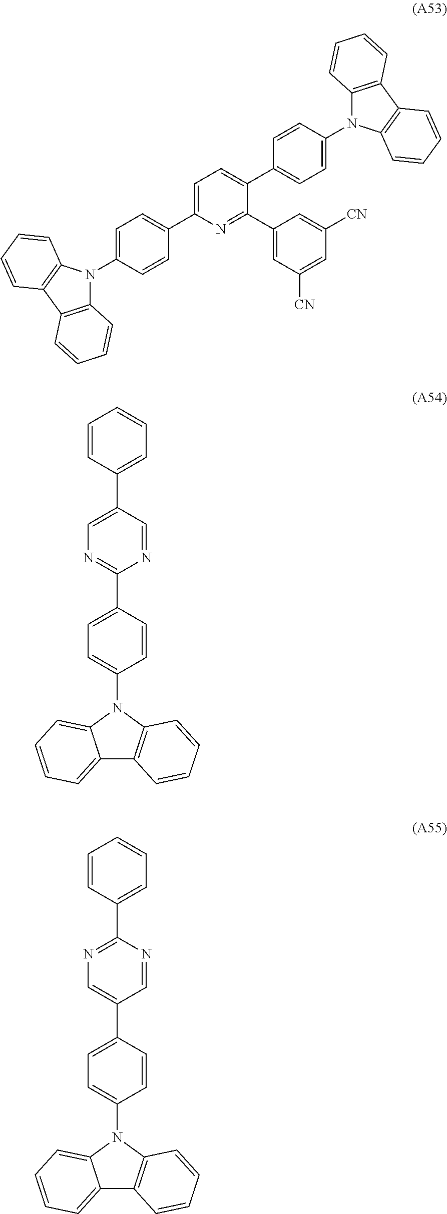 [SMILES: N#Cc1cc(C#N)cc(-c2nc(-c3ccc(-n4c5ccccc5c5ccccc54)cc3)ccc2-c2ccc(-n3c4ccccc4c4ccccc43)cc2)c1 ; c1ccc(-c2cnc(-c3ccc(-n4c5ccccc5c5ccccc54)cc3)nc2)cc1 ; c1ccc(-c2ncc(-c3ccc(-n4c5ccccc5c5ccccc54)cc3)cn2)cc1]

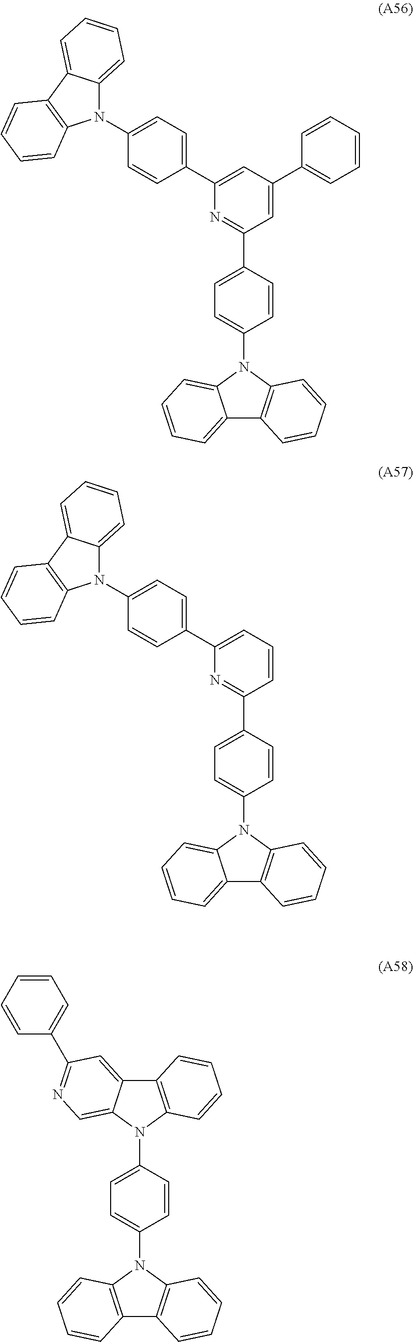 [SMILES: c1ccc(-c2cc(-c3ccc(-n4c5ccccc5c5ccccc54)cc3)nc(-c3ccc(-n4c5ccccc5c5ccccc54)cc3)c2)cc1 ; c1cc(-c2ccc(-n3c4ccccc4c4ccccc43)cc2)nc(-c2ccc(-n3c4ccccc4c4ccccc43)cc2)c1 ; c1ccc(-c2cc3c4ccccc4n(-c4ccc(-n5c6ccccc6c6ccccc65)cc4)c3cn2)cc1]

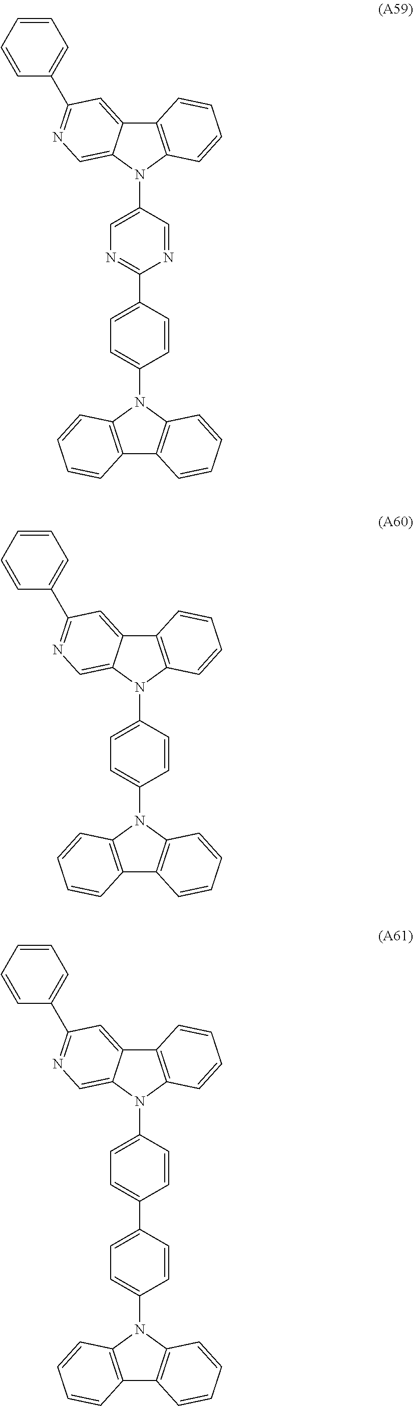 [SMILES: c1ccc(-c2cc3c4ccccc4n(-c4cnc(-c5ccc(-n6c7ccccc7c7ccccc76)cc5)nc4)c3cn2)cc1 ; c1ccc(-c2cc3c4ccccc4n(-c4ccc(-n5c6ccccc6c6ccccc65)cc4)c3cn2)cc1 ; c1ccc(-c2cc3c4ccccc4n(-c4ccc(-c5ccc(-n6c7ccccc7c7ccccc76)cc5)cc4)c3cn2)cc1]

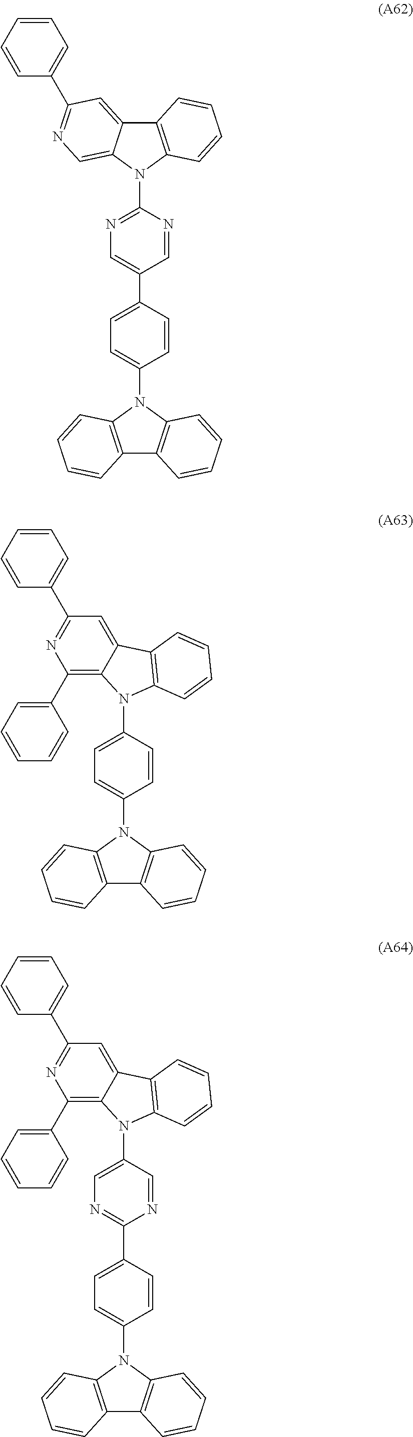 [SMILES: c1ccc(-c2cc3c4ccccc4n(-c4ncc(-c5ccc(-n6c7ccccc7c7ccccc76)cc5)cn4)c3cn2)cc1 ; c1ccc(-c2cc3c4ccccc4n(-c4ccc(-n5c6ccccc6c6ccccc65)cc4)c3c(-c3ccccc3)n2)cc1 ; c1ccc(-c2cc3c4ccccc4n(-c4cnc(-c5ccc(-n6c7ccccc7c7ccccc76)cc5)nc4)c3c(-c3ccccc3)n2)cc1]

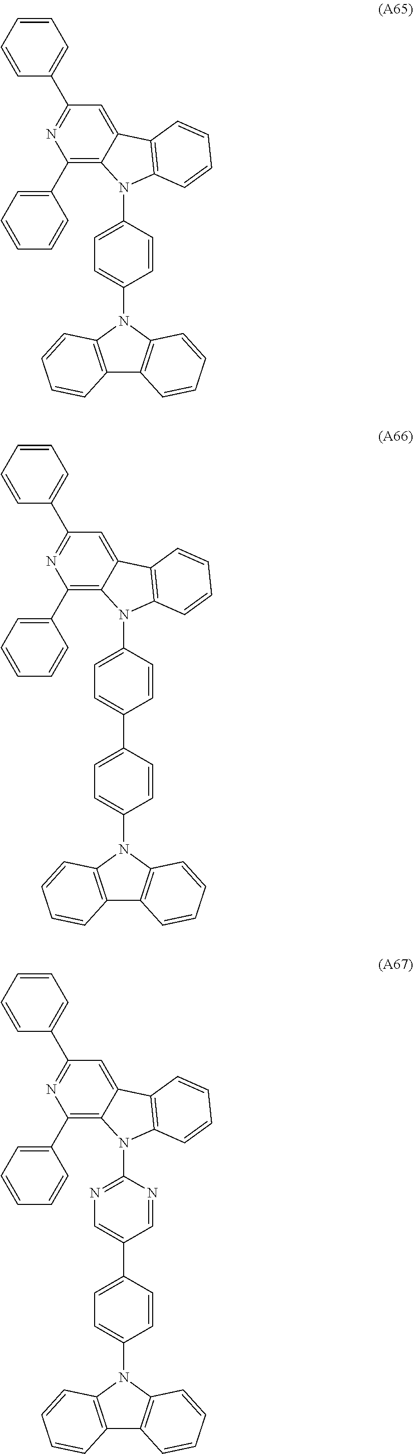 [SMILES: c1ccc(-c2cc3c4ccccc4n(-c4ccc(-n5c6ccccc6c6ccccc65)cc4)c3c(-c3ccccc3)n2)cc1 ; c1ccc(-c2cc3c4ccccc4n(-c4ccc(-c5ccc(-n6c7ccccc7c7ccccc76)cc5)cc4)c3c(-c3ccccc3)n2)cc1 ; c1ccc(-c2cc3c4ccccc4n(-c4ncc(-c5ccc(-n6c7ccccc7c7ccccc76)cc5)cn4)c3c(-c3ccccc3)n2)cc1]

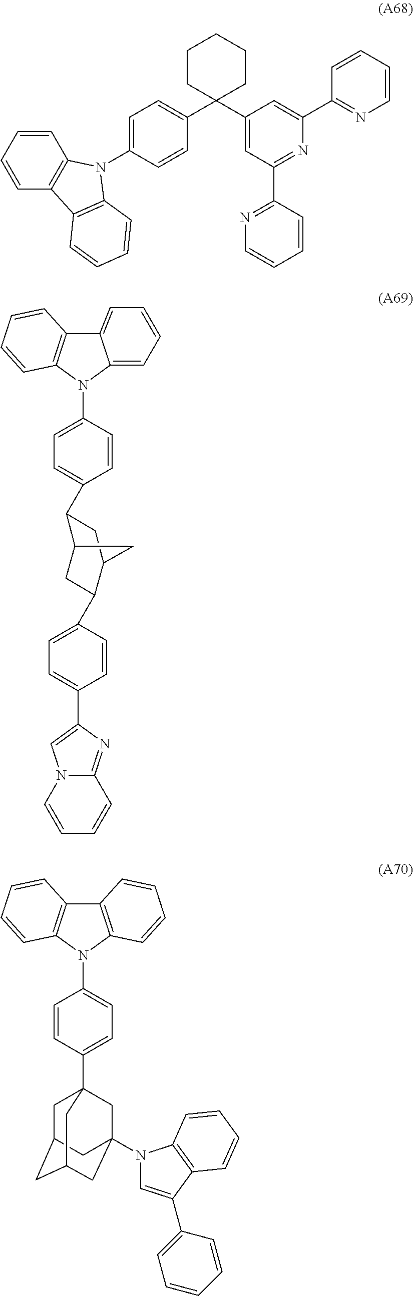

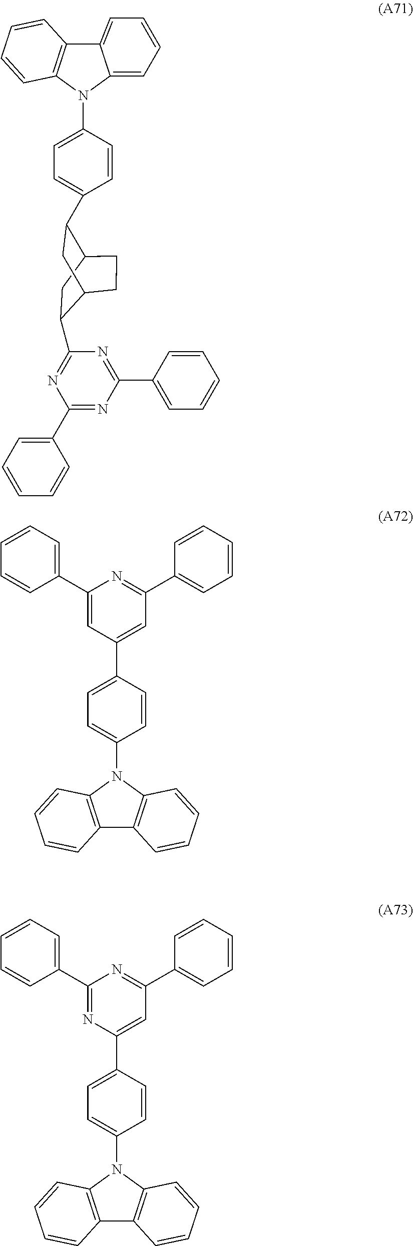

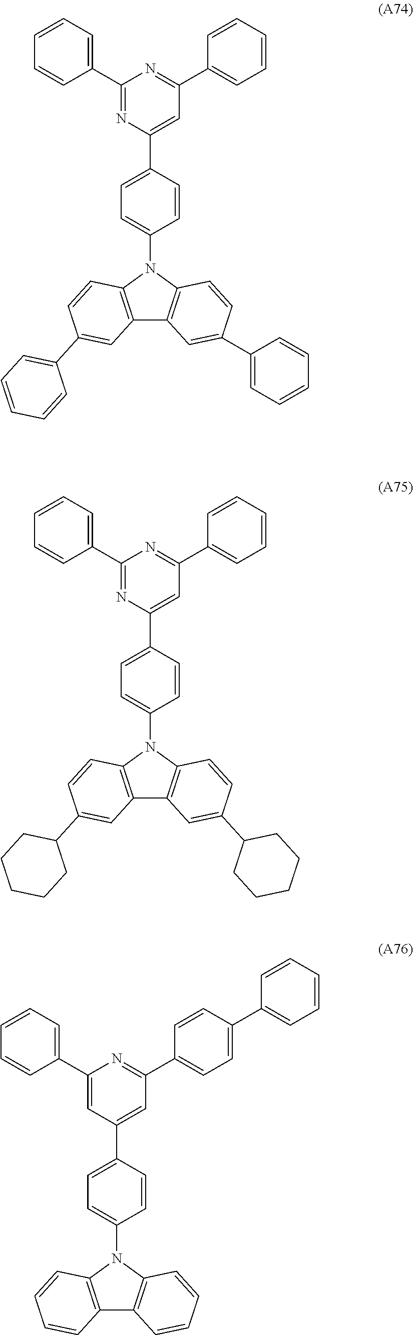 [SMILES: c1ccc(-c2ccc3c(c2)c2cc(-c4ccccc4)ccc2n3-c2ccc(-c3cc(-c4ccccc4)nc(-c4ccccc4)n3)cc2)cc1 ; c1ccc(-c2cc(-c3ccc(-n4c5ccc(C6CCCCC6)cc5c5cc(C6CCCCC6)ccc54)cc3)nc(-c3ccccc3)n2)cc1 ; c1ccc(-c2ccc(-c3cc(-c4ccc(-n5c6ccccc6c6ccccc65)cc4)cc(-c4ccccc4)n3)cc2)cc1]

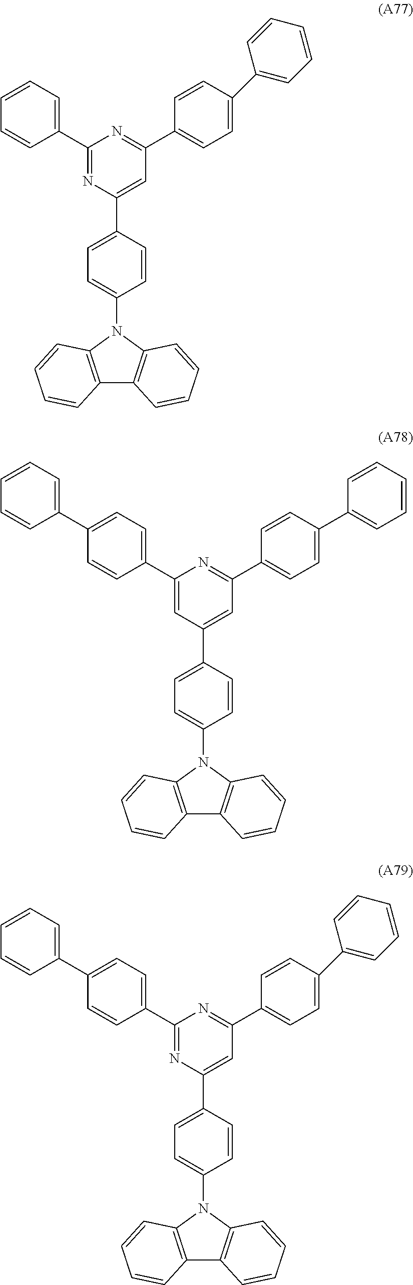 [SMILES: c1ccc(-c2ccc(-c3cc(-c4ccc(-n5c6ccccc6c6ccccc65)cc4)nc(-c4ccccc4)n3)cc2)cc1 ; c1ccc(-c2ccc(-c3cc(-c4ccc(-n5c6ccccc6c6ccccc65)cc4)cc(-c4ccc(-c5ccccc5)cc4)n3)cc2)cc1 ; c1ccc(-c2ccc(-c3cc(-c4ccc(-n5c6ccccc6c6ccccc65)cc4)nc(-c4ccc(-c5ccccc5)cc4)n3)cc2)cc1]

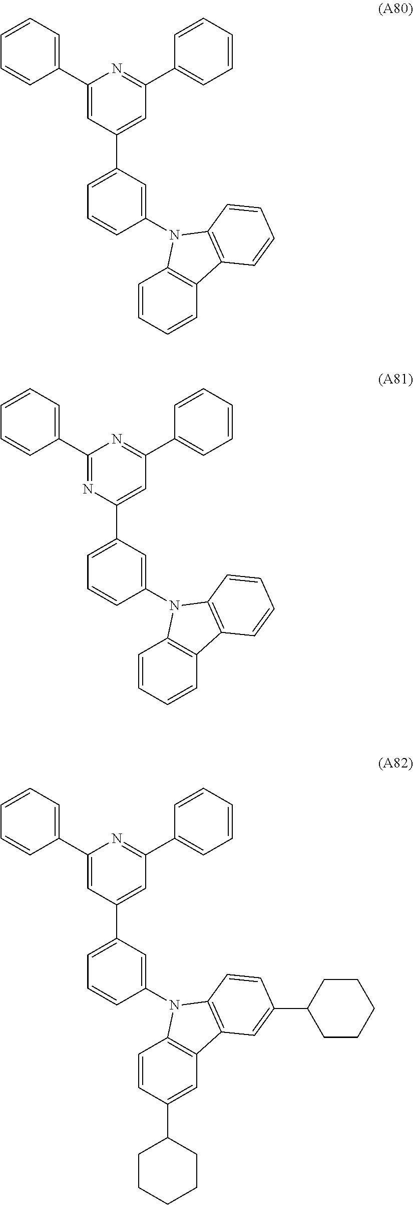 [SMILES: c1ccc(-c2cc(-c3cccc(-n4c5ccccc5c5ccccc54)c3)cc(-c3ccccc3)n2)cc1 ; c1ccc(-c2cc(-c3cccc(-n4c5ccccc5c5ccccc54)c3)nc(-c3ccccc3)n2)cc1 ; c1ccc(-c2cc(-c3cccc(-n4c5ccc(C6CCCCC6)cc5c5cc(C6CCCCC6)ccc54)c3)cc(-c3ccccc3)n2)cc1]

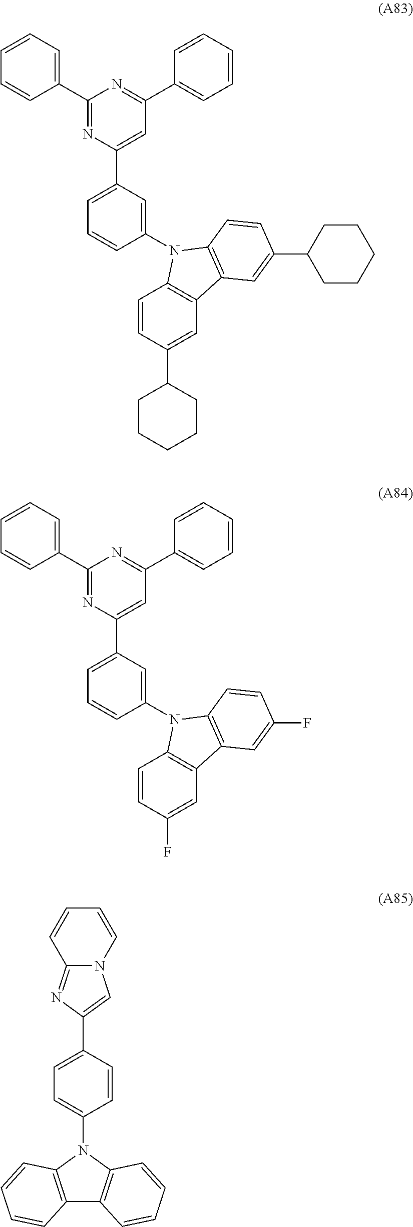 [SMILES: c1ccc(-c2cc(-c3cccc(-n4c5ccc(C6CCCCC6)cc5c5cc(C6CCCCC6)ccc54)c3)nc(-c3ccccc3)n2)cc1 ; Fc1ccc2c(c1)c1cc(F)ccc1n2-c1cccc(-c2cc(-c3ccccc3)nc(-c3ccccc3)n2)c1 ; c1ccc2c(c1)c1ccccc1n2-c1ccc(-c2cn3ccccc3n2)cc1]

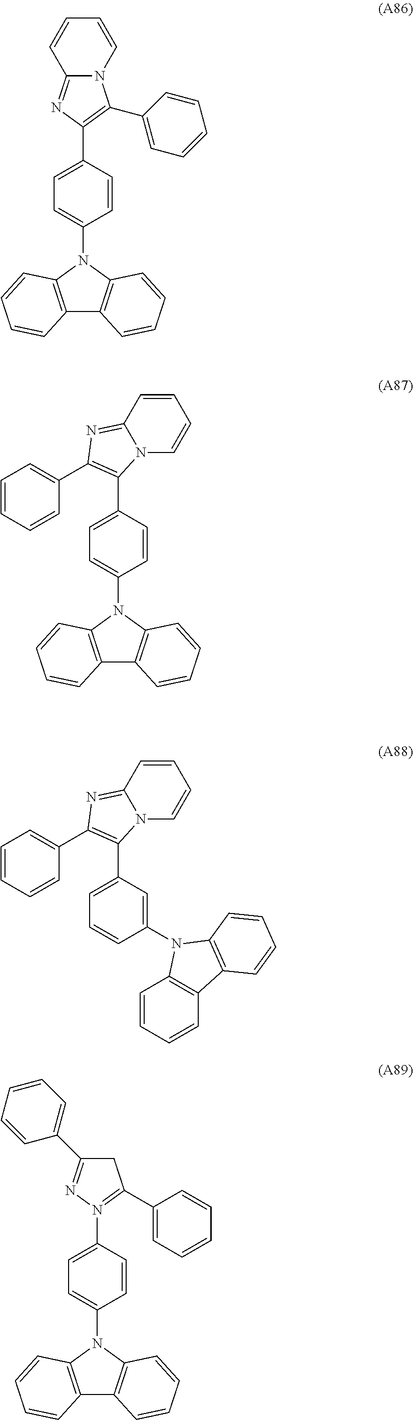

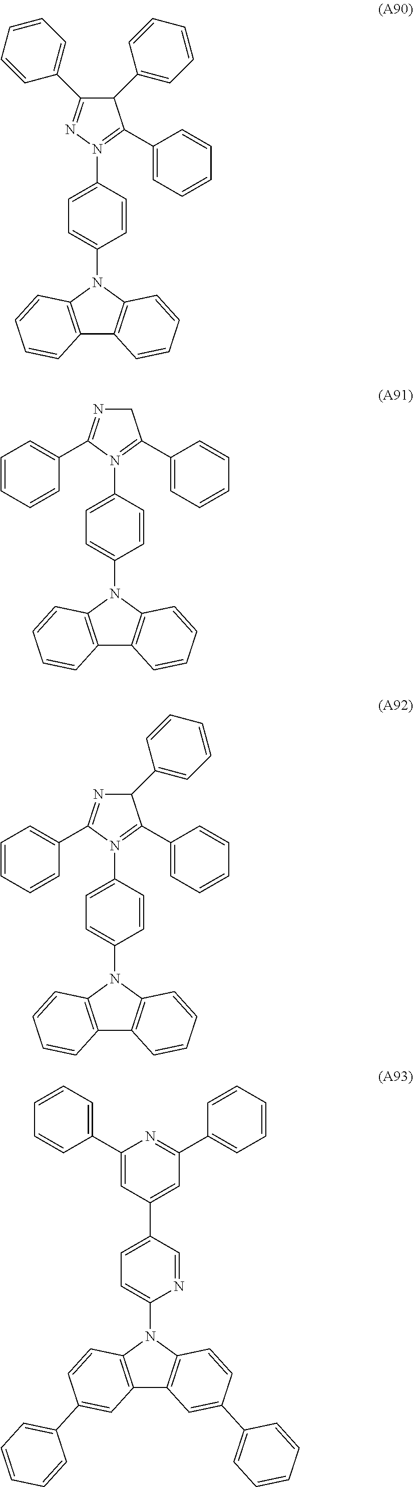

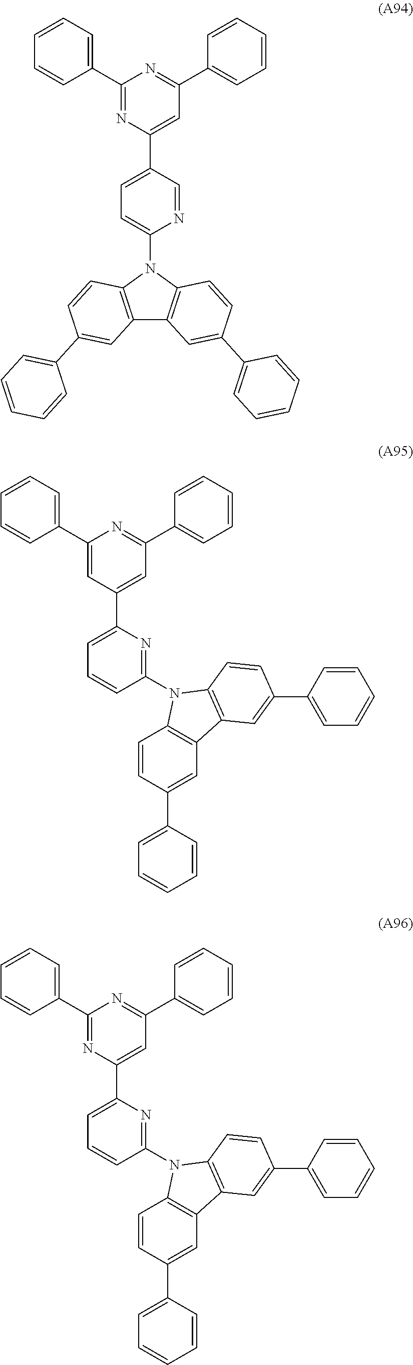 [SMILES: c1ccc(-c2ccc3c(c2)c2cc(-c4ccccc4)ccc2n3-c2ccc(-c3cc(-c4ccccc4)nc(-c4ccccc4)n3)cn2)cc1 ; c1ccc(-c2ccc3c(c2)c2cc(-c4ccccc4)ccc2n3-c2cccc(-c3cc(-c4ccccc4)nc(-c4ccccc4)c3)n2)cc1 ; c1ccc(-c2ccc3c(c2)c2cc(-c4ccccc4)ccc2n3-c2cccc(-c3cc(-c4ccccc4)nc(-c4ccccc4)n3)n2)cc1]

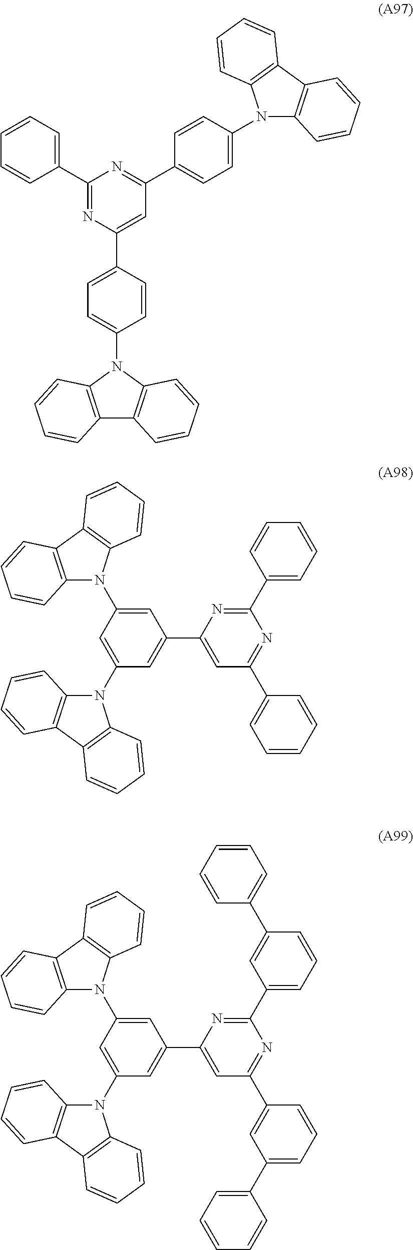 [SMILES: c1ccc(-c2nc(-c3ccc(-n4c5ccccc5c5ccccc54)cc3)cc(-c3ccc(-n4c5ccccc5c5ccccc54)cc3)n2)cc1 ; c1ccc(-c2cc(-c3cc(-n4c5ccccc5c5ccccc54)cc(-n4c5ccccc5c5ccccc54)c3)nc(-c3ccccc3)n2)cc1 ; c1ccc(-c2cccc(-c3cc(-c4cc(-n5c6ccccc6c6ccccc65)cc(-n5c6ccccc6c6ccccc65)c4)nc(-c4cccc(-c5ccccc5)c4)n3)c2)cc1]

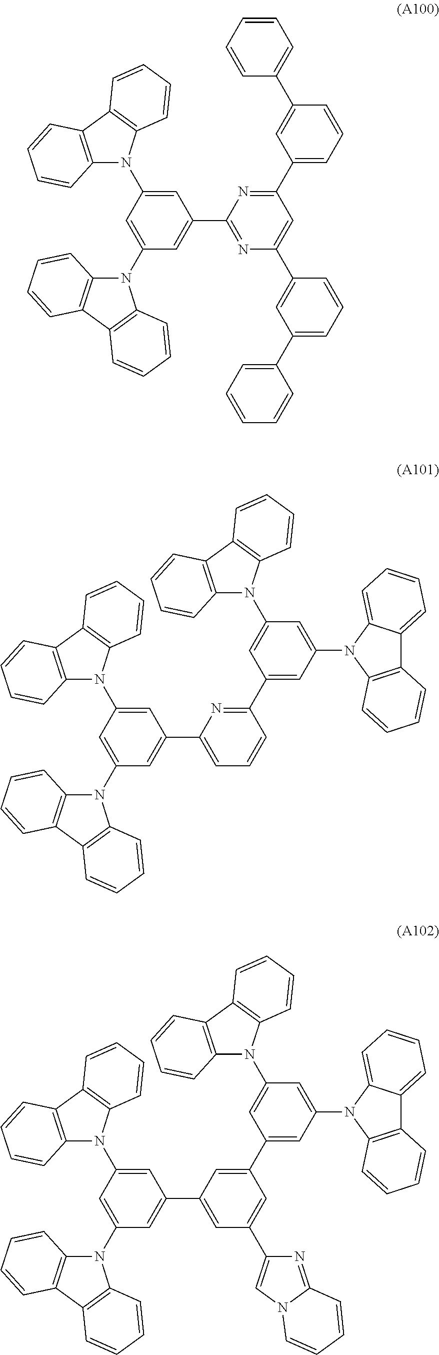 [SMILES: c1ccc(-c2cccc(-c3cc(-c4cccc(-c5ccccc5)c4)nc(-c4cc(-n5c6ccccc6c6ccccc65)cc(-n5c6ccccc6c6ccccc65)c4)n3)c2)cc1 ; c1cc(-c2cc(-n3c4ccccc4c4ccccc43)cc(-n3c4ccccc4c4ccccc43)c2)nc(-c2cc(-n3c4ccccc4c4ccccc43)cc(-n3c4ccccc4c4ccccc43)c2)c1 ; c1ccc2c(c1)c1ccccc1n2-c1cc(-c2cc(-c3cc(-n4c5ccccc5c5ccccc54)cc(-n4c5ccccc5c5ccccc54)c3)cc(-c3cn4ccccc4n3)c2)cc(-n2c3ccccc3c3ccccc32)c1]

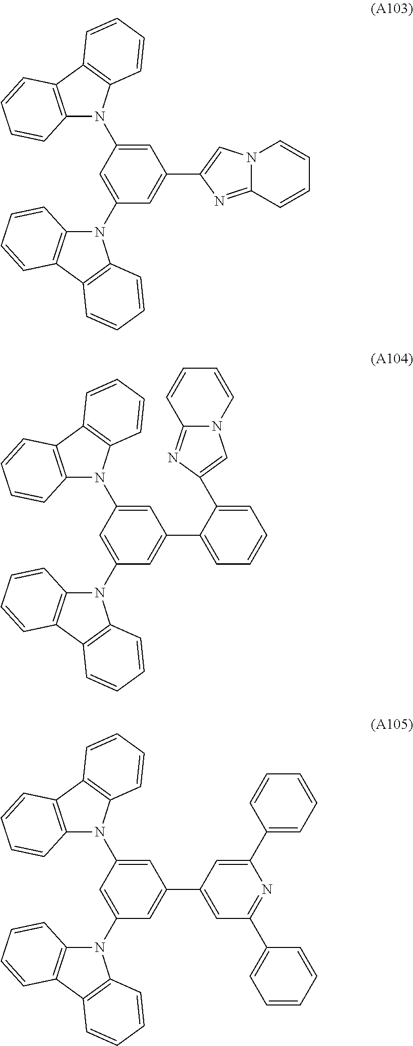

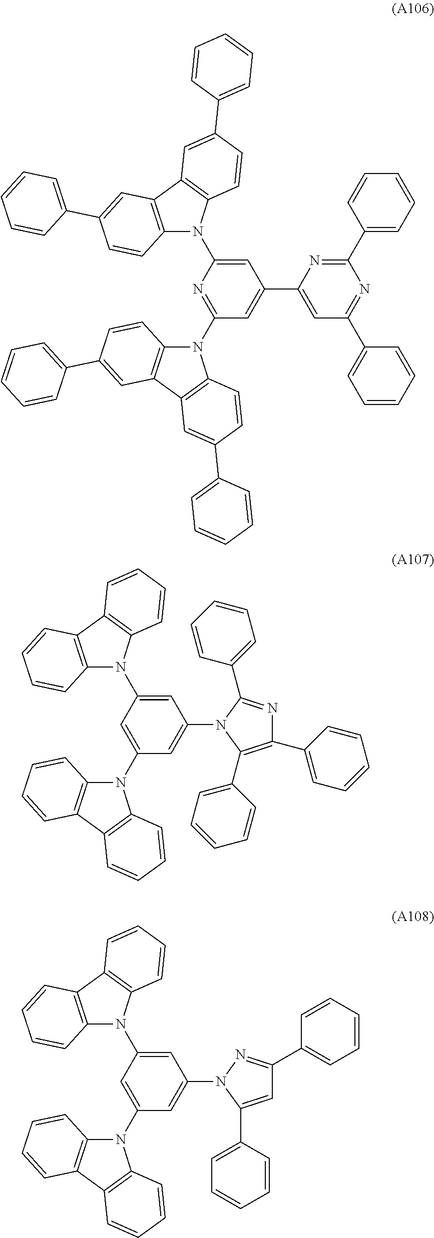

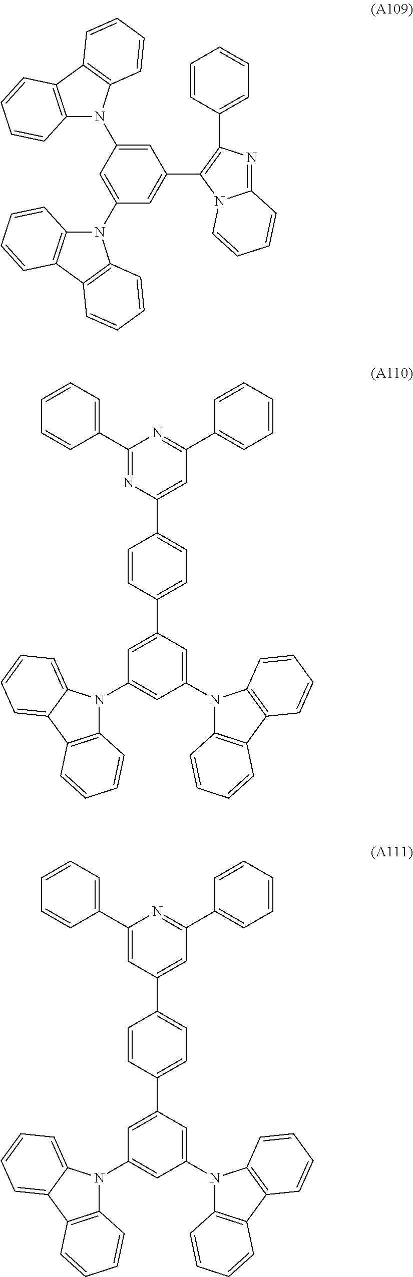 [SMILES: c1ccc(-c2nc3ccccn3c2-c2cc(-n3c4ccccc4c4ccccc43)cc(-n3c4ccccc4c4ccccc43)c2)cc1 ; c1ccc(-c2cc(-c3ccc(-c4cc(-n5c6ccccc6c6ccccc65)cc(-n5c6ccccc6c6ccccc65)c4)cc3)nc(-c3ccccc3)n2)cc1 ; c1ccc(-c2cc(-c3ccc(-c4cc(-n5c6ccccc6c6ccccc65)cc(-n5c6ccccc6c6ccccc65)c4)cc3)cc(-c3ccccc3)n2)cc1]

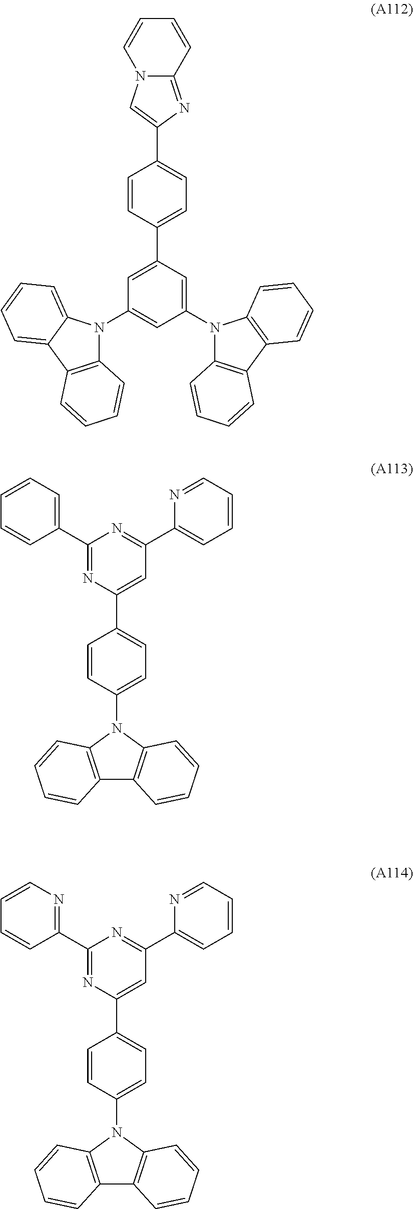 [SMILES: c1ccc2c(c1)c1ccccc1n2-c1cc(-c2ccc(-c3cn4ccccc4n3)cc2)cc(-n2c3ccccc3c3ccccc32)c1 ; c1ccc(-c2nc(-c3ccc(-n4c5ccccc5c5ccccc54)cc3)cc(-c3ccccn3)n2)cc1 ; c1ccc(-c2cc(-c3ccc(-n4c5ccccc5c5ccccc54)cc3)nc(-c3ccccn3)n2)nc1]

Some specific examples of the compound for the second host material represented by the formula (6) are shown below. However, the compound represented by the formula (6) is not limited thereto.

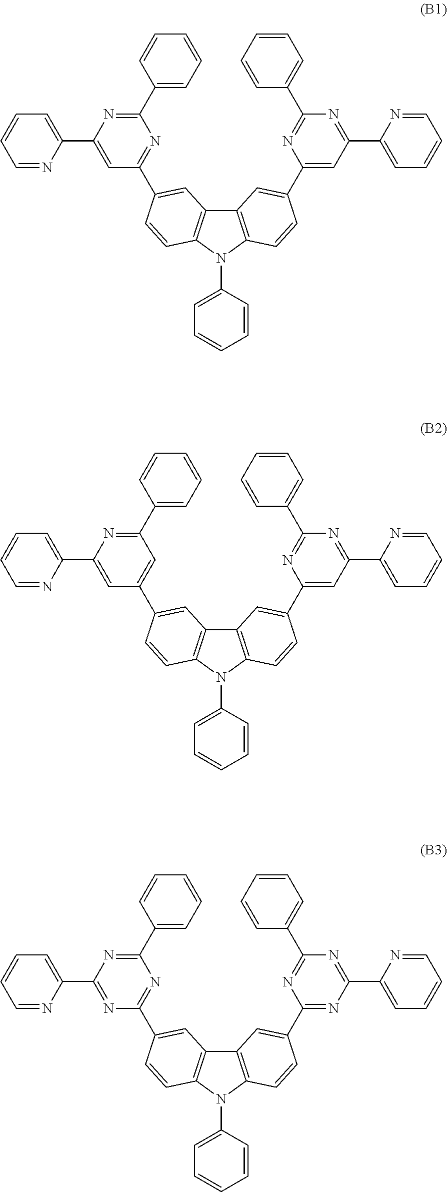 [SMILES: c1ccc(-c2nc(-c3ccc4c(c3)c3cc(-c5cc(-c6ccccn6)nc(-c6ccccc6)n5)ccc3n4-c3ccccc3)cc(-c3ccccn3)n2)cc1 ; c1ccc(-c2cc(-c3ccc4c(c3)c3cc(-c5cc(-c6ccccn6)nc(-c6ccccc6)n5)ccc3n4-c3ccccc3)cc(-c3ccccn3)n2)cc1 ; c1ccc(-c2nc(-c3ccc4c(c3)c3cc(-c5nc(-c6ccccc6)nc(-c6ccccn6)n5)ccc3n4-c3ccccc3)nc(-c3ccccn3)n2)cc1]

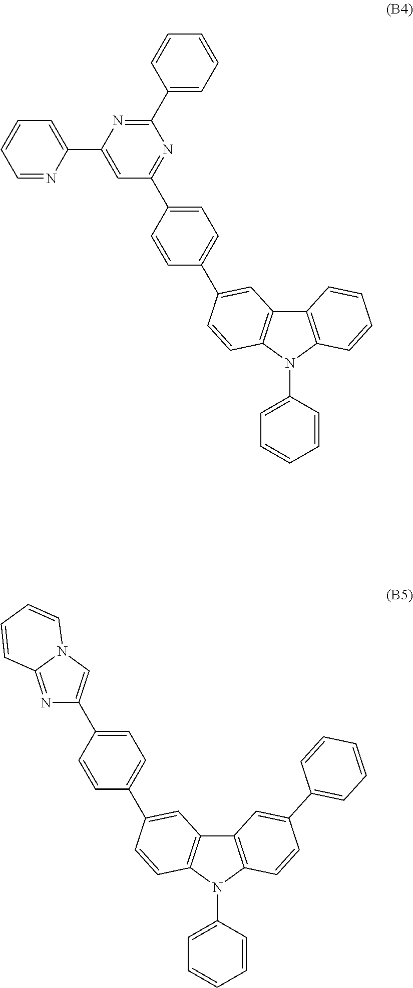 [SMILES: c1ccc(-c2nc(-c3ccc(-c4ccc5c(c4)c4ccccc4n5-c4ccccc4)cc3)cc(-c3ccccn3)n2)cc1 ; c1ccc(-c2ccc3c(c2)c2cc(-c4ccc(-c5cn6ccccc6n5)cc4)ccc2n3-c2ccccc2)cc1]

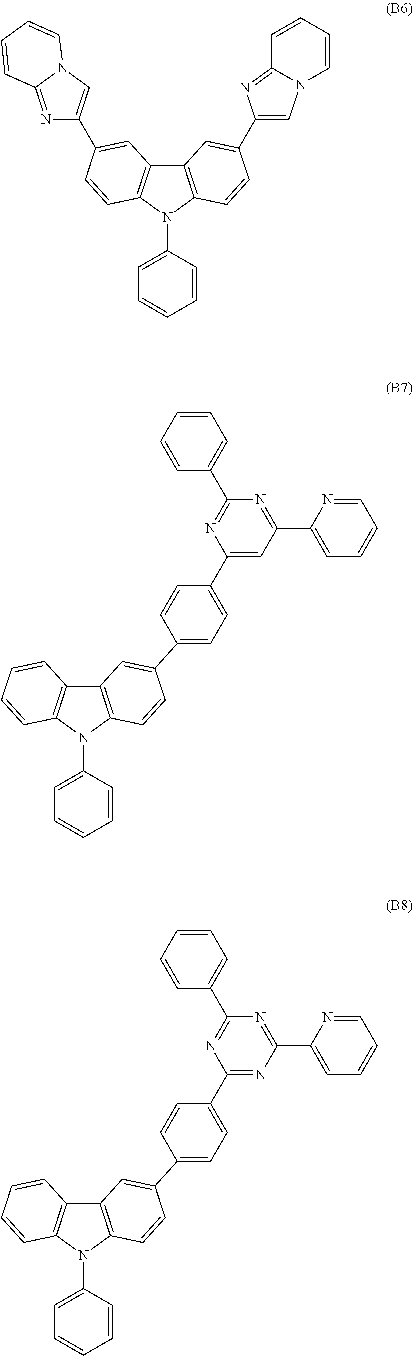 [SMILES: c1ccc(-n2c3ccc(-c4cn5ccccc5n4)cc3c3cc(-c4cn5ccccc5n4)ccc32)cc1 ; c1ccc(-c2nc(-c3ccc(-c4ccc5c(c4)c4ccccc4n5-c4ccccc4)cc3)cc(-c3ccccn3)n2)cc1 ; c1ccc(-c2nc(-c3ccc(-c4ccc5c(c4)c4ccccc4n5-c4ccccc4)cc3)nc(-c3ccccn3)n2)cc1]

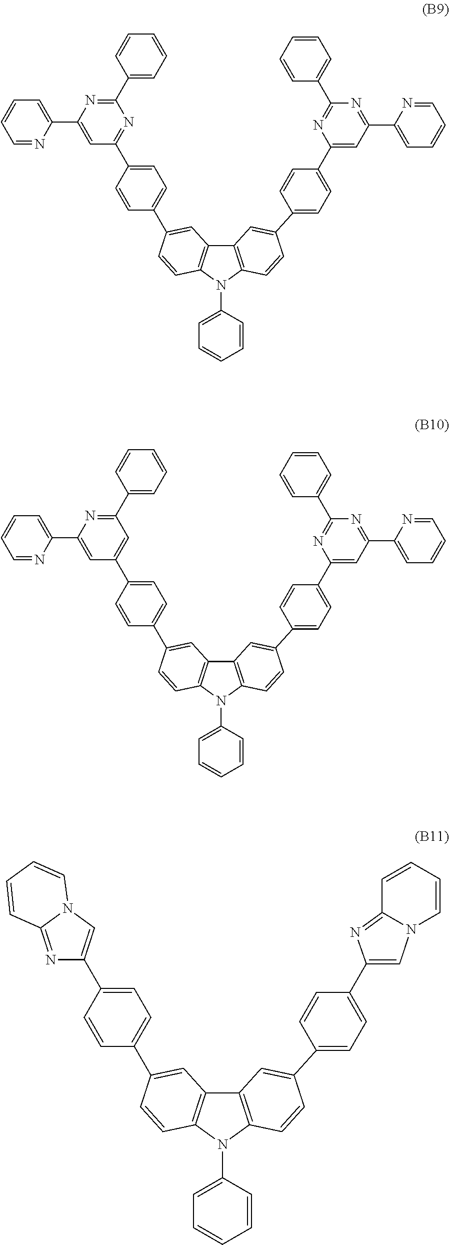 [SMILES: c1ccc(-c2nc(-c3ccc(-c4ccc5c(c4)c4cc(-c6ccc(-c7cc(-c8ccccn8)nc(-c8ccccc8)n7)cc6)ccc4n5-c4ccccc4)cc3)cc(-c3ccccn3)n2)cc1 ; c1ccc(-c2cc(-c3ccc(-c4ccc5c(c4)c4cc(-c6ccc(-c7cc(-c8ccccn8)nc(-c8ccccc8)n7)cc6)ccc4n5-c4ccccc4)cc3)cc(-c3ccccn3)n2)cc1 ; c1ccc(-n2c3ccc(-c4ccc(-c5cn6ccccc6n5)cc4)cc3c3cc(-c4ccc(-c5cn6ccccc6n5)cc4)ccc32)cc1]

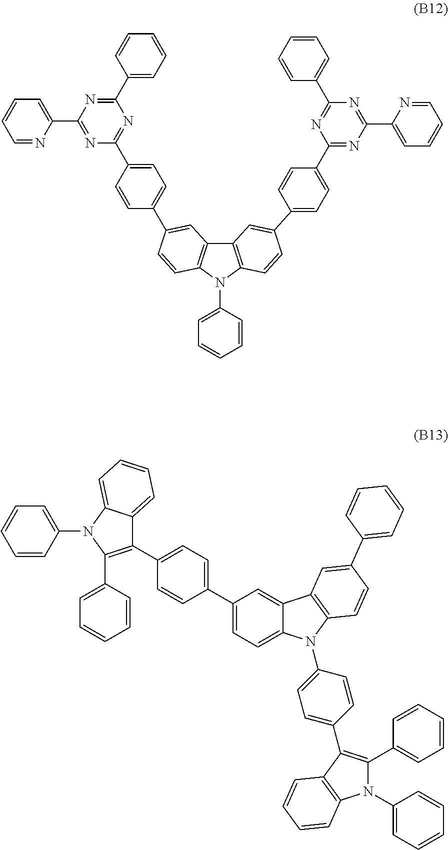 [SMILES: c1ccc(-c2nc(-c3ccc(-c4ccc5c(c4)c4cc(-c6ccc(-c7nc(-c8ccccc8)nc(-c8ccccn8)n7)cc6)ccc4n5-c4ccccc4)cc3)nc(-c3ccccn3)n2)cc1 ; c1ccc(-c2ccc3c(c2)c2cc(-c4ccc(-c5c(-c6ccccc6)n(-c6ccccc6)c6ccccc56)cc4)ccc2n3-c2ccc(-c3c(-c4ccccc4)n(-c4ccccc4)c4ccccc34)cc2)cc1]

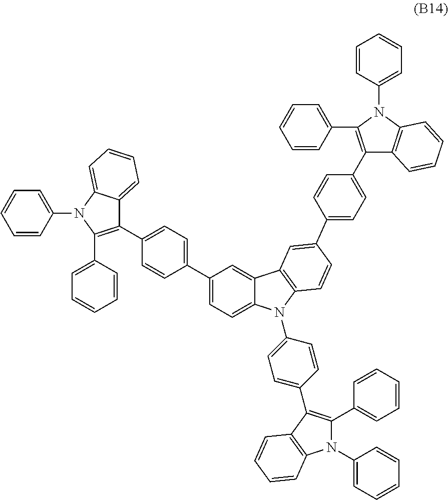 [SMILES: c1ccc(-c2c(-c3ccc(-c4ccc5c(c4)c4cc(-c6ccc(-c7c(-c8ccccc8)n(-c8ccccc8)c8ccccc78)cc6)ccc4n5-c4ccc(-c5c(-c6ccccc6)n(-c6ccccc6)c6ccccc56)cc4)cc3)c3ccccc3n2-c2ccccc2)cc1]

The compound represented by the formula (5) or (6) in this exemplary embodiment has triplet energy gap of 2.5 eV to 3.3 eV, preferably 2.5 eV to 3.2 eV.

The compound represented by the formula (5) or (6) in this exemplary embodiment has singlet energy gap of 2.8 eV to 3.8 eV, preferably 2.9 eV to 3.7 eV.

According to another embodiment, the second host material for the emitting layer of the organic EL device is a compound in which A3 in the formula (5) or (6) is a group represented by the formula (7B) below. This provides a second host material that has a poor electron injecting capability. When a material having an excellent electron injecting capability from the electrode (i.e., LiF) is used as the cathode, a carrier balance in the emitting layer becomes shifted toward the anode. By selecting a material having a poor electron injecting capability as the second host material the carrier balance can be improved.

(M³)_{c}-(L⁶)_{d}-(M⁴)ₑ (7B)

In the formula (7B): M³ and M⁴ each independently represent a substituted or unsubstituted aromatic hydrocarbon group having 6 to 40 ring carbon atoms; M³ and M⁴ may be the same or different; L6 represents a single bond, substituted or unsubstituted aromatic hydrocarbon group having 6 to 30 carbon atoms, substituted or unsubstituted fused aromatic hydrocarbon group having 6 to 30 carbon atoms, or substituted or unsubstituted cycloalkylene group having 5 to 30 carbon atoms;

c represents an integer of 0 to 2; d represents an integer of 1 to 2; e represents an integer of 0 to 2; and c+e represents 1 or more.

In the formula (7B), as the aromatic hydrocarbon group for M³ and M⁴ and the aromatic hydrocarbon group, fused aromatic hydrocarbon group and cycloalkylene group for L⁶, those represented by the formula (7A) can be used. As bonding patterns of the groups represented by the formula (7B), the same bonding patterns as those of the formula (7A) can be used. Specifically, in the bonding patterns of the formula (7A), M1, L5 and M2 may be respectively replaced with M³, L⁶ and M⁴.

In the bonding patterns of the formulas (5), (6) and (7B) and exemplary combinations of the groups as described above, compounds represented by [5] to [8] below are preferable.

[5] a=1 is given in the formula (5) and c=1 and d=0 are given in the formula (7B). In the formula (5), Cz is a substituted or unsubstituted arylcarbazolyl group or substituted or unsubstituted carbazolylaryl group. In the formula (7B): M³ is a substituted or unsubstituted nitrogen-containing six-membered or seven-membered hetero ring having 4 to 5 ring carbon atoms, substituted or unsubstituted nitrogen-containing five-membered hetero ring having 2 to 4 ring carbon atoms, substituted or unsubstituted nitrogen-containing hetero ring having 8 to 11 ring carbon atoms, substituted or unsubstituted imidazopyridinyl ring; and L⁶ is a substituted or unsubstituted aryl group or aromatic hydrocarbon group or fused aromatic hydrocarbon group having 6 to 30 carbon atoms and substituted or unsubstituted aromatic heterocyclic group or fused aromatic heterocyclic group having 2 to 30 carbon atoms.

[6] a=2 is given in the formula (5) and c=1 and e=0 are given in the formula (7B). In the formula (5), Cz is a substituted or unsubstituted arylcarbazolyl group or substituted or unsubstituted carbazolylaryl group. In the formula (7B): M³ is a substituted or unsubstituted nitrogen-containing six-membered or seven-membered hetero ring having 4 to 5 ring carbon atoms, substituted or unsubstituted nitrogen-containing five-membered hetero ring having 2 to 4 ring carbon atoms, substituted or unsubstituted nitrogen-containing hetero ring having 8 to 11 ring carbon atoms, substituted or unsubstituted imidazopyridinyl ring; and L⁶ is a substituted or unsubstituted aromatic hydrocarbon group or fused aromatic hydrocarbon group having 6 to 30 carbon atoms and substituted or unsubstituted aromatic heterocyclic group or fused aromatic heterocyclic group having 2 to 30 carbon atoms.

[7] a=1 is given in the formula (5) and c=2 and e=0 are given in the formula (7B). In the formula (5), Cz is a substituted or unsubstituted arylcarbazolyl group or substituted or unsubstituted carbazolylaryl group. In the formula (7B): M³ is a substituted or unsubstituted nitrogen-containing six-membered or seven-membered hetero ring having 4 to 5 ring carbon atoms, substituted or unsubstituted nitrogen-containing five-membered hetero ring having 2 to 4 ring carbon atoms, substituted or unsubstituted nitrogen-containing hetero ring having 8 to 11 ring carbon atoms, substituted or unsubstituted imidazopyridinyl ring; and L⁶ is a substituted or unsubstituted aromatic hydrocarbon group or fused aromatic hydrocarbon group having 6 to 30 carbon atoms and substituted or unsubstituted aromatic heterocyclic group or fused aromatic heterocyclic group having 2 to 30 carbon atoms.

[8] b=2 is given in the formula (6) and c=d=1 is given in the formula (7B). In the formula (6), Cz is a substituted or unsubstituted arylcarbazolyl group or substituted or unsubstituted carbazolylaryl group. In the formula (7B): M³ is a substituted or unsubstituted nitrogen-containing six-membered or seven-membered hetero ring having 4 to 5 ring carbon atoms, substituted or unsubstituted nitrogen-containing five-membered hetero ring having 2 to 4 ring carbon atoms, substituted or unsubstituted nitrogen-containing hetero ring having 8 to 11 ring carbon atoms, substituted or unsubstituted imidazopyridinyl ring; and L⁶ is a substituted or unsubstituted aromatic hydrocarbon group or fused aromatic hydrocarbon group having 6 to 30 carbon atoms and substituted or unsubstituted aromatic heterocyclic group or fused aromatic heterocyclic group having 2 to 30 carbon atoms.

In the formulas (5) and (6), Cz is preferably a substituted or unsubstituted arylcarbazolyl group, more preferably phenylcarbozolyl group. Moreover, an aryl site of the arylcarbazolyl group is preferably substituted by a carbazolyl group.

Examples of the compound in which A³ is a group represented by the following formula (7B) in the formula (5) or (6) are listed below.

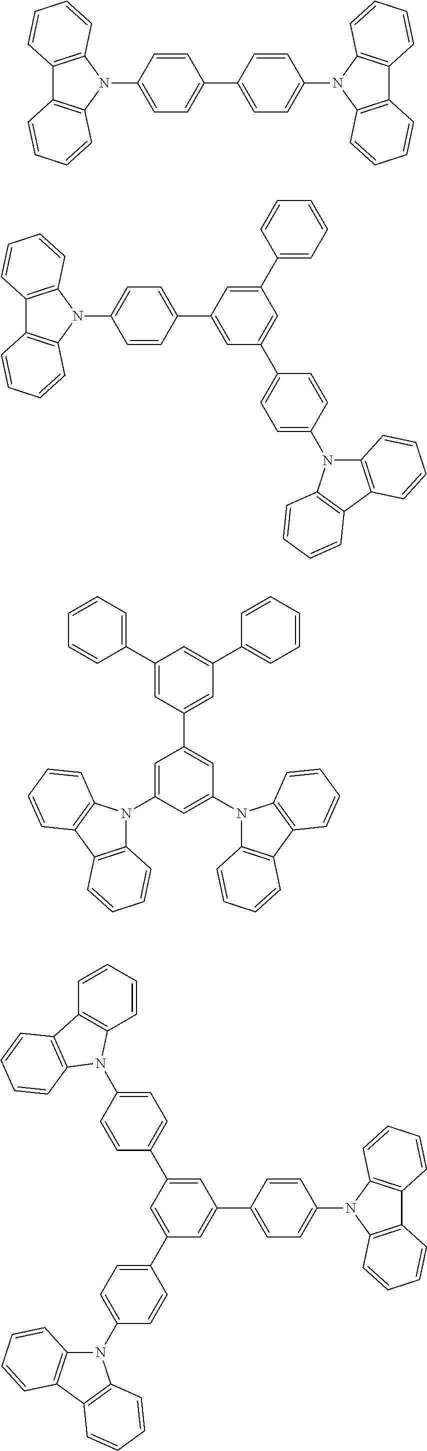 [SMILES: c1ccc2c(c1)c1ccccc1n2-c1ccc(-c2ccc(-n3c4ccccc4c4ccccc43)cc2)cc1 ; c1ccc(-c2cc(-c3ccc(-n4c5ccccc5c5ccccc54)cc3)cc(-c3ccc(-n4c5ccccc5c5ccccc54)cc3)c2)cc1 ; c1ccc(-c2cc(-c3ccccc3)cc(-c3cc(-n4c5ccccc5c5ccccc54)cc(-n4c5ccccc5c5ccccc54)c3)c2)cc1 ; c1ccc2c(c1)c1ccccc1n2-c1ccc(-c2cc(-c3ccc(-n4c5ccccc5c5ccccc54)cc3)cc(-c3ccc(-n4c5ccccc5c5ccccc54)cc3)c2)cc1]

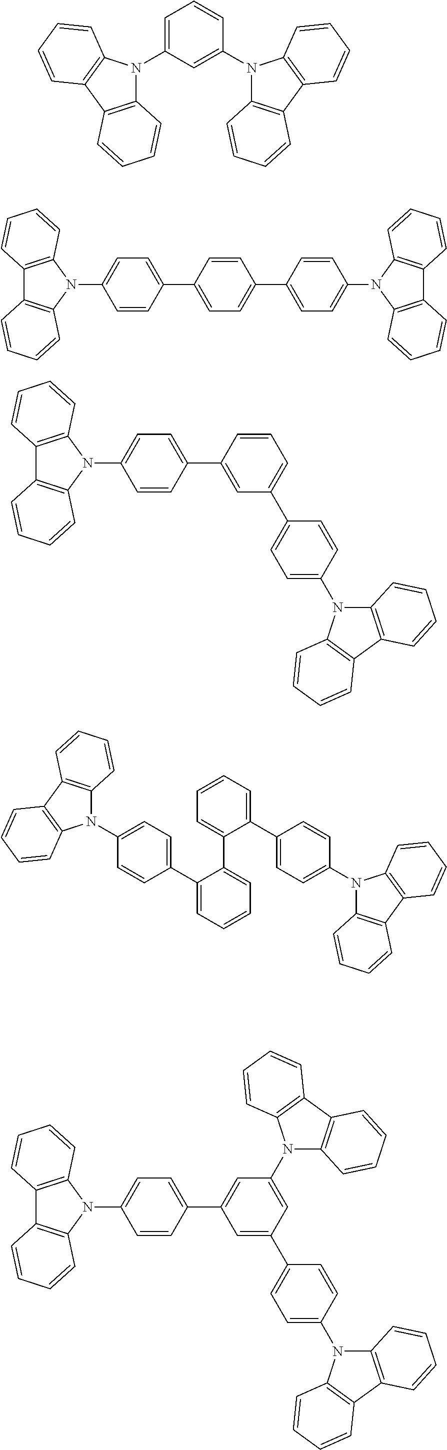

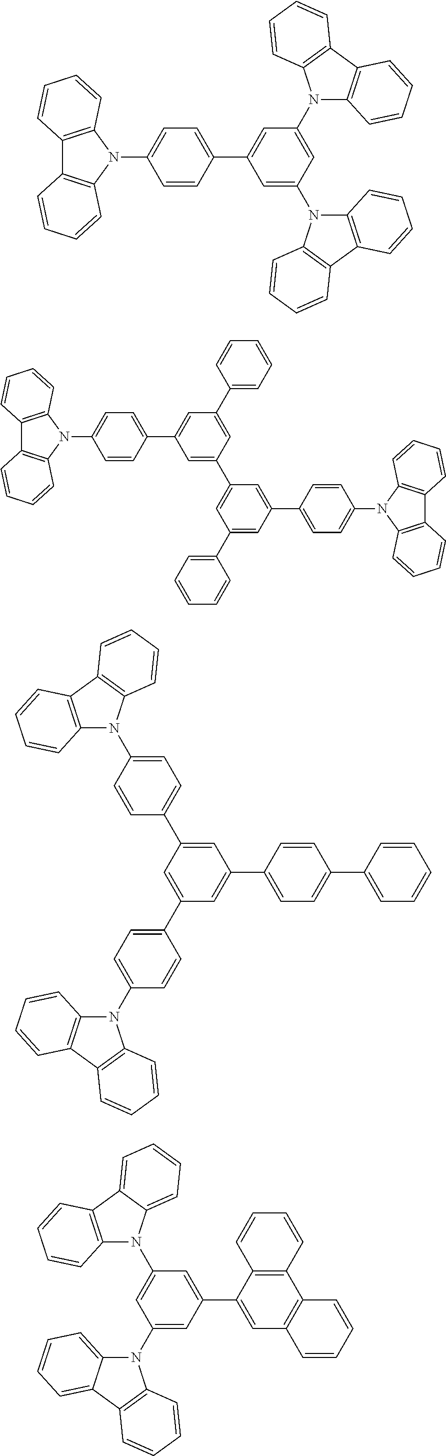

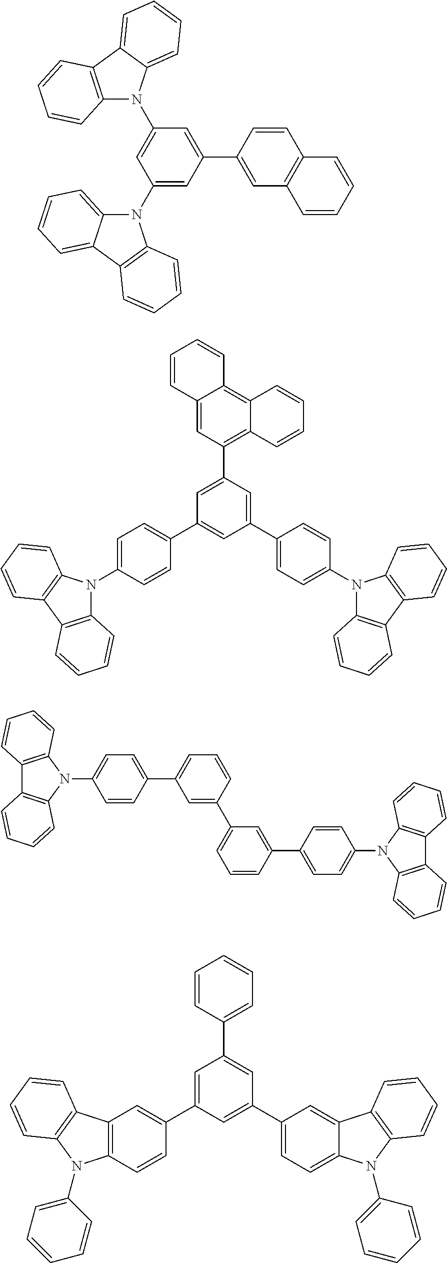 [SMILES: c1ccc2cc(-c3cc(-n4c5ccccc5c5ccccc54)cc(-n4c5ccccc5c5ccccc54)c3)ccc2c1 ; c1ccc2c(c1)cc(-c1cc(-c3ccc(-n4c5ccccc5c5ccccc54)cc3)cc(-c3ccc(-n4c5ccccc5c5ccccc54)cc3)c1)c1ccccc12 ; c1cc(-c2ccc(-n3c4ccccc4c4ccccc43)cc2)cc(-c2cccc(-c3ccc(-n4c5ccccc5c5ccccc54)cc3)c2)c1 ; c1ccc(-c2cc(-c3ccc4c(c3)c3ccccc3n4-c3ccccc3)cc(-c3ccc4c(c3)c3ccccc3n4-c3ccccc3)c2)cc1]

In another embodiment, the second host material for the emitting layer in the organic EL device can be a compound represented by a formula (8) below.

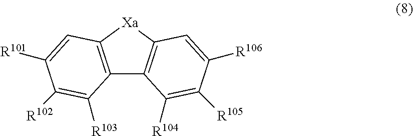

In the formula (8): R¹⁰¹ to R¹⁰⁶ each independently represent a hydrogen atom, halogen atom, substituted or unsubstituted alkyl group having 1 to 40 carbon atoms, substituted or unsubstituted cycloalkyl group having 3 to 15 carbon atoms, substituted or unsubstituted heterocyclic group having 3 to 20 carbon atoms, substituted or unsubstituted alkoxy group having 1 to 40 carbon atoms, substituted or unsubstituted aryl group having 6 to 40 carbon atoms, substituted or unsubstituted aryloxy group having 6 to 20 carbon atoms, substituted or unsubstituted aralkyl group having 7 to 20 carbon atoms, substituted or unsubstituted arylamino group having 6 to 40 carbon atoms, substituted or unsubstituted alkylamino group having 1 to 40 carbon atoms, substituted or unsubstituted aralkylamino group having 7 to 60 carbon atoms, substituted or unsubstituted arylcarbonyl group having 7 to 40 carbon atoms, substituted or unsubstituted arylthio group having 6 to 20 carbon atoms, substituted or unsubstituted halogenated alkyl group having 1 to 40 carbon atoms or cyano group;

at least one of R¹⁰¹ to R¹⁰⁶ is a substituted or unsubstituted 9-carbazolyl group, substituted or unsubstituted azacarbazolyl group having 2 to 5 nitrogen atoms, or -L-9-carbazolyl group;

L represents a substituted or unsubstituted alkyl group having 1 to 40 carbon atoms, substituted or unsubstituted cycloalkyl group having 3 to 15 carbon atoms, substituted or unsubstituted heterocyclic group having 3 to 20 carbon atoms, substituted or unsubstituted alkoxy group having 1 to 40 carbon atoms, substituted or unsubstituted aryl group having 6 to 40 carbon atoms, substituted or unsubstituted aryloxy group having 6 to 20 carbon atoms, substituted or unsubstituted aralkyl group having 7 to 20 carbon atoms, substituted or unsubstituted arylamino group having 6 to 40 carbon atoms, substituted or unsubstituted alkylamino group having 1 to 40 carbon atoms, substituted or unsubstituted aralkylamino group having 7 to 60 carbon atoms, substituted or unsubstituted arylcarbonyl group having 7 to 40 carbon atoms, substituted or unsubstituted arylthio group having 6 to 20 carbon atoms, or substituted or unsubstituted halogenated alkyl group having 1 to 40 carbon atoms;

Xa represents a sulfur atom, oxygen atom or N—R¹⁰⁸; and

R¹⁰⁸ represents the same as R¹⁰¹ to R¹⁰⁶.

Some specific examples of the substituted or unsubstituted azacarbazolyl group having 2 to 5 nitrogen atoms are shown below (in which any substituent is omitted), but the substituted or unsubstituted azacarbazolyl group is not limited thereto.

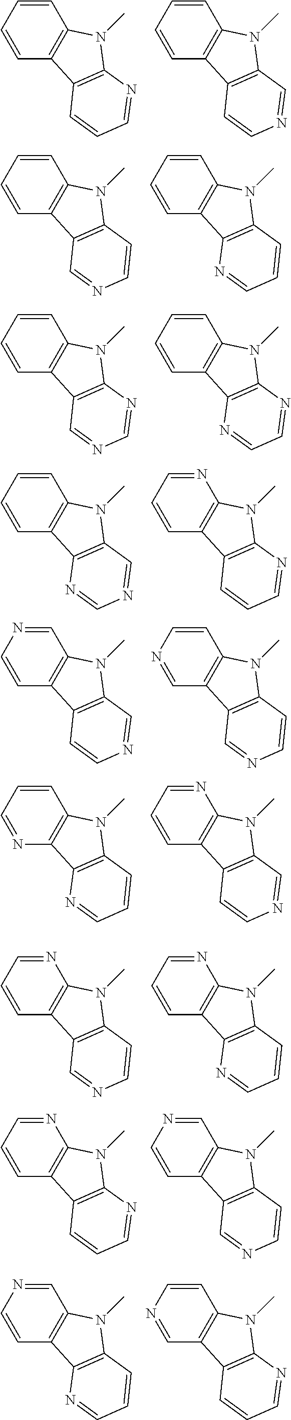

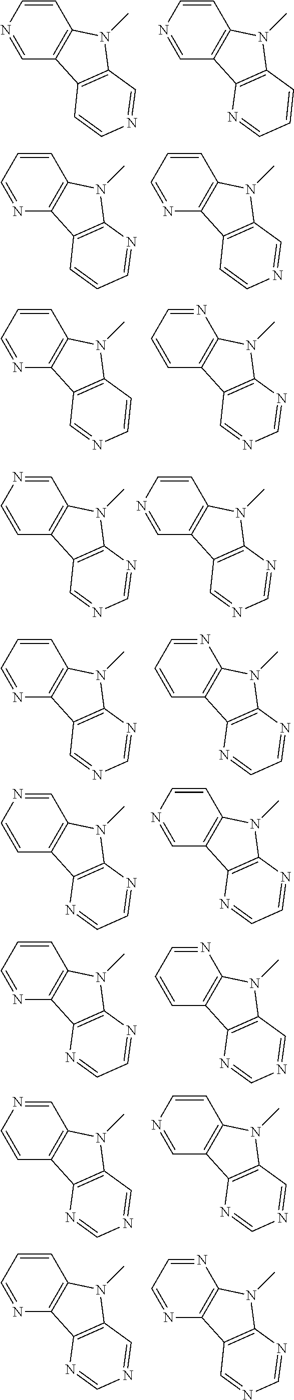

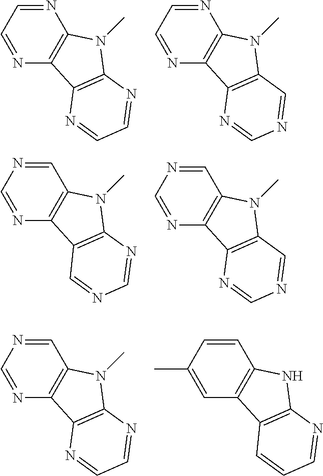

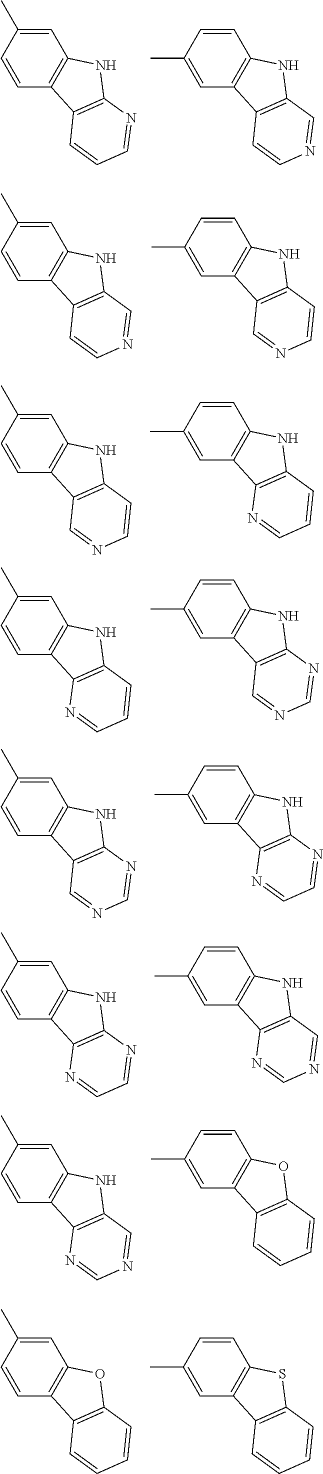

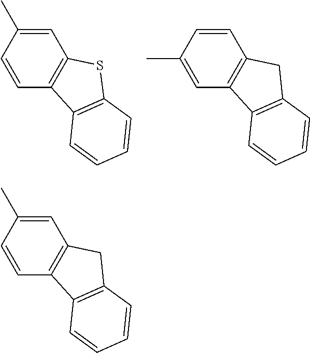

Some examples of the halogen atom include fluorine, chlorine, bromine, and iodine.

Some examples of the substituted or unsubstituted alkyl group having 1 to 40 carbon atoms include a methyl group, an ethyl group, a propyl group, an isopropyl group, an n-butyl group, an s-butyl group, an isobutyl group, a t-butyl group, an n-pentyl group, an n-hexyl group, an n-heptyl group, an n-octyl group, an n-nonyl group, an n-decyl group, an n-undecyl group, an n-dodecyl group, an n-tridecyl group, an n-tetradecyl group, an n-pentadecyl group, an n-hexadecyl group, an n-heptadecyl group, an n-octadecyl group, a neopentyl group, a 1-methylpentyl group, a 2-methylpentyl group, a 1-pentylhexyl group, a 1-butylpentyl group, a 1-heptyloctyl group, a 3-methylpentyl group, a hydroxymethyl group, a 1-hydroxyethyl group, a 2-hydroxyethyl group, a 2-hydroxyisobutyl group, a 1,2-dihydroxyethyl group, a 1,3-dihydroxyisopropyl group, a 2,3-dihydroxy-t-butyl group, a 1,2,3-trihydroxypropyl group, a chloromethyl group, a 1-chloroethyl group, a 2-chloroethyl group, a 2-chloroisobutyl group, a 1,2-dichloroethyl group, a 1,3-dichloroisopropyl group, a 2,3-dichloro-t-butyl group, a 1,2,3-trichloropropyl group, a bromomethyl group, a 1-bromoethyl group, a 2-bromoethyl group, a 2-bromoisobutyl group, a 1,2-dibromoethyl group, a 1,3-dibromoisopropyl group, a 2,3-dibromo-t-butyl group, a 1,2,3-tribromopropyl group, an iodomethyl group, a 1-iodoethyl group, a 2-iodoethyl group, a 2-iodoisobutyl group, a 1,2-diiodoethyl group, a 1,3-diiodoisopropyl group, a 2,3-diiodo-t-butyl group, a 1,2,3-triiodopropyl group, an aminomethyl group, a 1-aminoethyl group, a 2-aminoethyl group, a 2-aminoisobutyl group, a 1,2-diaminoethyl group, a 1,3-diaminoisopropyl group, a 2,3-diamino-t-butyl group, a 1,2,3-triaminopropyl group, a cyanomethyl group, a 1-cyanoethyl group, a 2-cyanoethyl group, a 2-cyanoisobutyl group, a 1,2-dicyanoethyl group, a 1,3-dicyanoisopropyl group, a 2,3-dicyano-t-butyl group, a 1,2,3-tricyanopropyl group, a nitromethyl group, a 1-nitroethyl group, a 2-nitroethyl group, a 1,2-dinitroethyl group, a 2,3-dinitro-t-butyl group, and a 1,2,3-trinitropropyl group, among of which a methyl group, an ethyl group, a propyl group, an isopropyl group, an n-butyl group, an s-butyl group, an isobutyl group, a t-butyl group, an n-pentyl group, an n-hexyl group, an n-heptyl group, an n-octyl group, an n-nonyl group, an n-decyl group, an n-undecyl group, an n-dodecyl group, an n-tridecyl group, an n-tetradecyl group, an n-pentadecyl group, an n-hexadecyl group, an n-heptadecyl group, an n-octadecyl group, a neopentyl group, a 1-methylpentyl group, a 1-pentylhexyl group, a 1-butylpentyl group, a 1-heptyloctyl group are preferable. The alkyl group (excluding a substituent) preferably has 1 to 10 carbon atoms.

Some examples of the substituted or unsubstituted cycloalkyl group having 3 to 15 carbon atoms include a cyclopentyl group, cyclohexyl group, cyclooctyl group, and 3,5,5,5-tetramethylcyclohexyl group. A cyclohexyl group, cyclooctyl group, and 3,5-tetramethylcyclohexyl group are preferable. The cycloalkyl group (excluding a substituent) preferably has 3 to 12 carbon atoms.

Some examples of the substituted or unsubstituted heterocyclic group having 3 to 20 carbon atoms are a 1-pyroryl group, 2-pyroryl group, 3-pyroryl group, pyrazinyl group, 2-pyridinyl group, 1-imidazolyl, 2-imidazolyl, 1-pyrazolyl, 1-indolidinyl, 2-indolidinyl, 3-indolidinyl, 5-indolidinyl, 6-indolidinyl, 7-indolidinyl, 8-indolidinyl, 2-imidazopyridinyl, 3-imidazopyridinyl, 5-imidazopyridinyl, 6-imidazopyridinyl, 7-imidazopyridinyl, 8-imidazopyridinyl, 3-pyridinyl group, 4-pyridinyl group, 1-indolyl group, 2-indolyl group, 3-indolyl group, 4-indolyl group, 5-indolyl group, 6-indolyl group, 7-indolyl group, 1-isoindolyl group, 2-isoindolyl group, 3-isoindolyl group, 4-isoindolyl group, 5-isoindolyl group, 6-isoindolyl group, 7-isoindolyl group, 2-furyl group, 3-furyl group, 2-benzofuranyl group, 3-benzofuranyl group, 4-benzofuranyl group, 5-benzofuranyl group, 6-benzofuranyl group, 7-benzofuranyl group, 1-isobenzofuranyl group, 3-isobenzofuranyl group, 4-isobenzofuranyl group, 5-isobenzofuranyl group, 6-isobenzofuranyl group, 7-isobenzofuranyl group, 2-quinolyl group, 3-quinolyl group, 4-quinolyl group, 5-quinolyl group, 6-quinolyl group, 7-quinolyl group, 8-quinolyl group, 1-isoquinolyl group, 3-isoquinolyl group, 4-isoquinolyl group, 5-isoquinolyl group, 6-isoquinolyl group, 7-isoquinolyl group, 8-isoquinolyl group, 2-quinoxalinyl group, 5-quinoxalinyl group, 6-quinoxalinyl group, 1-carbazolyl group, 2-carbazolyl group, 3-carbazolyl group, 4-carbazolyl group, 9-carbazolyl group, azacarbazolyl-1-yl, azacarbazolyl-2-yl, azacarbazolyl-3-yl, azacarbazolyl-4-yl, azacarbazolyl-5-yl, azacarbazolyl-6-yl, azacarbazolyl-7-yl, azacarbazolyl-8-yl, azacarbazolyl-9-yl, 1-phenanthrydinyl group, 2-phenanthrydinyl group, 3-phenanthrydinyl group, 4-phenanthrydinyl group, 6-phenanthrydinyl group, 7-phenanthrydinyl group, 8-phenanthrydinyl group, 9-phenanthrydinyl group, 10-phenanthrydinyl group, 1-acridinyl group, 2-acridinyl group, 3-acridinyl group, 4-acridinyl group, 9-acridinyl group, 1,7-phenanthroline-2-yl group, 1,7-phenanthroline-3-yl group, 1,7-phenanthroline-4-yl group, 1,7-phenanthroline-5-yl group, 1,7-phenanthroline-6-yl group, 1,7-phenanthroline-8-yl group, 1,7-phenanthroline-9-yl group, 1,7-phenanthroline-10-yl group, 1,8-phenanthroline-2-yl group, 1,8-phenanthroline-3-yl group, 1,8-phenanthroline-4-yl group, 1,8-phenanthroline-5-yl group, 1,8-phenanthroline-6-yl group, 1,8-phenanthroline-7-yl group, 1,8-phenanthroline-9-yl group, 1,8-phenanthroline-10-yl group, 1,9-phenanthroline-2-yl group, 1,9-phenanthroline-3-yl group, 1,9-phenanthroline-4-yl group, 1,9-phenanthroline-5-yl group, 1,9-phenanthroline-6-yl group, 1,9-phenanthroline-7-yl group, 1,9-phenanthroline-8-yl group, 1,9-phenanthroline-10-yl group, 1,10-phenanthroline-2-yl group, 1,10-phenanthroline-3-yl group, 1,10-phenanthroline-4-yl group, 1,10-phenanthroline-5-yl group, 2,9-phenanthroline-1-yl group, 2,9-phenanthroline-3-yl group, 2,9-phenanthroline-4-yl group, 2,9-phenanthroline-5-yl group, 2,9-phenanthroline-6-yl group, 2,9-phenanthroline-7-yl group, 2,9-phenanthroline-8-yl group, 2,9-phenanthroline-10-yl group, 2,8-phenanthroline-1-yl group, 2,8-phenanthroline-3-yl group, 2,8-phenanthroline-4-yl group, 2,8-phenanthroline-5-yl group, 2,8-phenanthroline-6-yl group, 2,8-phenanthroline-7-yl group, 2,8-phenanthroline-9-yl group, 2,8-phenanthroline-10-yl group, 2,7-phenanthroline-1-yl group, 2,7-phenanthroline-3-yl group, 2,7-phenanthroline-4-yl group, 2,7-phenanthroline-5-yl group, 2,7-phenanthroline-6-yl group, 2,7-phenanthroline-8-yl group, 2,7-phenanthroline-9-yl group, 2,7-phenanthroline-10-yl group, 1-phenazinyl group, 2-phenazinyl group, 1-phenothiazinyl group, 2-phenothiazinyl group, 3-phenothiazinyl group, 4-phenothiazinyl group, 10-phenothiazinyl group, 1-phenoxazinyl group, 2-phenoxazinyl group, 3-phenoxazinyl group, 4-phenoxazinyl group, 10-phenoxazinyl group, 2-oxazolyl group, 4-oxazolyl group, 5-oxazolyl group, 2-oxadiazolyl group, 5-oxadiazolyl group, 3-furazanyl group, 2-thienyl group, 3-thienyl group, 2-methylpyrrole-1-yl group, 2-methylpyrrole-3-yl group, 2-methylpyrrole-4-yl group, 2-methylpyrrole-5-yl group, 3-methylpyrrole-1-yl group, 3-methylpyrrole-2-yl group, 3-methylpyrrole-4-yl group, 3-methylpyrrole-5-yl group, 2-t-butylpyrrole-4-yl group, 3-(2-phenylpropyl)pyrrole-1-yl group, 2-methyl-1-indolyl group, 4-methyl-1-indolyl group, 2-methyl-3-indolyl group, 4-methyl-3-indolyl group, 2-t-butyl-1-indolyl group, 4-t-butyl-1-indolyl group, 2-t-butyl-3-indolyl group, 4-t-butyl-3-indolyl group, 1-dibenzofuranyl group, 2-dibenzofuranyl group, 3-dibenzofuranyl group, 4-dibenzofuranyl group, 1-dibenzothiophenyl group, 2-dibenzothiophenyl group, 3-dibenzothiophenyl group, 4-dibenzothiophenyl group, 1-silafluorenyl group, 2-silafluorenyl group, 3-silafluorenyl group, 4-silafluorenyl group, 1-germafluorenyl group, 2-germafluorenyl group, 3-germafluorenyl group and 4-germafluorenyl group.

Among the above, the heterocyclic group is preferably a 2-pyridinyl group, 1-indolidinyl, 2-indolidinyl, 3-indolidinyl, 5-indolidinyl, 6-indolidinyl, 7-indolidinyl, 8-indolidinyl, 2-imidazopyridinyl, 3-imidazopyridinyl, 5-imidazopyridinyl, 6-imidazopyridinyl, 7-imidazopyridinyl, 8-imidazopyridinyl, 3-pyridinyl group, 4-pyridinyl group, 1-indolyl group, 2-indolyl group, 3-indolyl group, 4-indolyl group, 5-indolyl group, 6-indolyl group, 7-indolyl group, 1-isoindolyl group, 2-isoindolyl group, 3-isoindolyl group, 4-isoindolyl group, 5-isoindolyl group, 6-isoindolyl group, 7-isoindolyl group, 9-carbazolyl group, 1-dibenzofuranyl group, 2-dibenzofuranyl group, 3-dibenzofuranyl group, 4-dibenzofuranyl group, 1-dibenzothiophenyl group, 2-dibenzothiophenyl group, 3-dibenzothiophenyl group, 4-dibenzothiophenyl group, 1-silafluorenyl group, 2-silafluorenyl group, 3-silafluorenyl group, 4-silafluorenyl group, 1-germafluorenyl group, 2-germafluorenyl group, 3-germafluorenyl group, 4-germafluorenyl group, azacarbazolyl-1-yl group, azacarbazolyl-2-yl group, azacarbazolyl-3-yl group, azacarbazolyl-4-yl group, azacarbazolyl-5-yl group, azacarbazolyl-6-yl group, azacarbazolyl-7-yl group, azacarbazolyl-8-yl group, and azacarbazolyl-9-yl group. The heterocyclic group (excluding a substituent) preferably has 3 to 14 carbon atoms.

The substituted or unsubstituted alkoxy group having 1 to 40 carbon atoms is a group represented by —OY. Examples of Y are the same as those described in relation to the alkyl group. Preferred examples are also the same.

Some examples of the substituted or unsubstituted aryl group having 6 to 40 carbon atoms (including a fused aromatic hydrocarbon group and a ring assembly aromatic hydrocarbon group) are a phenyl group, 2-biphenylyl group, 3-biphenylyl group, 4-biphenylyl group, p-terphenyl-4-yl group, p-terphenyl-3-yl group, p-terphenyl-2-yl group, m-terphenyl-4-yl group, m-terphenyl-3-yl group, m-terphenyl-2-yl group, o-tolyl group, m-tolyl group, p-tolyl group, p-t-butylphenyl group, p-(2-phenylpropyl)phenyl group, 4′-methylbiphenylyl group, 4″-t-butyl-p-terphenyl-4-yl group, o-cumenyl group, m-cumenyl group, p-cumenyl group, 2,3-xylyl group, 3,4-xylyl group, 2,5-xylyl group, mesityl group and m-quarter-phenyl group. Among the above, the substituted or unsubstituted aryl group is preferably a phenyl group, 2-biphenylyl group, 3-biphenylyl group, 4-biphenylyl group, m-terphenyl-4-yl group, m-terphenyl-3-yl group, m-terphenyl-2-yl group, p-tolyl group, 3,4-xylyl group, m-quarter-phenyl-2-yl group, 1-naphtyl group, 2-naphtyl group, 1-phenanthrenyl group, 2-phenanthrenyl group, 3-phenanthrenyl group, 4-phenanthrenyl group, 9-phenanthrenyl group, 1-triphenylenyl group, 2-triphenylenyl group, 3-triphenylenyl group, 4-triphenylenyl group, 1-chrysenyl group, 2-chrysenyl group, 3-chrysenyl group, 4-chrysenyl group, 5-chrysenyl group, and 6-chrysenyl group. The aryl group (excluding a substituent) preferably has 6 to 24 carbon atoms. The aryl group preferably further includes a 9-carbazolyl group as a substituent.

The substituted or unsubstituted aryloxy group having 6 to 20 carbon atoms is a group represented by —OAr. Examples of Ar are the same as those described in relation to the aryl group. Preferred examples are also the same.

Some examples of the substituted or unsubstituted aralkyl group having 7 to 20 carbon atoms are a benzyl group, 1-phenylethyl group, 2-phenylethyl group, 1-phenylisopropyl group, 2-phenylisopropyl group, phenyl-t-butyl group, á-naphthylmethyl group, 1-á-naphthylethyl group, 2-á-naphthylethyl group, 1-á-naphthylisopropyl group, 2-á-naphthylisopropyl group, â-naphthylmethyl group, 1-â-naphthylethyl group, 2-â-naphthylethyl group, 1-â-naphthylisopropyl group, 2-â-naphthylisopropyl group, 1-pyrorylmethyl group, 2-(1-pyroryl)ethyl group, p-methylbenzyl group, m-methylbenzyl group, o-methylbenzyl group, p-chlorobenzyl group, m-chlorobenzyl group, o-chlorobenzyl group, p-bromobenzyl group, m-bromobenzyl group, o-bromobenzyl group, p-iodobenzyl group, m-iodobenzyl group, o-iodobenzyl group, p-hydroxybenzyl group, m-hydroxybenzyl group, o-hydroxybenzyl group, p-aminobenzyl group, m-aminobenzyl group, o-aminobenzyl group, p-nitrobenzyl group, m-nitrobenzyl group, o-nitrobenzyl group, p-cyanobenzyl group, m-cyanobenzyl group, o-cyanobenzyl group, 1-hydroxy-2-phenylisopropyl group, 1-chloro-2-phenylisopropyl group and the like. Among these, preferred are a benzyl group, a p-cyanobenzyl group, m-cyanobenzyl group, o-cyanobenzyl group, 1-phenylethyl group, 2-phenylethyl group, 1-phenylisopropyl group, and 2-phenylisopropyl group. An alkyl portion of the aralkyl group preferably has 1 to 8 carbon atoms. An aryl portion thereof (including heteroaryl) preferably has 6 to 18 carbon atoms.

The substituted or unsubstituted arylamino group having 6 to 40 carbon atoms, the substituted or unsubstituted alkylamino group having 1 to 40 carbon atoms, and the substituted or unsubstituted aralkylamino group having 7 to 60 carbon atoms each are represented by —NQ1Q2. Examples of Q1 and Q2 each are independently the same as those described in relation to the alkyl group, aryl group and aralkyl group. Preferred examples are also the same.

The substituted or unsubstituted arylcarbonyl group having 7 to 40 carbon atoms is represented by —COAr2. Examples of Ar2 are the same as those described in relation to the aryl group. Preferred examples are also the same.

The substituted or unsubstituted arylthio group having 6 to 20 carbon atoms is exemplified by a group obtained by replacing an oxygen atom of the aryloxy group represented by —OAr with a sulfur atom. Preferred examples are also the same.

The substituted or unsubstituted halogenated alkyl group having 1 to 40 carbon atoms is exemplified by a halogenated alkyl group in which at least one hydrogen atom of the alkyl group is substituted by a halogen atom. Preferred examples are also the same.

The compound represented by the general formula (8) preferably has triplet energy gap of 2.2 eV to 3.2 eV. Some specific examples of the formula (8) are shown below.

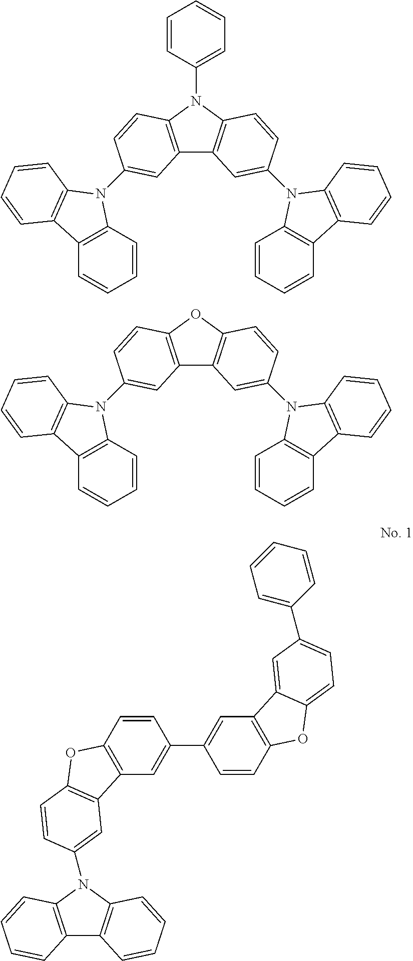

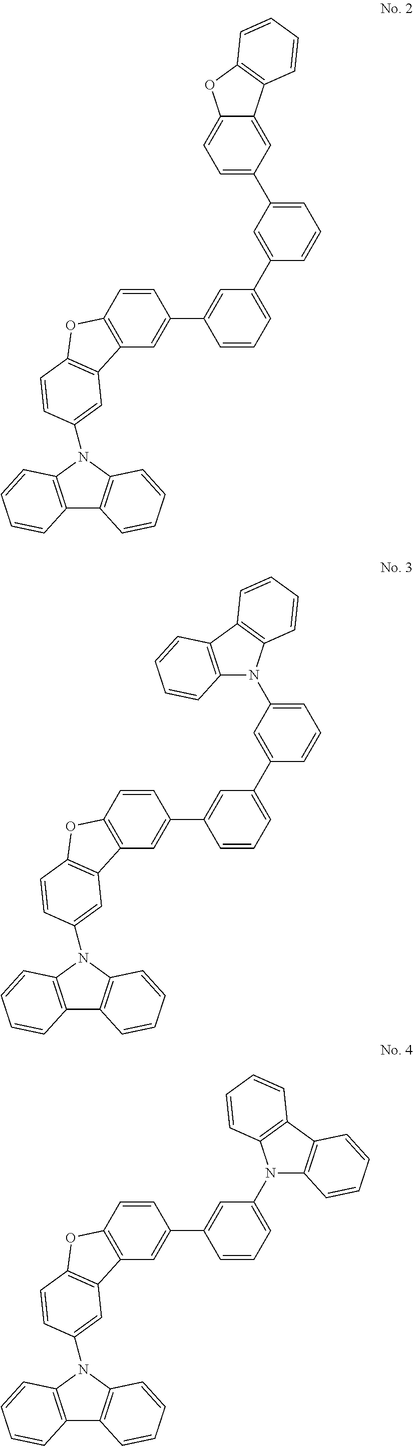

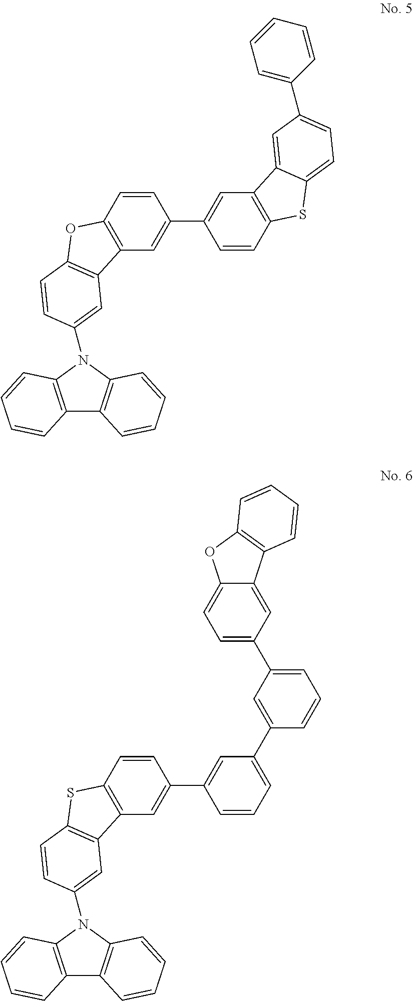

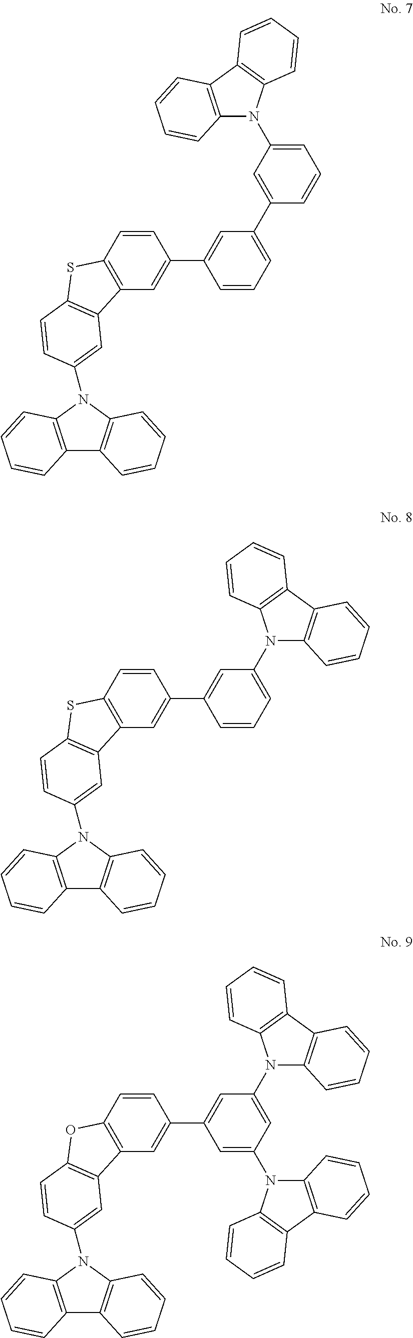

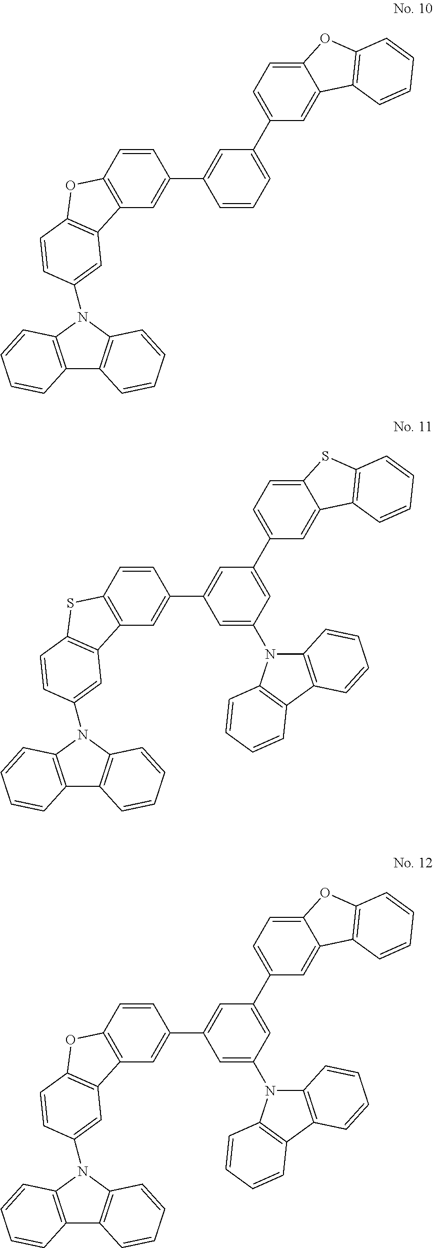

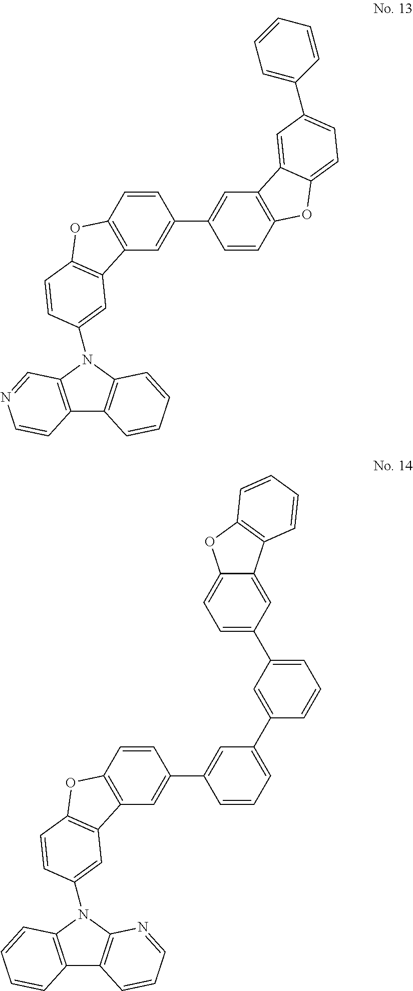

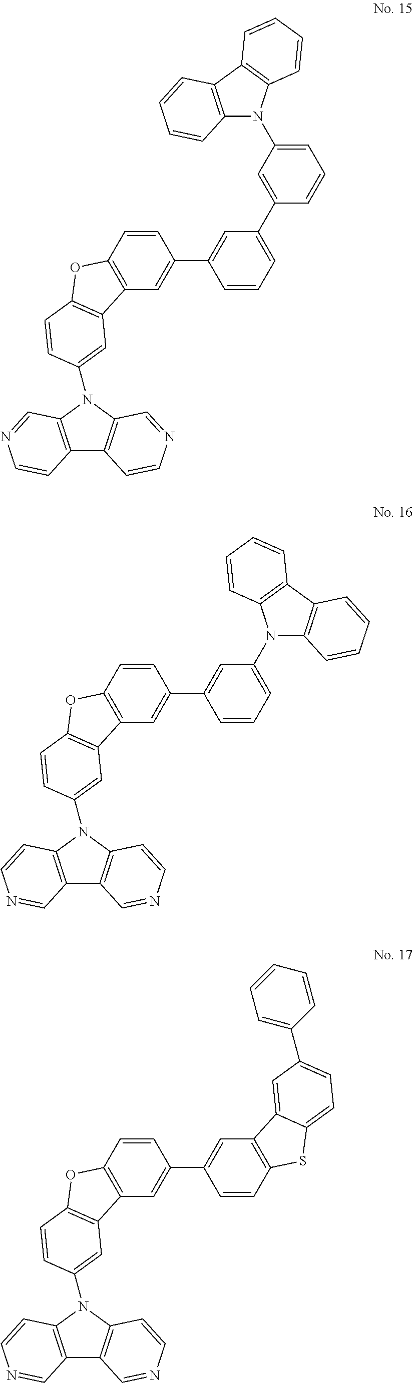

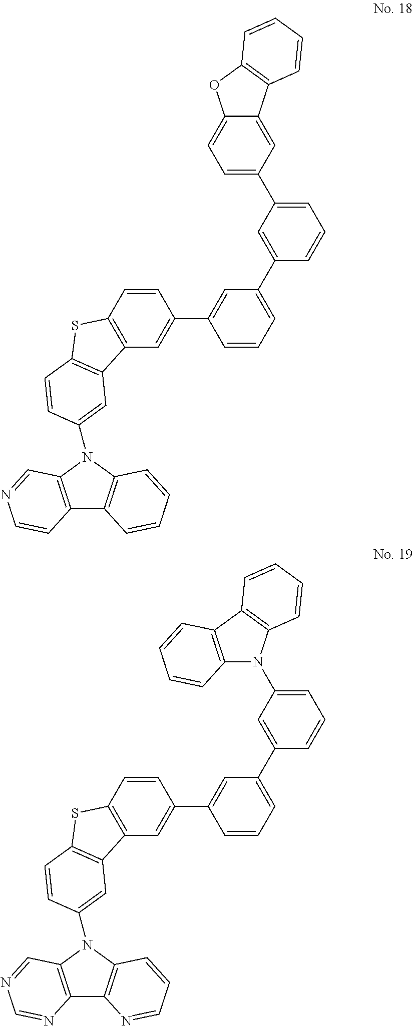

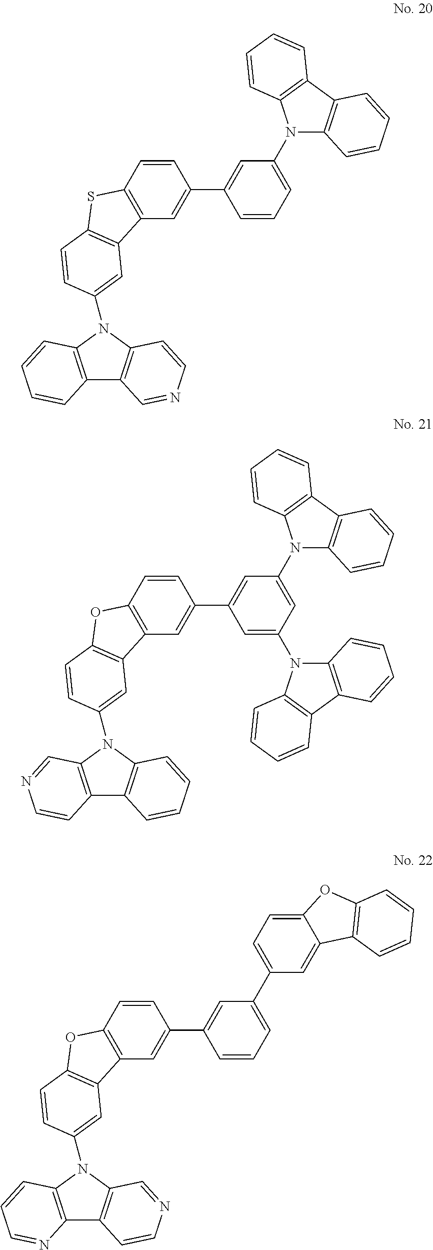

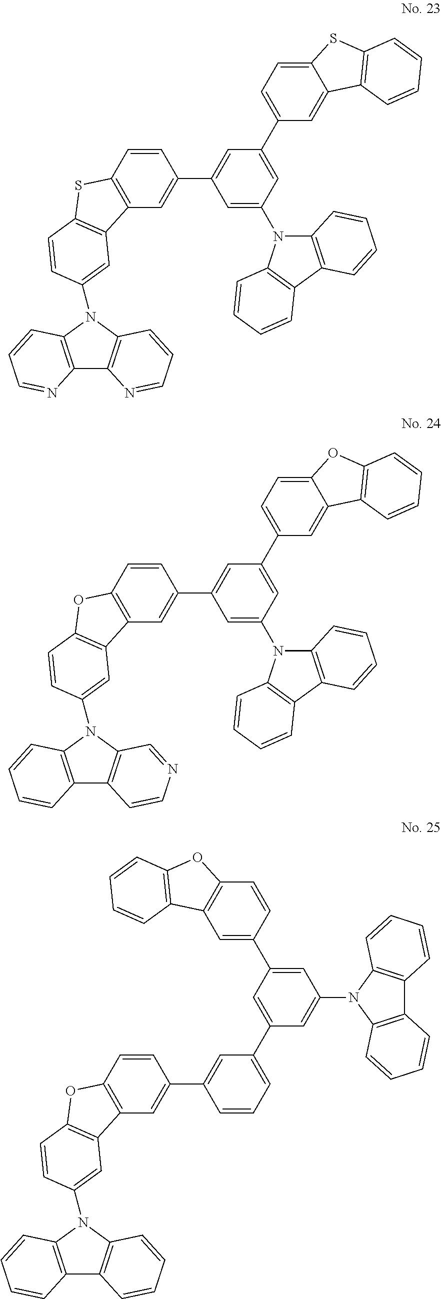

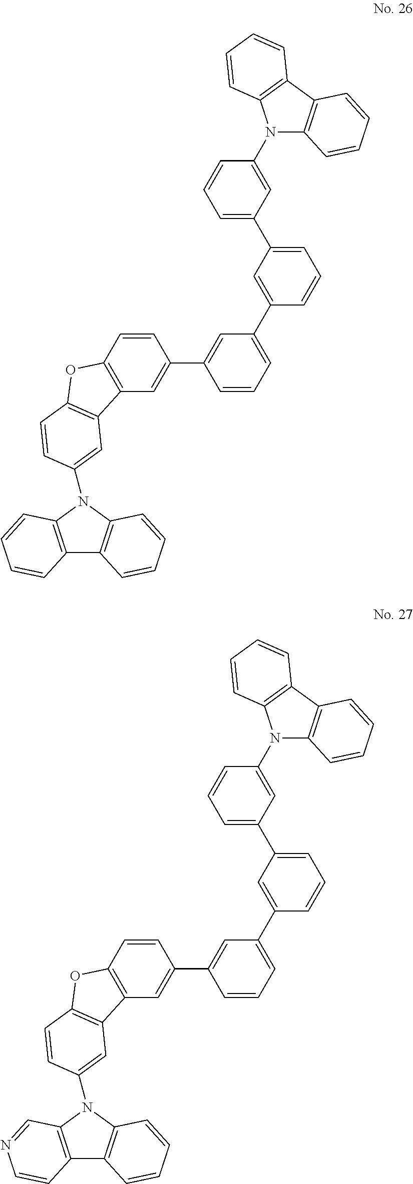

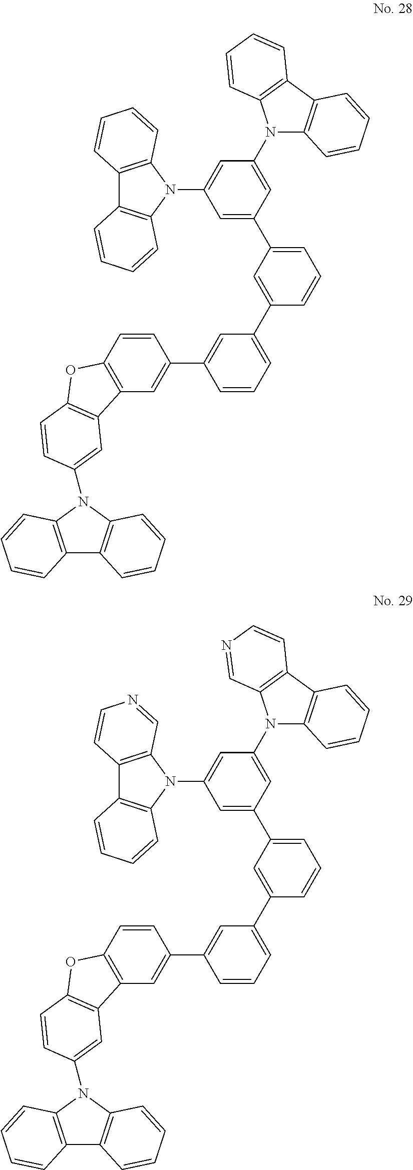

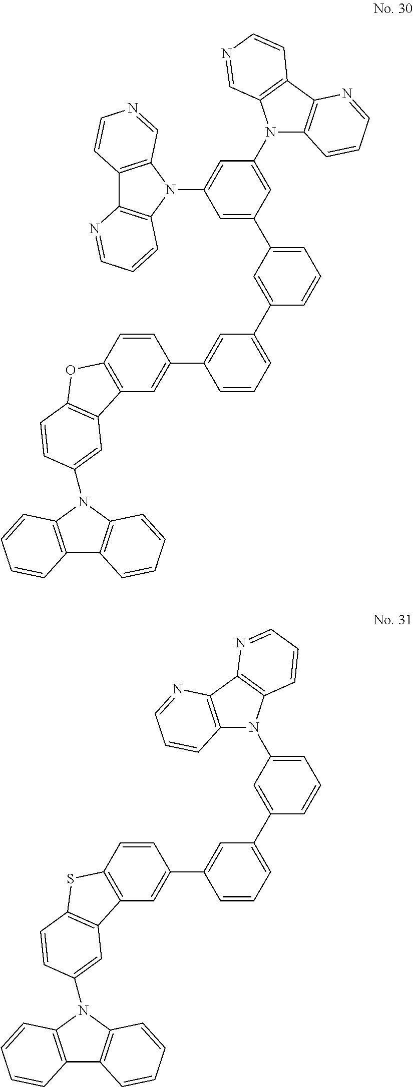

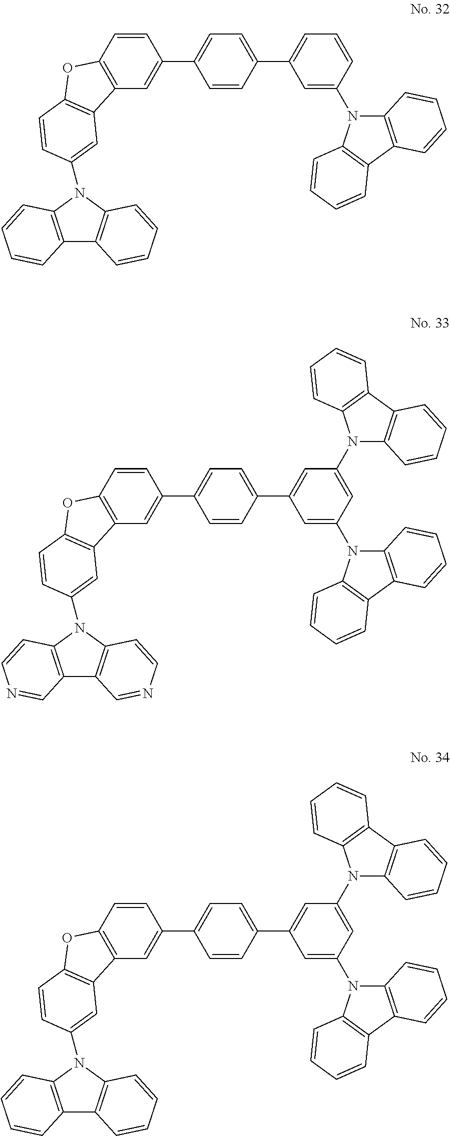

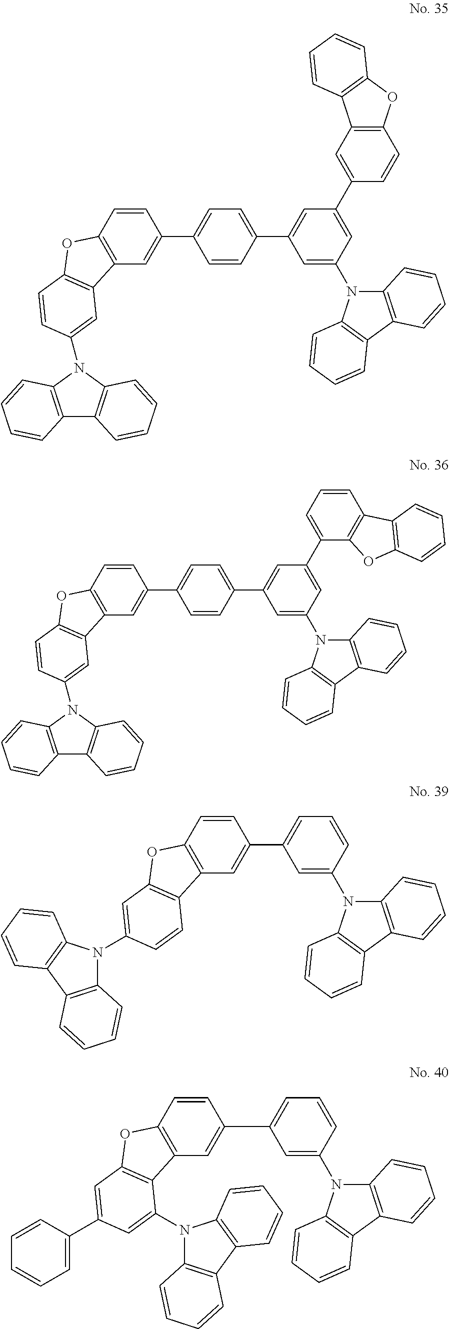

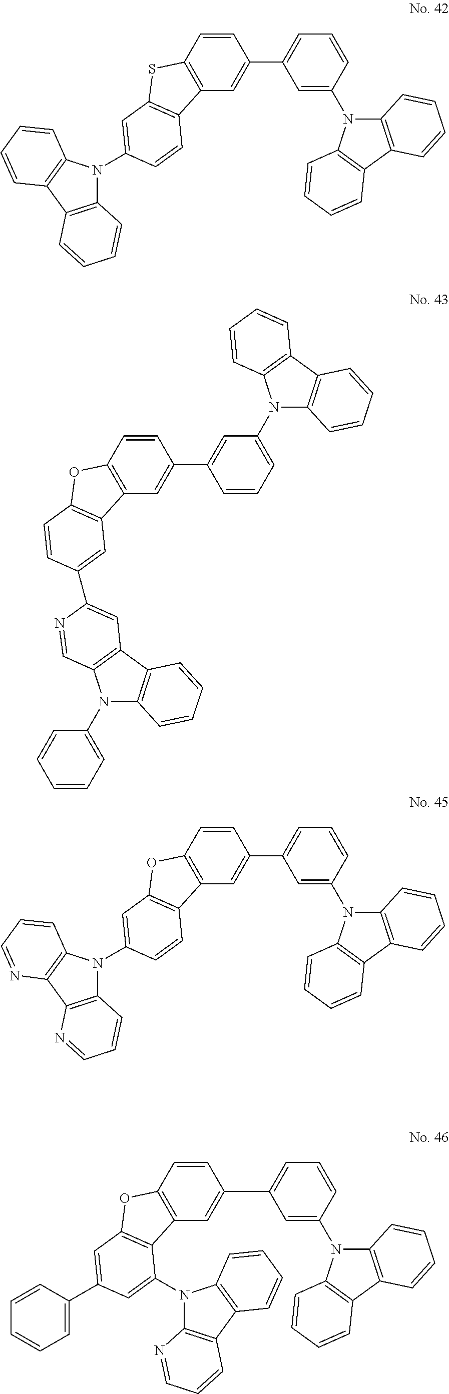

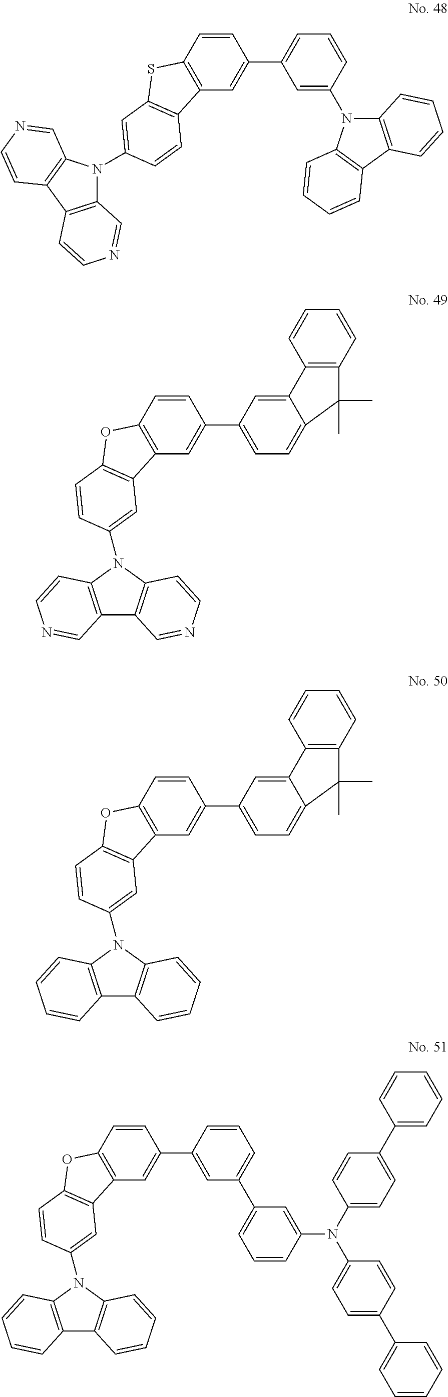

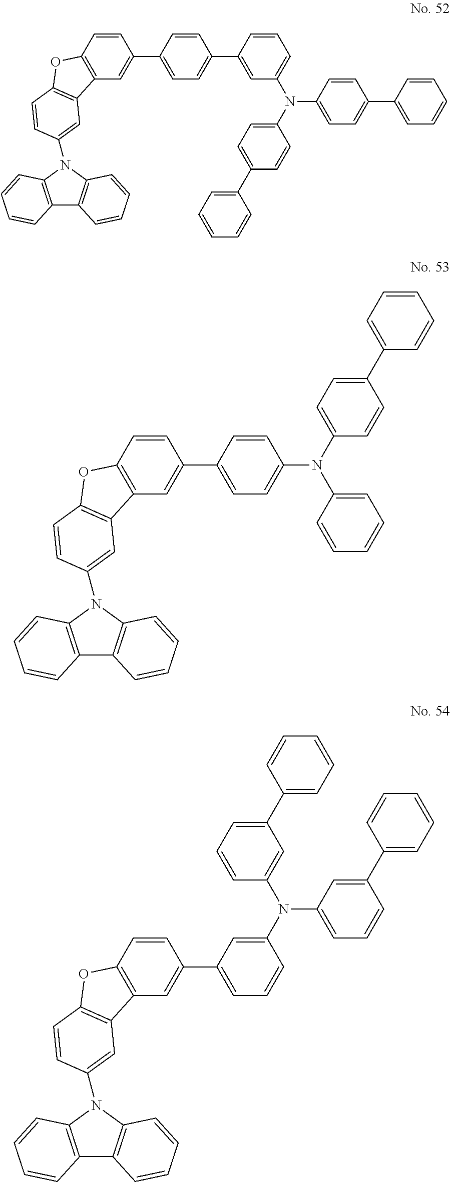

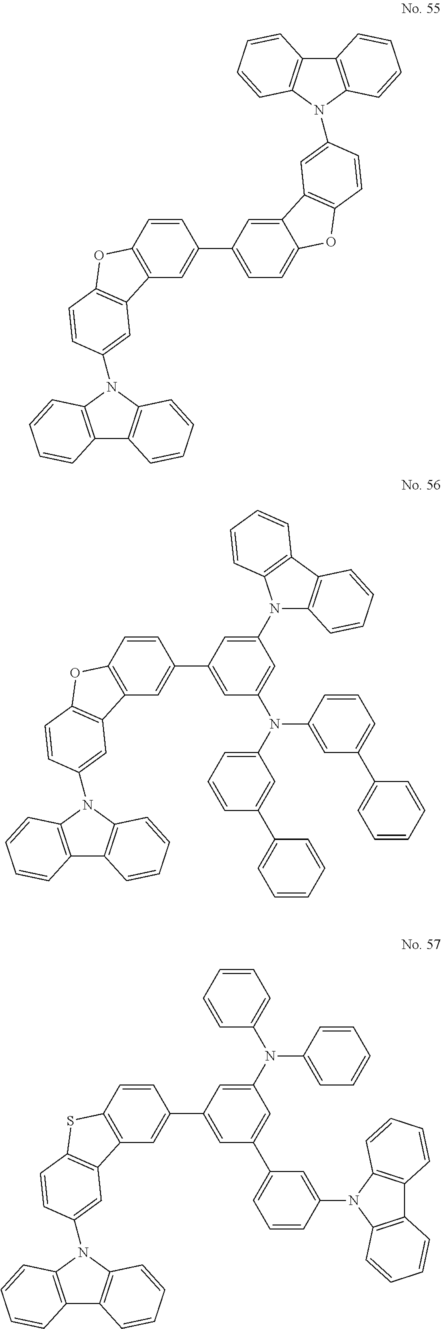

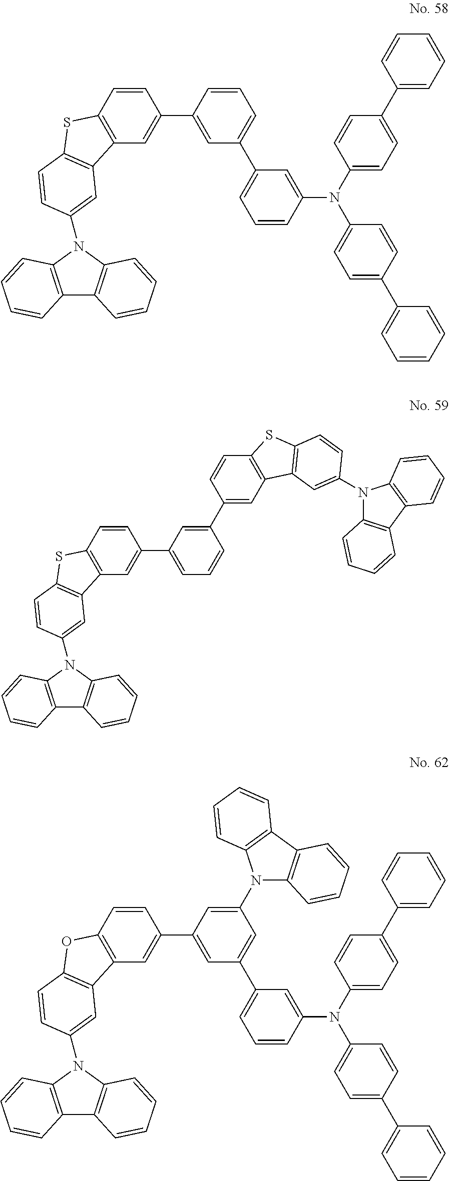

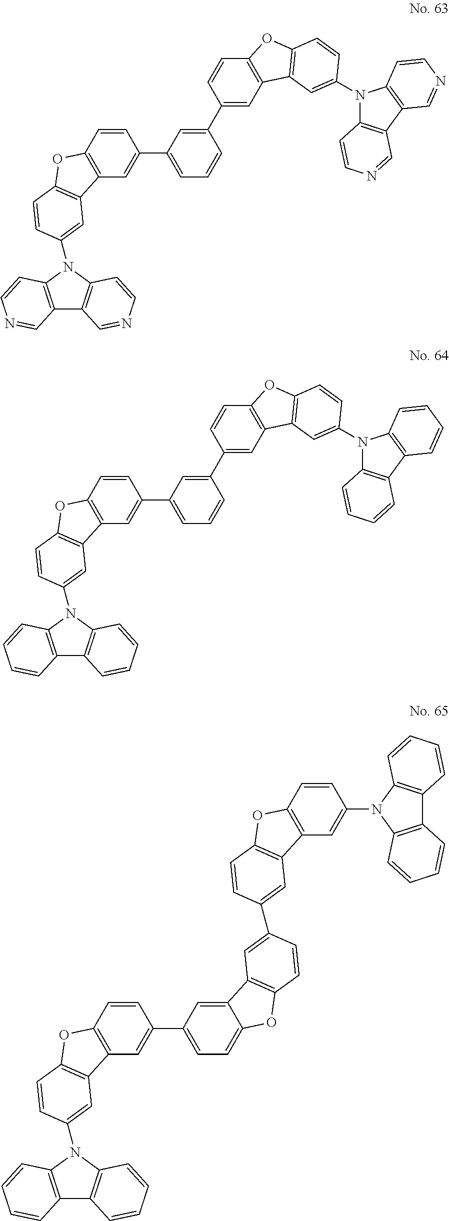

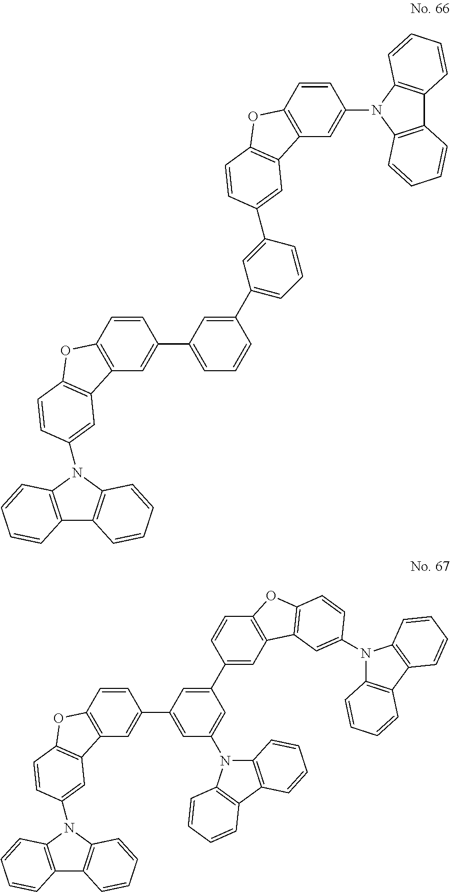

In another embodiment, the second host material can be a monoamine derivative represented by any one of formulas (10) to (12) below.

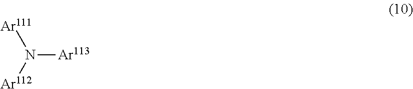

In the formula (10), Ar¹¹¹, Ar¹¹² and Ar¹¹³ each are a substituted or unsubstituted aryl group or heteroaryl group. The aryl group has 6 to 50 ring carbon atoms (preferably 6 to 30 ring carbon atoms, more preferably 6 to 20 ring carbon atoms). Examples of the aryl group are a phenyl group, naphthyl group, phenanthrenyl group, benzophenanthrenyl group, dibenzophenanthrenyl group, benzochrysenyl group, dibenzochrysenyl group, fluoranthenyl group, benzofluoranthenyl group, triphenylenyl group, benzotriphenylenyl group, dibenzotriphenylenyl group, picenyl group, benzopicenyl group, dibenzopicenyl group, phenalenyl group, acenaphthenyl group, and diazaphenanthrenyl group. Among the above, a phenyl group or naphthyl group is preferable.

The heteroaryl group has 5 to 50 ring atoms, preferably 6 to 30 ring atoms, and more preferably 6 to 20 ring atoms. Examples of the heteroaryl group are a pyrimidyl group and diazaphenanthrenyl group.

At least one of Ar¹¹¹, Ar¹¹² and Ar¹¹³ is preferably a fused aromatic hydrocarbon group selected from a phenanthrenyl group, benzophenanthrenyl group, dibenzophenanthrenyl group, benzochrysenyl group, dibenzochrysenyl group, fluoranthenyl group, benzofluoranthenyl group, triphenylenyl group, benzotriphenylenyl group, dibenzotriphenylenyl group, picenyl group, benzopicenyl group, dibenzopicenyl group, phenalenyl group, and diazaphenanthrenyl group. Among the above, a benzochrysenyl group, triphenylenyl group, or phenanthrenyl group is more preferable. Preferably, the fused aromatic hydrocarbon group is unsubstituted.

In the monoamine derivative represented by the formula (10), Ar¹¹¹ and Ar¹¹² each are preferably a phenyl group or naphthyl group, and Ar¹¹³ is preferably a benzochrysenyl group, triphenylenyl group, or phenanthrenyl group.

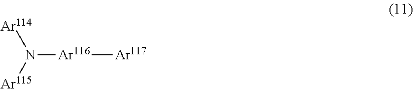

In the formula (11), Ar¹¹⁴, Ar¹¹⁵ and Ar¹¹⁷ each are a substituted or unsubstituted aryl group or heteroaryl group. Examples of the aryl group or heteroaryl group are the same as those defined as the aryl group or heteroaryl group for Ar¹¹¹, among which a phenyl group or naphthyl group is preferable. Ar¹¹⁶ is a substituted or unsubstituted arylene group or heteroarylene group.

The arylene group has 6 to 50 ring carbon atoms (preferably 6 to 30 ring carbon atoms, more preferably 6 to 20 ring carbon atoms). Some examples of the arylene group are a phenylene group, naphthylene group, phenanthrenylene group, naphthacenylene group, pyrenylene group, biphenylene group, terphenylenylene group, benzophenanthrenylene group, dibenzophenanthrenylene group, benzochrysenylene group, dibenzochrysenylene group, fluoranthenylene group, benzofluoranthenylene group, triphenylenylene group, benzotriphenylenylene group, dibenzotriphenylenylene group, picenylene group, benzopicenylene group, and dibenzopicenylene group. Among the above, a phenylene group or naphthylene group is preferable.

The heteroaryl group has 5 to 50 ring atoms (preferably 6 to 30 ring atoms, more preferably 6 to 20 ring atoms). Some examples of the heteroaryl group are a pyridylene group, pyrimidylene group, dibenzofuranylene group, and dibenzothiophenylene group.

Ar¹¹⁷ is preferably a fused aromatic hydrocarbon group selected from a phenanthrenyl group, benzophenanthrenyl group, dibenzophenanthrenyl group, benzochrysenyl group, dibenzochrysenyl group, fluoranthenyl group, benzofluoranthenyl group, triphenylenyl group, benzotriphenylenyl group, dibenzotriphenylenyl group, picenyl group, benzopicenyl group, and dibenzopicenyl group. Among the above, a benzochrysenyl group, triphenylenyl group, or phenanthrenyl group is more preferable. Preferably, the fused aromatic hydrocarbon group is unsubstituted.

In the monoamine derivative of the formula (11), more preferably, Ar¹¹⁴ and Ar¹¹⁵ each are a phenyl group or naphthyl group, Ar¹¹⁶ is a phenyl group or naphthyl group, and Ar¹¹⁷ is a benzochrysenyl group, triphenylenyl group, or phenanthrenyl group.

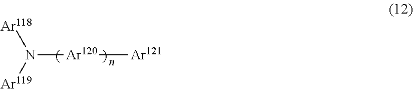

In the formula (12), Ar¹¹⁸, Ar¹¹⁹ and Ar¹²¹ are a substituted or unsubstituted aryl group or heteroaryl group. Examples of the aryl group or heteroaryl group are the same as those defined as the aryl group or heteroaryl group for Ar¹¹¹ and are preferably a phenyl group. Ar¹²⁰ is a substituted or unsubstituted arylene group or heteroarylene group and the same as those defined as the arylene group or heteroarylene group for Ar¹¹⁶. Ar¹²⁰ is preferably a phenylene group or naphthylene group. n is an integer of 2 to 5, preferably 2 to 4, more preferably 2 to 3. When n is 2 or more, Ar¹²⁰ may be mutually the same or different.

Ar¹²¹ is preferably a fused aromatic hydrocarbon group selected from a phenyl group, naphthyl group, phenanthrenyl group, benzophenanthrenyl group, dibenzophenanthrenyl group, benzochrysenyl group, dibenzochrysenyl group, fluoranthenyl group, benzofluoranthenyl group, triphenylenyl group, benzotriphenylenyl group, dibenzotriphenylenyl group, picenyl group, benzopicenyl group, dibenzopicenyl group, phenalenyl group, and diazaphenanthrenyl group. Among the above, a benzochrysenyl group, triphenylenyl group, or phenanthrenyl group is more preferable.

In the exemplary embodiment, for the second host material in the formula (12), Ar¹¹⁸ and Ar¹¹⁹ each are preferably a phenyl group or naphthyl group; Ar¹²⁰ is preferably a phenylene group or naphthylene group; and Ar¹²¹ is preferably a benzochrysenyl group, triphenylenyl group, or phenanthrenyl group.

When Ar¹⁰¹ to Ar¹²¹ have substituent(s), the substituent(s) is preferably an alkyl group having 1 to 20 carbon atoms, haloalkyl group having 1 to 20 carbon atoms, cycloalkyl group having 3 to 18 carbon atoms, aryl group having 6 to 30 ring carbon atoms, silyl group having 3 to 20 carbon atoms, cyano group, and halogen atom.

Some examples of the alkyl group are a methyl group, ethyl group, propyl group, isopropyl group, n-butyl group, 1-methylpropyl group and 1-propylbutyl group. Examples of the aryl group are the same as those for Ar¹⁰¹.

The haloalkyl group is exemplified by a 2,2,2-trifluoroethyl group.

Some examples of the cycloalkyl group are a cyclopropyl group, cyclobutyl group, cyclopentyl group, cyclohexyl group and cyclooctyl group.

Some examples of the silyl group are a trimethylsilyl group and triethylsilyl group.

Some examples of the halogen atom are fluorine, chlorine, bromine, and iodine.

When the monoamine derivatives represented by the formulas (10) to (12) do not have a substituent, it is meant that a hydrogen atom is substituted. The hydrogen atom of the monoamine derivatives represented by the formulas (10) to (12) includes light hydrogen and deuterium. “Carbon atoms forming a ring (ring carbon atoms)” mean carbon atoms forming a saturated ring, unsaturated ring, or aromatic ring. “Atoms forming a ring (ring atoms)” mean carbon atoms and hetero atoms forming a ring including a saturated ring, unsaturated ring, or aromatic ring.

Some specific examples of the monoamine derivatives represented by the formula (10) are shown below.

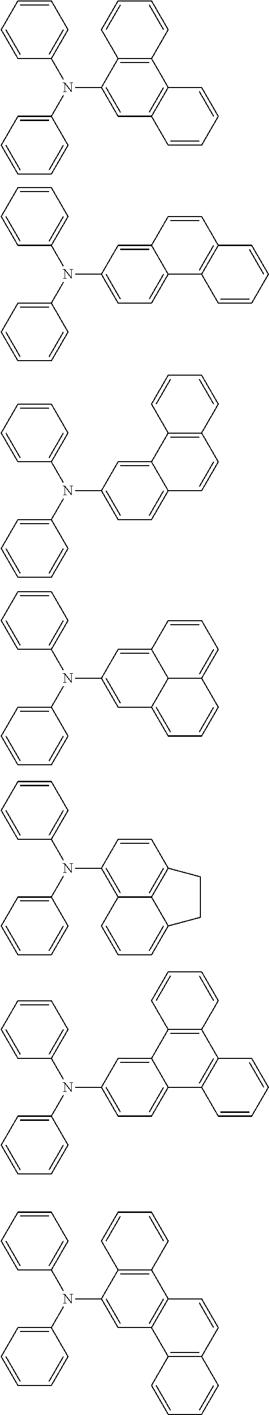

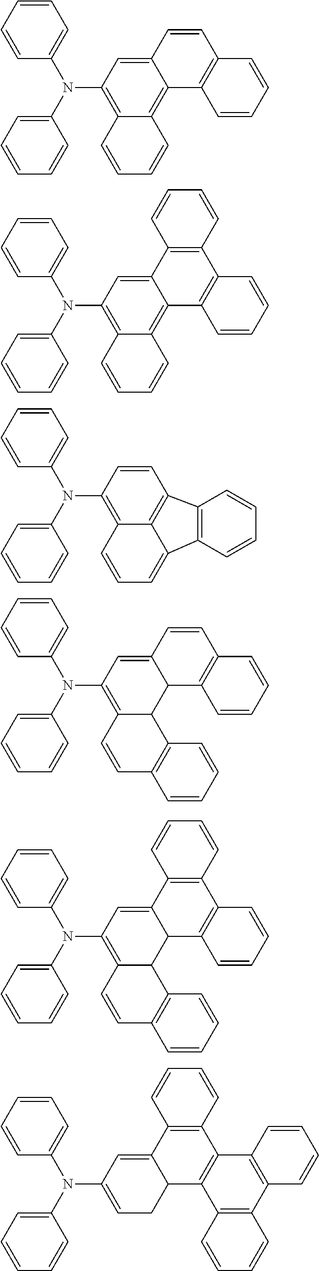

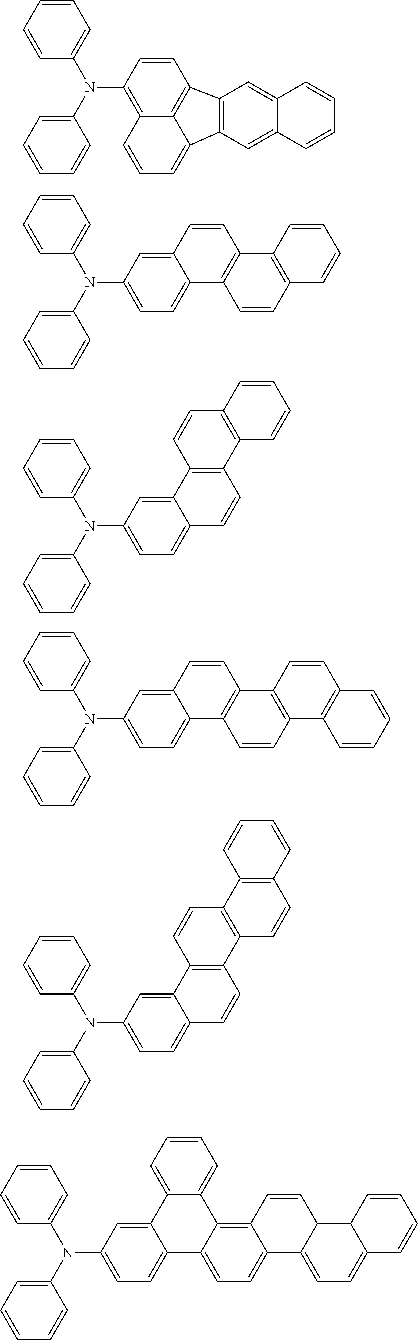

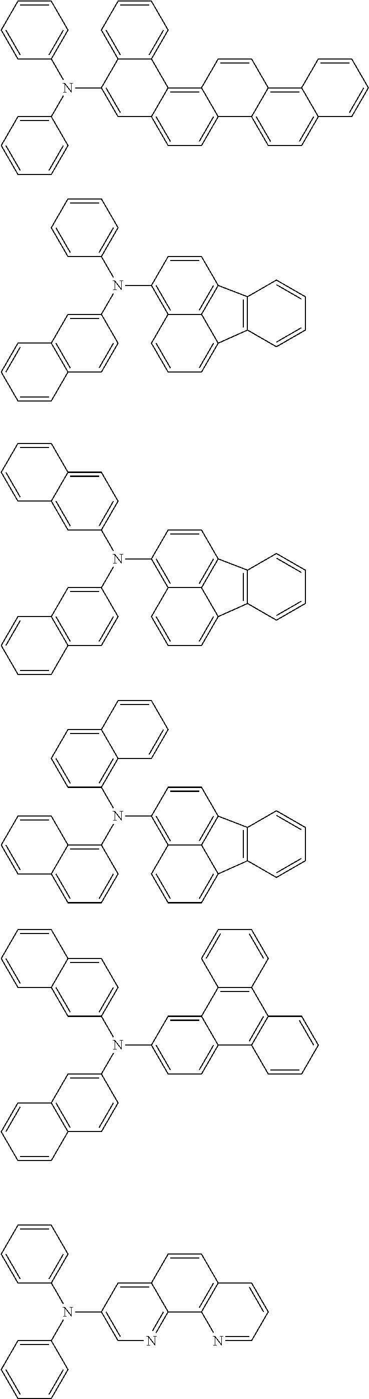

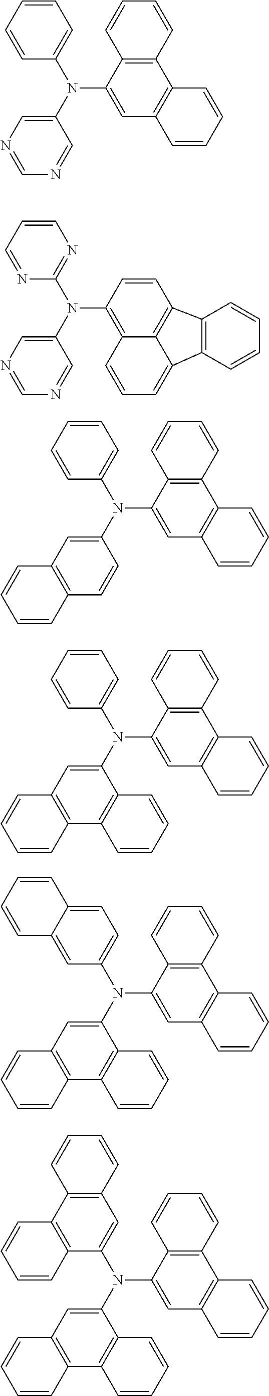

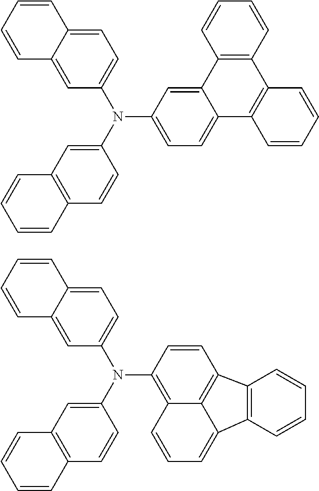

Some specific examples of the monoamine derivatives represented by the formula (11) are shown below.

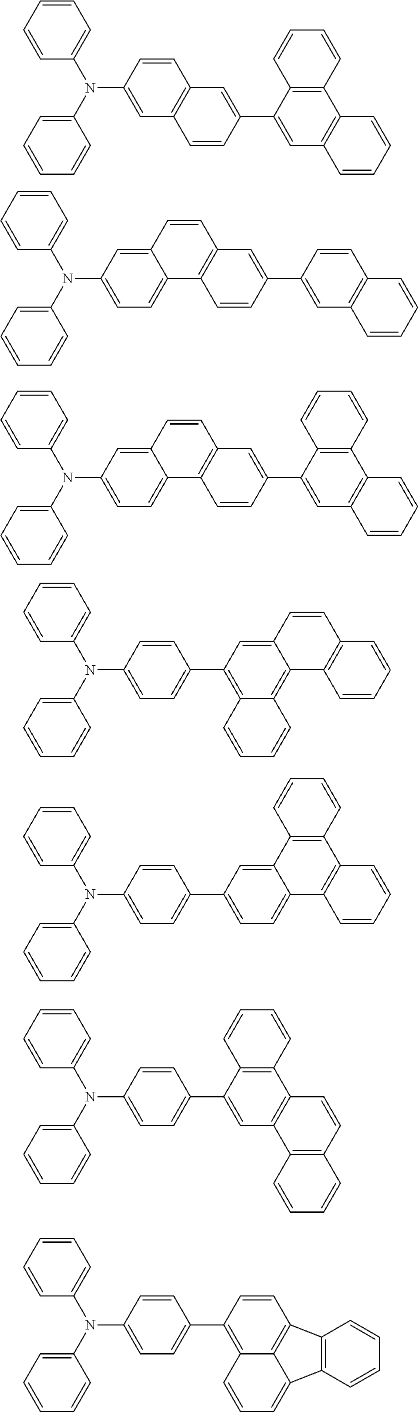

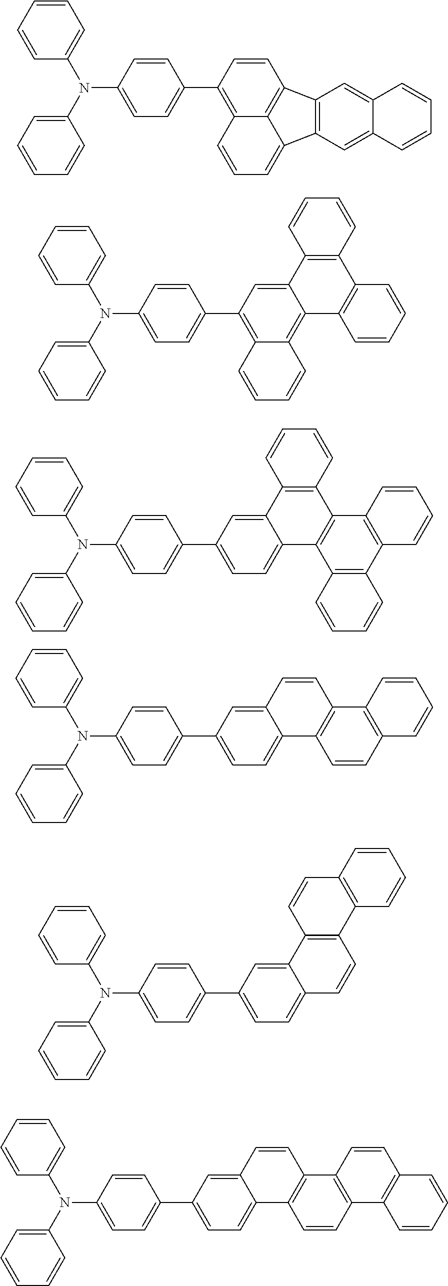

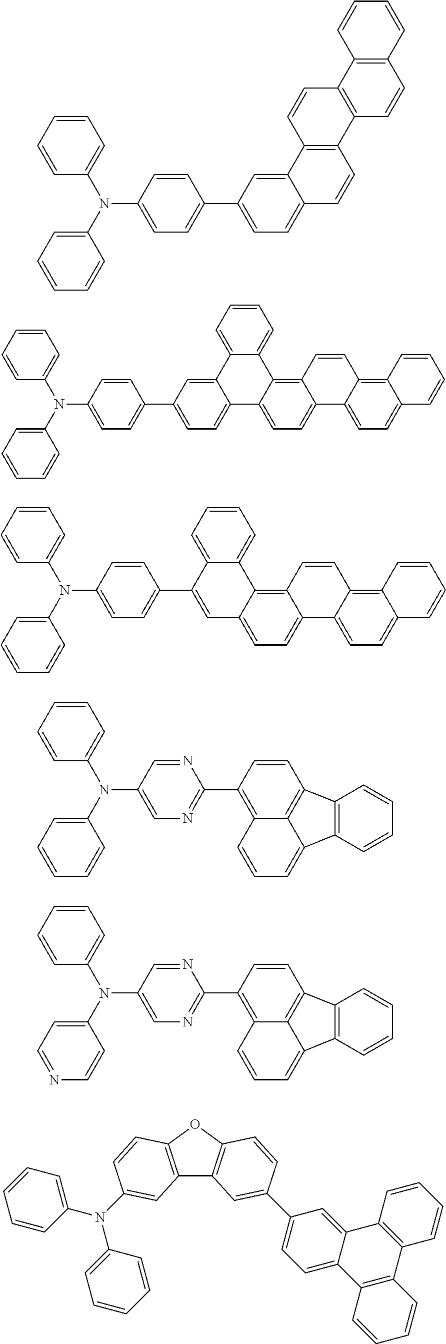

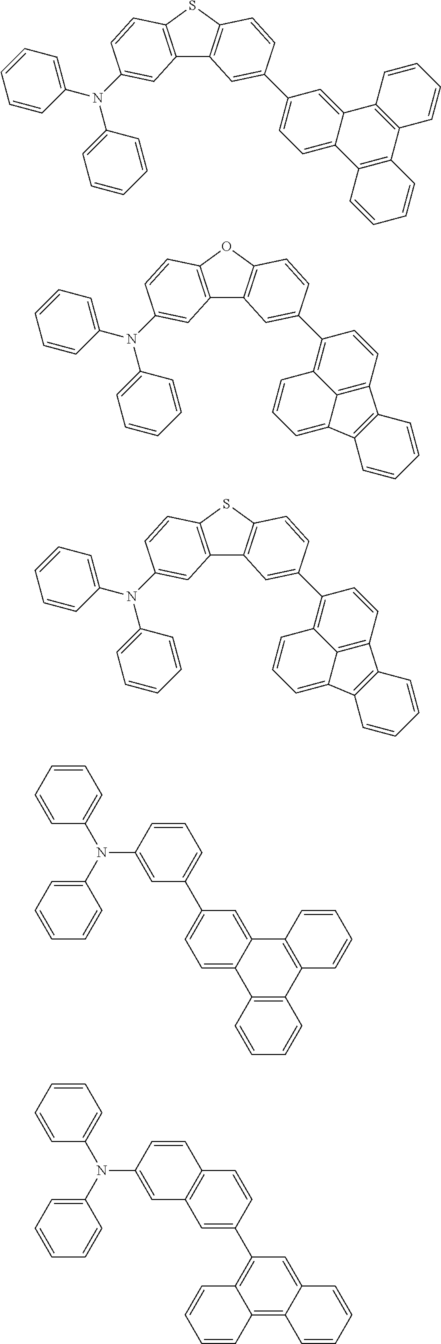 [SMILES: c1ccc(N(c2ccccc2)c2ccc3sc4ccc(-c5ccc6c7ccccc7c7ccccc7c6c5)cc4c3c2)cc1 ; c1ccc(N(c2ccccc2)c2ccc3oc4ccc(-c5ccc6c7c(cccc57)-c5ccccc5-6)cc4c3c2)cc1 ; c1ccc(N(c2ccccc2)c2ccc3sc4ccc(-c5ccc6c7c(cccc57)-c5ccccc5-6)cc4c3c2)cc1 ; c1ccc(N(c2ccccc2)c2cccc(-c3ccc4c5ccccc5c5ccccc5c4c3)c2)cc1 ; c1ccc(N(c2ccccc2)c2ccc3ccc(-c4cc5ccccc5c5ccccc45)cc3c2)cc1]

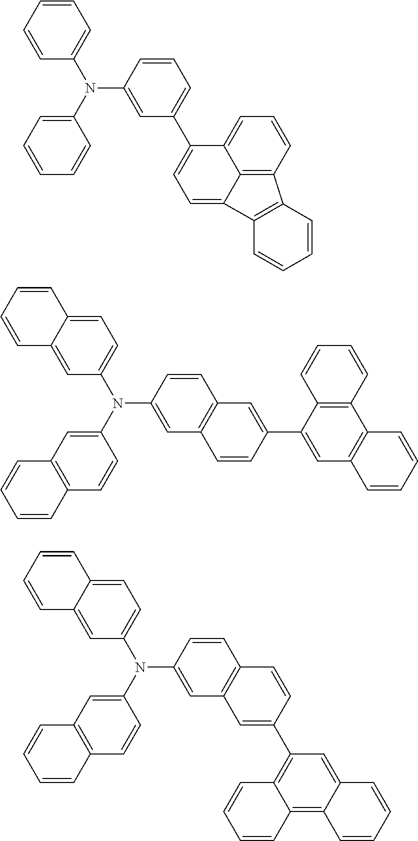

Some specific examples of the monoamine derivatives represented by the formula (12) are shown below.

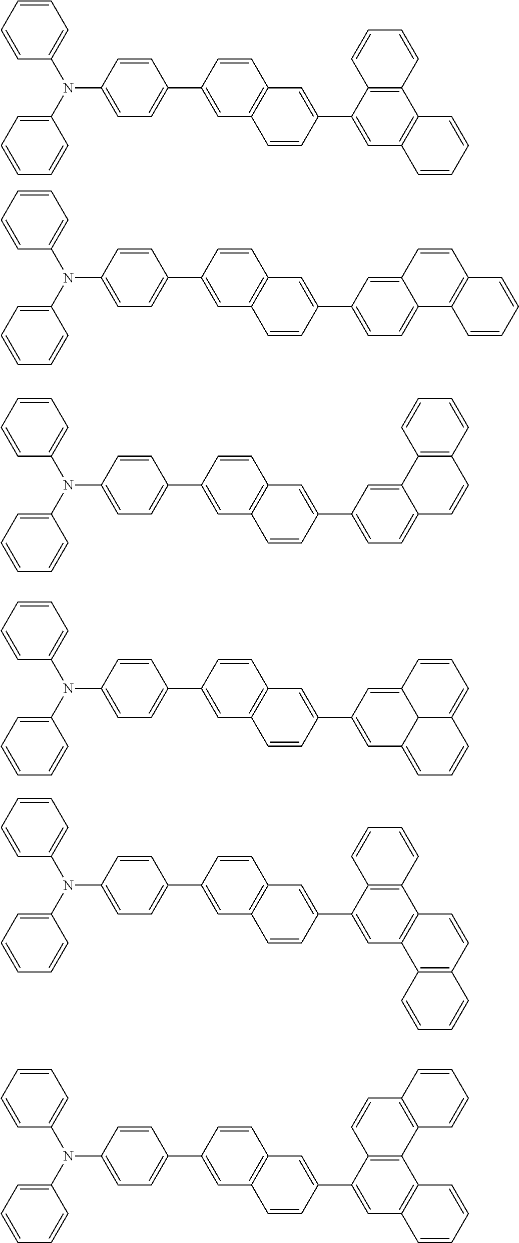

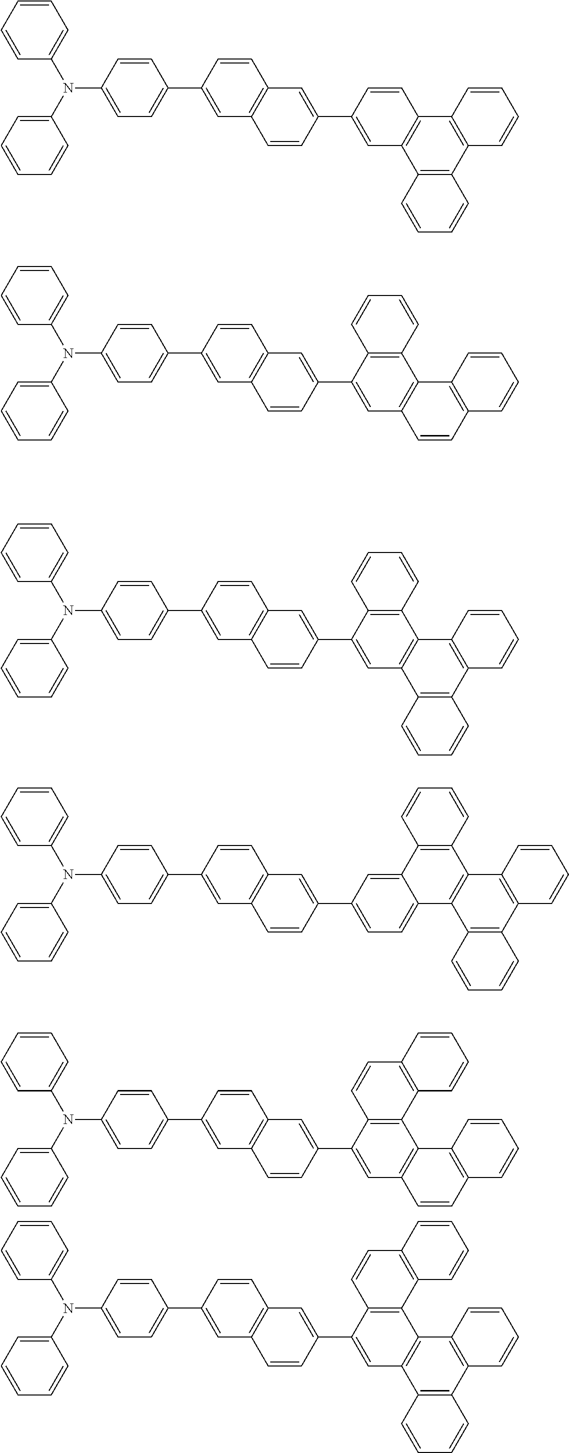

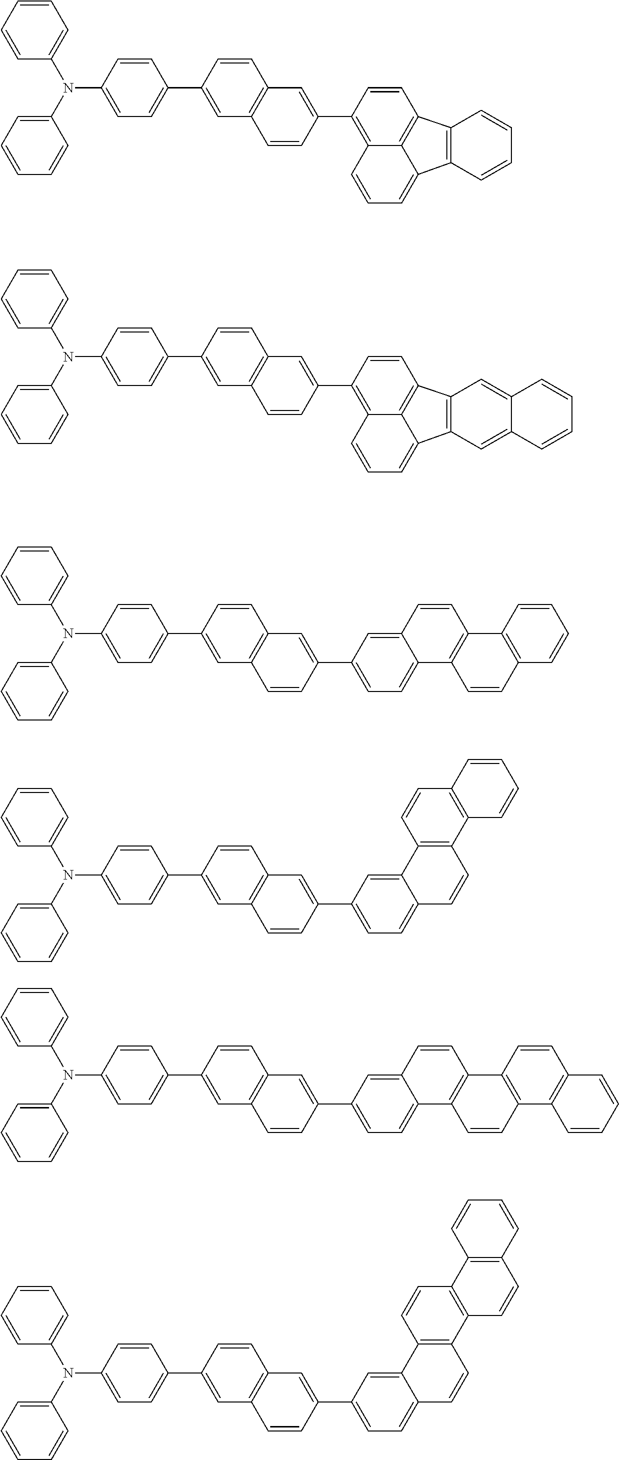

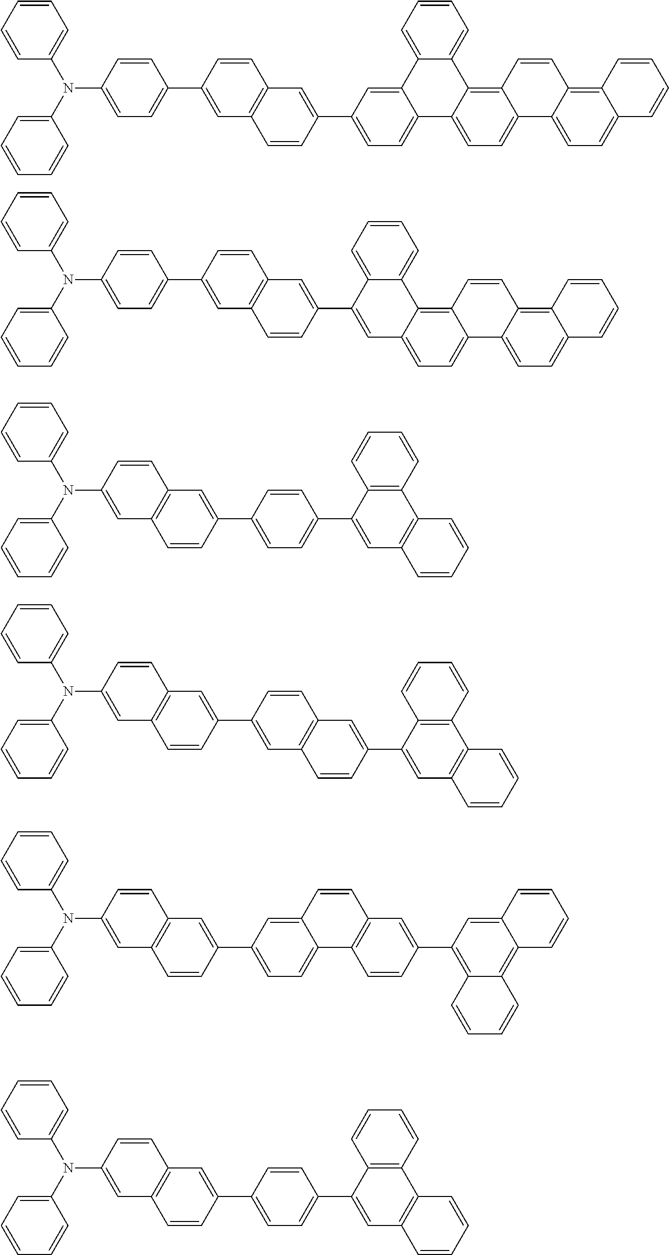

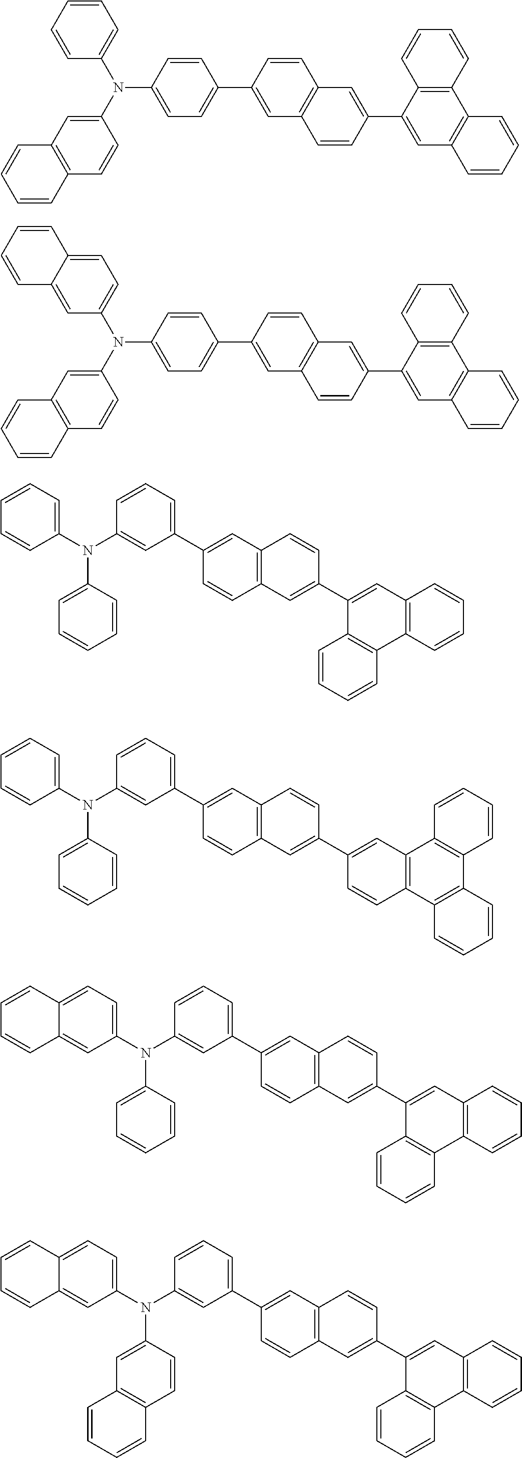

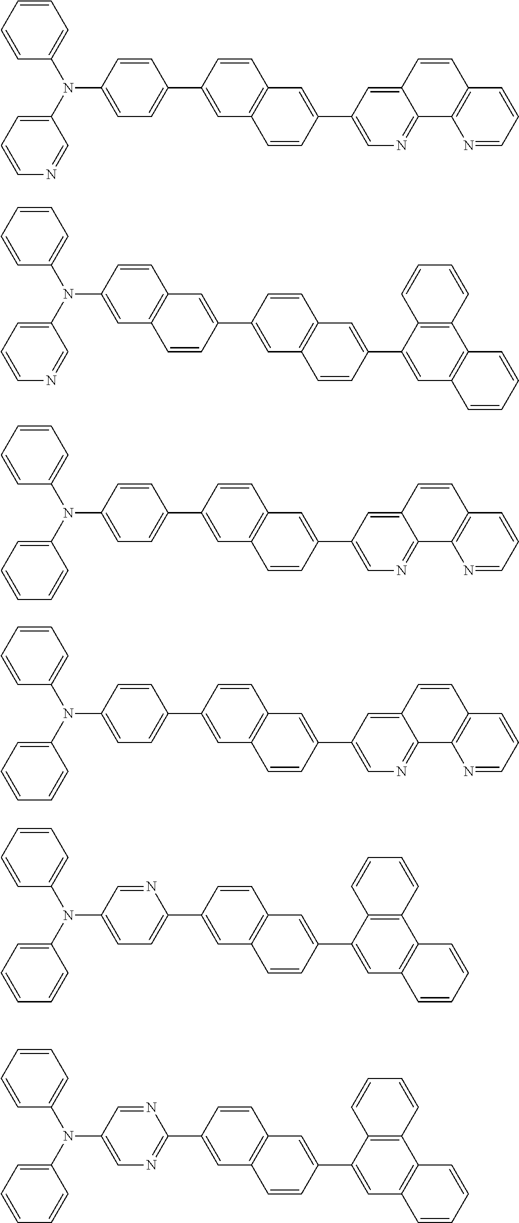

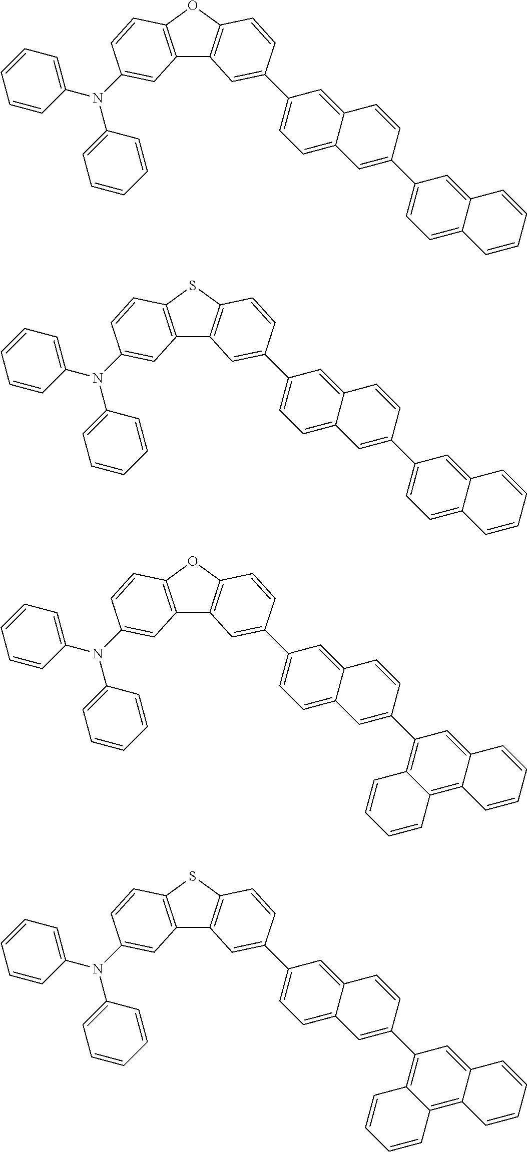 [SMILES: c1ccc(N(c2ccccc2)c2ccc3oc4ccc(-c5ccc6cc(-c7ccc8ccccc8c7)ccc6c5)cc4c3c2)cc1 ; c1ccc(N(c2ccccc2)c2ccc3sc4ccc(-c5ccc6cc(-c7ccc8ccccc8c7)ccc6c5)cc4c3c2)cc1 ; c1ccc(N(c2ccccc2)c2ccc3oc4ccc(-c5ccc6cc(-c7cc8ccccc8c8ccccc78)ccc6c5)cc4c3c2)cc1 ; c1ccc(N(c2ccccc2)c2ccc3sc4ccc(-c5ccc6cc(-c7cc8ccccc8c8ccccc78)ccc6c5)cc4c3c2)cc1]

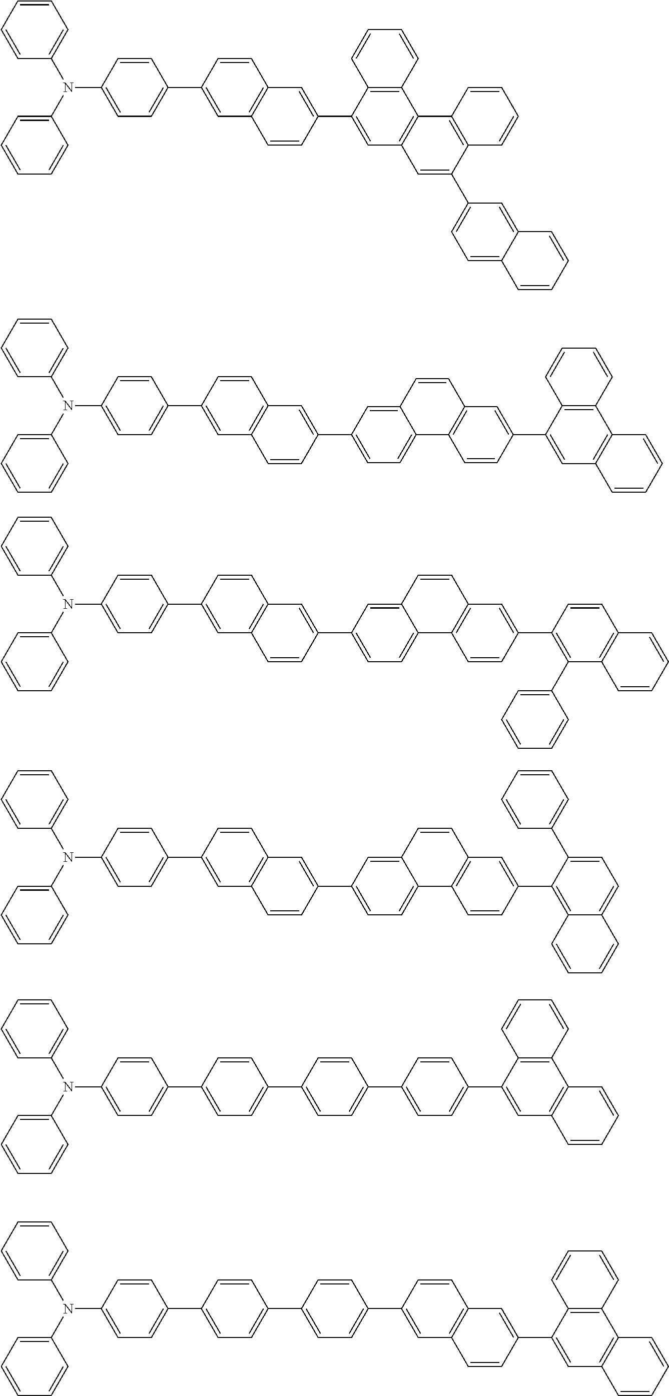

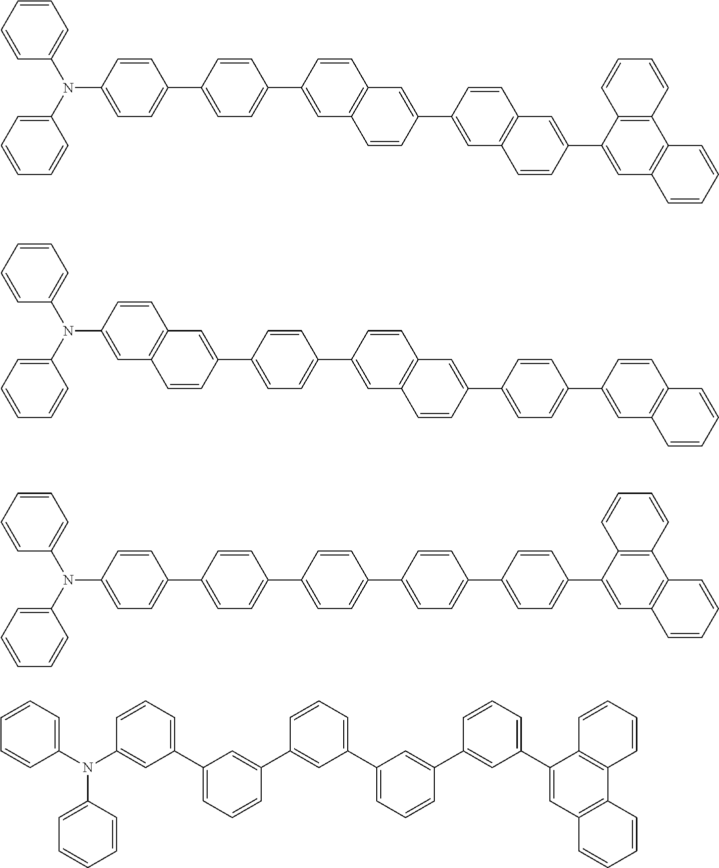

In another embodiment, the second host material is an aromatic amine compound. An example of the aromatic amine compound is preferably a compound represented by the formula (13) or (14).

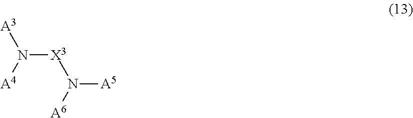

In the formula (13): X³ represents a substituted or unsubstituted arylene group having 10 to 40 ring carbon atoms; and A³ to A⁶ represent a substituted or unsubstituted aryl group having 6 to 60 ring carbon atoms, or heteroaryl group having 6 to 60 ring atoms.

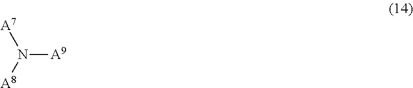

In the formula (14), A⁷ to A⁹ represent a substituted or unsubstituted aryl group having 6 to 60 ring carbon atoms, or heteroaryl group having 6 to 60 ring atoms.

The second host material represented by the formula (13) or (14) is preferably represented by formulae (15) to (19).

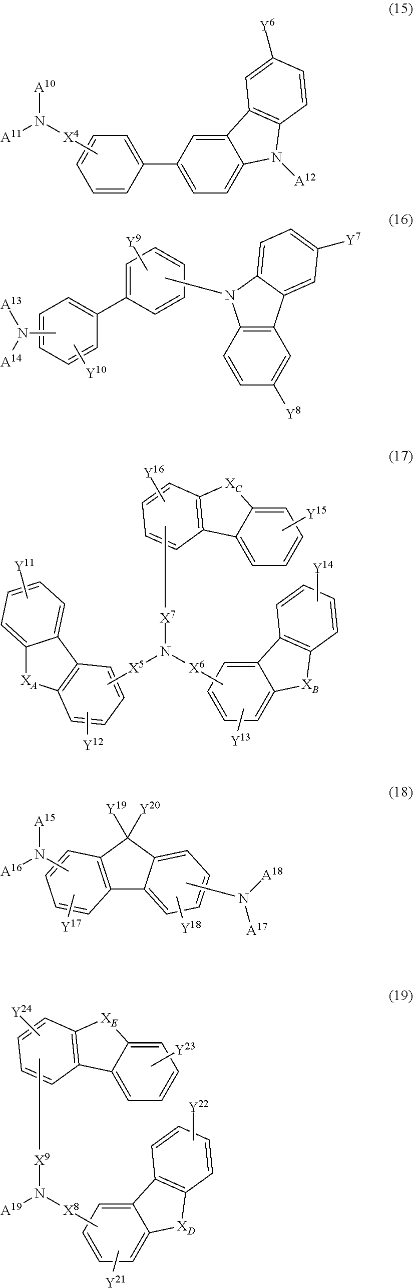

In the formulae (15) to (19): A¹⁰ to A¹⁹ each represent a substituted or unsubstituted aryl group having 6 to 40 carbon atoms, substituted or unsubstituted aromatic heterocyclic group having 2 to 40 carbon atoms, substituted or unsubstituted aryl group having 8 to 40 carbon atoms bonded with an aromatic amino group, or substituted or unsubstituted aryl group having 8 to 40 carbon atoms bonded with an aromatic heterocyclic group;

A¹⁰, A¹³, A¹⁵ and A¹⁷ are adapted to be respectively bonded to A¹¹, A¹⁴, A¹⁶ and A¹⁸ to form a ring;

X⁴ to X⁹ represent a single bond or a linking group having 1 to 30 carbon atoms;

Y⁶ to Y²⁴ represent a hydrogen atom, halogen atom, substituted or unsubstituted alkyl group having 1 to 40 carbon atoms, substituted or unsubstituted heterocyclic group having 3 to 20 carbon atoms, substituted or unsubstituted aryl group having 6 to 40 carbon atoms, substituted or unsubstituted aralkyl group having 7 to 20 carbon atoms, substituted or unsubstituted alkenyl group having 2 to 40 carbon atoms, substituted or unsubstituted alkylamino group having 1 to 40 carbon atoms, substituted or unsubstituted aralkylamino group having 7 to 60 carbon atoms, substituted or unsubstituted alkylsilyl group having 3 to 20 carbon atoms, substituted or unsubstituted arylsilyl group having 8 to 40 carbon atoms, substituted or unsubstituted aralkylsilyl group having 8 to 40 carbon atoms, or substituted or unsubstituted halogenated alkyl group having 1 to 40 carbon atoms; and

X_{A}, X_{B}, X_{C}, X_{D}, X_{E} each represent a sulfur atom, an oxygen atom or a monoaryl-substituted nitrogen atom.

Some examples of compounds represented by the formulas (13), (14), and (15) to (19) are as follows.

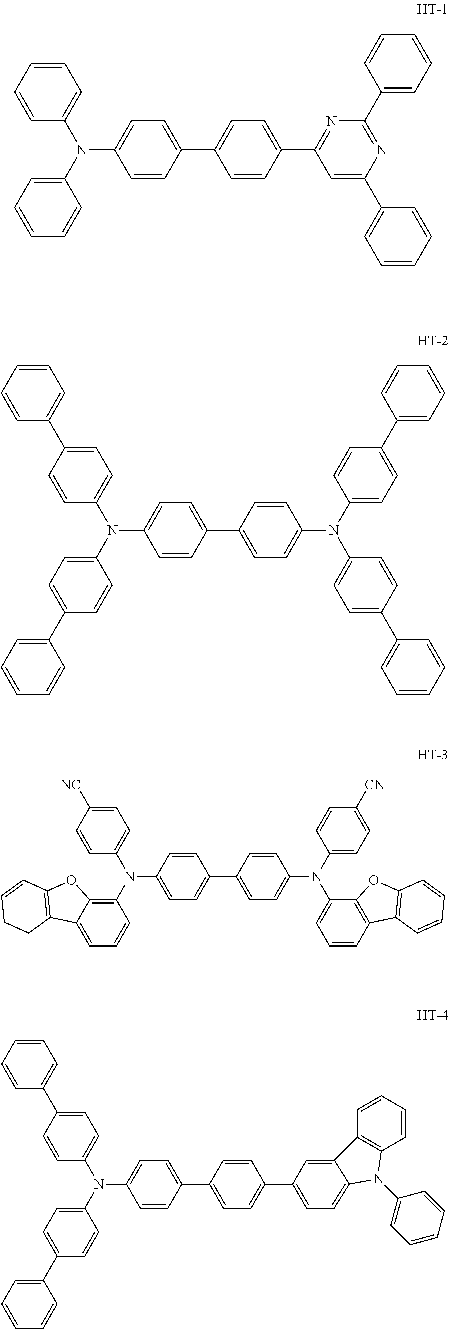 [SMILES: c1ccc(-c2cc(-c3ccc(-c4ccc(N(c5ccccc5)c5ccccc5)cc4)cc3)nc(-c3ccccc3)n2)cc1 ; c1ccc(-c2ccc(N(c3ccc(-c4ccccc4)cc3)c3ccc(-c4ccc(N(c5ccc(-c6ccccc6)cc5)c5ccc(-c6ccccc6)cc5)cc4)cc3)cc2)cc1 ; N#Cc1ccc(N(c2ccc(-c3ccc(N(c4ccc(C#N)cc4)c4cccc5c4oc4ccccc45)cc3)cc2)c2cccc3c4c(oc23)C=CCC4)cc1 ; c1ccc(-c2ccc(N(c3ccc(-c4ccccc4)cc3)c3ccc(-c4ccc(-c5ccc6c(c5)c5ccccc5n6-c5ccccc5)cc4)cc3)cc2)cc1]

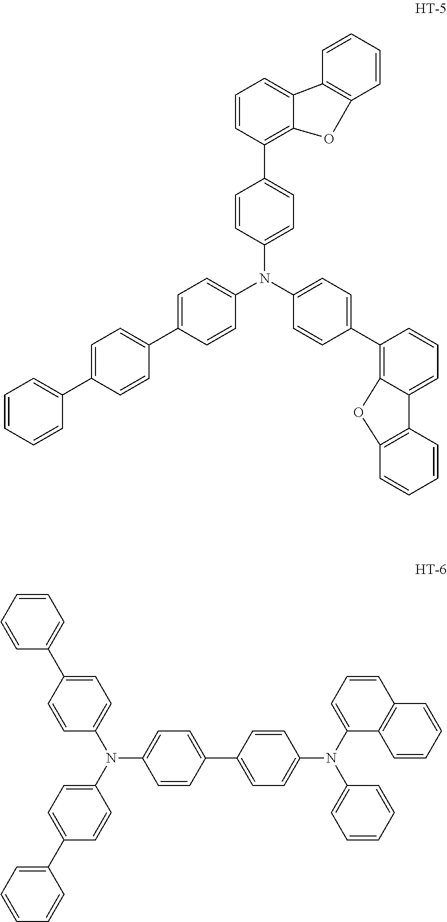 [SMILES: c1ccc(-c2ccc(-c3ccc(N(c4ccc(-c5cccc6c5oc5ccccc56)cc4)c4ccc(-c5cccc6c5oc5ccccc56)cc4)cc3)cc2)cc1 ; c1ccc(-c2ccc(N(c3ccc(-c4ccccc4)cc3)c3ccc(-c4ccc(N(c5ccccc5)c5cccc6ccccc56)cc4)cc3)cc2)cc1]

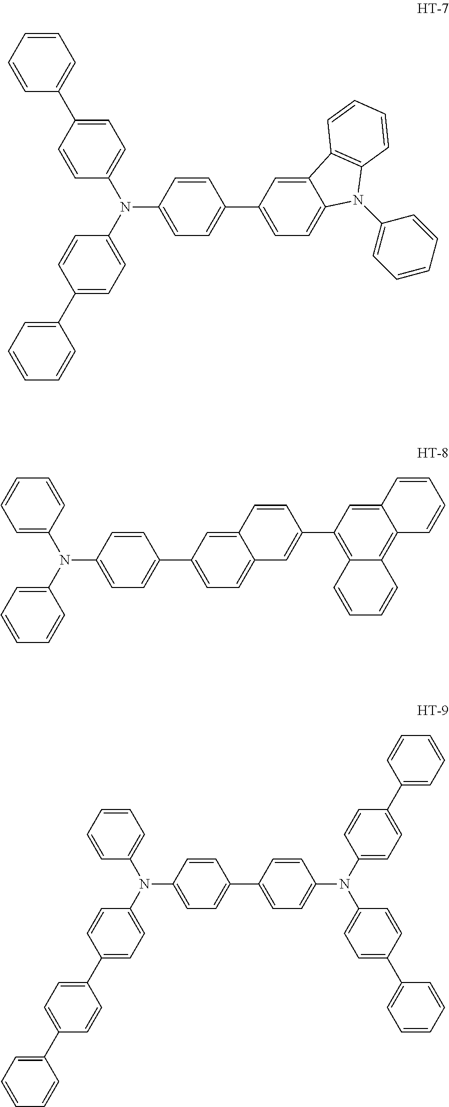 [SMILES: c1ccc(-c2ccc(N(c3ccc(-c4ccccc4)cc3)c3ccc(-c4ccc5c(c4)c4ccccc4n5-c4ccccc4)cc3)cc2)cc1 ; c1ccc(N(c2ccccc2)c2ccc(-c3ccc4cc(-c5cc6ccccc6c6ccccc56)ccc4c3)cc2)cc1 ; c1ccc(-c2ccc(-c3ccc(N(c4ccccc4)c4ccc(-c5ccc(N(c6ccc(-c7ccccc7)cc6)c6ccc(-c7ccccc7)cc6)cc5)cc4)cc3)cc2)cc1]

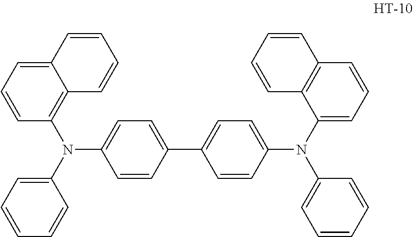 [SMILES: c1ccc(N(c2ccc(-c3ccc(N(c4ccccc4)c4cccc5ccccc45)cc3)cc2)c2cccc3ccccc23)cc1]

According to another embodiment, the second host material is a metal complex. The metal complex is preferably represented by a formula (20) below.

L¹¹L¹²L¹³M¹¹₂Q¹¹ (20)

In the formula: ligands L¹¹, L¹² and L¹³ are independently selected from a structure represented by a formula (21) below; M¹¹ is a divalent metal; and Q¹¹ is a monovalent anion induced from inorganic or organic acids.

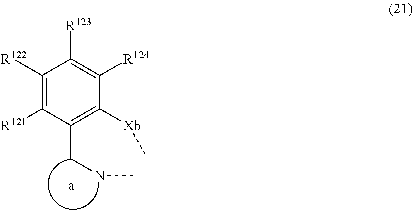

In the ligands: Xb is O, S or Se; a-ring is oxazole, thiazole, imidazoles, oxadiazole, thiadiazole, benzooxazole, benzothiazole, benzoimidazole, pyridine, or quinoline; R¹²¹ to R¹²⁴ are independently hydrogen, an alkyl group having 1 to 5 carbon atoms, halogen, silyl group or aryl group having 6 to 20 carbon atoms, which may be bonded to an adjacent substituent via alkylene or alkenylene to form a fused ring. The pyridine and quinoline may be bonded to R¹²¹ or R¹²² to form a fused ring.

The a-ring and the aryl group for R¹²¹ to R¹²⁴ may be further substituted by a C1-C5 alkyl group, halogen, C1-C5 alkyl group having a halogen substituent, phenyl group, naphthyl group, silyl group, or amino group.

The ligands L¹¹, L¹² and L¹³ are independently selected from the following structures.

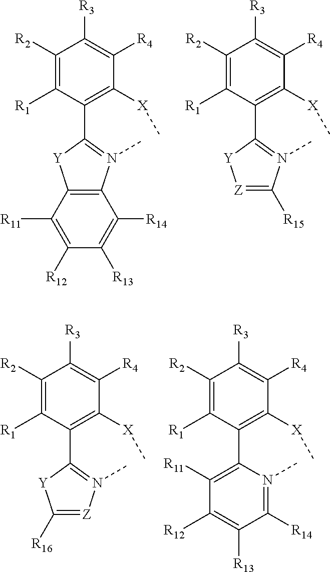

In the ligands: X and R₁ to R₄ represent the same as Xb and R¹²¹ to R¹²⁴ in the formula (21); Y is O, S or NR₂₁; Z is CH or N; R₁₁ to R₁₆ are independently hydrogen, a C1-C5 alkyl group, halogen, C1-C5 alkyl group having a halogen substituent, phenyl group, naphthyl group, silyl group, or amino group; and R₁₁ to R₁₄ may be bonded to an adjacent substituent via alkylene or alkenylene to form a fused ring.

The ligands L¹¹, L¹² and L¹³ of the compound may be the same and can be selected from the following structures.

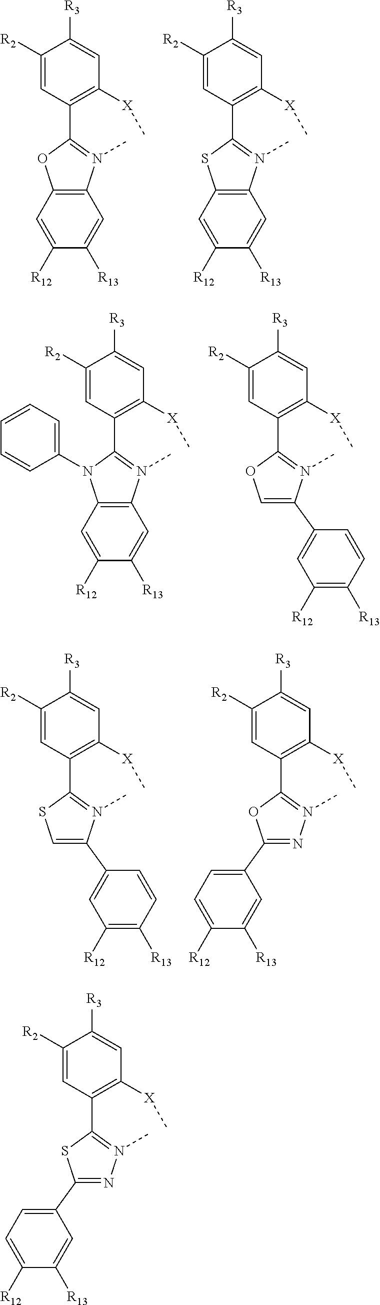

In the ligands: X is O, S or Se; R₂, R₃, R₁₂ and R₁₃ are independently hydrogen, methyl, ethyl, n-propyl, isopropyl, fluorine, chlorine, trifluoromethyl, phenyl, naphthyl, fluorenyl, trimethylsilyl, triphenylsilyl, t-butyldimethylsilyl, dimethylamine, diethylamine, or diphenylamine. The phenyl, naphthyl, fluorenyl are further substituted by fluorine, chlorine, trimethylsilyl, triphenylsilyl, t-butyldimethylsilyl, dimethylamine, diethylamine, or diphenylamine. Furthermore, in this exemplary embodiment, the metal complex is preferably a zinc complex. Some examples of such a preferable zinc complex are shown below.

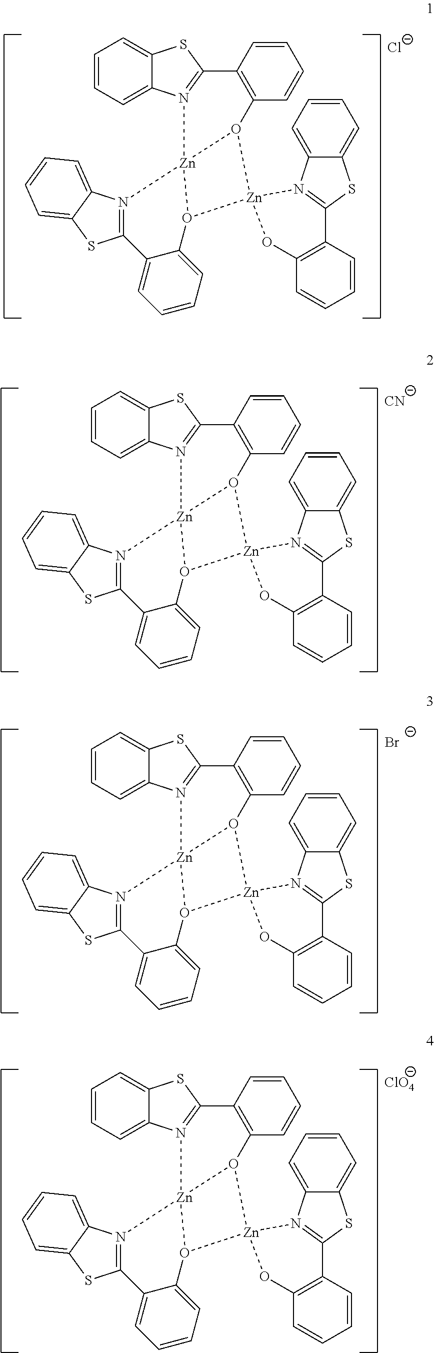

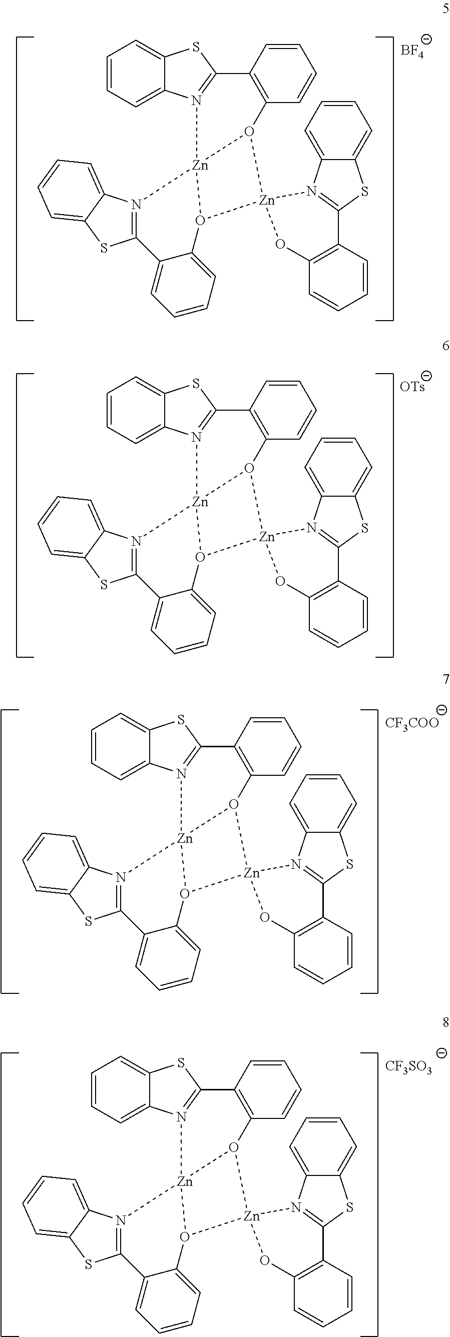

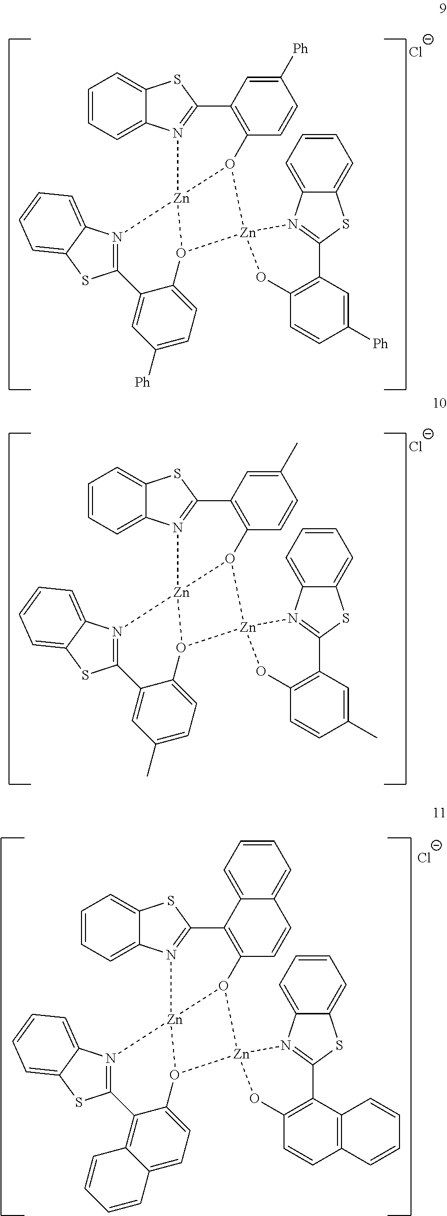

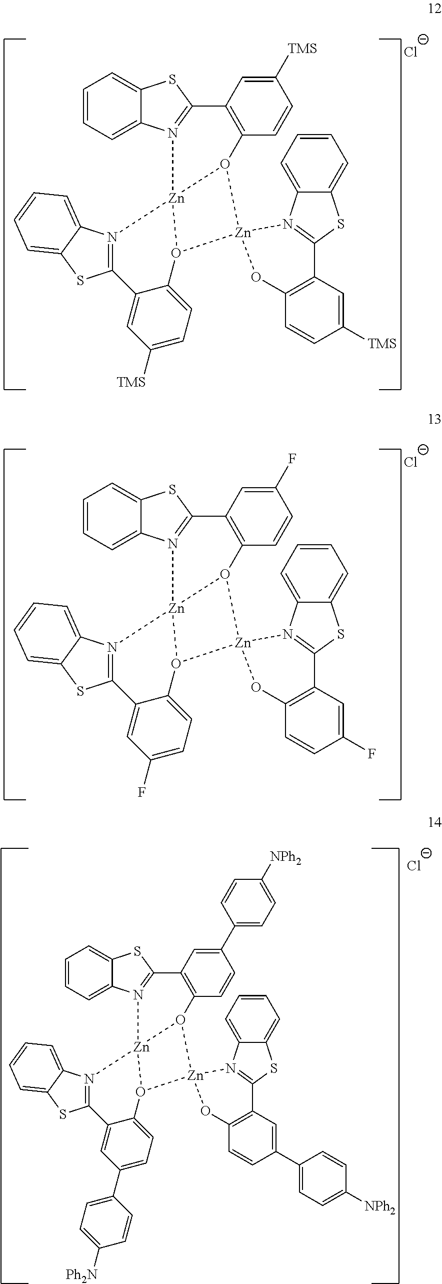

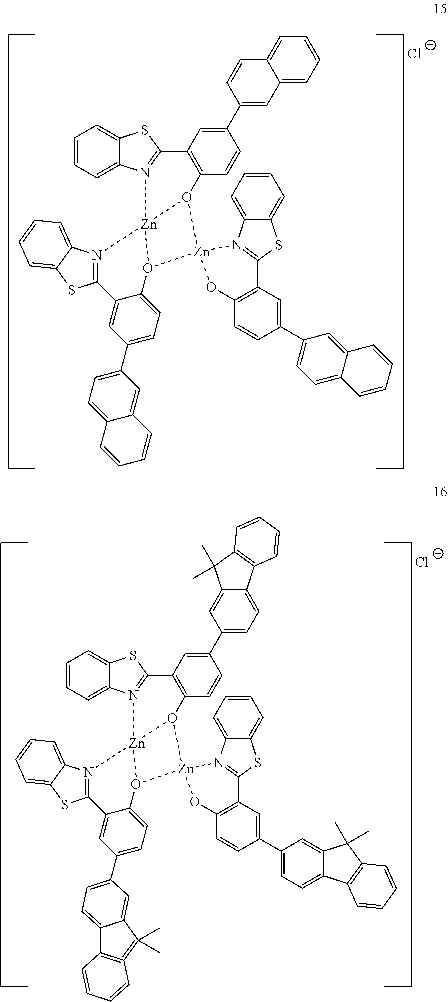

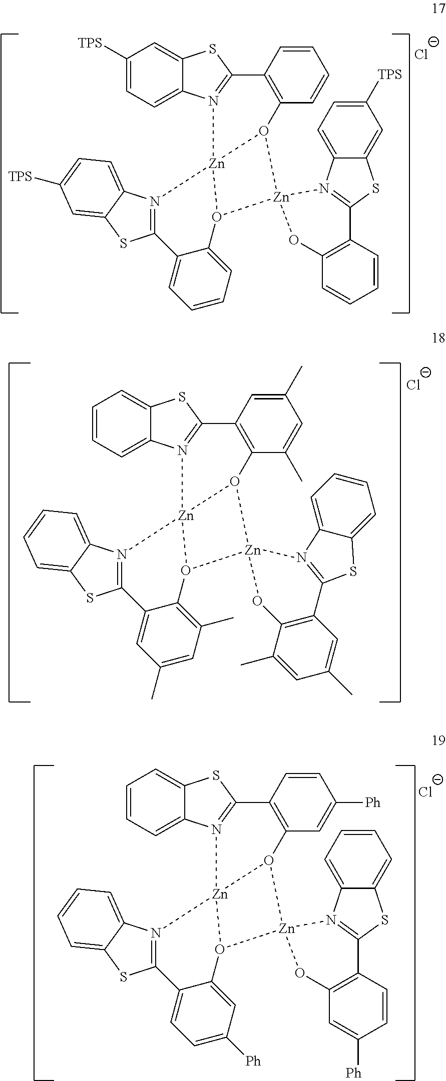

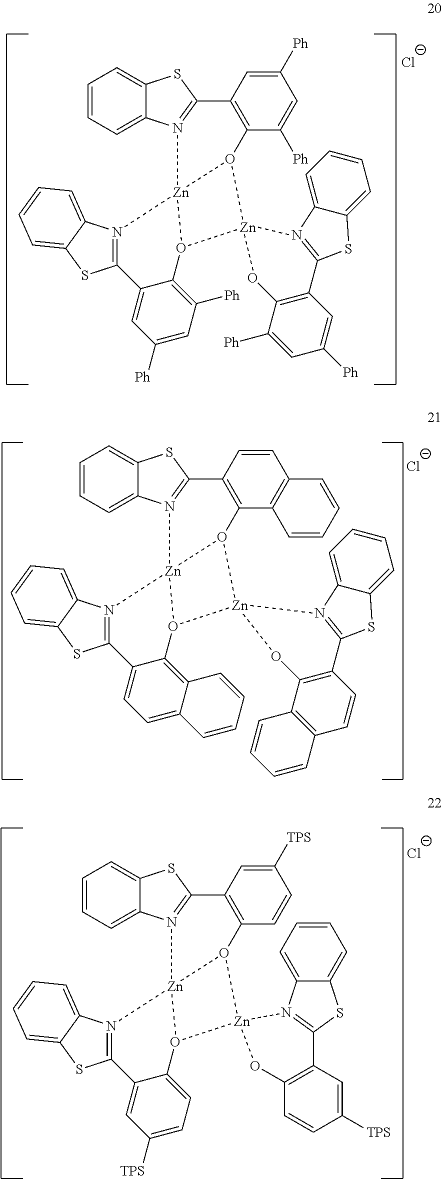

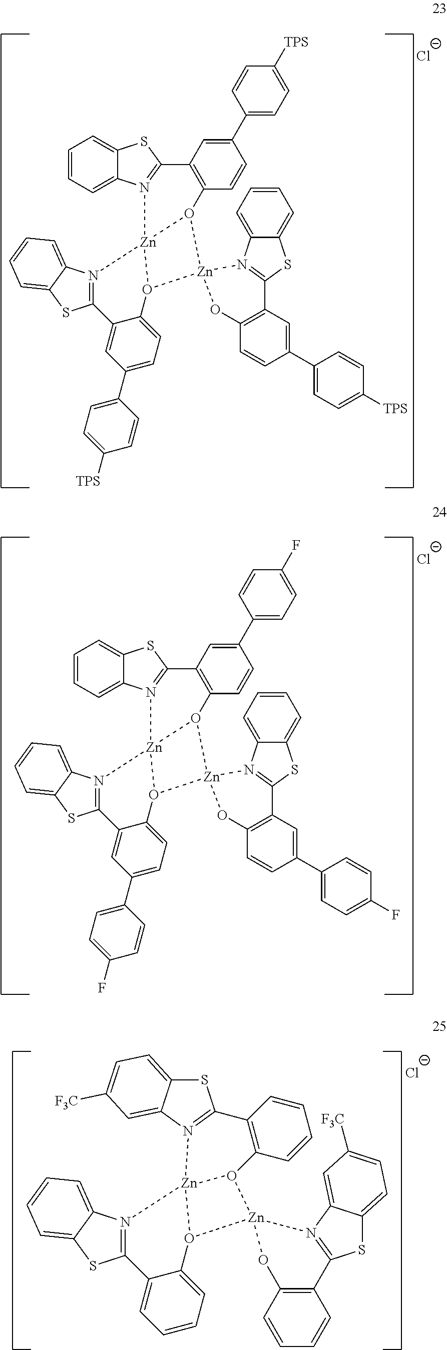

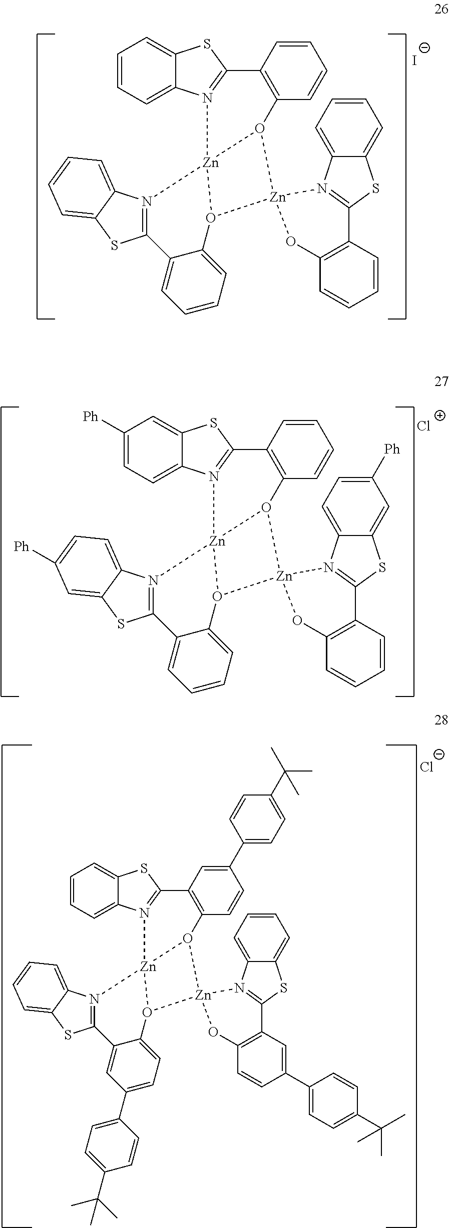

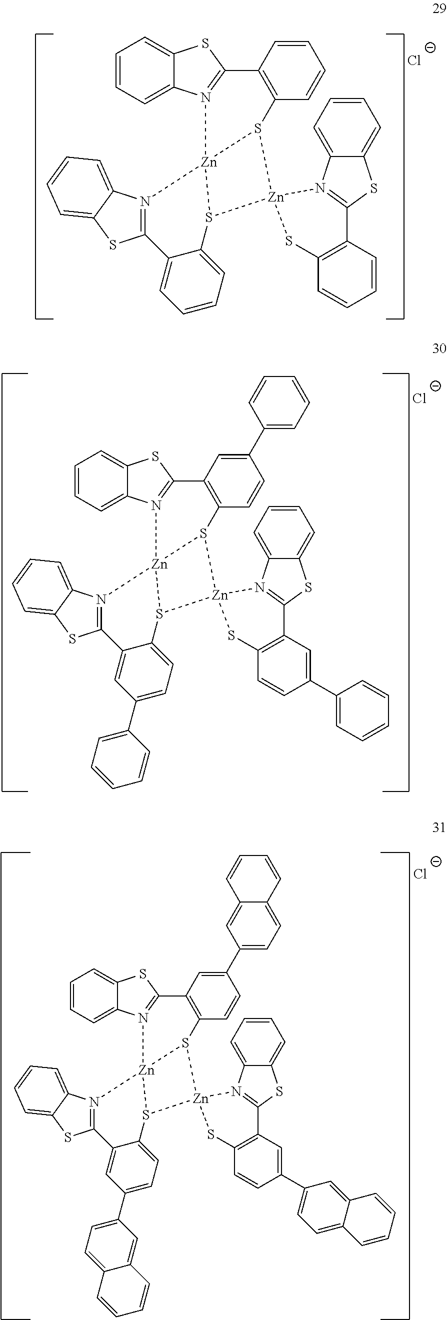

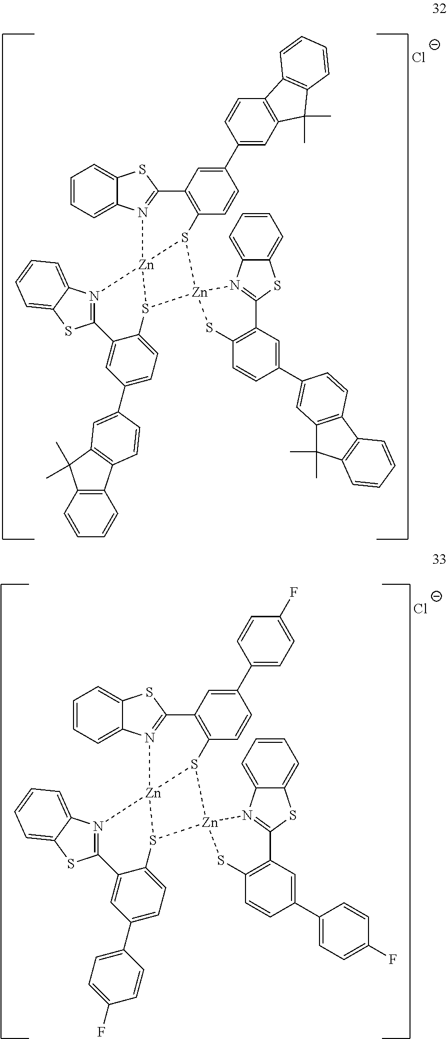

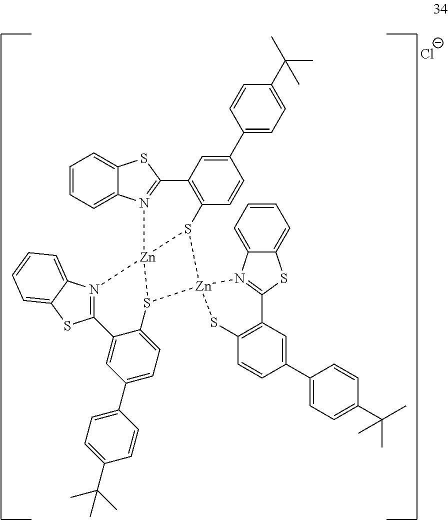

In another embodiment, the second host material may be compounds represented by formulas (22) to (24) below.

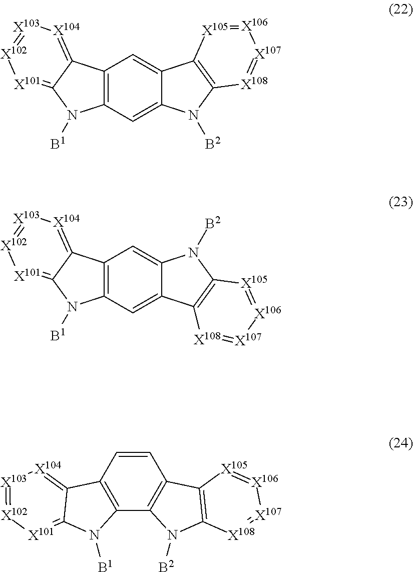

In the formulae (22) to (24): X¹⁰¹ to X¹⁰⁸ are a nitrogen atom or C—Ar¹³¹. Ar¹³¹ represent a hydrogen atom, a fluorine atom, a cyano group, a substituted or unsubstituted alkyl group having 1 to 20 carbon atoms, substituted or unsubstituted alkoxy group having 1 to 20 carbon atoms, substituted or unsubstituted haloalkyl group having 1 to 20 carbon atoms, substituted or unsubstituted haloalkoxy group having 1 to 20 carbon atoms, substituted or unsubstituted alkylsilyl having 1 to 10 carbon atoms, substituted or unsubstituted arylsilyl having 6 to 30 carbon atoms, substituted or unsubstituted aromatic hydrocarbon group having 6 to 30 ring carbon atoms, substituted or unsubstituted fused aromatic hydrocarbon group having 6 to 30 ring carbon atoms, substituted or unsubstituted aromatic heterocyclic group having 2 to 30 ring carbon atoms, or substituted or unsubstituted fused aromatic heterocyclic group having 2 to 30 ring carbon atoms.

Adjacent ones of X¹⁰¹ to X¹⁰⁸ may be bonded to each other to form a ring structure.

B¹ and B² represent a group represented by a formula (25A) or (25B) below.

(M¹)_{c}-(L⁵)_{d}-(M²)ₑ (25A)

In the formula (25A): M¹ and M² each independently represent a substituted or unsubstituted nitrogen-containing aromatic heterocyclic ring or nitrogen-containing fused aromatic heterocyclic ring having 2 to 40 ring carbon atoms; M¹ and M² may be the same or different; L⁵ represents a single bond, substituted or unsubstituted aromatic hydrocarbon group having 6 to 30 carbon atoms, substituted or unsubstituted fused aromatic hydrocarbon group having 6 to 30 carbon atoms, substituted or unsubstituted cycloalkylene group having 5 to 30 carbon atoms, substituted or unsubstituted aromatic heterocyclic group having 2 to 30 carbon atoms, or substituted or unsubstituted fused aromatic heterocyclic group having 2 to 30 carbon atoms;

c represents an integer of 0 to 2; d represents an integer of 1 to 2; e represents an integer of 0 to 2; and c+e represents 1 or more.

(M³)_{c}-(L⁶)_{d}-(M⁴)ₑ (25B)

In the formula (25B): M³ and M⁴ each independently represent a substituted or unsubstituted aromatic hydrocarbon group having 2 to 40 ring carbon atoms; M³ and M⁴ may be the same or different; L⁶ represents a single bond, substituted or unsubstituted aromatic hydrocarbon group having 6 to 30 carbon atoms, substituted or unsubstituted fused aromatic hydrocarbon group having 6 to 30 carbon atoms, or substituted or unsubstituted cycloalkylene group having 5 to 30 carbon atoms;

c represents an integer of 0 to 2; d represents an integer of 1 to 2; e represents an integer of 0 to 2; and c+e represents 1 or more.

The formulae (25A) and (7A) are respectively the same as the formulas (25B) and (7B). M¹ to M⁴ and L⁵ to L⁶ are the same as those described in relation to the formulae (7A) and (7B).

Some specific examples of compounds represented by the formulas (22) to (24) are shown below.

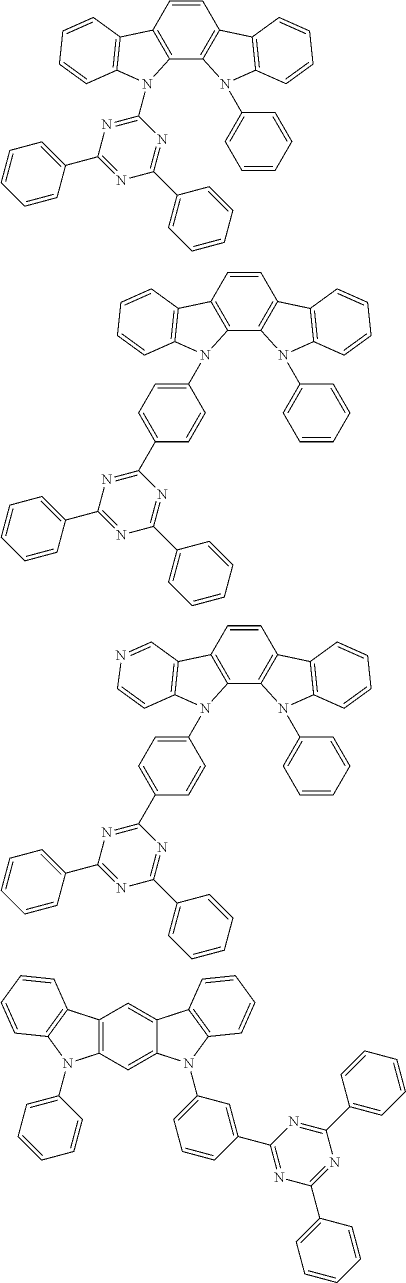

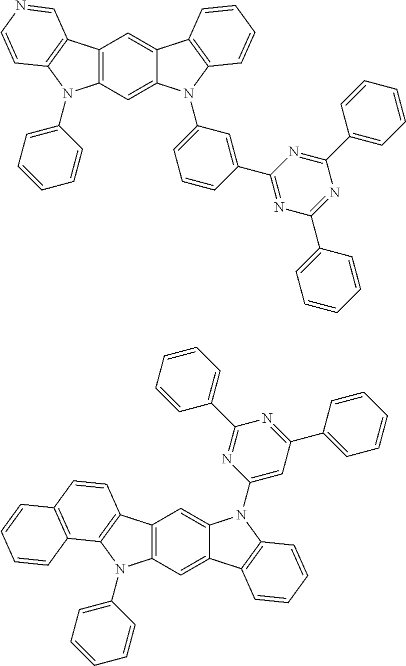 [SMILES: c1ccc(-c2nc(-c3ccccc3)nc(-c3cccc(-n4c5ccccc5c5cc6c7cnccc7n(-c7ccccc7)c6cc54)c3)n2)cc1 ; c1ccc(-c2cc(-n3c4ccccc4c4cc5c(cc43)c3ccc4ccccc4c3n5-c3ccccc3)nc(-c3ccccc3)n2)cc1]

In another embodiment, the second host material can be a compound represented by the formula (1) and having a different structure from that of the first host material.

It should be noted that the invention is not limited to the above description but may include any modification as long as such modification stays within a scope and a spirit of the invention.

### [Synthesis of the Exemplary Compound H1 for First Host Material]:

For synthesis of Compound H1, an intermediate body H1-1 was firstly synthesized by applying a method described in a document (J. Bergman, A. Brynolf, B. Elman and E. Vuorinen, Tetrahedron, 42, 3697-3706 (1986)). Specifically, to a three-necked flask (500 ml), 1M tetrahydrofuran solution of phenylmagnesium bromide (100 ml, 100 mmol) was added. Dry ether (100 ml) was further added and heated to reflux in an oil bath at 45 degrees C. A dry ether solution (50 ml) of 2-cyanoaniline (5.91 g, 50 mmol) was dropped in for 30 minutes. After being refluxed for another 1.5 hours, the reaction solution was cooled down to 0 degree C. in an ice water bath. Subsequently, a dry ether solution (100 ml) of 4-bromobenzoate chloride (13.2 g, 60 mmol) was dropped in the reaction solution for 10 minutes and heated to reflux for 2 hours in a 45-degree-C oil bath. After reaction, the reaction solution was cooled down to 0 degree C. in an ice water bath. A saturated ammonium chloride aqueous solution was added. A precipitated solid was separated by filtration. Then, the obtained was washed with a small amount of methanol and vacuum-dried to obtain an intermediate body H1-1 (10.8 g, a yield of 60%).

Subsequently, under a nitrogen atmosphere, the intermediate body (H1-1) (1.4 g, 3.9 mmol), the intermediate body 1-4 (1.6 g, 3.9 mmol), tris(dibenzylideneacetone)dipalladium (0.071 g, 0.078 mmol), tri-t-butylphosphonium tetrafluoroborate (0.091 g, 0.31 mmol), sodium t-butoxide (0.53 g, 5.5 mmol), and anhydrous toluene (20 mL) were sequentially mixed, and heated to reflux for 8 hours. After the reaction solution was cooled down to the room temperature, an organic layer was removed and an organic solvent was distilled away under reduced pressure. The obtained residue was refined by silica-gel column chromatography, whereby a compound H1 (2.0 g, a yield of 75%) was obtained. FD-MS analysis consequently showed that m/e was equal to 688 while a calculated molecular weight was 688.

A synthesis scheme of the compound H1 is shown below.

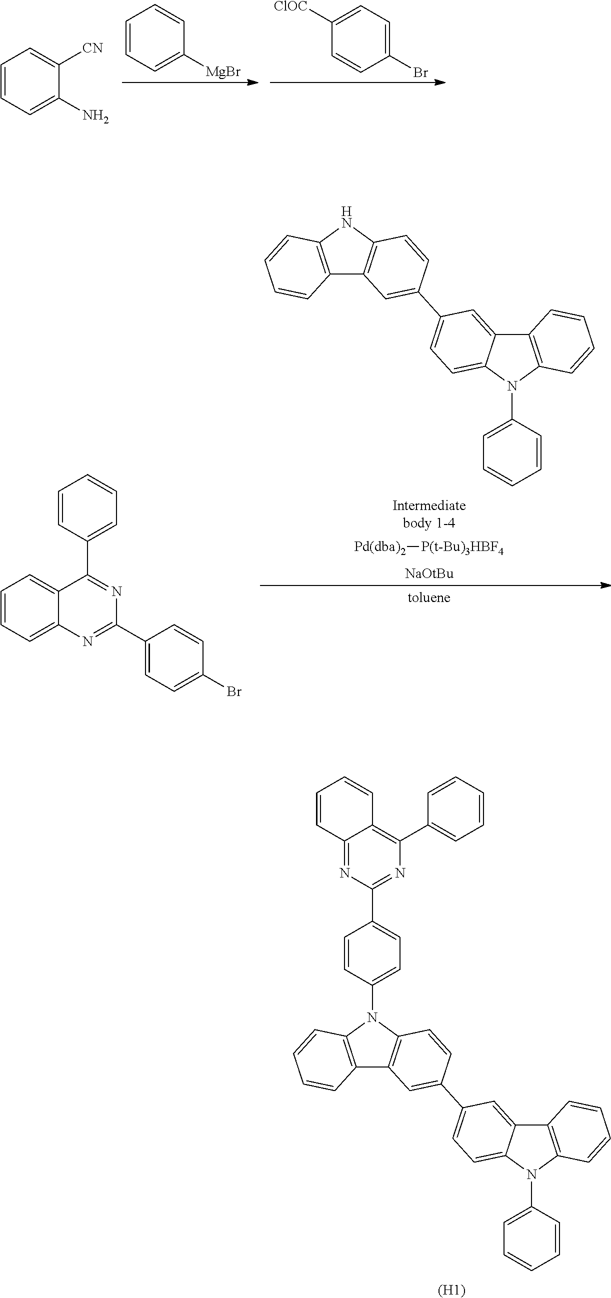

### [Synthesis of Red Phosphorescent Dopant Compound D8]

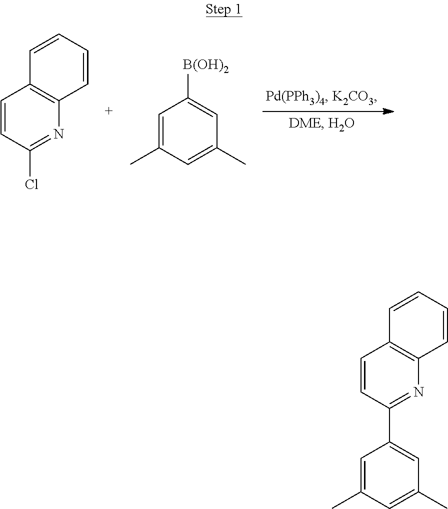

To a 500 mL round bottle flask, 9.0 g (−54.4 mmol) of 2-chloroquinoline, 9.2 g (59.8 mmol) of 3,5-dimethylphenylboronic acid, 1.8 g (1.5 mmol) of Tetrakis(triphenylphosphine)palladium, 22.4 g (163 mmol) Of K₂CO₃, 150 mL of 1,2-dimethoxyethane, and 150 mL of water were charged. The reaction mixture was heated to reflux under nitrogen overnight. The reaction mixture was cooled, and the organic extracts were purified by a silica gel column chromatography (10% ethyl acetate in hexane as eluent). The material obtained was further purified by vacuum distillation (Kugelrohr) at 185° C. to yield 12.2 g (95% yield) of product as a colorless liquid.

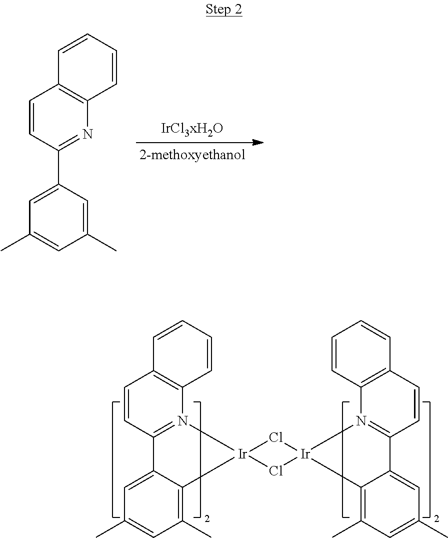

46 g (197.4 mmol) of the product from Step 1, 536 mL of 2-methoxyethanol, and 178 mL of water were charged in a 1000 mL three-neck flask. The reaction mixture was bubbled with nitrogen for 45 min with stirring. Then 32 g (86.2 mmol) of IrCl₃. H₂O was added into this mixture and heated to reflux (100-105° C.) under nitrogen for 17 hrs. The reaction mixture was cooled and filtered. The black-gray solid was washed with methanol (4×150 mL) followed by hexane (3×300 mL). 36.5 g of the dimer was obtained after drying in a vacuum oven. The dimer was used for the next step without further purification.

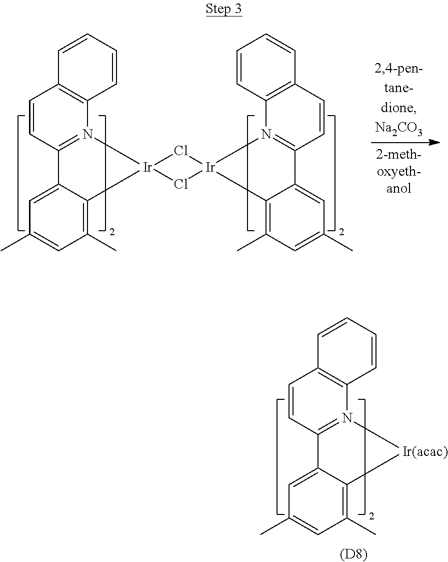

36 g of the dimer (26 mmol), 120 g of 2,4-pentanedione (−1200 mmol), 66 g (622 mmol) of sodium carbonate, and about 500 mL of 2-methoxyethanol were added in a 1000 mL round bottle flask. The reaction mixture was vigorously stirred at room temperature for 24 hrs. The reaction mixture was then suction filtered and washed with methanol (3×250 mL) followed by hexane (4×300 mL). The solid was collected and stirred in 1000 mL of a solvent mixture (900 mL of methylene chloride and 100 mL of triethylamine) for ˜10 min. Then the mixture was gravity filtered with a Whatman Quality 1 Circle filter paper. ˜20 g of red final product, Compound D8, (52% yield) was obtained after evaporating the solvent in the filtrate (99.5% pure with non-acidic HPLC column)

### [Synthesis of Red Phosphorescent Dopant Compound D9]

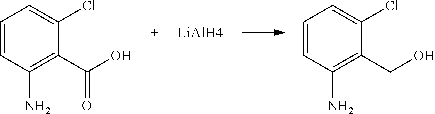 [SMILES: Nc1cccc(Cl)c1C(=O)O ; "LiAlH4" ; Nc1cccc(Cl)c1CO]

### Synthesis of (2-amino-6-chlorophenyl)methanol

2-Amino-6-chlorobenzoic acid (25.0 g, 143 mmol) was dissolved in 120 mL of anhydrous THF in a 500 mL 2 neck round bottom flask. The solution was cooled in an ice-water bath. 215 mL of 1.0 M lithium aluminum hydride (LAH) Tetrahydrofuran (THF) solution was then added dropwise. After all of the LAH was added, the reaction mixture was allowed to warm up to room temperature and then stirred at room temperature overnight. ˜10 mL of water was added to the reaction mixture followed by 7 g 15% NaOH. An additional 20 g of water was added to the reaction mixture. The organic THF phase was decanted and ˜200 mL of ethyl acetate was added to the solid with stirring. Na₂SO₄ was added as a drying agent to the combined ethyl acetate organic portion and THF portion. The mixture was filtered and evaporated. ˜20 g yellow solid was obtained and taken on to the next step without further purification.

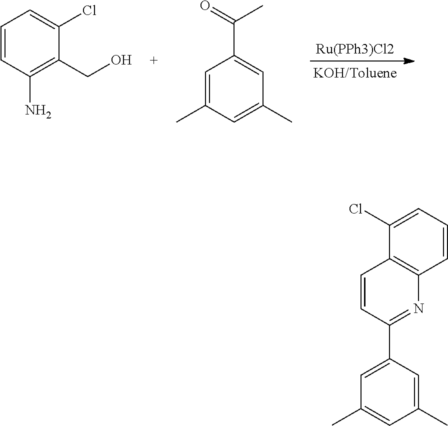

### Synthesis of 5-chloro-2-(3,5-dimethylphehyl)quinoline

(2-Amino-6-chlorophenyl)methanol (16 g, 102 mmol), 3,5-dimethylacetophenone (22.6 g, 152 mmol), RuCl₂(PPh₃)₃ (0.973 g, 1.015 mmol), and KOH (10.25 g, 183 mmol) were refluxed in 270 mL of toluene for 18 h. Water was collected from the reaction using a Dean-stark trap. The reaction mixture was allowed to cool to room temperature, filtered through a silica gel plug and eluted with 5% ethyl acetate in hexanes. The product was further purified by Kugelrohr distillation to give 23.5 g of crude product, which was crystallized from 60 mL of MeOH to give 8.6 g (32% yield) of the desired product.

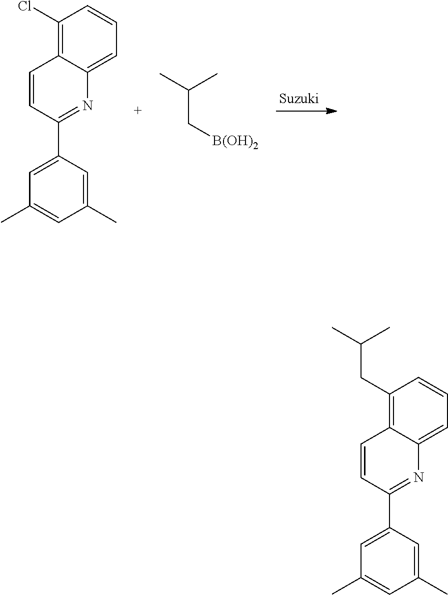

### Synthesis of 2-(3,5-dimethylphenyl)-5-isobutylquinoline

5-Chloro-2-(3,5-dimethylphenyl)quinoline (4.3 g, 16.06 mmol), isobutylboronic acid (3.2 g, 31.4 mmol), dicyclohexyl(2′,6′-dimethoxy-[1,1′-biphenyl]-2-yl)phosphine (0.538 g, 1.31 mmol), and potassium phosphate monohydrate (18.3 g, 79 mmol) were mixed in 114 mL of toluene. The system was degassed for 20 minutes. Pd₂(dba)₃ was then added and the system was refluxed overnight. After cooling to room temperature, the reaction mixture was filtered through a Celite® plug and eluted with dichloromethane. The product was further purified by a Kugelrohr distillation and then further purified by column chromatography using 5% ethyl acetate in hexanes. This was followed by another Kugelrohr distillation to give 3.2 g (72% yield) of product

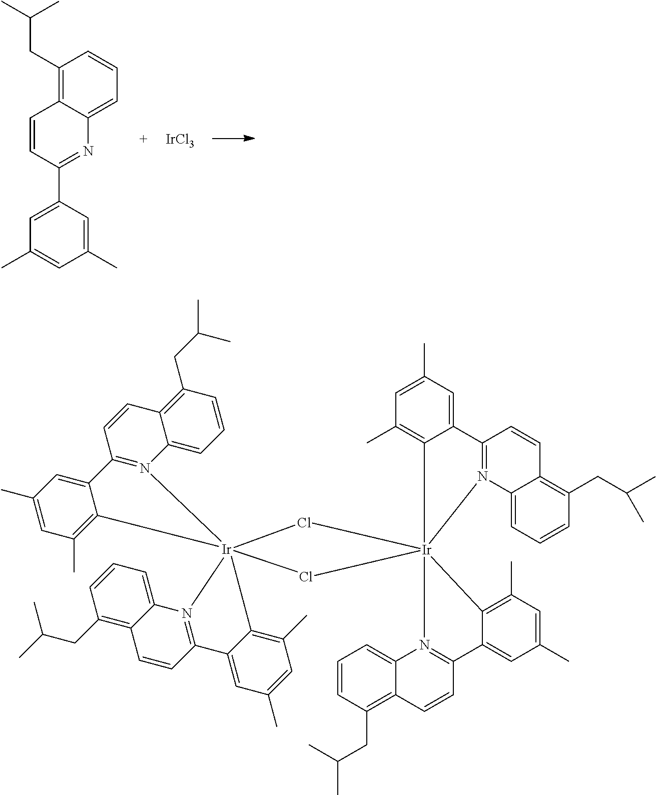

### Synthesis of Iridium Dimer

A mixture of 2-(3,5-dimethylphenyl)-5-isobutylquinoline (3.2 g, 11.06 mmol), IrCl₃.4H₂O (1.79 g, 4.83 mmol), 2-ethoxyethanol (45 mL) and water (105 mL) was refluxed under nitrogen overnight. The reaction mixture was filtered and washed with MeOH (3×10 mL). ˜2.9 g of dimer was obtained after vacuum drying. The dimer was used for the next step without further purification.

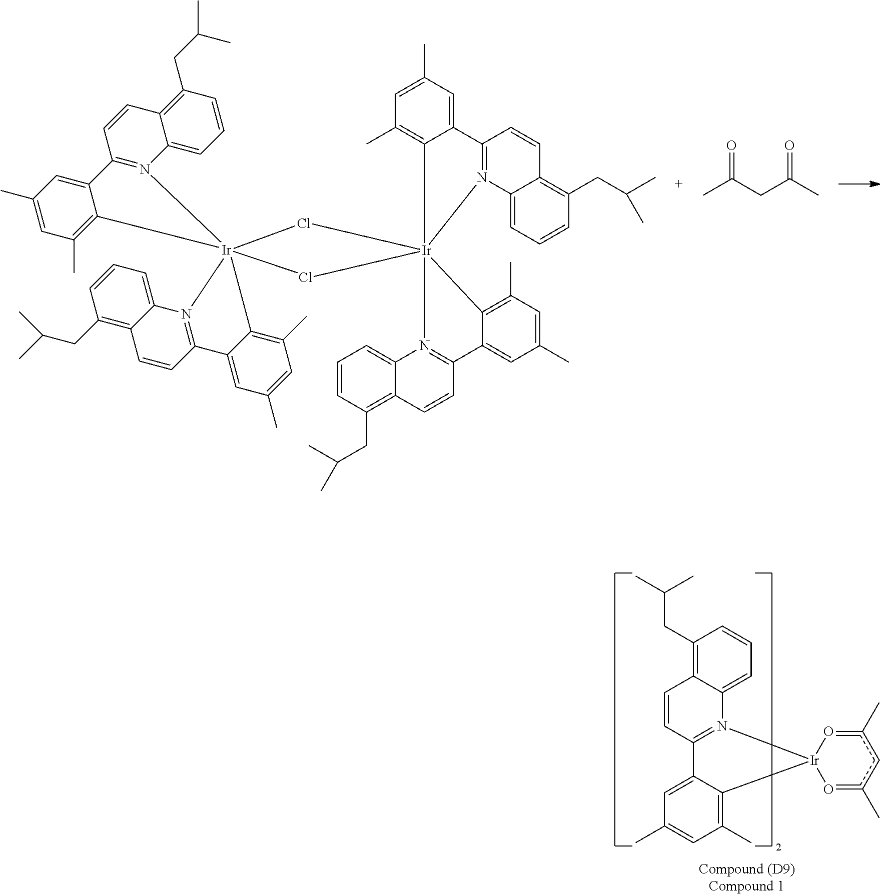

### Synthesis of Compound D9

Dimer (2.9 g, 1.80 mmol), pentane-2,4-dione (1.80 g, 18.02 mmol), K₂CO₃ (2.49 g, 18.02 mmol) and 2-ethoxyethanol (22 mL) were stirred at room temperature for 24 h. The precipitate was filtered and washed with methanol. The solid was further purified by passing it through a silica gel plug (that was pretreated with 15% triethylamine (TEA) in hexanes and eluted with methylene chloride. 2-Propanol was added to the filtrate. The filtrate was concentrated, but not to dryness. 1.6 g of product was obtained after filtration. The solid was sublimed twice under high vacuum at 240° C. to give 1.0 g (64%) of Compound D9.

### [Manufacture of Organic EL Device Example 1]

In Example 1, an organic EL device was manufactured as follows. A glass substrate (size: 25 mm×75 mm×1.1 mm thick, manufactured by Geomatec Co., Ltd.) having an ITO transparent electrode (anode, 130 nm thick) was ultrasonic-cleaned in isopropyl alcohol for five minutes, and then UV/ozone-cleaned for 30 minutes.

After the glass substrate having the transparent electrode line was cleaned, the glass substrate was mounted on a substrate holder of a vacuum deposition apparatus and a compound HI1 was evaporated to form a 20-nm thick HI1 film on the surface of the glass substrate where the transparent electrode line was provided so as to cover the transparent electrode. The HI1 film serves as a hole injection layer. The hole injection layer compound HI1 is represented by the following formula:

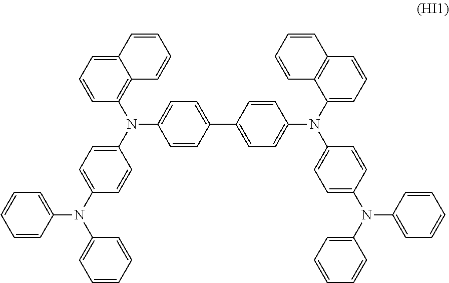 [SMILES: c1ccc(N(c2ccccc2)c2ccc(N(c3ccc(-c4ccc(N(c5ccc(N(c6ccccc6)c6ccccc6)cc5)c5cccc6ccccc56)cc4)cc3)c3cccc4ccccc34)cc2)cc1]

A compound HT1 was evaporated on the hole injection layer to form a 185-nm thick HT1 film that serves as a first hole transporting layer. Next, a compound HT2 was evaporated on the HT1 film to form a 20-nm thick HT2 film that serves as a second hole transporting layer. The first hole transporting layer compound HT1 is represented by the following formula:

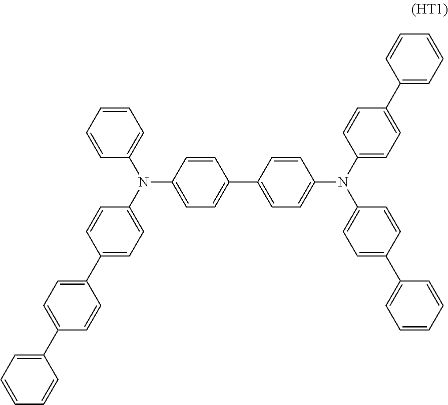 [SMILES: c1ccc(-c2ccc(-c3ccc(N(c4ccccc4)c4ccc(-c5ccc(N(c6ccc(-c7ccccc7)cc6)c6ccc(-c7ccccc7)cc6)cc5)cc4)cc3)cc2)cc1]

The second hole transporting layer compound HT2 is represented by the following formula:

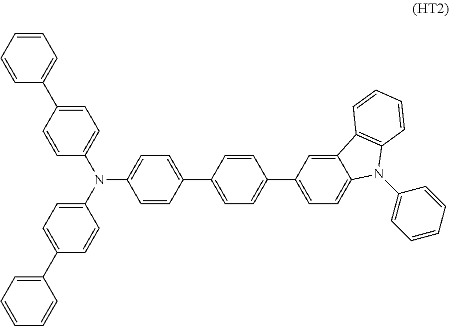 [SMILES: c1ccc(-c2ccc(N(c3ccc(-c4ccccc4)cc3)c3ccc(-c4ccc(-c5ccc6c(c5)c5ccccc5n6-c5ccccc5)cc4)cc3)cc2)cc1]

The host compound H1 and the red phosphorescent dopant material D8 were co-evaporated on the HT2 film. Thus, a 45-nm thick emitting layer for red emission was formed. The concentration of the phosphorescent dopant material was set at 10 mass % and the concentration of the host material was set at 90 mass %. A compound ET1 was evaporated on the emitting layer to form a 30-nm electron transporting layer. LiF was further evaporated at a rate of 1 Å/min on the electron transporting layer to form a 1-nm electron injecting layer. A metal Al was further evaporated on the electron injecting layer to form an 80-nm thick cathode. The electron transporting layer compound ET1 is represented by the following formula:

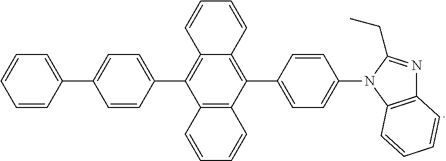 [SMILES: CCc1nc2ccccc2n1-c1ccc(-c2c3ccccc3c(-c3ccc(-c4ccccc4)cc3)c3ccccc23)cc1]

### [Evaluation of Organic EL Device Example 1]

The prepared organic EL devices were evaluated in terms of drive voltage, external quantum efficiency (EQE) and lifetime. The results are shown in Table 4.

Drive Voltage: Voltage was applied between ITO and Al such that a current density was 10 mA/cm2, where the voltage (unit: V) was measured.

External Quantum Efficiency EQE: Voltage was applied on each of the organic EL devices such that a current density was 10 mA/cm2, where spectral-radiance spectrum was measured using a spectroradiometer (CS-1000 manufactured by Konica Minolta Holdings, Inc.). The external quantum efficiency EQE (unit: %) was calculated from the obtained spectral-radiance spectrum, assuming that Lambertian radiation was carried out.

Lifetime: The devices were driven at constant current with the initial luminance intensity of 20,000 cd/m2, and time (LT₅₀) elapsed until the luminance intensity was decreased to 50% was obtained.

### Example 2 and Comparative Examples 1 to 4

In Example 2 and Comparative Examples 1 to 4, the organic EL devices were formed in the same manner as in Example 1 except that the materials used in Example 1 were replaced as summarized in Table 4. These organic EL devices were evaluated in the same manner as in Example 1. The results are shown in Table 4.

TABLE 4

| | | | Current | Volt- | | | | | | | | |
|---|---|---|---|---|---|---|---|---|---|---|---|---|
| | | | density | age | Luminance | L/J | η | EQE | CIE | | λₚ | LT₅₀@20,000 cd/m2 |
| | emitter | host | (mA/cm²) | (V) | (cd/m²) | (cd/A) | (lm/W) | (%) | x | y | (nm) | (hrs) |
| Example1 | RD002 | RHU-24 | 1 | 4.48 | 184 | 18.4 | 12.9 | 17.3 | 0.671 | 0.328 | 622 | 140 |
| | D8 | H1 | 10 | 7.45 | 1721 | 17.2 | 7.3 | 16.1 | 0.671 | 0.328 | 622 | |
| Comparative example1 | | CBP | 1 | 5.30 | 164 | 16.4 | 9.7 | 14.8 | 0.669 | 0.330 | 621 | 3 |
| | | | 10 | 8.58 | 1401 | 14.0 | 5.1 | 12.6 | 0.669 | 0.331 | 621 | |
| Example2 | RD004 | RHU-24 | 1 | 4.28 | 219 | 21.9 | 16.1 | 20.3 | 0.671 | 0.329 | 621 | 220 |
| | D9 | H1 | 10 | 7.15 | 2042 | 20.4 | 9.0 | 18.7 | 0.670 | 0.330 | 621 | |
| Comparative example2 | | CBP | 1 | 4.77 | 146 | 14.6 | 9.6 | 13.7 | 0.671 | 0.329 | 622 | 3 |
| | | | 10 | 7.63 | 1156 | 11.6 | 4.8 | 10.6 | 0.670 | 0.330 | 622 | |
| Comparative example3 | Ir(piq)3 | RHU-24 | 1 | 4.26 | 96 | 9.6 | 7.1 | 12.1 | 0.676 | 0.323 | 625 | _0_{—} |
| | | H1 | 10 | 7.09 | 929 | 9.3 | 4.1 | 11.6 | 0.676 | 0.323 | 625 | |
| Comparative example4 | | CBP | 1 | 5.61 | 64 | 6.4 | 3.6 | 8.0 | 0.676 | 0.323 | 624 | -0- |
| | | | 10 | 8.96 | 609 | 6.1 | 2.1 | 7.6 | 0.675 | 0.324 | 624 | |

Table 4 shows that the device Example 1 and device Example 2 whose emitting layer comprises the novel combination of emitter host material(s) and the red phosphorescent dopant material according to the present disclosure exhibited a significantly longer luminance half-life (LT₅₀) and a higher EQE and luminous efficiency (L/J) while being capable of lower voltage drive compared with the comparative example devices 1 to 4.

For example, the red PHOLED using the H1 host compound with red phosphorescent dopant material D8, (the device Example 1), exhibited EQE of 16.1% and a drive voltage of 7.45V at 10 mA/cm², and LT₅₀ of 140 hrs at 20,000 cd/m². In comparison, the comparative red PHOLED using CBP host compound with the red phosphorescent dopant material D8, (the Comparative example 1), exhibited EQE of 12.6% and a drive voltage of 8.54V at 10 mA/cm², and LT₅₀ of 3 hrs at 20,000 cd/m².

The red PHOLED using the H1 host compound with red phosphorescent dopant material D9, (the device Example 2), exhibited EQE of 18.7% and a drive voltage of 7.15V at 10 mA/cm², and LT₅₀ of 220 hrs at 20,000 cd/m². In comparison, the comparative red PHOLED using CBP host compound with the red phosphorescent dopant material D9, (the Comparative example 2), exhibited EQE of 10.6% and a drive voltage of 7.63V at 10 mA/cm², and LT₅₀ of 3 hrs at 20,000 cd/m². The comparative red PHOLED using the H1 host compound with Ir(piq)₃ as the phosphorescent dopant material, (the Comparative Example 3), exhibited EQE of 11.6% and a drive voltage of 7.09V at 10 mA/cm². The comparative red PHOLED using CBP host compound with Ir(piq)3 as the phosphorescent dopant material, (the Comparative Example 4), exhibited EQE of 7.6% and a drive voltage of 8.96V at 10 mA/cm². There are no LT₅₀ at 20,000 cd/m² data for the Comparative Example devices 3 and 4 utilizing Ir(piq)₃ as the phosphorescent dopant because they could not achieve 20,000 cd/m².

According to the embodiments of the present disclosure in which the emitting layer of the organic EL device comprises the combinations of the co-host materials and the phosphorescent dopant materials are expected to exhibit enhanced EQE, lower drive voltage and longer LT₅₀.

According to another aspect of the present disclosure, the scope of the invention described herein includes a lighting apparatus and/or display apparatus that incorporates one or more of the various embodiments of the organic electroluminescence devices described herein. Some examples of such display apparatus are television screens, computer display screens, mobile phone display screens, billboard screens, etc.

What is claimed is:

1. An organic electroluminescence device comprising:
a cathode; an anode; and a plurality of organic thin-film layers provided between the cathode and the anode, the plurality of organic thin-film layers comprising at least one emitting layer, wherein
at least one of the emitting layers comprising a red phosphorescent dopant material and a host material that is a biscarbazole derivative compound represented by a formula (1) below: 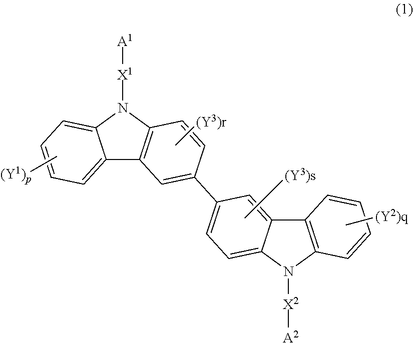
wherein A¹ represents a substituted or unsubstituted nitrogen-containing heterocyclic group having 1 to 30 ring carbon atoms;
A² represents a substituted or unsubstituted aromatic hydrocarbon group having 6 to 30 ring carbon atoms, or substituted or unsubstituted nitrogen-containing heterocyclic group having 1 to 30 ring carbon atoms;
X¹ and X² each are a linking group and independently represent a single bond, substituted or unsubstituted aromatic hydrocarbon group having 6 to 30 ring carbon atoms, substituted or unsubstituted fused aromatic hydrocarbon group having 6 to 30 ring carbon atoms, substituted or unsubstituted aromatic heterocyclic group having 2 to 30 ring carbon atoms, or substituted or unsubstituted fused aromatic heterocyclic group having 2 to 30 ring carbon atoms;
Y¹ to Y⁴ independently represent a hydrogen atom, fluorine atom, cyano group, substituted or unsubstituted alkyl group having 1 to 20 carbon atoms, substituted or unsubstituted alkoxy group having 1 to 20 carbon atoms, substituted or unsubstituted haloalkyl group having 1 to 20 carbon atoms, substituted or unsubstituted haloalkoxy group having 1 to 20 carbon atoms, substituted or unsubstituted alkylsilyl having 1 to 10 carbon atoms, substituted or unsubstituted arylsilyl having 6 to 30 carbon atoms, substituted or unsubstituted aromatic hydrocarbon group having 6 to 30 ring carbon atoms, substituted or unsubstituted fused aromatic hydrocarbon group having 6 to 30 ring carbon atoms, substituted or unsubstituted aromatic heterocyclic group having 2 to 30 ring carbon atoms, or substituted or unsubstituted fused aromatic heterocyclic group having 2 to 30 ring carbon atoms;
adjacent ones of Y¹ to Y⁴ are allowed to be bonded to each other to form a ring structure;
p and q represent an integer of 1 to 4; r and s represent an integer of 1 to 3; and
when p and q are an integer of 2 to 4 and r and s are an integer of 2 to 3, a plurality of Y¹ to Y⁴ are allowed to be the same or different;
wherein the red phosphorescent dopant material is a phosphorescent organometallic complex having a substituted chemical structure represented by one of the following partial chemical structures represented by the formulas (D1), (D2), and (D3): 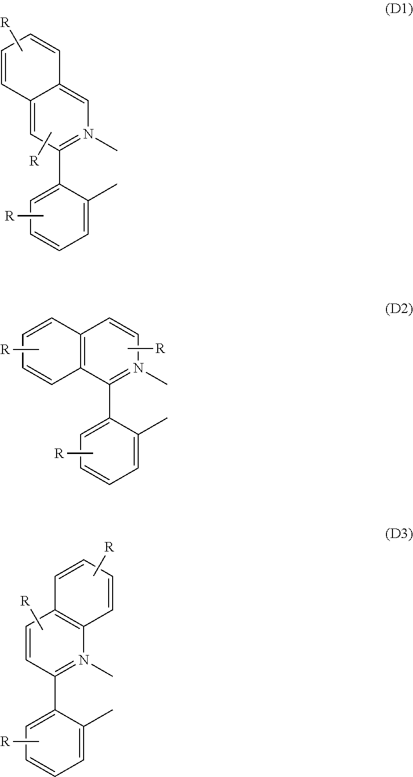
wherein each R is independently selected from the group consisting of H, alkyl, alkenyl, alkynyl, alkylaryl, CN, CF₃, CₙF₂ₙ₊₁, trifluorovinyl, CO₂R, C(O)R, NR₂, NO₂, OR, halo, aryl, heteroaryl, substituted aryl, substituted heteroaryl or a heterocyclic group.

2. The device of claim 1, wherein A¹ in formula (1) is selected from the group consisting of a substituted or unsubstituted pyridine ring, substituted or unsubstituted pyrimidine ring and substituted or unsubstituted triazine ring.

3. The device of claim 1, wherein A¹ in formula (1) is selected from a substituted or unsubstituted pyrimidine ring or substituted or unsubstituted triazine ring.

4. The device of claim 1, wherein A¹ in formula (1) is a substituted or unsubstituted pyrimidine ring.

5. The device of claim 1, wherein the biscarbazole derivative compound is a compound represented by a formula (2) below: 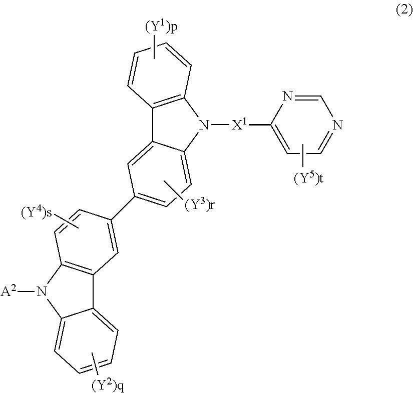
wherein A², X¹, Y¹ to Y⁴, p, q, r and s represent the same as A², X¹, Y¹ to Y⁴, p, q, r and s of the formula (1);
Y⁵ represents the same as Y¹ to Y⁴ of the formula (1);
t represents an integer in a range of 1 to 3; and
when t is an integer of 2 to 3, a plurality of Y⁵ are allowed to be the same or different.

6. The device of claim 1, wherein A¹ in formula (1) is a substituted or unsubstituted quinazoline ring.

7. The device of claim 1, further wherein the red phosphorescent dopant material is an iridium compound having a formula: 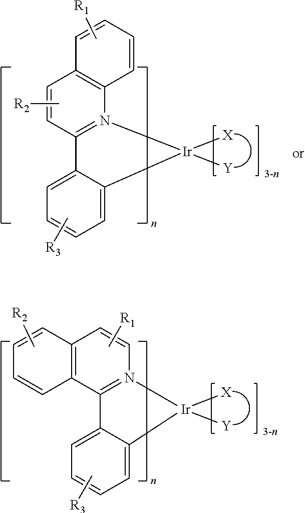
wherein n is 1, 2 or 3;
each of R₁, R₂, and R₃ is independently a hydrogen, or a mono-, di-, tri-, tetra-, or penta-substitution of alkyl or aryl, wherein R₃ is di-alkyl or di-aryl; and
X—Y is an ancillary ligand.

8. The device of claim 1, further wherein the red phosphorescent dopant material is an iridium compound having a formula: 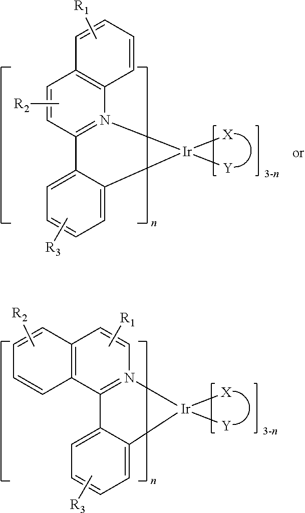
wherein n is 1, 2 or 3;
each of R₁, R₂, and R₃ is independently a hydrogen, or a mono-, di-, tri-, tetra-, or penta-substitution of alkyl or aryl;
at least one of R₁, R₂, and R₃ is a branched alkyl containing at least 4 carbon atoms; and
X—Y is an ancillary ligand.

9. The device of claim 1, wherein the host material is a biscarbazole derivative compound represented by a formula (H1) 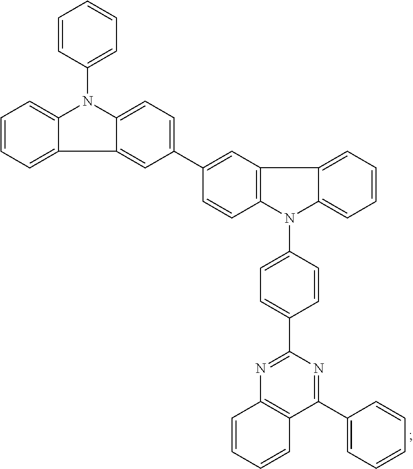 [SMILES: c1ccc(-c2nc(-c3ccc(-n4c5ccccc5c5cc(-c6ccc7c(c6)c6ccccc6n7-c6ccccc6)ccc54)cc3)nc3ccccc23)cc1]
and
the red phosphorescent dopant material is

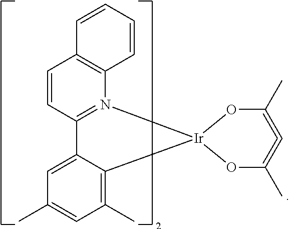

10. The device of claim 1, wherein the host material is a biscarbazole derivative compound represented by a formula (H1) 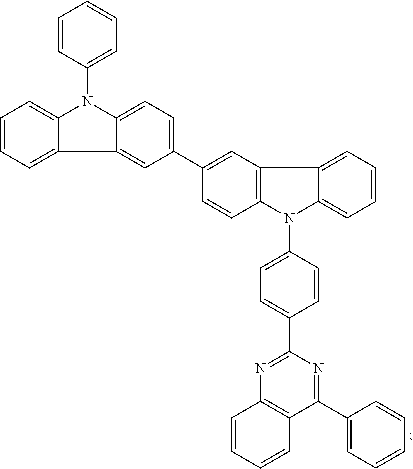 [SMILES: c1ccc(-c2nc(-c3ccc(-n4c5ccccc5c5cc(-c6ccc7c(c6)c6ccccc6n7-c6ccccc6)ccc54)cc3)nc3ccccc23)cc1]
and
the red phosphorescent dopant material is

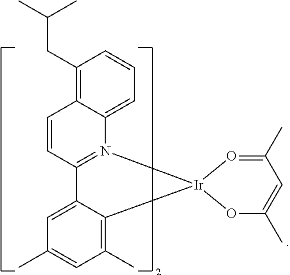

11. An organic electroluminescence device comprising: a cathode; an anode; and a plurality of organic thin-film layers provided between the cathode and the anode, the plurality of organic thin-film layers comprising at least one emitting layer, wherein
at least one of the emitting layers comprising a first host material, a second host material that is different from the first host material and a red phosphorescent emitter material, wherein the first host material is a biscarbazole derivative compound represented by a formula (1) below: 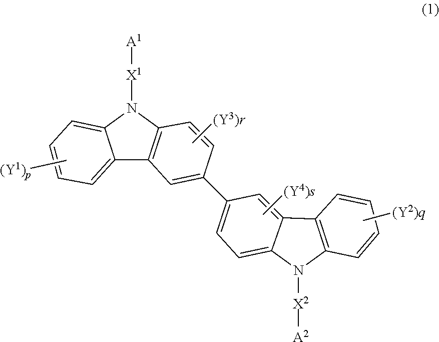
wherein A¹ represents a substituted or unsubstituted nitrogen-containing heterocyclic group having 1 to 30 ring carbon atoms;
A² represents a substituted or unsubstituted aromatic hydrocarbon group having 6 to 30 ring carbon atoms, or substituted or unsubstituted nitrogen-containing heterocyclic group having 1 to 30 ring carbon atoms;
X¹ and X² each are a linking group and independently represent a single bond, substituted or unsubstituted aromatic hydrocarbon group having 6 to 30 ring carbon atoms, substituted or unsubstituted fused aromatic hydrocarbon group having 6 to 30 ring carbon atoms, substituted or unsubstituted aromatic heterocyclic group having 2 to 30 ring carbon atoms, or substituted or unsubstituted fused aromatic heterocyclic group having 2 to 30 ring carbon atoms;
Y¹ to Y⁴ independently represent a hydrogen atom, fluorine atom, cyano group, substituted or unsubstituted alkyl group having 1 to 20 carbon atoms, substituted or unsubstituted alkoxy group having 1 to 20 carbon atoms, substituted or unsubstituted haloalkyl group having 1 to 20 carbon atoms, substituted or unsubstituted haloalkoxy group having 1 to 20 carbon atoms, substituted or unsubstituted alkylsilyl having 1 to 10 carbon atoms, substituted or unsubstituted arylsilyl having 6 to 30 carbon atoms, substituted or unsubstituted aromatic hydrocarbon group having 6 to 30 ring carbon atoms, substituted or unsubstituted fused aromatic hydrocarbon group having 6 to 30 ring carbon atoms, substituted or unsubstituted aromatic heterocyclic group having 2 to 30 ring carbon atoms, or substituted or unsubstituted fused aromatic heterocyclic group having 2 to 30 ring carbon atoms;
adjacent ones of Y¹ to Y⁴ are allowed to be bonded to each other to form a ring structure;
p and q represent an integer of 1 to 4; r and s represent an integer of 1 to 3; and
when p and q are an integer of 2 to 4 and r and s are an integer of 2 to 3, a plurality of Y¹ to Y⁴ are allowed to be the same or different;
wherein the red phosphorescent emitter material is a phosphorescent organometallic complex having a substituted chemical structure represented by one of the following partial chemical structures represented by the formulas (D1), (D2), and (D3): 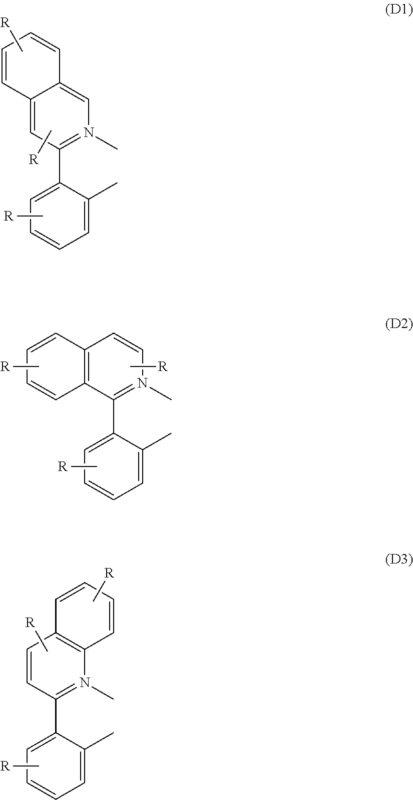
wherein each R is independently selected from the group consisting of H, alkyl, alkenyl, alkynyl, alkylaryl, CN, CF₃, CₙF₂ₙ₊₁, trifluorovinyl, CO₂R, C(O)R, NR₂, NO₂, OR, halo, aryl, heteroaryl, substituted aryl, substituted heteroaryl or a heterocyclic group.

12. The device of claim 11, wherein A¹ in formula (1) is selected from the group consisting of a substituted or unsubstituted pyridine ring, substituted or unsubstituted pyrimidine ring and substituted or unsubstituted triazine ring.

13. The device of claim 11, wherein A¹ in formula (1) is selected from a substituted or unsubstituted pyrimidine ring or substituted or unsubstituted triazine ring.

14. The device of claim 11, wherein A¹ in formula (1) is a substituted or unsubstituted pyrimidine ring.

15. The device of claim 11, wherein the first host material is a biscarbazole derivative compound represented by a formula (2) below: 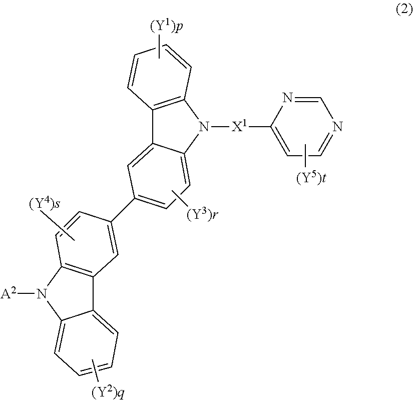
wherein A², X¹, Y¹ to Y⁴, p, q, r and s represent the same as A², X¹, Y¹ to Y⁴, p, q, r and s of the formula (1);
Y⁵ represents the same as Y¹ to Y⁴ of the formula (1);
t represents an integer in a range of 1 to 3; and
when t is an integer of 2 to 3, a plurality of Y⁵ are allowed to be the same or different.

16. The device of claim 11, wherein A¹ in formula (1) is a substituted or unsubstituted quinazoline ring.

17. The device of claim 16, further wherein the red phosphorescent emitter material is an iridium compound having the formula: 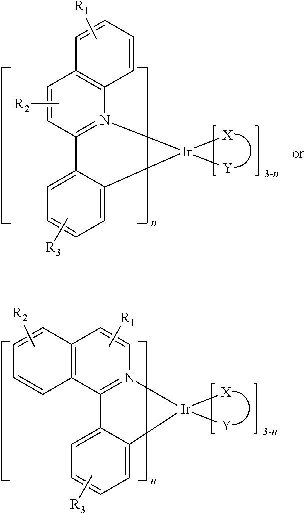
wherein n is 1, 2 or 3;
each of R₁, R₂, and R₃ is independently a hydrogen, or a mono-, di-, tri-, tetra-, or penta-substitution of alkyl or aryl, wherein R₃ is di-alkyl or di-aryl; and
X—Y is an ancillary ligand.

18. The device of claim 16, further wherein the red phosphorescent emitter material is an iridium compound having the formula: 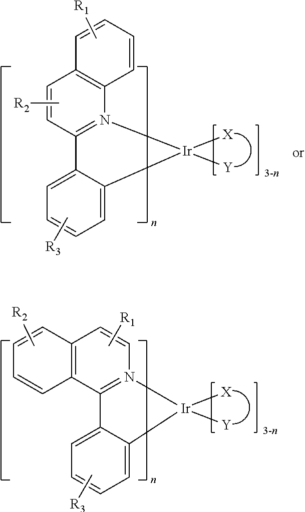
wherein n is 1, 2 or 3;
each of R₁, R₂, and R₃ is independently a hydrogen, or a mono-, di-, tri-, tetra-, or penta-substitution of alkyl or aryl;
at least one of R₁, R₂, and R₃ is a branched alkyl containing at least 4 carbon atoms; and
X—Y is an ancillary ligand.

19. The device of claim 11, wherein the first host material is a biscarbazole derivative compound represented by a formula H1 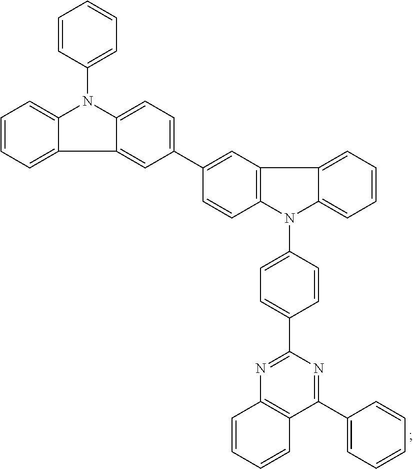 [SMILES: c1ccc(-c2nc(-c3ccc(-n4c5ccccc5c5cc(-c6ccc7c(c6)c6ccccc6n7-c6ccccc6)ccc54)cc3)nc3ccccc23)cc1]
and
the red phosphorescent dopant material is

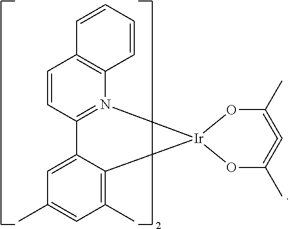

20. The device of claim 11, wherein the first host material is a biscarbazole derivative compound represented by a formula H1 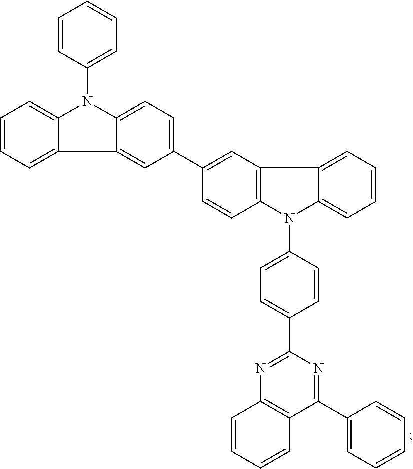 [SMILES: c1ccc(-c2nc(-c3ccc(-n4c5ccccc5c5cc(-c6ccc7c(c6)c6ccccc6n7-c6ccccc6)ccc54)cc3)nc3ccccc23)cc1]
and
the red phosphorescent dopant material is [chemical structure]
